(19) United States
(12) Patent Application Publication
(10) Pub. No.: US 2019/0369315 A1
(43) Pub. Date: Dec. 5, 2019

(54) RETARDATION FILM, ELLIPTICALLY POLARIZING PLATE, AND DISPLAY DEVICE USING THE SAME

(71) Applicant: DIC Corporation, Tokyo (JP)

(72) Inventors: Kouichi Endo, Kita-adachi-gun (JP); Kazuaki Hatsusaka, Kita-adachi-gun (JP); Mika Takasaki, Kita-adachi-gun (JP)

(73) Assignee: DIC Corporation, Tokyo (JP)

(21) Appl. No.: 16/349,378

(22) PCT Filed: Nov. 7, 2017
(86) PCT No.: PCT/JP2017/040048

§ 371 Date: May 13, 2019

(30) Foreign Application Priority Data
Nov. 11, 2016 (JP) 2016-220529

(51) Int. Cl. G02B 5/30; C08F 222/10; C08J 5/18; H01L 51/52; H01L 27/32

(52) U.S. Cl. CPC G02B 5/305; C08F 222/1006; C08J 5/18; H01L 51/5293; C08J 2335/02; C08F 2800/20; C08F 2222/102; C08F 2222/1033; H01L 27/32

(57) ABSTRACT

The optical film (retardation film) has a good antireflection ability not only in a direction perpendicular to the film but also over a wide angle range and provides an optical film that can maintain its ability even after the film is subjected to high temperature. It can provide an elliptically polarizing plate and a display device that use the optical film. The optical film includes a first retardation layer and a second retardation layer. The first retardation layer is formed of a cured product of a polymerizable composition containing at least one compound A having at least three polymerizable groups and satisfying (formula 1) and at least one compound B satisfying (formula 2). The second retardation layer is formed of a cured product of a polymerizable composition containing at least one compound satisfying (formula 1) and/or at least one compound B satisfying (formula 2).

### TECHNICAL FIELD

A conventional quarter waveplate including one retardation plate can produce a retardation of a quarter of a wavelength only at specific wavelengths. When such a quarter waveplate is used as an antireflection filter for preventing surface reflection from, for example, a display, sufficient antireflection performance is not obtained at wavelengths other than the specific wavelengths at which a retardation of a quarter of a wavelength is produced, and this disadvantageously results in poor viewability. Specifically, the display is colored in blue, purple, red, etc.

To address this problem, several retardation plates have been proposed (PTL 1 to PTL 3). Specifically, a plurality of retardation plates are stacked such that their optical axes cross each other. For example, PTL 2 reports the following. The wavelength characteristics of a retardation plate are defined using a retardation ratio Re(450)/Re(550) of a retardation Re(450) at a wavelength of 450 nm to a retardation Re(550) at a wavelength of 550 nm. In a retardation plate including two stacked retardation plates, good antireflection performance is obtained when the retardation ratio of one of the retardation plates is 1.16 and the retardation ratio of the other retardation plate is 1.025. PTL 3 reports that, in a retardation plate including two stacked retardation plates with a retardation ratio of 1.005, good antireflection performance is obtained.

However, in each of the retardation plates in PTL 1 to PTL 3, a wavelength range in which a retardation of a quarter of a wavelength is produced is not sufficiently wide. Even when a circularly polarizing plate is produced by stacking a polarizing plate on the retardation plate, the improvement in the viewability of, for example, a display including the retardation plate or the circularly polarizing plate is insufficient because the wavelength range in which good antireflection performance is obtained is not sufficiently wide. Specifically, when, for example, the display is viewed at an angle, a slight amount of unpreventable reflected light always occurs. The problem in this case is that the slight amount of the reflected light is not colorless but is colored in blue, violet, red, etc. The coloration means that the surroundings of the viewer, particularly a fluorescent lamp and the sun, are reflected as blue, violet, or red glare on the display, and this is a significantly serious problem in terms of the viewability of the display etc.

In each of PTL 1 to PTL 3, stretched films having a thickness of several tens of micrometers are stacked, so that the thickness of the retardation plate stack is 150 to 200 μm. This is disadvantageous because the thickness of the retardation plate is excessively large for displays etc. that are constantly required to be reduced in thickness.

Moreover, in each of PTL 1 to PTL 3, a stretched film in which its slow axis is fixed in the stretching direction is used. The problem in this case is that, in the step of stacking the retardation plate and the polarizing plate such that the slow axis of the retardation plate crosses the transmission axis of the polarizing plate, a sheet-fed method with poor production efficiency must be used.

PTL 4 shows a retardation plate that uses a compound having reverse wavelength dispersion characteristics and useful for a wide-band retardation plate. However, when only this retardation plate is used, the value of the retardation of obliquely incident light deviates, and this disadvantageously causes deterioration in viewing angle characteristics.

Displays used for smartphones etc. are often required to have high reliability and required to show almost no change in optical characteristics even after the displays are left to stand at high temperature.

### CITATION LIST

### Patent Literature

PTL 1: Japanese Unexamined Patent Application Publication No. 10-68816

PTL 2: Japanese Unexamined Patent Application Publication No. 10-90521

PTL 3: Japanese Unexamined Patent Application Publication No. 11-52131

PTL 4: Japanese Unexamined Patent Application Publication No. 2002-267838

### SUMMARY OF INVENTION

### Technical Problem

It is an object of the present invention to provide an optical film (retardation film) that has a high antireflection ability not only in a direction perpendicular to the film but also over a wide angle range, to provide an optical film that can maintain its ability even after the film is subjected to high temperature, and to provide an elliptically polarizing plate and a display device that use these optical films.

### Solution to Problem

As a result of repeated extensive studies conducted in order to achieve the above object, the present invention is provided.

Accordingly, the present invention provides an optical film including a first retardation layer and a second retardation layer, wherein the first retardation layer is formed of a cured product of a polymerizable composition containing at least one compound A having at least three polymerizable groups and satisfying (formula 1) below and at least one compound B satisfying (formula 2) below,

wherein the second retardation layer is formed of a cured product of a polymerizable composition containing at least one compound satisfying (formula 1) below and/or at least one compound B satisfying (formula 2) below:

Re(450)/Re(550)<1, (formula 1)

Re(450)/Re(550)>1, (formula 2)

(wherein Re(450) represents an in-plane retardation at a wavelength of 450 nm when a compound used is formed into a film, and Re(550) represents an in-plane retardation at a wavelength of 550 nm when the compound used is formed into the film), and

wherein the first retardation layer satisfies nx>ny≅nz, and the second retardation layer satisfies nx≅ny<nz (where nz represents a refractive index in a thickness direction; nx represents an in-plane refractive index in an in-plane direction in which the in-plane refractive index is maximum; and ny represents an in-plane refractive index in an in-plane direction orthogonal to the direction for nx).

The present invention also provides an elliptically polarizing plate, a display device, and an organic light-emitting display device that use the above optical film.

### Advantageous Effects of Invention

The optical film of the present invention has optical characteristics suitable for the antireflection ability and can therefore reduce surface reflection from display devices. In particular, when the optical film is used for organic EL displays, good viewability can be obtained. Even after the optical film is subjected to high temperature, its characteristics and ability can be maintained, and therefore the optical film is best suitable for display devices for outdoor use etc.

### DESCRIPTION OF EMBODIMENTS

Best modes of the optical film of the present invention will be described.

The optical film of the present invention is an optical film including a first retardation layer and a second retardation layer, wherein the first retardation layer is formed of a cured product of a polymerizable composition containing at least one compound A having at least three polymerizable groups and satisfying (formula 1) below and at least one compound B satisfying (formula 2) below,

wherein the second retardation layer is formed of a cured product of a polymerizable composition containing at least one compound satisfying (formula 1) below and/or at least one compound B satisfying (formula 2) below:

Re(450)/Re(550)<1, (formula 1)

Re(450)/Re(550)>1, (formula 2)

(wherein Re(450) represents an in-plane retardation at a wavelength of 450 nm when a compound used is formed into a film, and Re(550) represents an in-plane retardation at a wavelength of 550 nm when the compound used is formed into the film), and

wherein the first retardation layer satisfies nx>ny≅nz, and the second retardation layer satisfies nx≅ny<nz (where nz represents a refractive index in a thickness direction; nx represents an in-plane refractive index in an in-plane direction in which the in-plane refractive index is maximum; and ny represents an in-plane refractive index in an in-plane direction orthogonal to the direction for nx).

### (Compound A)

In the optical film of the present invention, the first retardation layer contains at least one compound A having at least three polymerizable groups and satisfying the following (formula 1).

Re(450)/Re(550)<1 (formula 1)

(wherein Re(450) represents an in-plane retardation at a wavelength of 450 nm when the compound used is formed into a film, and Re(550) represents an in-plane retardation at a wavelength of 550 nm when the compound used is formed into the film)

Preferably a polymerizable liquid crystal compound represented by general formula (9) is used as the compound A. In the present invention, the “liquid crystalline compound” is intended to mean a compound having a mesogenic skeleton, and it is not necessary for the compound alone to exhibit liquid crystallinity. The term polymerizable means that polymerization (formation of a film) is possible through polymerization treatment by irradiation with light such as UV rays or heating.

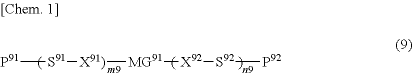

(in general formula (9), P⁹¹ and P⁹² each independently represent a polymerizable group;

S⁹¹ and S⁹² each independently represent a spacer group or a single bond; when a plurality of S⁵¹s and S⁹²s are present, they may be the same or different;

X⁹¹ and X⁹² each independently represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that P⁹¹—(S⁹¹—X⁹¹)— and P⁹²—(S⁹²—X⁹²)— contain no —O—O— bond); when a plurality of X⁹¹s and X⁹²s are present, they may be the same or different;

m9 and n9 each independently represent an integer from 0 to 5;

MG⁹¹ represents general formula (a9):

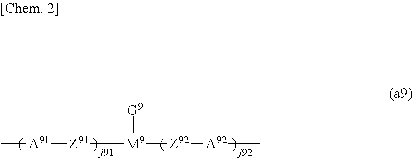

(in general formula (a9), A⁹¹ and A⁹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, each of which may be unsubstituted or substituted by at least one L¹; when a plurality of A⁹'s and/or A⁹²s are present, they may be the same or different;

in general formula (a9), Z⁹¹ and Z⁹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond; when a plurality of Z⁹¹s and/or Z⁹²s are present, they may be the same or different;

in general formula (a9), M⁹ represents a group selected from formula (M-91) to formula (M-101) below:

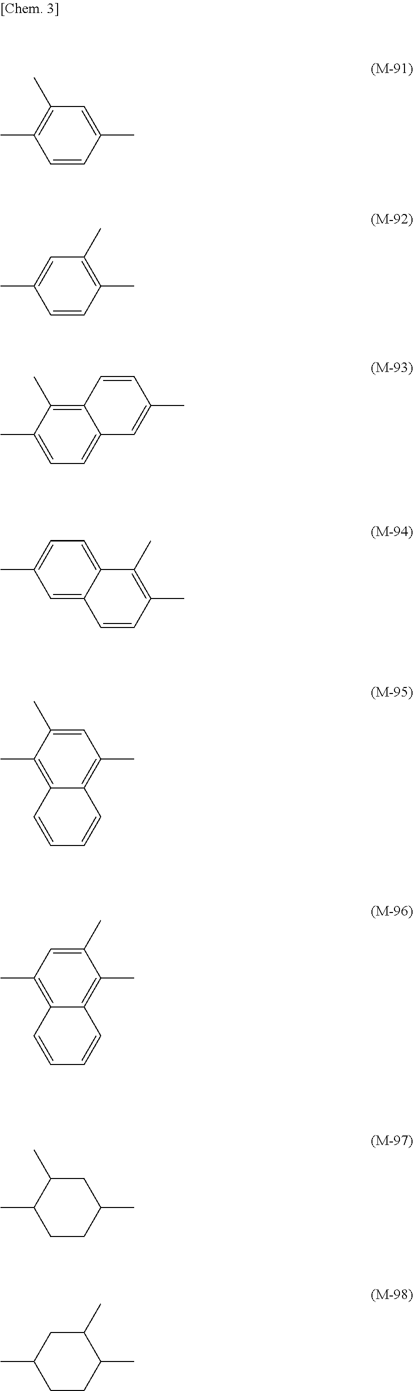

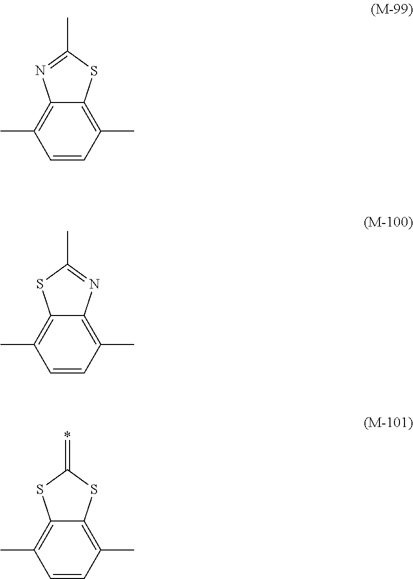

the groups represented by formula (M-91) to formula (M-101) may be unsubstituted or substituted by at least one L¹;

in general formula (a9), G⁹ represents a group selected from general formula (G-91) to general formula (G-95) below:

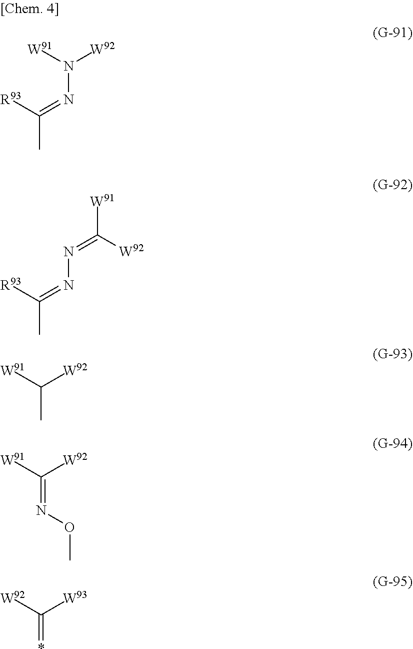

(wherein R⁹³ represents a hydrogen atom or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by —O—, —S—, —CO—, —COO—, —OCO—, —CO—S—, —S—CO—, —O—CO—O—, —CO—NH—, —NH—CO—, or —C≡C—);

W⁹¹ represents a group that has at least one aromatic group and has 5 to 30 carbon atoms and that may be unsubstituted or substituted by at least one L¹;

W⁹² represents a group represented by P⁹³—(S⁹³—X⁹³)ⱼ₉₃—; P⁹³ represents a polymerizable group; X⁹³ represents a spacer group or a single bond; when a plurality of S⁹³s are present, they may be the same or different; X⁹³ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that P⁹³—(S⁵³—X⁹³)ⱼ₉₃— contains no —O—O— bond); when a plurality of X⁹³s are present, they may be the same or different; j93 represents an integer from 1 to 10;

W⁹³ represents a halogen atom, a cyano group, a hydroxy group, a nitro group, a carboxyl group, a carbamoyloxy group, an amino group, a sulfamoyl group, a group having at least one aromatic group and having 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— group or two or more nonadjacent —CH₂— groups in each of the alkyl group, the cycloalkyl group, the alkenyl group, the cycloalkenyl group, the alkoxy group, the acyloxy group, and the alkylcarbonyloxy group being each independently optionally replaced by —O—, —S—, —CO—, —COO—, —OCO—, —CO—S—, —S—CO—, —O—CO—O—, —CO—NH—, —NH—CO—, or —C≡C—;

when M⁹ is selected from formula (M-91) to formula (M-100), G⁹ is selected from formula (G-91) to formula (G-94); when M⁹ represents formula (M-101), G⁹ represents formula (G-95); * in each of M⁹ and G⁹ represents a bonding portion; one of two bonds in M⁹ other than * is bonded to Z⁹¹ or A⁹¹ present; the other one of the two bonds is bonded to Z⁹² or A⁹² present;

L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C≡C—; when a plurality of L's are present in the compound, they may be the same or different;

j91, j92, and j93 each independently represent an integer from 1 to 5; and j91+j92 represents an integer from 2 to 6.))

In general formula (9), it is preferable that the polymerizable groups P⁹¹ and P⁹² each independently represent a group selected from formula (P-1) to formula (P-20) below.

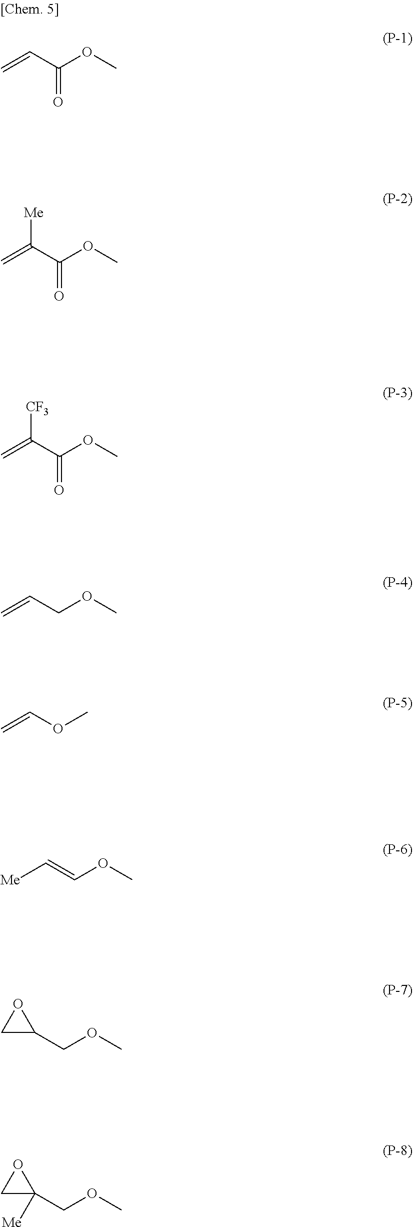

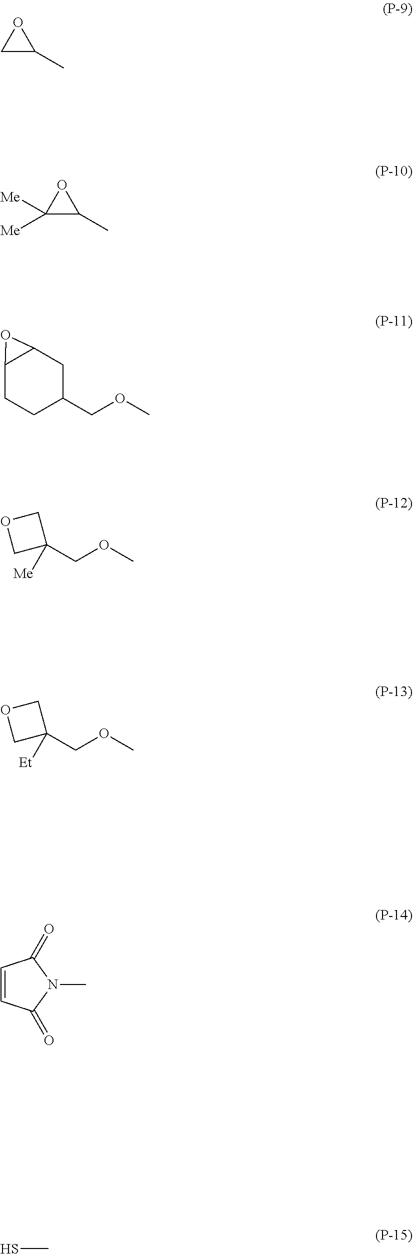

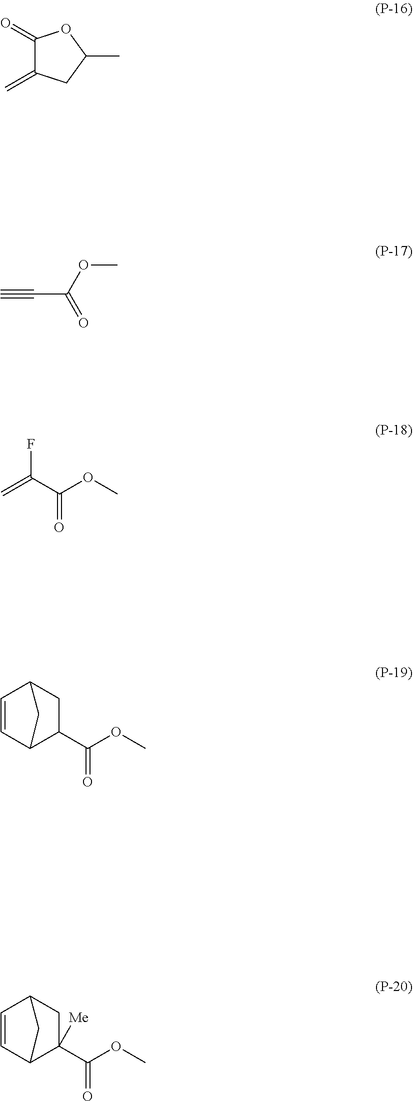

These polymerizable groups are polymerized by radical polymerization, radical addition polymerization, cationic polymerization, or anionic polymerization. In particular, when the polymerization method is UV polymerization, formula (P-1), formula (P-2), formula (P-3), formula (P-4), formula (P-5), formula (P-7), formula (P-11), formula (P-13), formula (P-15), or formula (P-18) is preferable, and formula (P-1), formula (P-2), formula (P-7), formula (P-11), or formula (P-13) is more preferable. Formula (P-1), formula (P-2), or formula (P-3) is still more preferable, and formula (P-1) or formula (P-2) is particularly preferable.

In general formula (9), S⁹¹ and S⁹² each independently represent a spacer group or a single bond. When a plurality of S⁹¹s and S⁹s are present, they may be the same or different. Preferably, the spacer group represents an alkylene group which has 1 to 20 carbon atoms and in which one —CH₂— group or two or more nonadjacent —CH₂— groups may be each independently replaced by —O—, —COO—, —OCO—, —OCO—O—, —CO—NH—, —NH—CO—, —CH═CH—, —C≡C—, or formula (S-1) below.

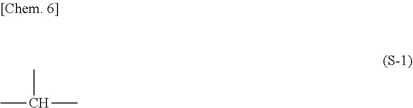

When a plurality of S⁹¹s and S⁹²s are present, they may be the same or different and more preferably each independently represent a single bond or an alkylene group which has 1 to 10 carbon atoms and in which one —CH₂— group or two or more nonadjacent —CH₂— groups may be each independently replaced by —O—, —COO—, or —OCO—, in terms of availability of raw materials and ease of synthesis. Still more preferably, S⁹¹ and S⁹² each independently represent a single bond or an alkylene group having 1 to 10 carbon atoms. When a plurality of S⁹¹s and S⁹²s are present, they may be the same or different and particularly preferably each independently represent an alkylene group having 1 to 8 carbon atoms.

In general formula (9), X⁹¹ and X⁹² each independently represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that P⁹¹—(S⁹¹—X^{9′})— and P⁹²—(S⁹—X⁹²)— contain no —O—O— bond). When a plurality of X⁹¹s and X⁹²s are present, they may be the same or different. In terms of availability of raw materials and ease of synthesis, when a plurality of X⁹¹s and X⁹²s are present, they may be the same or different and preferably each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond. More preferably, X⁹¹ and X⁹² each independently represent —O—, —OCH₂—, —CH₂O—, —COO—, —OCO—, —COO—CH₂CH₂—, —OCO—CH₂CH₂—, —CH₂CH₂—COO—, —CH₂CH₂—OCO—, or a single bond. When a plurality of X⁹¹s and X⁹²s are present, they may be the same or different and particularly preferably each independently represent —O—, —COO—, —OCO—, or a single bond.

In general formula (9), m9 and n9 each independently represent an integer from 0 to 5. In terms of liquid crystallinity, availability of raw materials, and ease of synthesis, m9 and n9 preferably each independently represent an integer from 0 to 4, more preferably each independently represent an integer from 0 to 2, still more preferably each independently represent 0 or 1, and particularly preferably each represent 1.

In general formula (a9), A⁹¹ and A⁹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, each of which may be unsubstituted or substituted by at least one L¹. When a plurality of A⁹¹s and/or A⁹²s are present, they may be the same or different. In terms of availability of raw materials and ease of synthesis, A⁹¹ and A⁹² preferably each independently represent a 1,4-phenylene group, a 1,4-cyclohexylene group, or naphthalene-2,6-diyl, each of which may be unsubstituted or substituted by at least one L¹, more preferably each independently represent a group selected from formula (A-1) to formula (A-11) below:

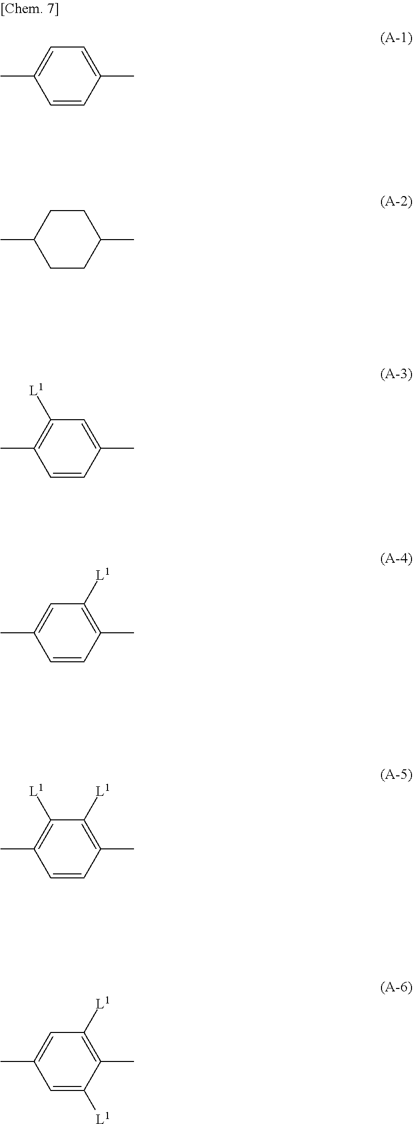

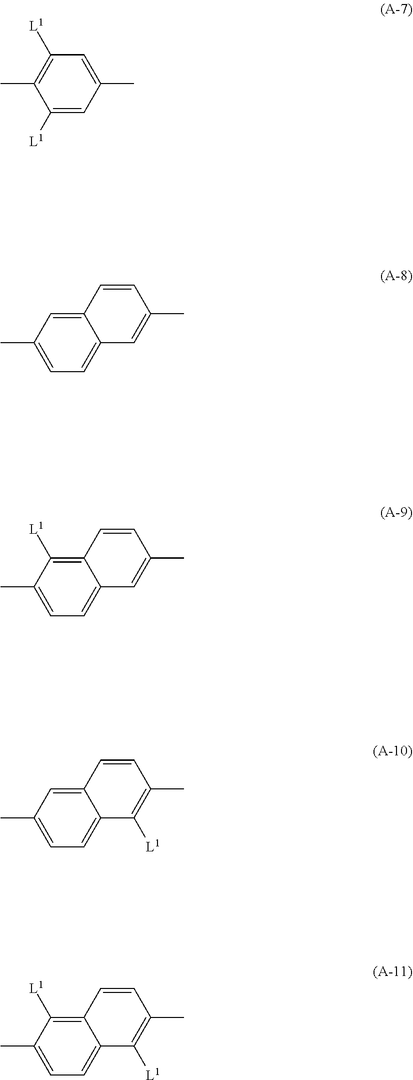

still more preferably each independently represent a group selected from formula (A-1) to formula (A-8), and particularly preferably each independently represent a group selected from formula (A-1) to formula (A-4).

In general formula (a9), Z⁹¹ and Z⁹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond. When a plurality of Z⁹¹s and/or Z⁹²s are present, they may be the same or different. In terms of the liquid crystallinity of the compound, availability of raw materials, and ease of synthesis, Z⁹¹ and Z⁹² preferably each independently represent —OCH₂—, —CH₂O—, —COO—, —OCO—, —CF₂O—, —OCF₂—, —CH₂CH₂—, —CF₂CF₂—, —CH═CH—COO—, —CH═CH—OCO—, —COO—CH═CH—, —OCO—CH═CH—, —COO—CH—CH₂—, —OCO—CH—CH₂—, —CH₂CH₂—COO—, —CH₂CH₂—OCO—, —CH═CH—, —CF═CF—, —C≡C—, or a single bond, more preferably each independently represent —OCH₂—, —CH₂O—, —CH₂CH₂—, —COO—, —OCO—, —COO—CH₂CH₂—, —OCO—CH₂CH₂—, —CH₂CH₂—COO—, —CH₂CH₂—OCO—, —CH═CH—, —C≡C—, or a single bond, still more preferably each independently represent —OCH₂—, —CH₂O—, —CH₂CH₂—, —COO—, —OCO—, —COO—CH₂CH₂—, —OCO—CH₂CH—, —CH₂CH₂—COO—, —CH₂CH₂—OCO—, or a single bond, and particularly preferably each independently represent —OCH₂—, —CH₂O—, —CH₂CH₂—, —COO—, —OCO—, or a single bond.

In general formula (a9), M⁹ represents a group selected from formula (M-91) to formula (M-101) below.

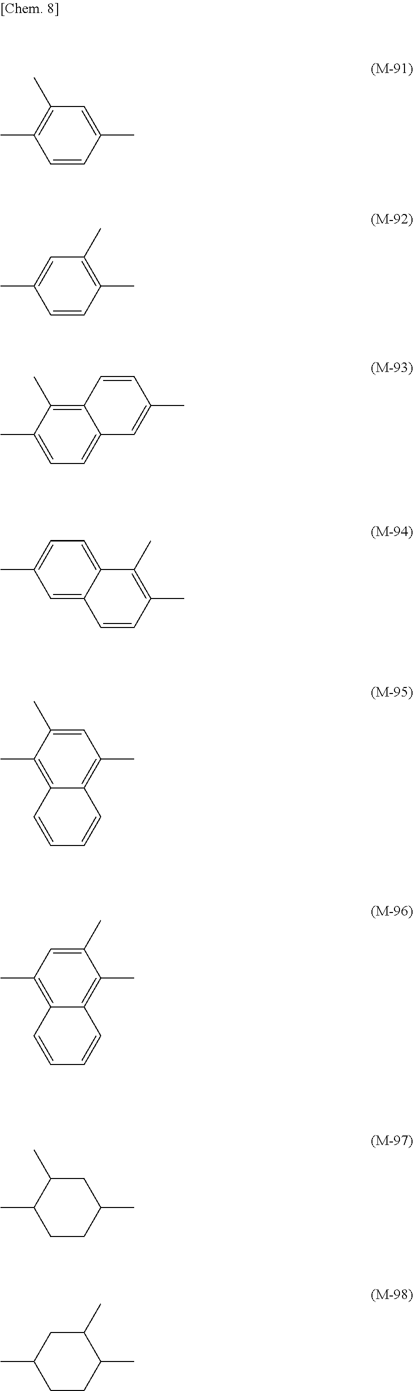

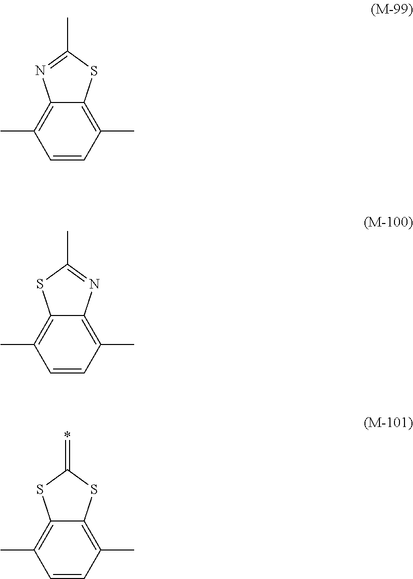

These groups may be unsubstituted or substituted by at least one L¹. In terms of availability of raw materials and ease of synthesis, M⁹ preferably represents a group selected from formula (M-91) and formula (M-92) that may be unsubstituted or substituted by at least one L¹ and formula (M-93) to formula (M-96) that are unsubstituted, more preferably represents a group selected from formula (M-91) and formula (M-92) that may be unsubstituted or substituted by at least one L¹, and particularly preferably represents a group selected from formula (M-91) and formula (M-92) that are unsubstituted.

In general formula (a9), G⁹ represents a group selected from general formula (G-91) to general formula (G-95).

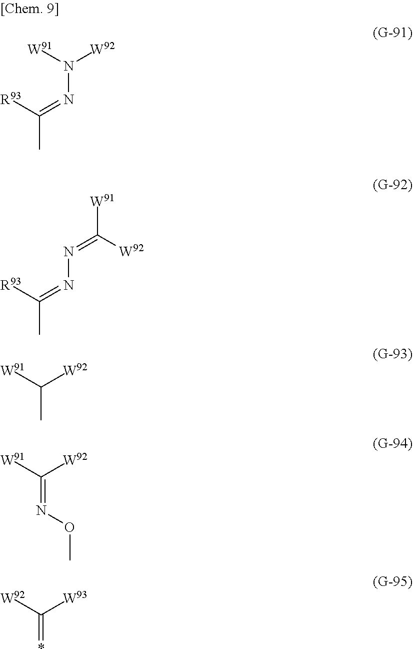

In general formula (G-91) to general formula (G-95), R⁹³ represents a hydrogen atom or an alkyl group having 1 to 20 carbon atoms. The alkyl group may be linear or branched, and any hydrogen atom in the alkyl group is optionally replaced by a fluorine atom. In the alkyl group, one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C—. In terms of availability of raw materials and ease of synthesis, R⁹³ is preferably a hydrogen atom or an alkyl group having 1 to 5 carbon atoms and more preferably a hydrogen atom.

In general formula (G-91) to general formula (G-95), W⁹¹ represents a group that has at least one aromatic group and has 5 to 30 carbon atoms, and this group may be unsubstituted or substituted by at least one L¹.

In general formula (G-91) to general formula (G-95), the aromatic group included in W⁹¹ may be an aromatic hydrocarbon group or a heteroaromatic group, and W⁹¹ may include both of them. These aromatic groups may be bonded through a single bond or a linking group (—OCO—, —COO—, —CO—, or —O—) or may form a condensed ring. W⁹¹ may include, in addition to the aromatic group, an acyclic structure and/or a cyclic structure other than the aromatic group. In terms of availability of raw materials and ease of synthesis, the aromatic group included in W⁹¹ is preferably selected from formula (W-1) to formula (W-19) below that may be unsubstituted or substituted by at least one L¹.

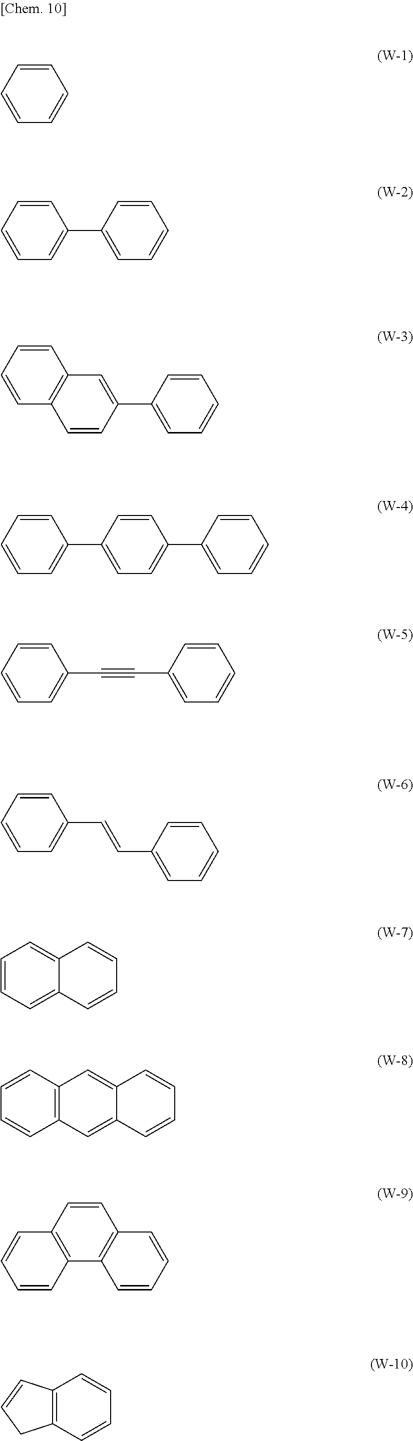

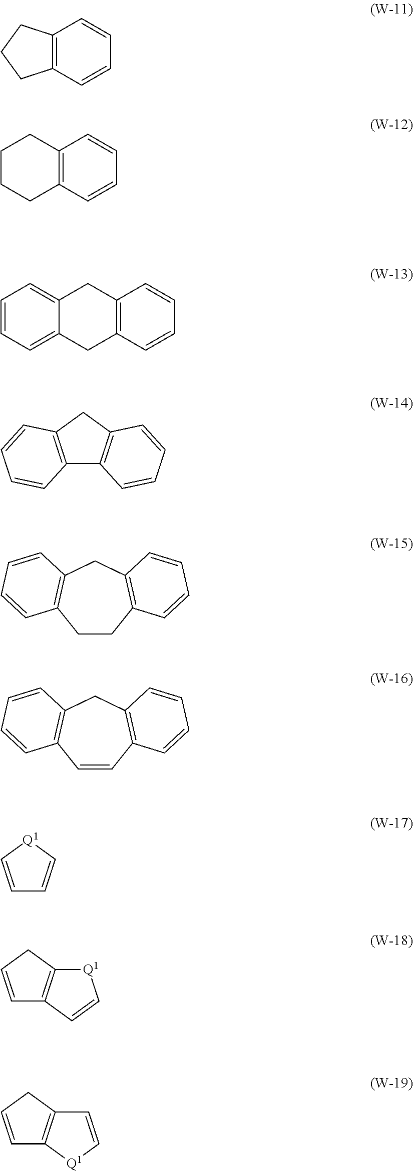

These groups in formula (W-1) to formula (W-19) may have at least one bond at any position, and any two or more aromatic groups selected from these groups may form a group connected through a single bond. Q¹ represents —O—, —S—, —NR⁴— (wherein R⁴ represents a hydrogen atom or an alkyl group having 1 to 8 carbon atoms), or —CO—. In the aromatic groups in formula (W-1) to formula (W-19), —CH═ groups may be each independently replaced by —N═, and —CH₂— groups may be each independently replaced by —O—, —S—, —NR⁴— (wherein R⁴ represents a hydrogen atom or an alkyl group having 1 to 8 carbon atoms) or —CO—. However, these groups include no —O—O— bond.

The group represented by formula (W-1) above is preferably a group selected from formula (W-1-1) to formula (W-1-8) below that may be unsubstituted or substituted by at least one L¹.

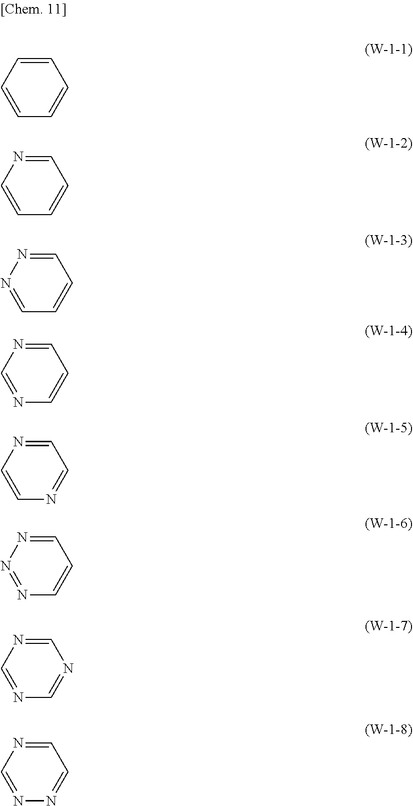

These groups in formula (W-1-1) to formula (W-1-8) above may have at least one bond at any position.

The group represented by formula (W-7) above is preferably a group selected from formula (W-7-1) to formula (W-7-7) below that may be unsubstituted or substituted by at least one L¹.

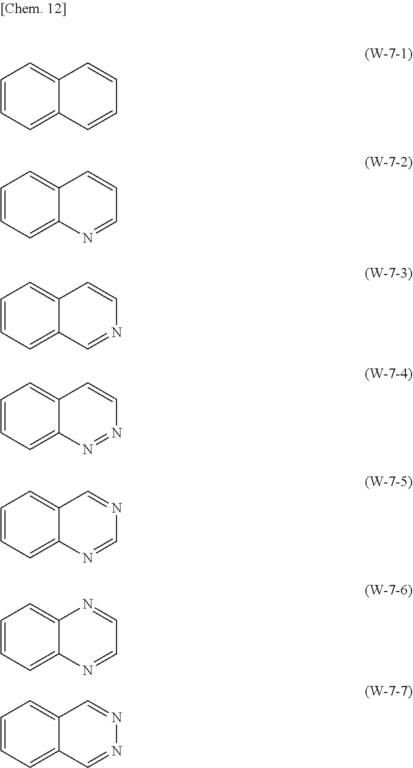

These groups in formula (W-7-1) to formula (W-7-7) above may have at least one bond at any position.

The group represented by formula (W-10) above is preferably a group selected from formula (W-10-1) to formula (W-10-8) below that may be unsubstituted or substituted by at least one L¹.

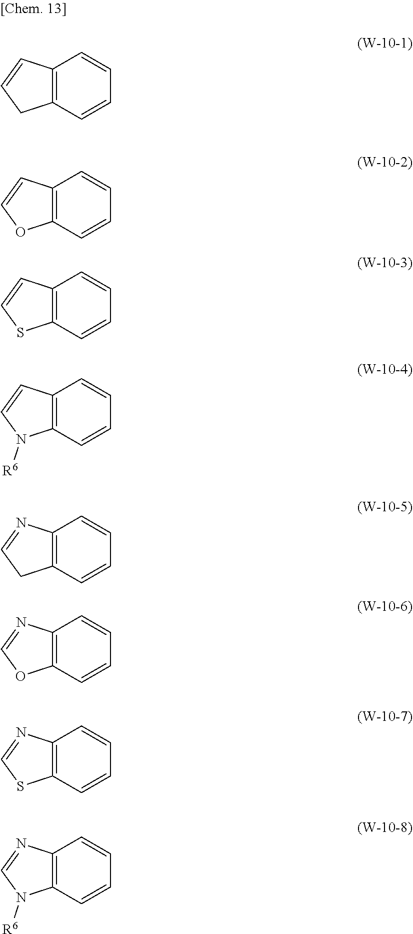

These groups in formula (W-10-1) to formula (W-10-8) above may have at least one bond at any position, and R⁶ represents a hydrogen atom or an alkyl group having 1 to 8 carbon atoms.

The group represented by formula (W-11) above is preferably a group selected from formula (W-11-1) to formula (W-11-13) below that may be unsubstituted or substituted by at least one L¹.

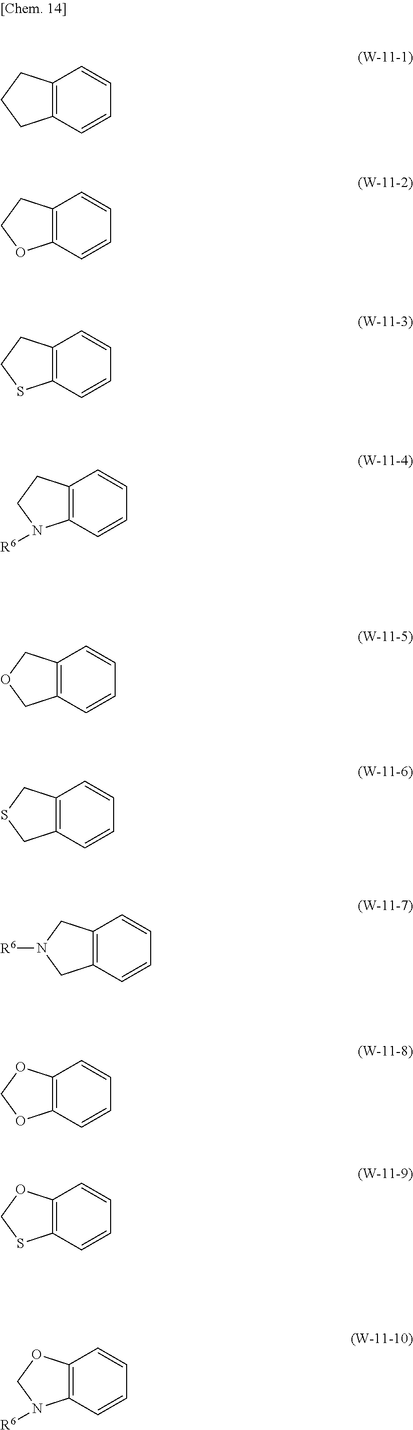

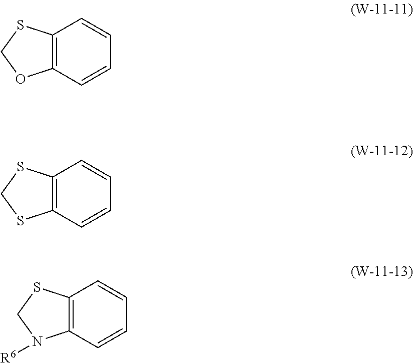

These groups in the above formulas may have at least one bond at any position, and R⁶ represents a hydrogen atom or an alkyl group having 1 to 8 carbon atoms.

The group represented by formula (W-12) above is preferably a group selected from formula (W-12-1) to formula (W-12-19) below that may be unsubstituted or substituted by at least one L¹.

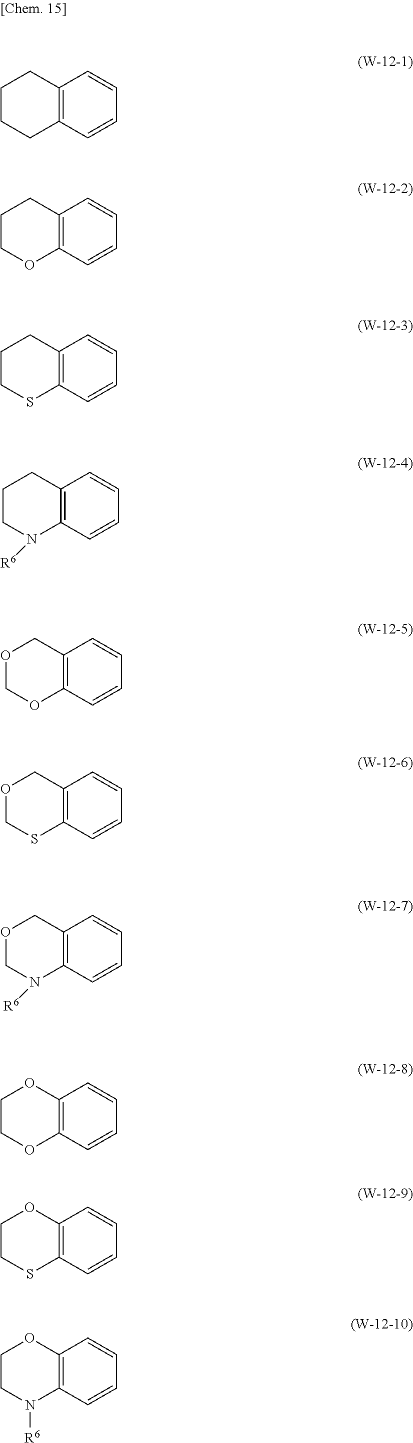

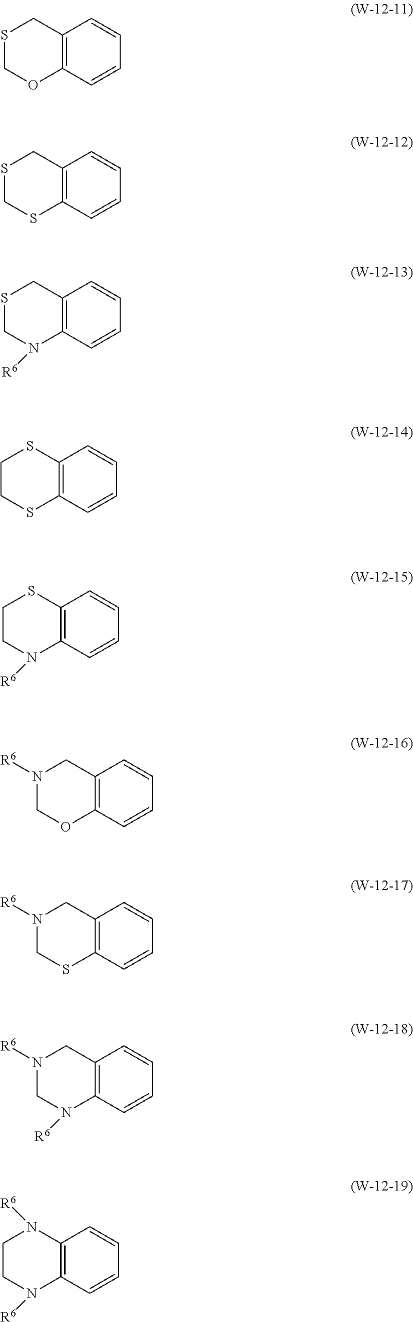

These groups in formula (W-12-1) to formula (W-12-19) may have at least one bond at any position, and R⁶ represents a hydrogen atom or an alkyl group having 1 to 8 carbon atoms. When a plurality of R⁶s are present, they may be the same or different.

The group represented by formula (W-13) above is preferably a group selected from formula (W-13-1) to formula (W-13-10) below that may be unsubstituted or substituted by at least one L¹.

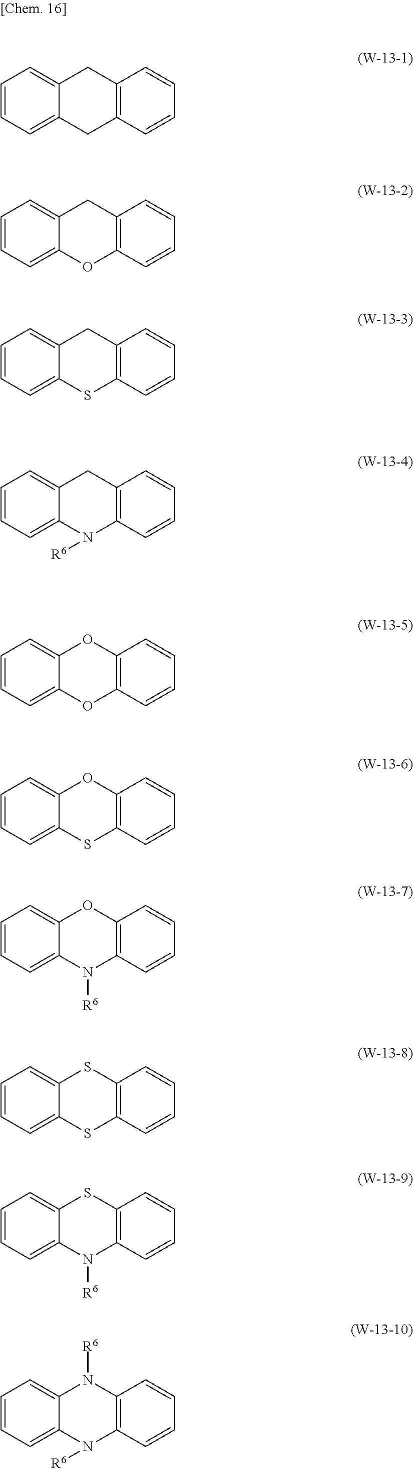

These groups in formula (W-13-1) to formula (W-13-10) above may have at least one bond at any position, and R⁶ represents a hydrogen atom or an alkyl group having 1 to 8 carbon atoms. When a plurality of R⁶s are present, they may be the same or different.

The group represented by formula (W-14) above is preferably a group selected from formula (W-14-1) to formula (W-14-4) below that may be unsubstituted or substituted by at least one L¹.

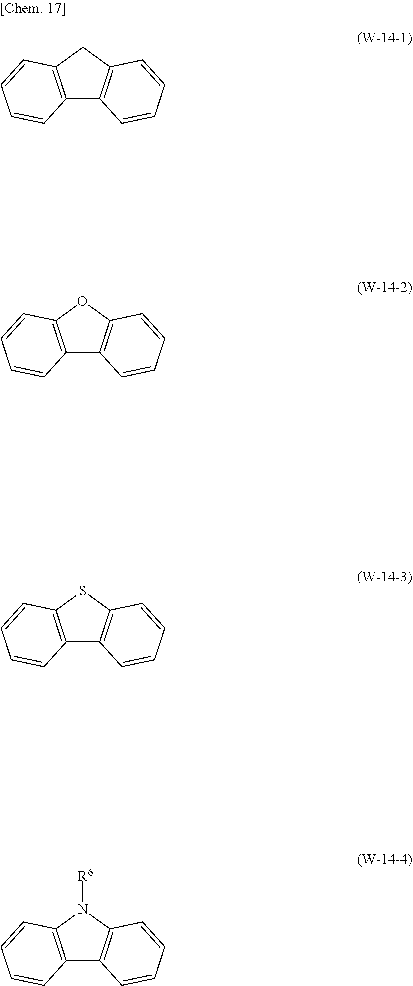

These groups in formula (W-14-1) to formula (W-14-4) above may have at least one bond at any position, and R⁶ represents a hydrogen atom or an alkyl group having 1 to 8 carbon atoms.

The group represented by formula (W-15) above is preferably a group selected from formula (W-15-1) to formula (W-15-18) below that may be unsubstituted or substituted by at least one L¹.

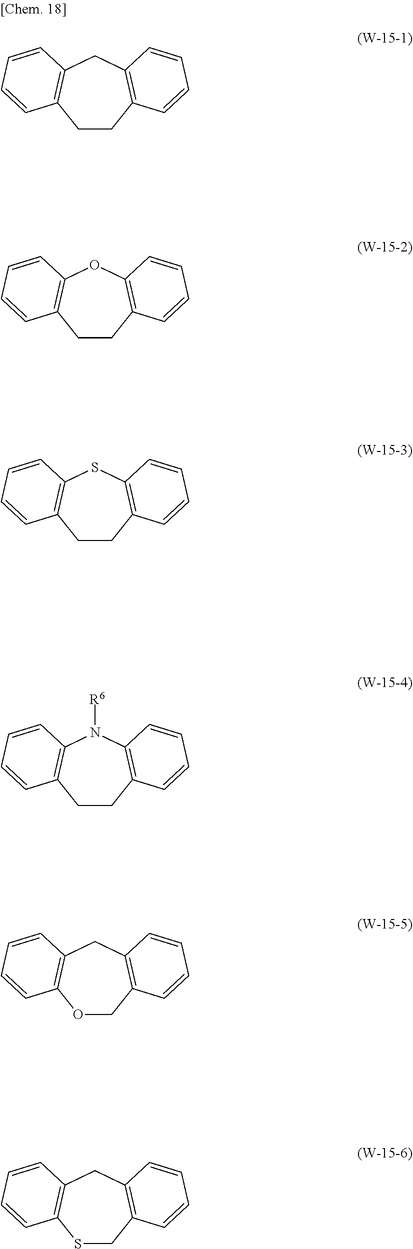

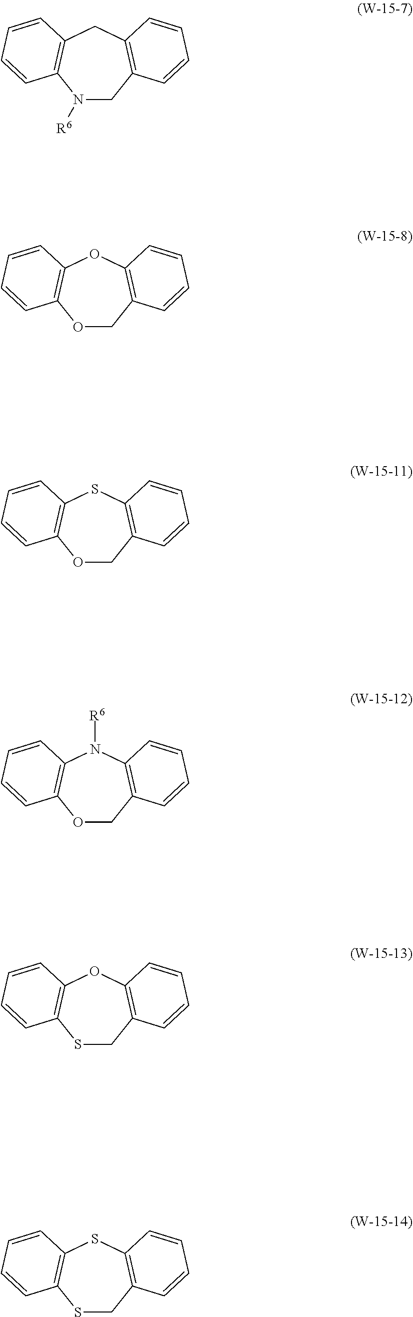

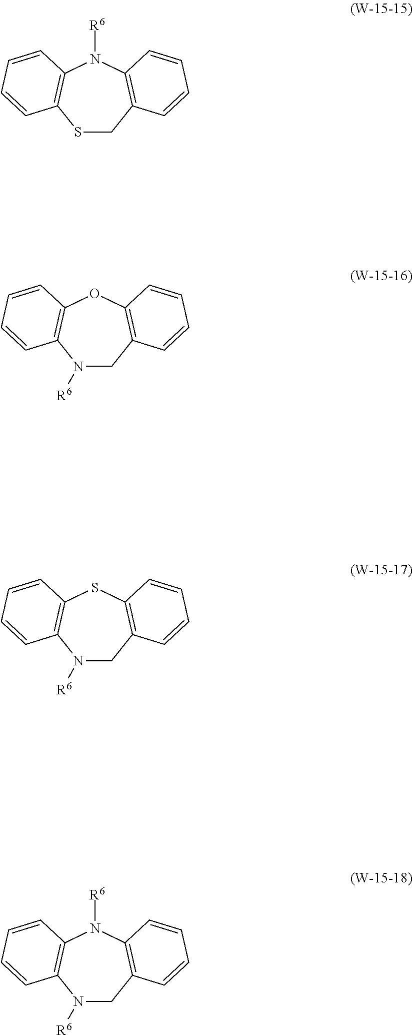

These groups in formula (W-15-1) to formula (W-15-18) above may have at least one bond at any position, and R⁶ represents a hydrogen atom or an alkyl group having 1 to 8 carbon atoms.

The group represented by formula (W-16) above is preferably a group selected from formula (W-16-1) to formula (W-16-4) below that may be unsubstituted or substituted by at least one L¹.

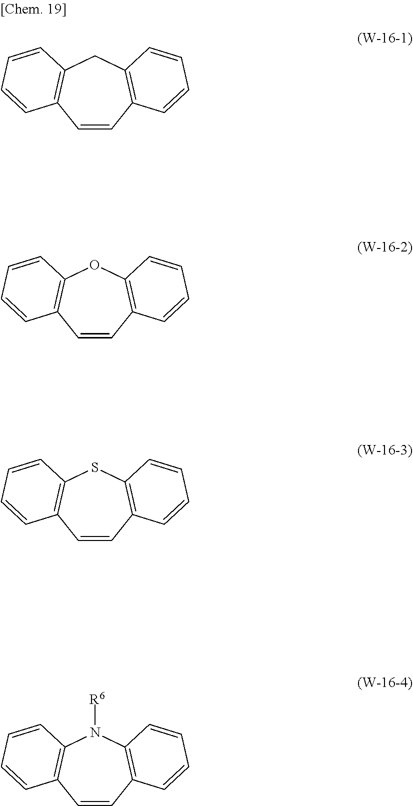

These groups in formula (W-16-1) to formula (W-16-4) above may have at least one bond at any position, and R⁶ represents a hydrogen atom or an alkyl group having 1 to 8 carbon atoms.

The group represented by formula (W-17) above is preferably a group selected from formula (W-17-1) to formula (W-17-6) that may be unsubstituted or substituted by at least one L¹.

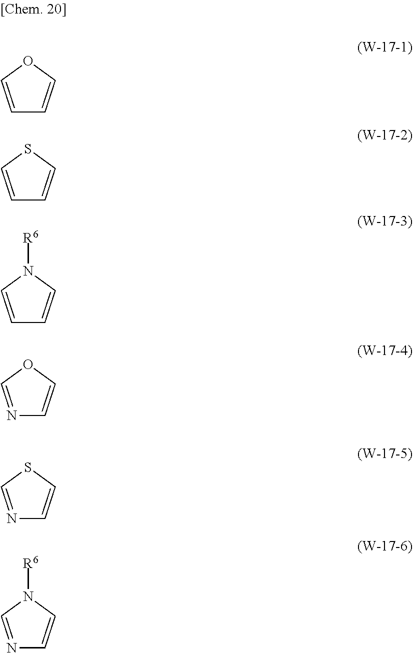

These groups in formula (W-17-1) to formula (W-17-6) may have at least one bond at any position, and R⁶ represents a hydrogen atom or an alkyl group having 1 to 8 carbon atoms.

The group represented by formula (W-18) above is preferably a group selected from formula (W-18-1) to formula (W-18-6) below that may be unsubstituted or substituted by at least one L.

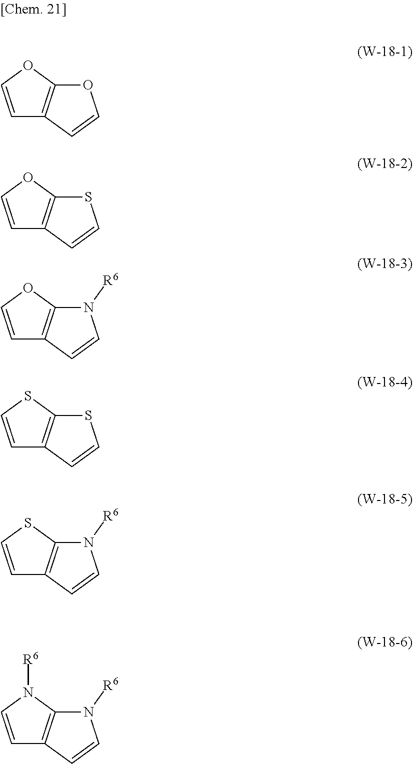

These groups in formula (W-18-1) to formula (W-18-6) above may have at least one bond at any position, and R⁶ represents a hydrogen atom or an alkyl group having 1 to 8 carbon atoms. When a plurality of R⁶s are present, they may be the same or different.

The group represented by formula (W-19) above is preferably a group selected from formula (W-19-1) to formula (W-19-9) below that may be unsubstituted or substituted by at least one L¹.

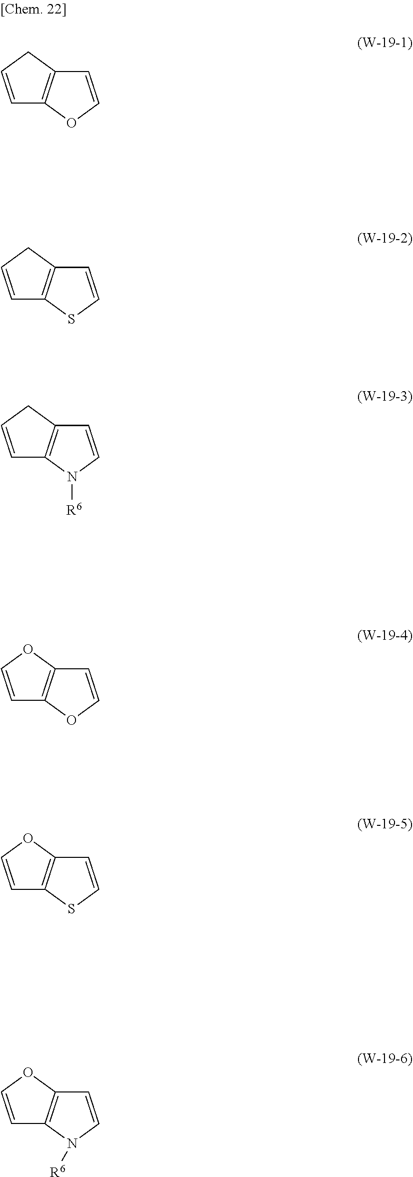

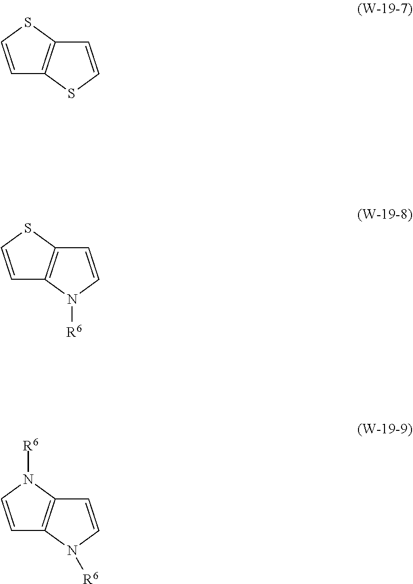

These groups in formula (W-19-1) to formula (W-19-9) above may have at least one bond at any position, and R⁶ represents a hydrogen atom or an alkyl group having 1 to 8 carbon atoms. When a plurality of R's are present, they may be the same or different.

The aromatic group included in W⁹¹ is more preferably a group selected from formula (W-1-1), formula (W-7-1), formula (W-7-2), formula (W-7-7), formula (W-8), formula (W-10-6), formula (W-10-7), formula (W-10-8), formula (W-11-8), formula (W-11-9), formula (W-11-10), formula (W-11-11), formula (W-11-12), and formula (W-11-13) above that may be unsubstituted or substituted by at least one L¹ and is particularly preferably a group selected from formula (W-1-1), formula (W-7-1), formula (W-7-2), formula (W-7-7), formula (W-10-6), formula (W-10-7), and formula (W-10-8) that may be unsubstituted or substituted by at least one L¹. Particularly preferably, W⁹¹ represents a group selected from formula (W-a-1) to formula (W-a-6) below.

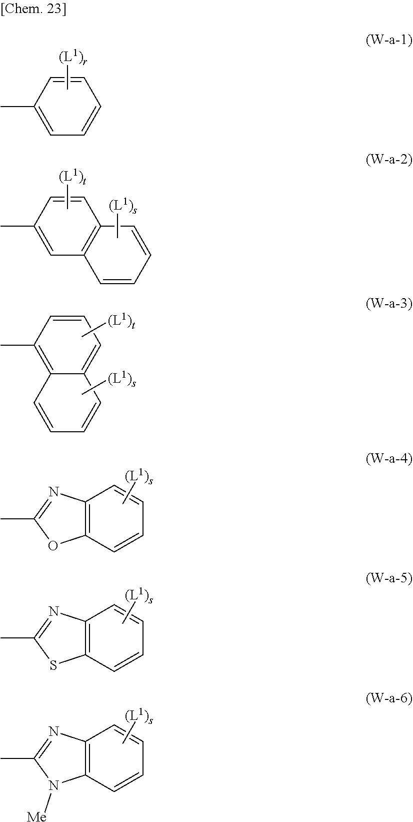

In formula (W-a-1) to formula (W-a-6) above, r represents an integer from 0 to 5; s represents an integer from 0 to 4; and t represents an integer from 0 to 3.

W⁹¹ represents particularly preferably a group selected from formula (W-a-5) and formula (W-a-6) above, and the total number of π electrons contained in W⁹¹ is preferably 4 to 24, in terms of wavelength dispersion properties, storage stability, liquid crystallinity, and ease of synthesis.

In general formula (G-91) to general formula (G-95), W⁹² represents a group represented by P⁵³—(S⁹³—X⁹³)ⱼ₉₃—.

In the group W⁹², P⁹³ represents a polymerizable group. The polymerizable group is preferably a group selected from formula (P-1) to formula (P-20) below.

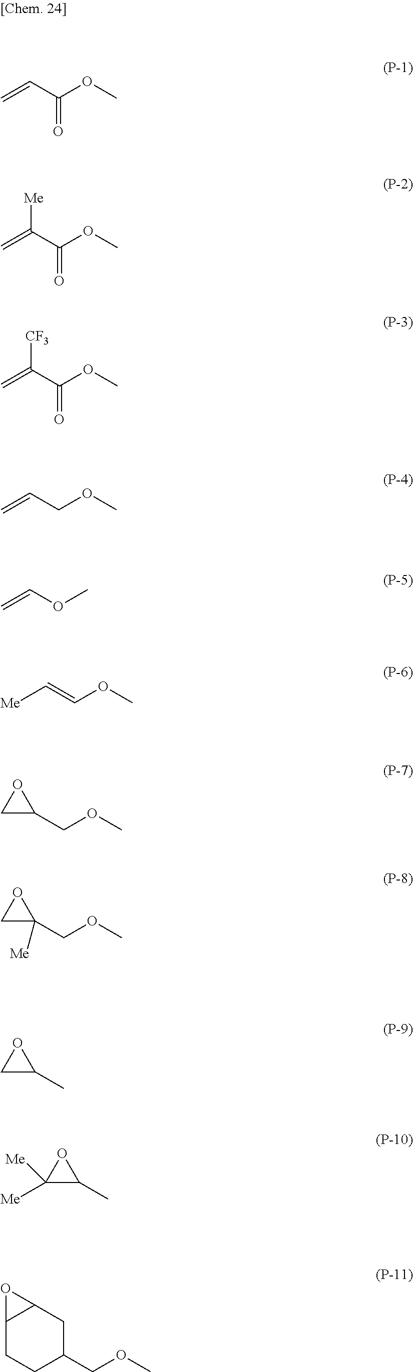

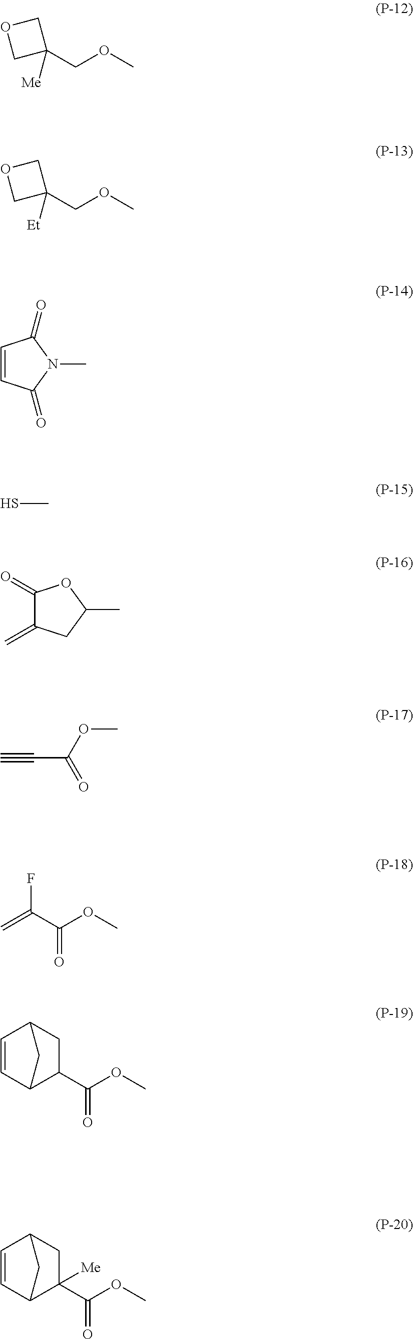

These polymerizable groups are polymerized by radical polymerization, radical addition polymerization, cationic polymerization, or anionic polymerization. In particular, when the polymerization method is UV polymerization, formula (P-1), formula (P-2), formula (P-3), formula (P-4), formula (P-5), formula (P-7), formula (P-11), formula (P-13), formula (P-15), or formula (P-18) is preferable, and formula (P-1), formula (P-2), formula (P-7), formula (P-11), or formula (P-13) is more preferable. Formula (P-1), formula (P-2), or formula (P-3) is still more preferable, and formula (P-1) or formula (P-2) is particularly preferable.

In the group W⁹², S⁴³ represents a spacer group or a single bond. When a plurality of S⁹³s are present, they may be the same or different. Preferably, the spacer group represents an alkylene group which has 1 to 20 carbon atoms and in which one —CH₂— group or two or more nonadjacent —CH₂— groups may be each independently replaced by —O—, —COO—, —OCO—, —OCO—O—, —CO—NH—, —NH—CO—, —CH═CH—, —C≡C—, or formula (S-1) below.

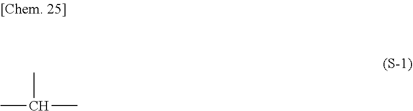

When a plurality of S⁹³s are present, they may be the same or different and more preferably each independently represent a single bond or an alkylene group which has 1 to 10 carbon atoms and in which one —CH₂— group or two or more nonadjacent —CH₂— groups may be each independently replaced by —O—, —COO—, or —OCO— and still more preferably each independently represent a single bond or an alkylene group having 1 to 10 carbon atoms, in terms of availability of raw materials and ease of synthesis. When a plurality of S⁹³s are present, they may be the same or different and particularly preferably each independently represent an alkylene group having 1 to 8 carbon atoms.

In the group W⁹², X⁹³ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond. When a plurality of X⁹³s are present, they may be the same or different. In terms of availability of raw materials and ease of synthesis, when a plurality of X⁹³s are present, they may be the same or different, preferably each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond, and more preferably each independently represent —O—, —OCH₂—, —CH₂O—, —COO—, —OCO—, —COO—CH₂CH₂—, —OCO—CH₂CH₂—, —CH₂CH₂—COO—, —CH₂CH₂—OCO—, or a single bond. Particularly preferably, when a plurality of X⁹³s are present, they may be the same or different and each independently represent —O—, —COO—, —OCO—, or a single bond. However, P⁵³—(S⁹³—X⁹³)ⱼ₉₃— contains no —O—O— bond.

In the group W⁹², j93 represents an integer from 1 to 10. j93 represent preferably 0, 1, 2, or 3 and more preferably 1, 2, or 3.

W⁹³ represents a halogen atom, a cyano group, a hydroxy group, a nitro group, a carboxyl group, a carbamoyloxy group, an amino group, a sulfamoyl group, a group having at least one aromatic group and having 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms. In the alkyl group, the cycloalkyl group, the alkenyl group, the cycloalkenyl group, the alkoxy group, the acyloxy group, and the alkylcarbonyloxy group, one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C—. W⁹³ is more preferably a group selected from a cyano group, a nitro group, a carboxyl group, and alkyl, alkenyl, acyloxy, and alkylcarbonyloxy groups which have 1 to 20 carbon atoms and in which one —CH₂— group or two or more nonadjacent —CH₂— groups may be independently replaced by —O—, —S—, —CO—, —COO—, —OCO—, —CO—S—, —S—CO—, —O—CO—O—, —CO—NH—, —NH—CO—, or —C≡C—. W⁹³ is particularly preferably a group selected from a cyano group, a carboxyl group, and alkyl, alkenyl, acyloxy, and alkylcarbonyloxy groups which have 1 to 20 carbon atoms and in which one —CH₂— group or two or more nonadjacent —CH₂— groups may be each independently replaced by —CO—, —COO—, —OCO—, —O—CO—O—, —CO—NH—, —NH—CO—, or —C≡C—.

In general formula (a9) above, L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or a linear or branched alkyl group which has 1 to 20 carbon atoms and in which one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—. In this alkyl group, any hydrogen atom may be replaced by a fluorine atom. In terms of liquid crystallinity and ease of synthesis, L¹ preferably represents a fluorine atom, a chlorine atom, a pentafluorosulfuranyl group, a nitro group, a methylamino group, a dimethylamino group, a diethylamino group, a diisopropylamino group, or a linear or branched alkyl group which has 1 to 20 carbon atoms, in which any hydrogen atom may be replaced by a fluorine atom, and in which one —CH₂— group or two or more nonadjacent —CH₂— groups may be each independently replaced by a group selected from —O—, —S—, —CO—, —COO—, —OCO—, —O—CO—O—, —CH═CH—, —CF═CF—, and —C≡C—. L¹ more preferably represents a fluorine atom, a chlorine atom, or a linear or branched alkyl group which has 1 to 12 carbon atoms, in which any hydrogen atom may be replaced by a fluorine atom, and in which one —CH₂— group or two or more nonadjacent —CH₂— groups may be each independently replaced by a group selected from —O—, —COO—, and —OCO— and still more preferably represents a fluorine atom, a chlorine atom, or a linear or branched alkyl or alkoxy group which has 1 to 12 carbon atoms and in which any hydrogen atom may be replaced by a fluorine atom. Particularly preferably, L¹ represents a fluorine atom, a chlorine atom, a linear alkyl group having 1 to 8 carbon atoms, or a linear alkoxy group having 1 to 8 carbon atoms.

In general formula (9), substituents bonded to MG⁹¹ are bonded to A⁹¹, A⁹², M⁹ and/or G⁹ in general formula (a9) above.

In general formula (a9) above, j91 and j92 each independently represent an integer from 1 to 5, and j91+j92 represents an integer from 2 to 5. In terms of liquid crystallinity, ease of synthesis, and storage stability, j91 and j92 each independently represent preferably an integer from 1 to 4, more preferably an integer from 1 to 3, and particularly preferably 1 or 2. Preferably, j91+j92 represents an integer from 2 to 4.

Specifically, the compound represented by general formula (9) is preferably compounds represented by formula (9-a-1) to formula (9-a-8) below:

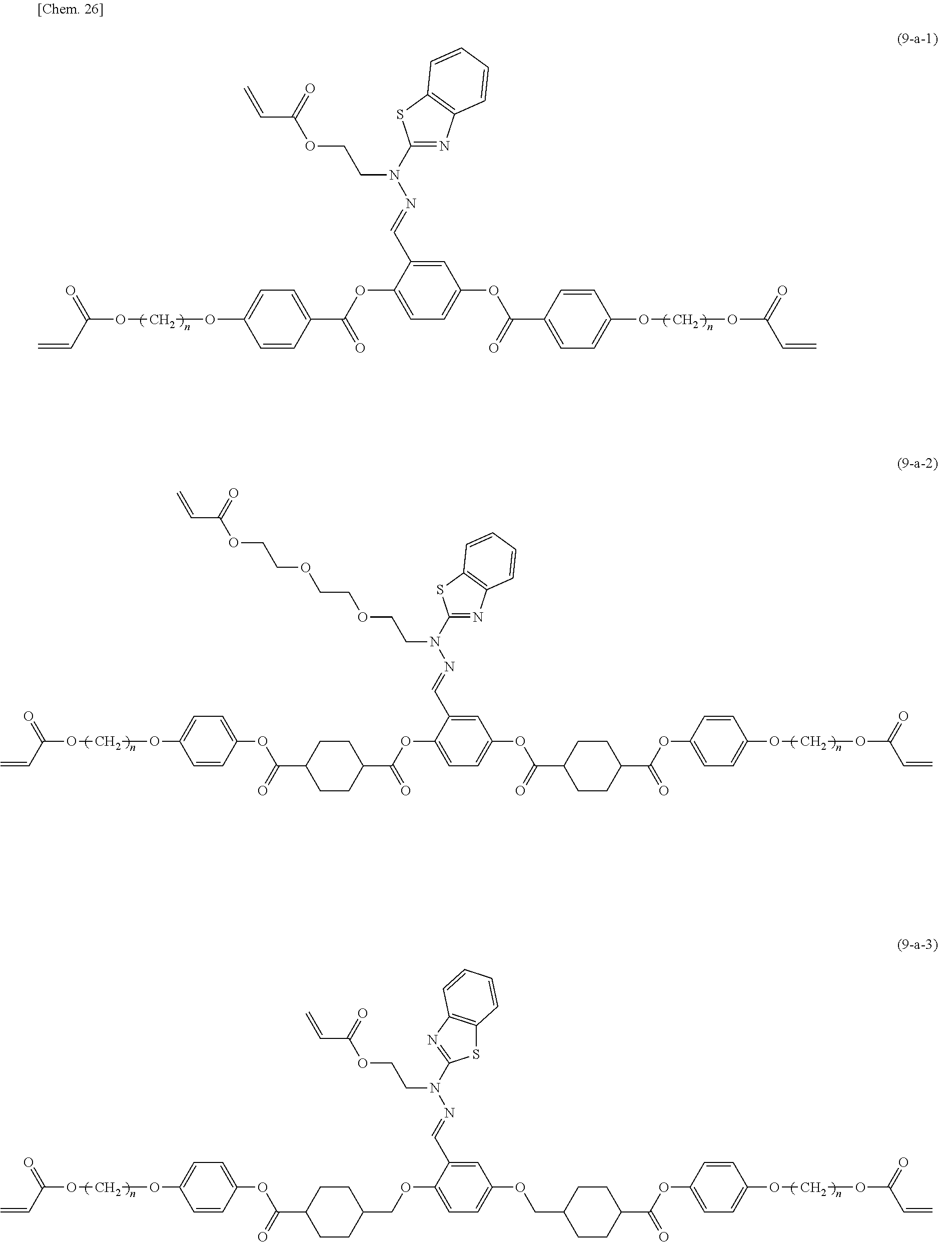

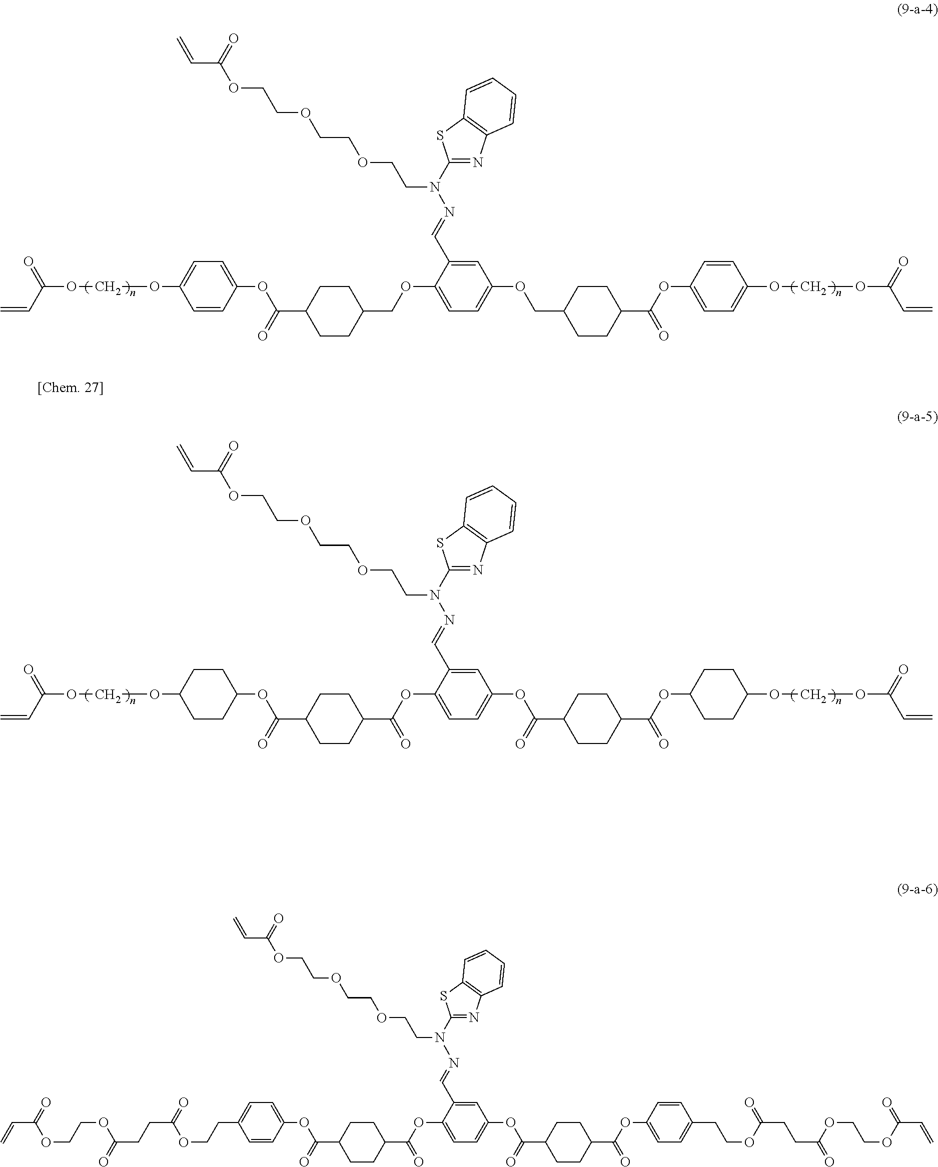

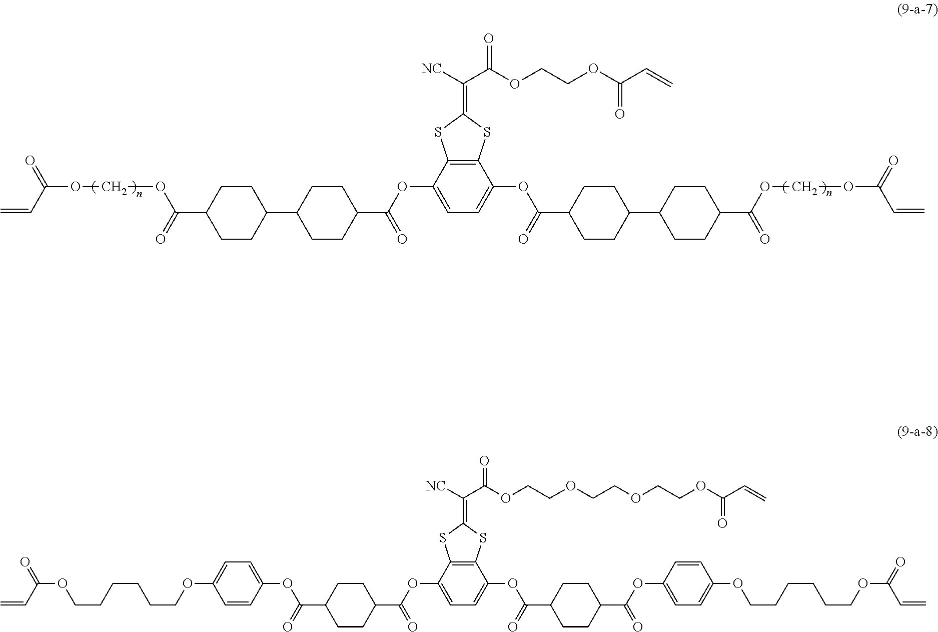

(wherein n represents an integer of 1 to 10). Theses polymerizable liquid crystal compounds may be used alone or as a mixture of two or more.

The total content of the polymerizable liquid crystal compound represented by general formula (9) above is preferably 10 to 99% by mass, more preferably 30 to 98% by mass, and particularly preferably 50 to 97% by mass with respect to the total mass of the polymerizable liquid crystal compounds used for the polymerizable composition forming the first retardation layer.

### (Compound B)

In addition to the compound A having at least three polymerizable groups and satisfying (formula 1), the first retardation layer of the optical film of the present invention contains compound B satisfying the following (formula 2).

Re(450)/Re(550)>1 (formula 2)

(wherein Re(450) represents an in-plane retardation at a wavelength of 450 nm when the compound used is formed into a film, and Re(550) represents an in-plane retardation at a wavelength of 550 nm when the compound used is formed into the film.)

The second retardation layer of the optical film of the present invention may contain the compound B.

The compound B may include a polymerizable liquid crystal compound represented by general formula (1-b) and/or a polymerizable liquid crystal compound represented by general formula (2-b). The total content of the polymerizable liquid crystal compound represented by the compound B used for the first retardation layer is preferably 1 to 90% by mass, more preferably 2 to 70% by mass, and particularly preferably 3 to 50% by mass with respect to the total mass of the polymerizable liquid crystal compounds used for the polymerizable composition forming the first retardation layer.

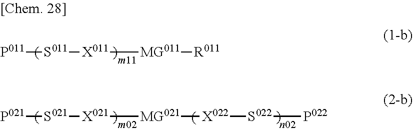

In general formula (1-b) and general formula (2-b), P⁰¹¹, P⁰²¹, and P⁰²² each independently represent a polymerizable group and each independently represent a group selected from formula (P-1) to formula (P-20) below.

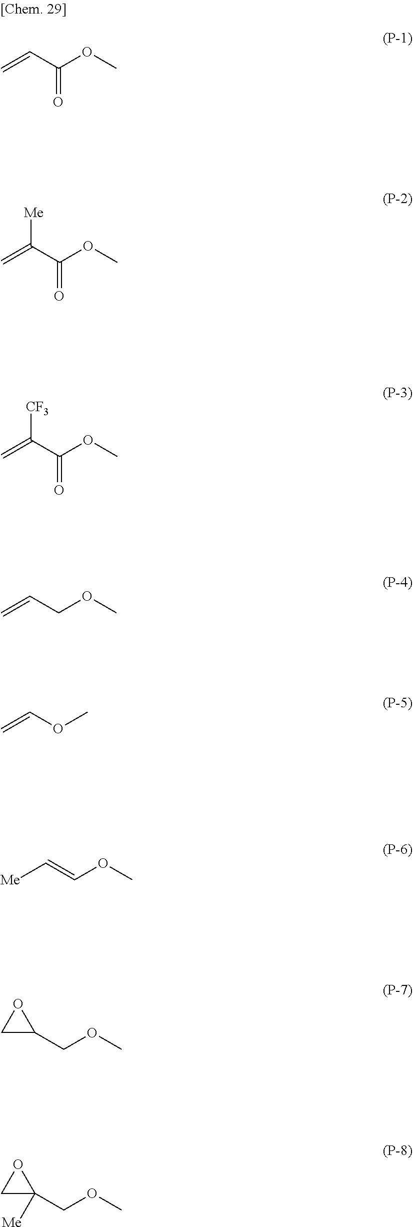

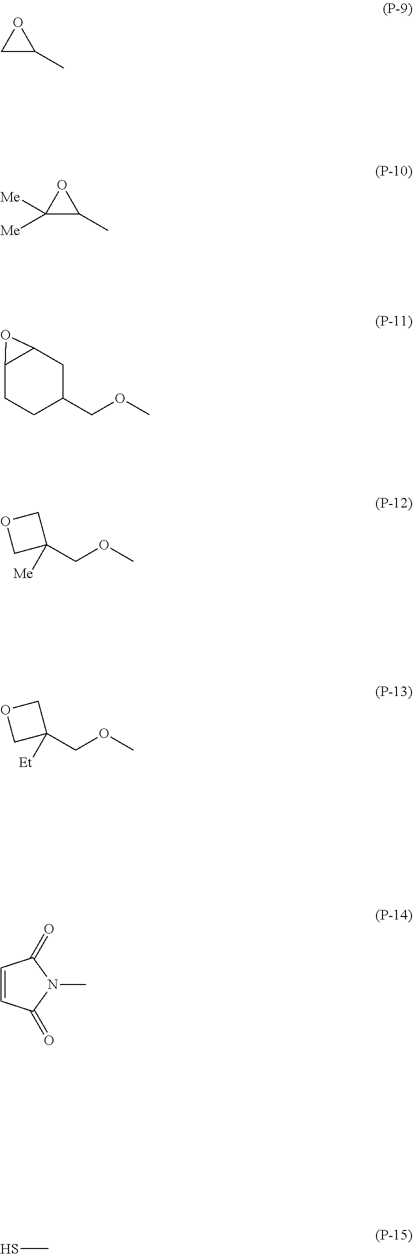

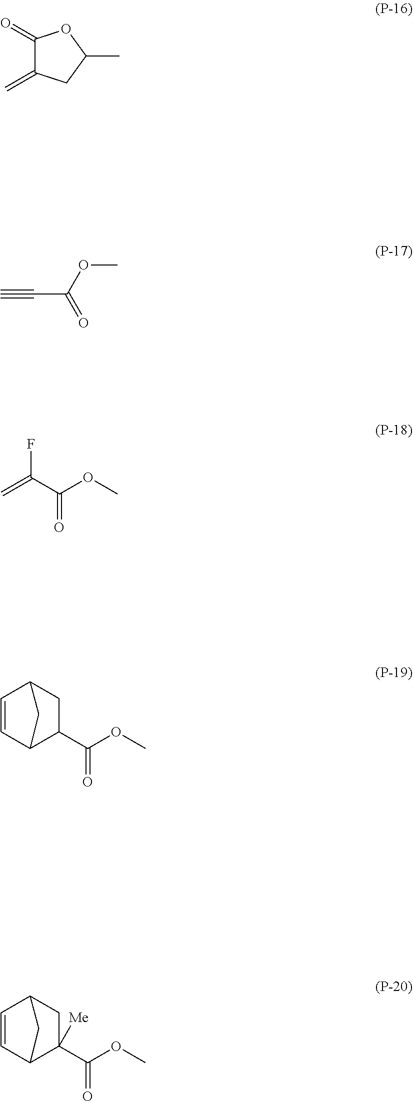

These polymerizable groups are polymerized by radical polymerization, radical addition polymerization, cationic polymerization, or anionic polymerization. In particular, when the polymerization method is UV polymerization, formula (P-1), formula (P-2), formula (P-3), formula (P-4), formula (P-5), formula (P-7), formula (P-11), formula (P-13), formula (P-15), or formula (P-18) is preferable, and formula (P-1), formula (P-2), formula (P-7), formula (P-11), or formula (P-13) is more preferable. Formula (P-1), formula (P-2), or formula (P-3) is still more preferable, and formula (P-1) or formula (P-2) is particularly preferable.

In general formula (1-b) and general formula (2-b), S⁰¹¹, S⁰²¹, and S⁰²² each independently represent a spacer group or a single bond. When a plurality of S⁰¹¹s, S⁰²¹s, and S⁰²²s are present, they may be the same or different. Preferably, the spacer group represents an alkylene group which has 1 to 20 carbon atoms and in which one —CH₂— group or two or more nonadjacent —CH₂— groups may be each independently replaced by —O—, —COO—, —OCO—, —OCO—O—, —CO—NH—, —NH—CO—, —CH═CH—, —C≡C—, or formula (S-1) below.

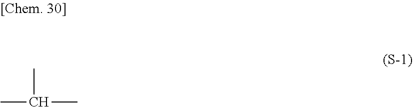

When a plurality of S⁰¹¹s, S⁰²¹s, and S⁰²²s are present, they may be the same or different and more preferably each independently represent a single bond or an alkylene group which has 1 to 10 carbon atoms and in which one —CH₂— group or two or more nonadjacent —CH₂— groups may be each independently replaced by —O—, —COO—, or —OCO—, in terms of availability of raw materials and ease of synthesis. More preferably, S⁰¹¹, S⁰²¹, and S⁰²² each independently represent a single bond or an alkylene group having 1 to 10 carbon atoms. When a plurality of S⁰¹¹s, S⁰²¹s, and S⁰²²s are present, they may be the same or different and particularly preferably each independently represent an alkylene group having 1 to 8 carbon atoms.

In general formula (1-b) and general formula (2-b), X⁰¹¹, X⁰²¹, and X⁰²² each independently represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that each P—(S—X)— bond contains no —O—O—). When a plurality of X⁰¹¹s, X⁰²¹s, and X⁰²²s are present, they may be the same or different. In terms of availability of raw materials and ease of synthesis, when a plurality of X⁰¹¹s, X⁰²¹s, and X⁰²²s are present, they may be the same or different and preferably each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond. More preferably, they each independently represent —O—, —OCH₂—, —CH₂O—, —COO—, —OCO—, —COO—CH₂CH₂—, —OCO—CH₂CH₂—, —CH₂CH₂—COO—, —CH₂CH₂—OCO—, or a single bond. When a plurality of X⁰¹¹s, X⁰²¹s, and X⁰²²s are present, they may be the same or different and particularly preferably each independently represent —O—, —COO—, —OCO—, or a single bond.

In general formula (1-b) and general formula (2-b), m11 represents an integer of 0 to 8. In terms of availability of raw materials and ease of synthesis, m11 is preferably 1 to 3 and more preferably 1.

In general formula (1-b) and general formula (2-b), m02 and n02 each independently represent an integer from 0 to 5. In terms of availability of raw materials and ease of synthesis, m02 and n02 each independently represent preferably 1 to 3 and more preferably 1.

In general formula (1-b) and general formula (2-b), R⁰¹¹ represents a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms. This alkyl group may be linear or branched, and any hydrogen atom in the alkyl group may be optionally replaced by a fluorine atom. In the alkyl group, one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C—. In terms of availability of raw materials and ease of synthesis, R⁰¹¹ is preferably a cyano group or a linear alkyl group having 1 to 20 carbon atoms (in the alkyl group, one —CH₂— group or two or more nonadjacent —CH₂— groups may be each independently replaced by —O—). More preferably, R⁰¹¹ is a linear alkyl group having 1 to 8 carbon atoms (in the alkyl group, one —CH₂— group may be replaced by —O—).

In general formula (1-b) and general formula (2-b), MG⁰¹¹ and MG⁰²¹ each independently represent formula (b).

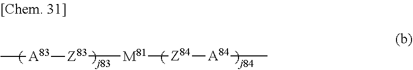

In formula (b), A⁸³ and A⁸⁴ each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, each of which may be unsubstituted or substituted by at least one L². When a plurality of A³s and/or A⁸⁴s are present, they may be the same or different. In terms of availability of raw materials and ease of synthesis, A⁸³ and A⁸⁴ preferably each independently represent a 1,4-phenylene group, a 1,4-cyclohexylene group, or a naphthalene-2,6-diyl group (these groups may be unsubstituted or substituted by at least one L²).

In formula (b), Z⁸³ and Z⁸⁴ each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond. When a plurality of Z⁸³s and/or Z⁸⁴s are present, they may be the same or different. In terms of availability of raw materials and ease of synthesis, Z⁸³ and Z⁸⁴ preferably each independently represent —COO—, —OCO—, or a single bond.

In formula (b), M⁸¹ represents a group selected from a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-tetrahydronaphthalene-2,6-diyl group, a naphthylene-1,4-diyl group, a naphthylene-1,5-diyl group, a naphthylene-1,6-diyl group, a naphthylene-2,6-diyl group, a phenanthrene-2,7-diyl group, a 9,10-dihydrophenanthrene-2,7-diyl group, a 1,2,3,4,4a,9,10a-octahydrophenanthrene-2,7-diyl group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, and a fluorene-2,7-diyl group, each of which may be unsubstituted or substituted by at least one L². In terms of availability of raw materials and ease of synthesis, M⁸¹ preferably represents a 1,4-phenylene group or a 1,4-cyclohexylene group (these groups may be unsubstituted or substituted by at least one L²).

In formula (b), L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms. This alkyl group may be linear or branched, and any hydrogen atom in the alkyl group may be replaced by a fluorine atom. In the alkyl group, one —CH₂— group or two or more nonadjacent —CH₂— groups may be each independently replaced by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C≡C—. When a plurality of L²s are present in the compound, they may be the same or different. In terms of availability of raw materials and ease of synthesis, L²s preferably each independently represent a fluorine atom, a methylene group, or a methoxy group.

In formula (b), j83 and j84 each independently represent an integer from 0 to 5, and j83+j84 represents an integer from 1 to 5. In terms of availability of raw materials and ease of synthesis, j83 and j84 preferably each independently represent 0 or 1.

Specific examples of the compound represented by general formula (1-b) above include compounds represented by formula (1-b-1) to formula (1-b-39) below:

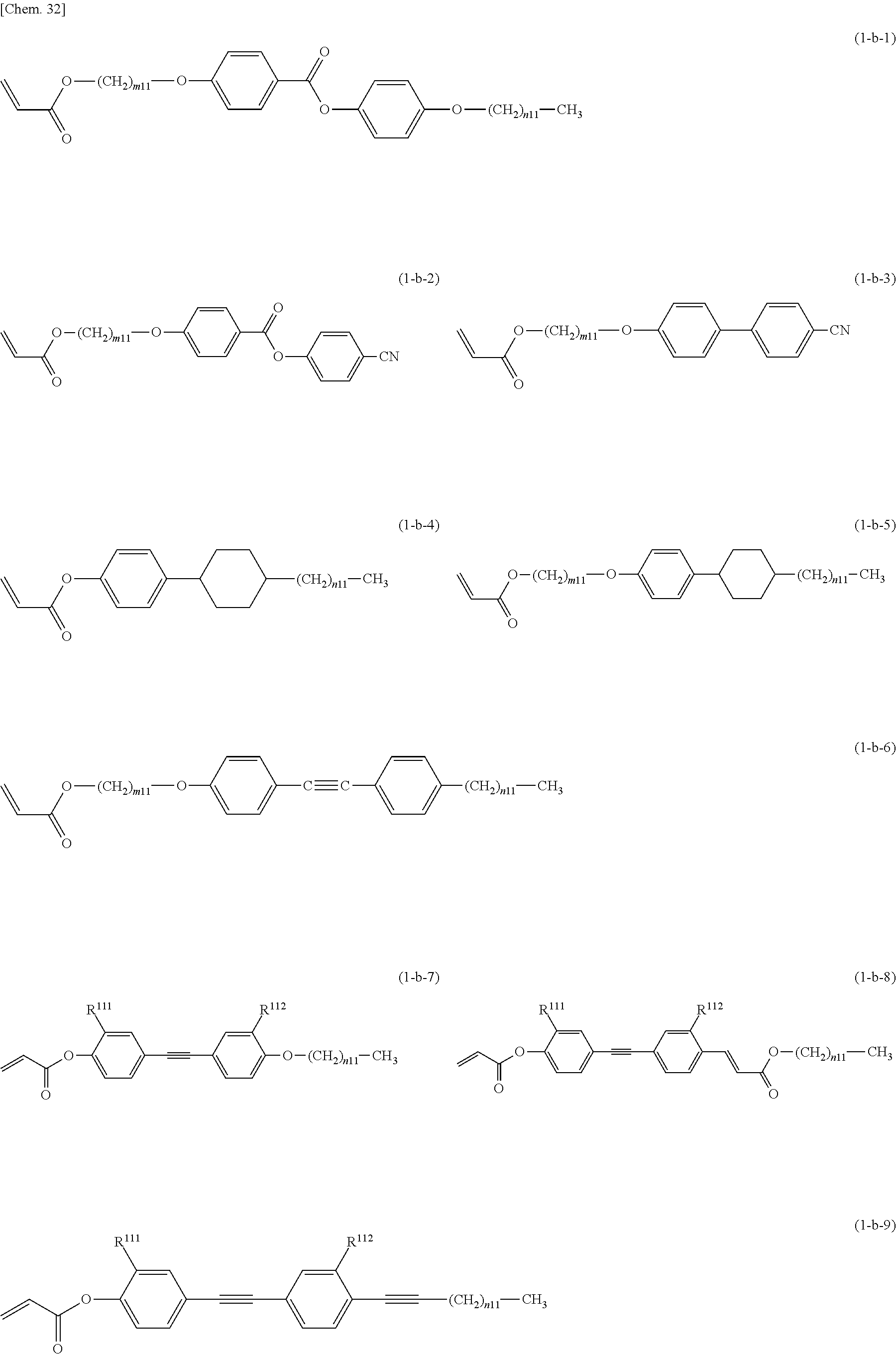

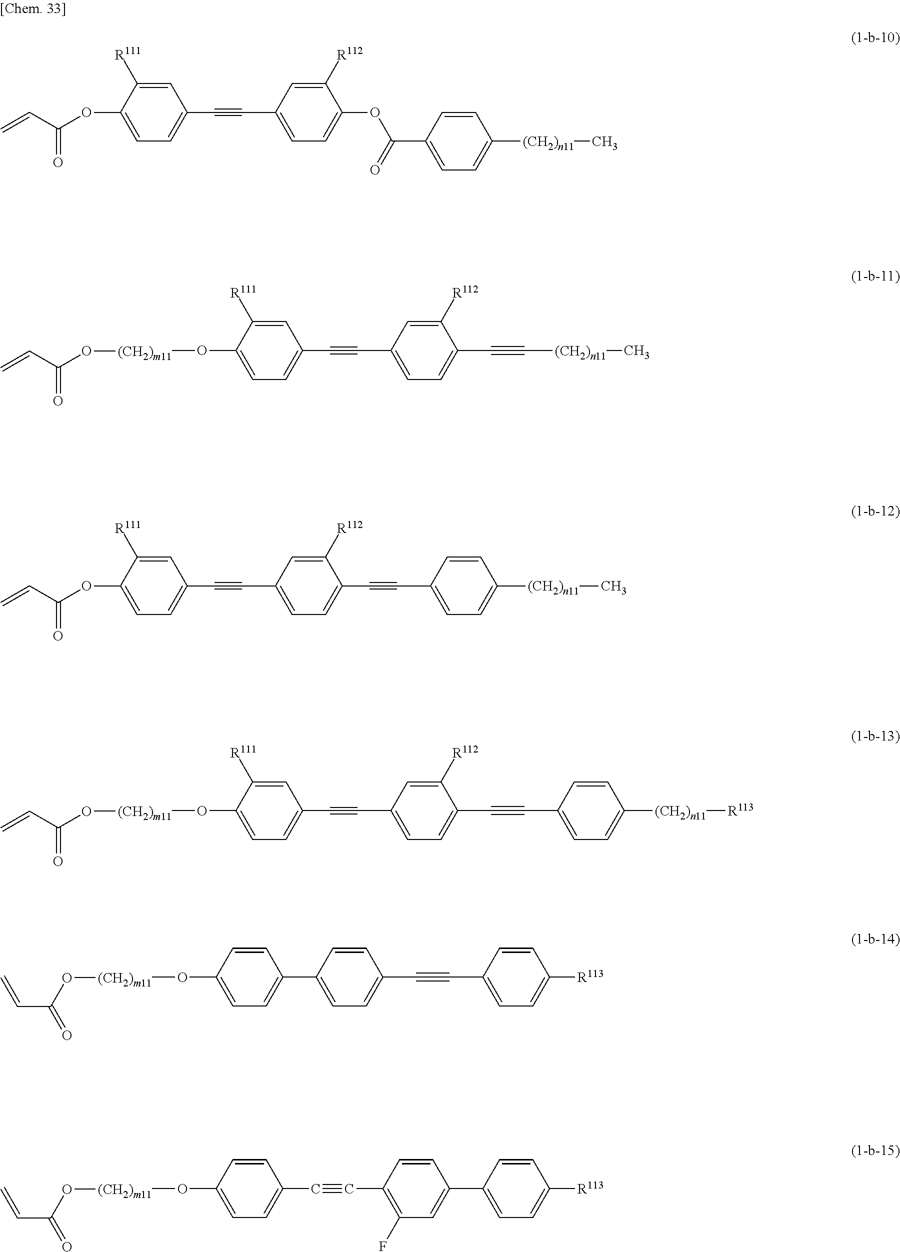

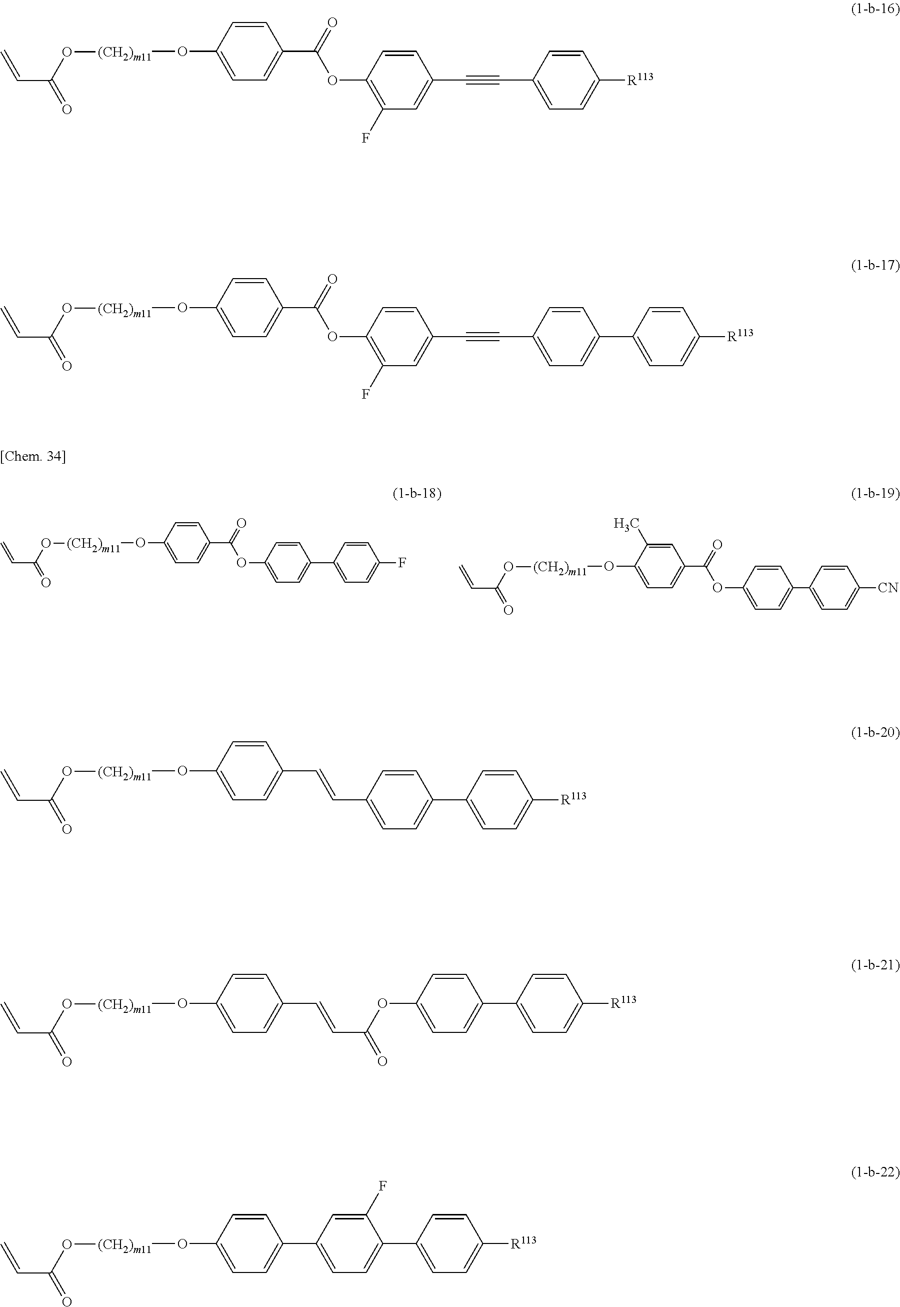

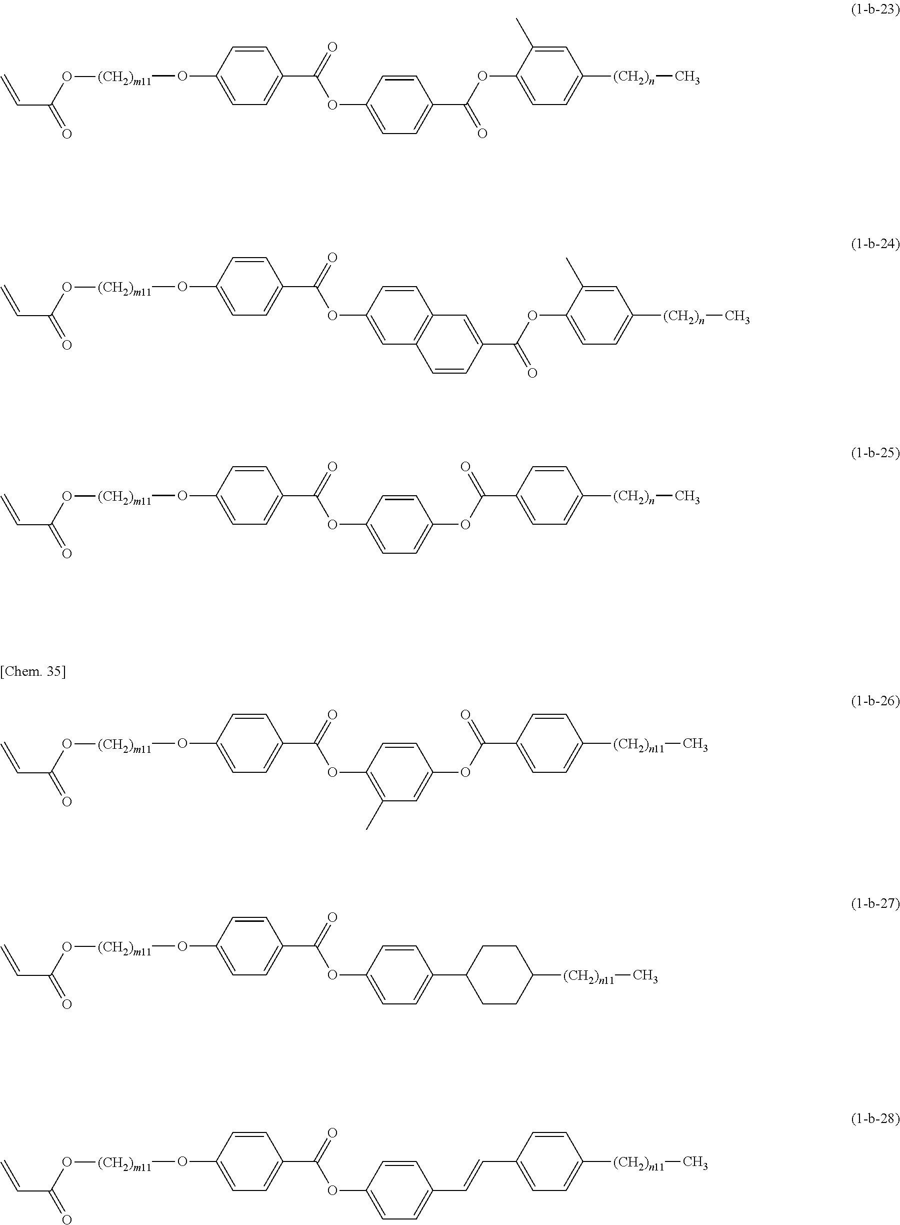

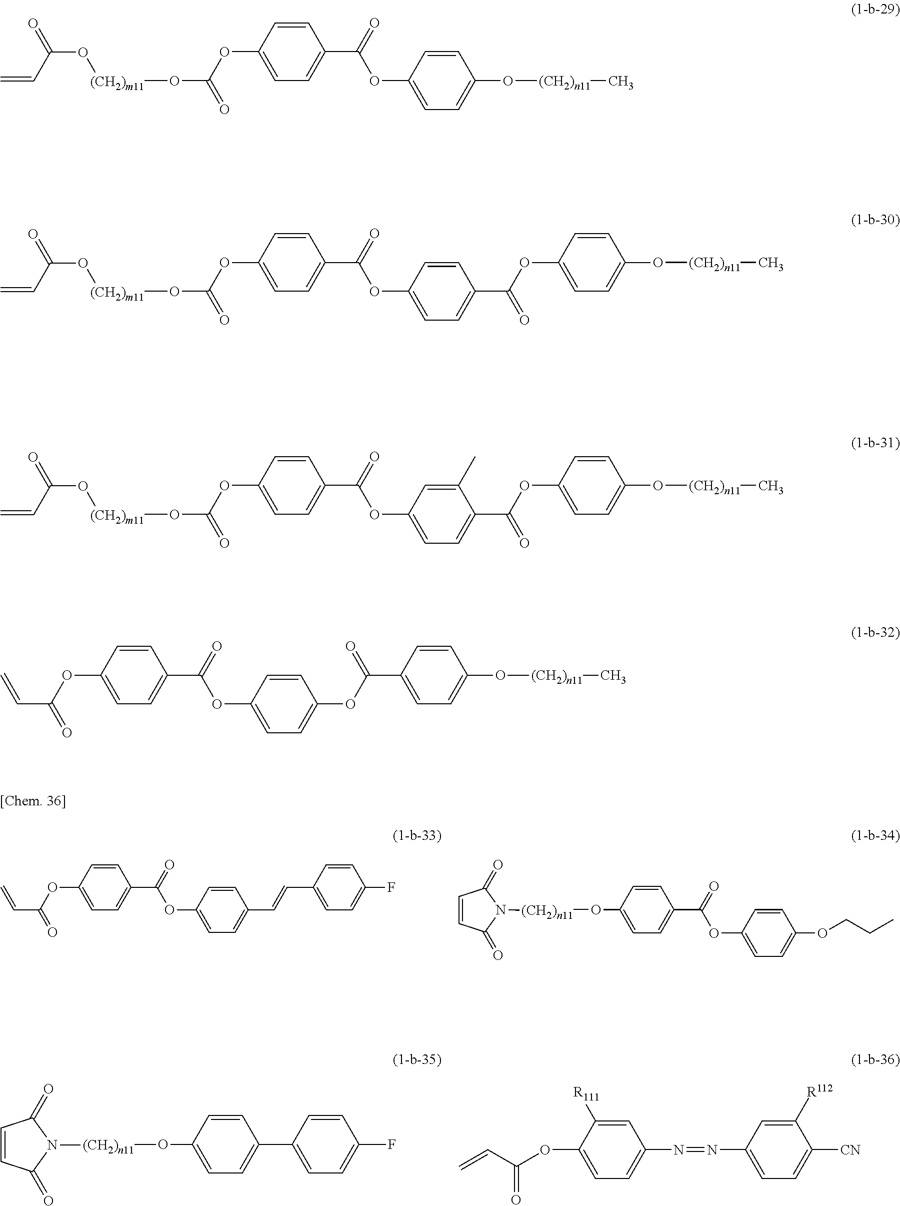

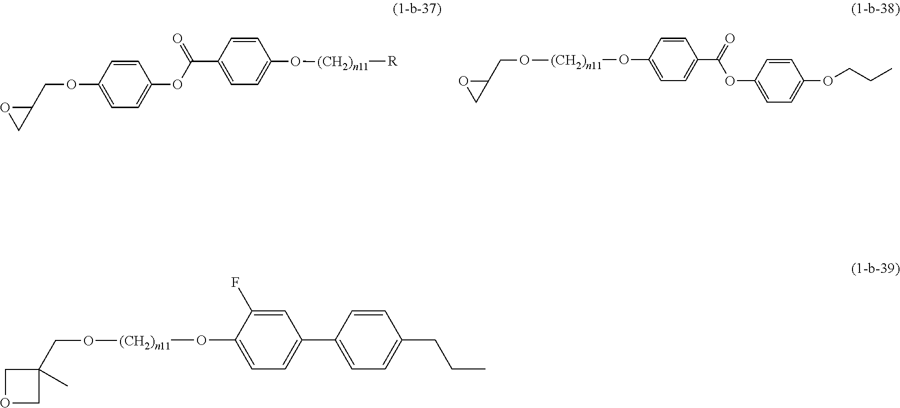

(wherein m11 and n11 each independently represent an integer of 1 to 10; R¹¹¹ and R¹¹² each independently represent a hydrogen atom, an alkyl group having 1 to 10 carbon atoms, or a fluorine atom; and R¹¹³ represents a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group which has 1 to 20 carbon atoms and in which one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C—, any hydrogen atom in the alkyl group being optionally replaced by a fluorine atom). These polymerizable liquid crystal compounds may be used alone or as a mixture of two or more.

Specific examples of the compound represented by general formula (2-b) include compounds represented by formula (2-b-1) to formula (2-b-34) below:

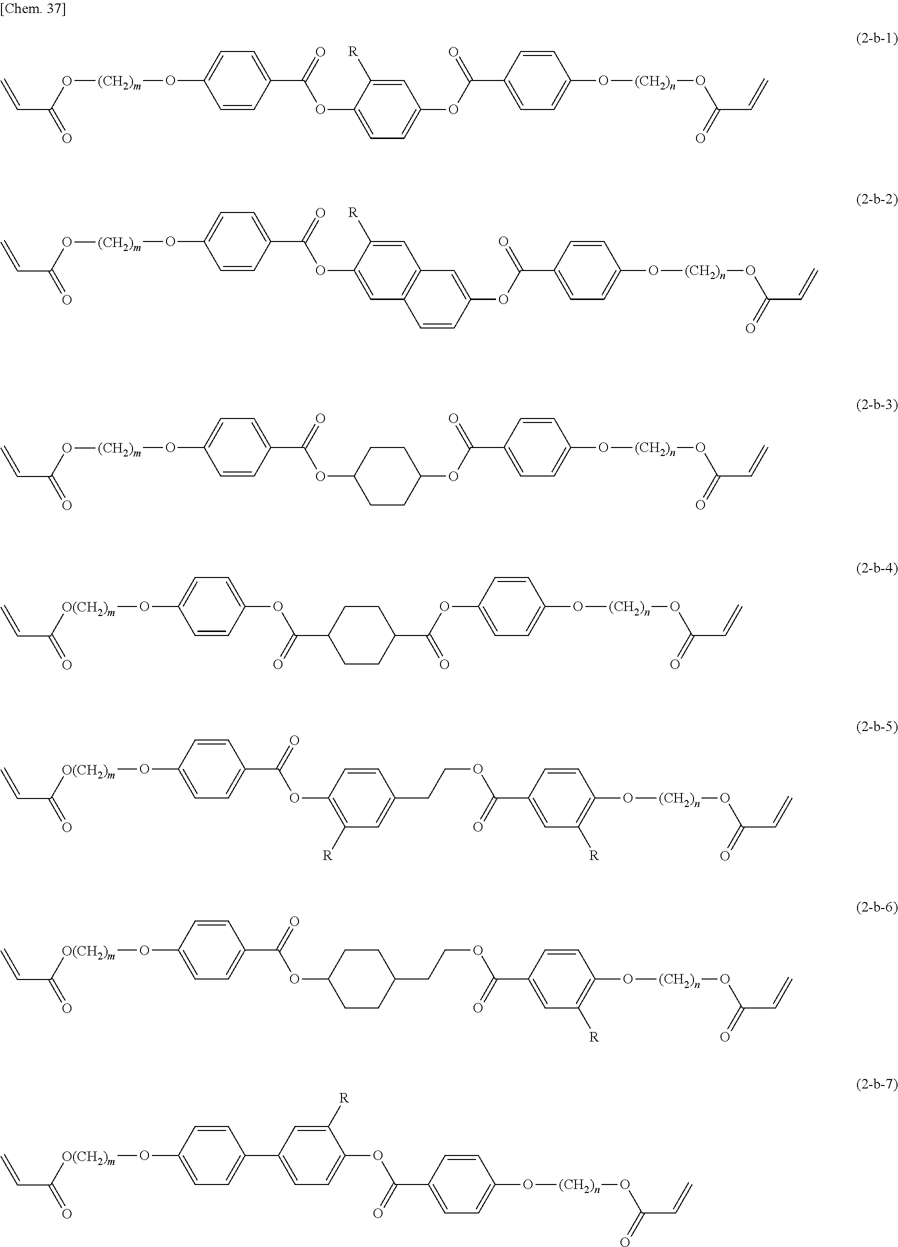

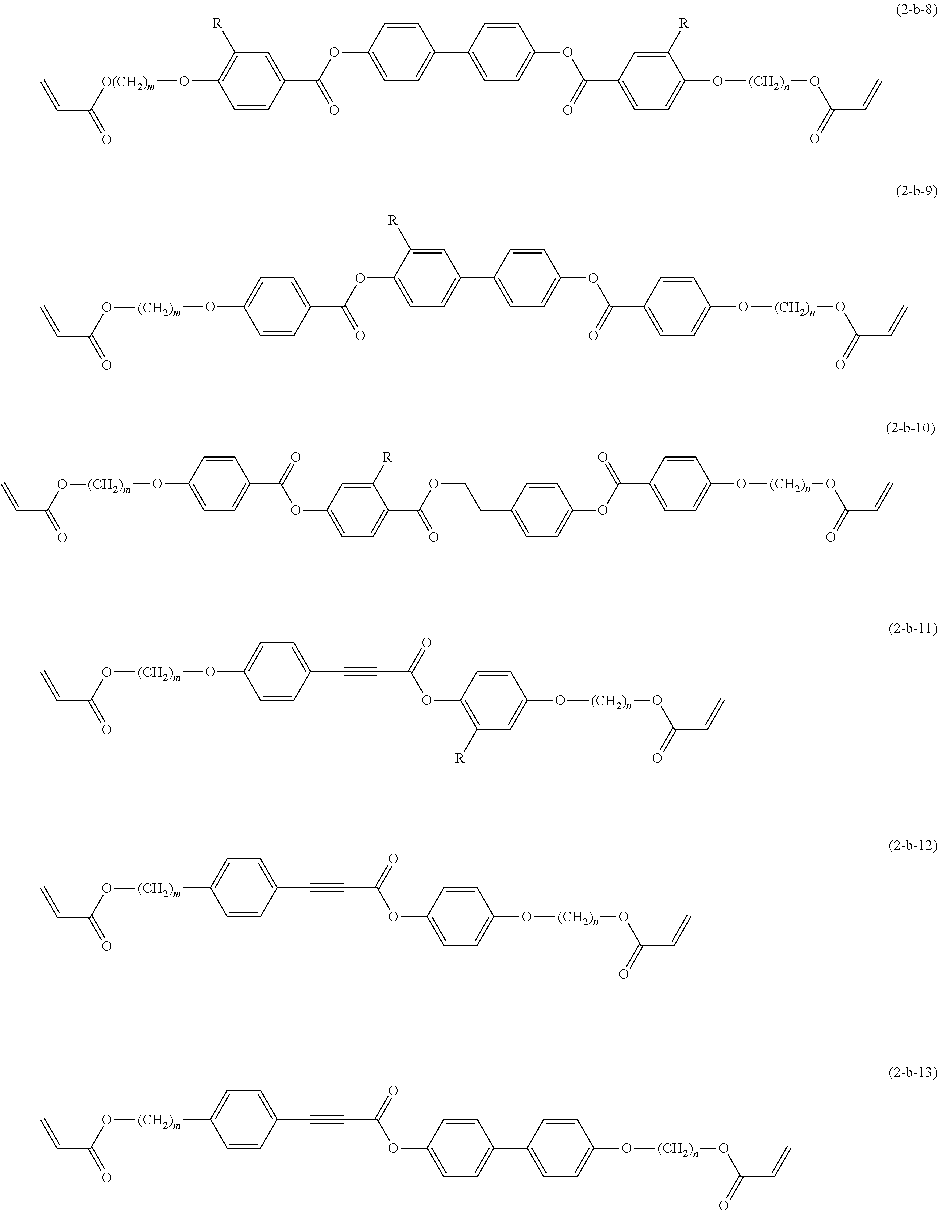

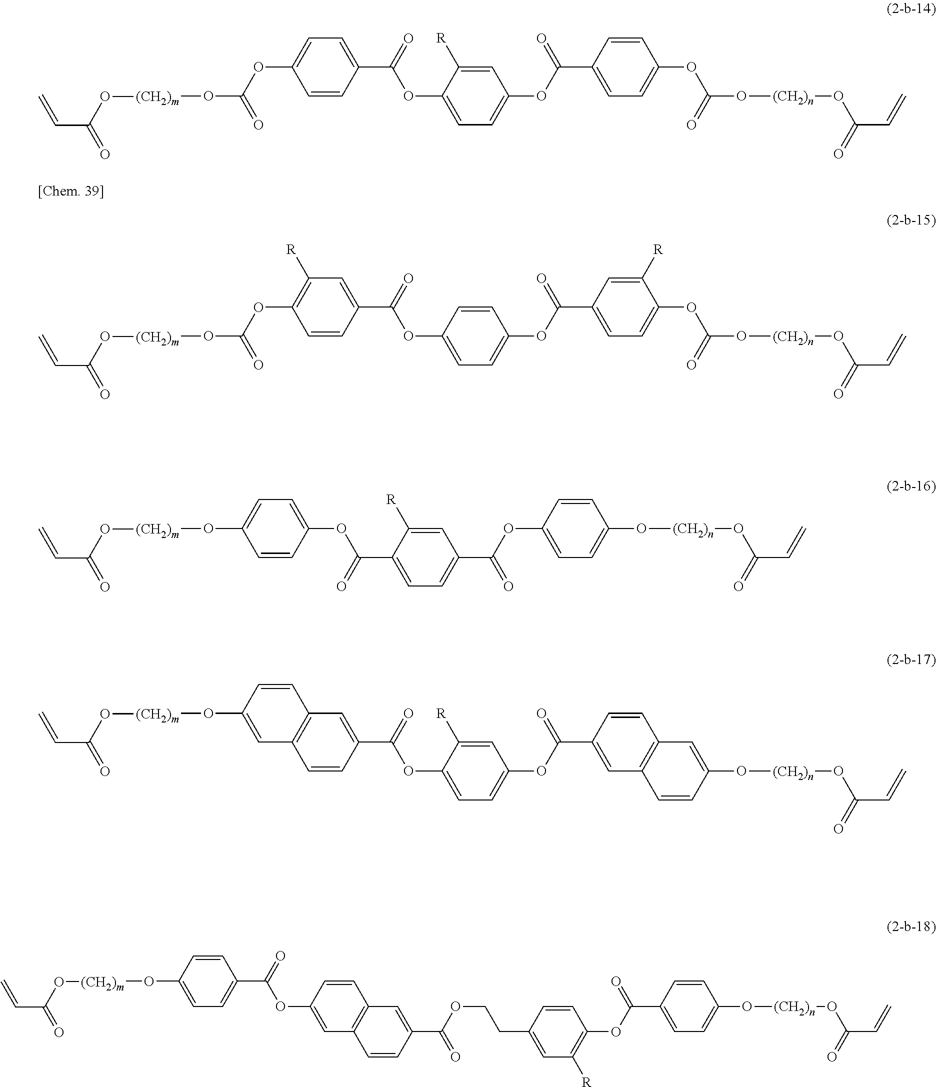

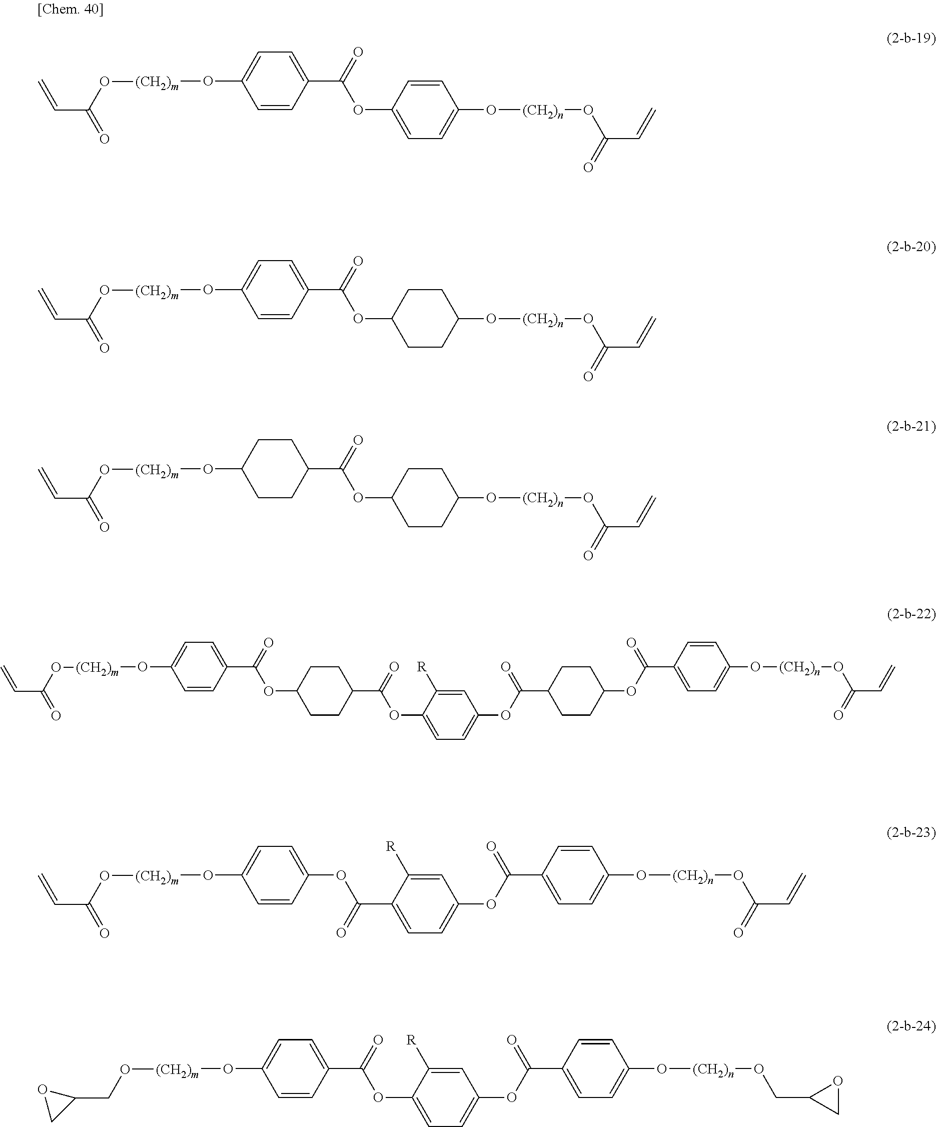

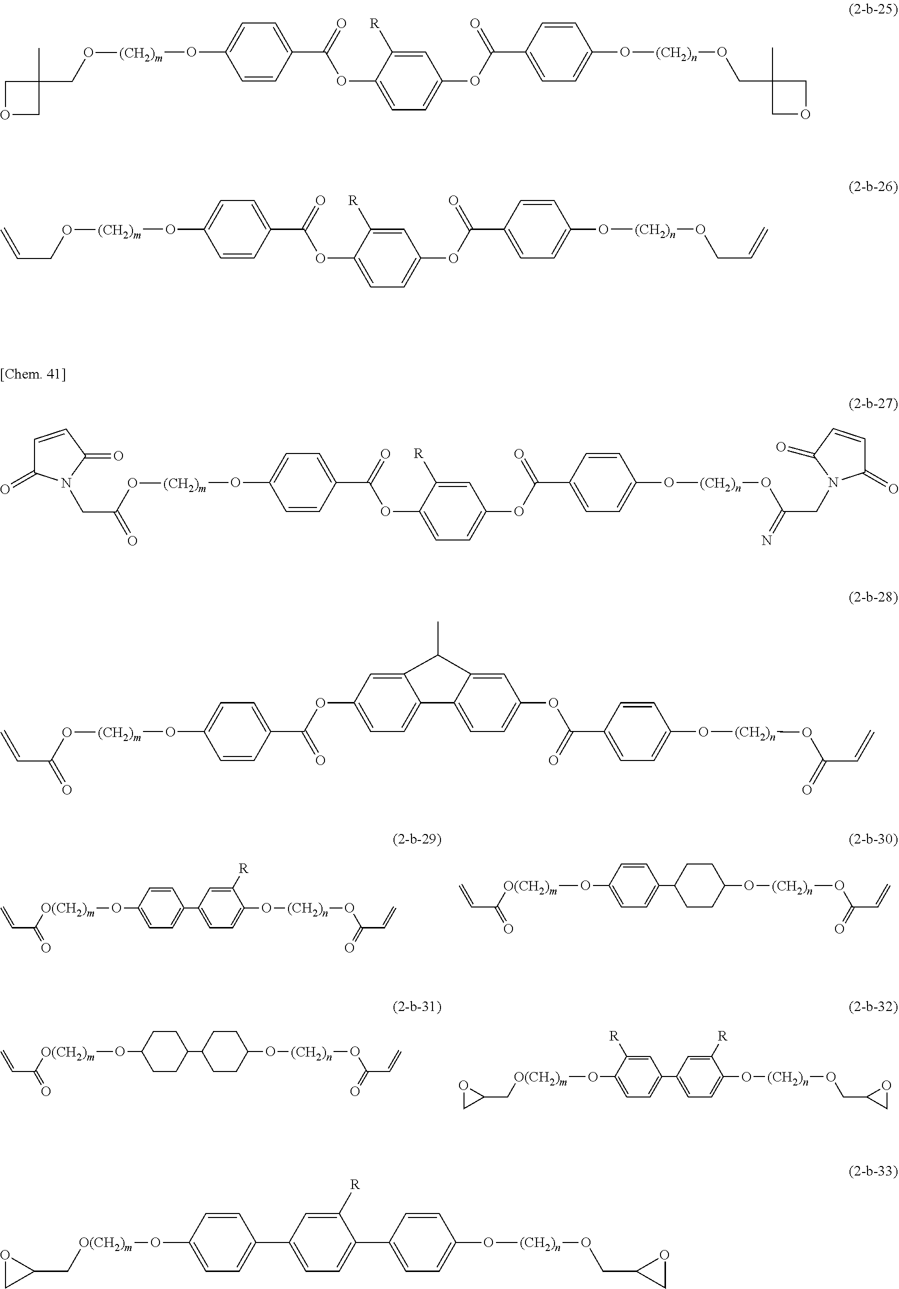

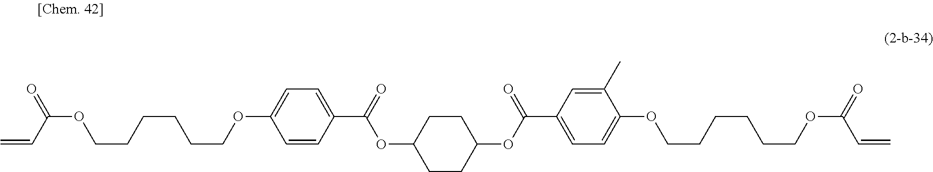

(wherein m and n each independently represent an integer of 1 to 18; R represents a hydrogen atom, halogen atom, an alkyl group having 1 to 6 carbon atoms, an alkoxy group having 1 to 6 carbon atoms, or a cyano group; when these groups are each an alkyl group having 1 to 6 carbon atoms or an alkoxy group having 1 to 6 carbon atoms, all of them are unsubstituted or may be substituted by one or two or more halogen atoms). These polymerizable liquid crystal compounds may be used alone or as a mixture of two or more.

When the polymerizable liquid crystal compound represented by the compound B and used for the first retardation layer includes the compound represented by general formula (1-b) above and/or the compound represented by formula (2-b) above, the total content of the compound represented by general formula (1-b) and/or the compound represented by general formula (2-b) is preferably 1 to 90% by mass, more preferably 2 to 70% by mass, and particularly preferably 3 to 50% by mass with respect to the total mass of the polymerizable liquid crystal compounds used for the polymerizable composition forming the first retardation layer.

When the polymerizable liquid crystal compound represented by the compound B and used for the second retardation layer includes the compound represented by general formula (1-b) above and/or the compound represented by formula (2-b) above, the total content of the compound represented by general formula (1-b) and/or the compound represented by general formula (2-b) is preferably 0 to 100% by mass, more preferably 50 to 100% by mass, and particularly preferably 90 to 100% by mass with respect to the total mass of the polymerizable liquid crystal compounds used for the polymerizable composition forming the second retardation layer.

### (Additional Polymerizable Liquid Crystal Compounds)

The first retardation layer of the optical film of the present invention may contain, in addition to the compound A and the compound B, at least one polymerizable compound selected from polymerizable compounds represented by general formulas (1) to (7) below.

The second retardation layer of the optical film of the present invention may contain, as the polymerizable compound satisfying (formula 1) above, at least one polymerizable compound selected from polymerizable compounds represented by general formulas (1) to (7) below:

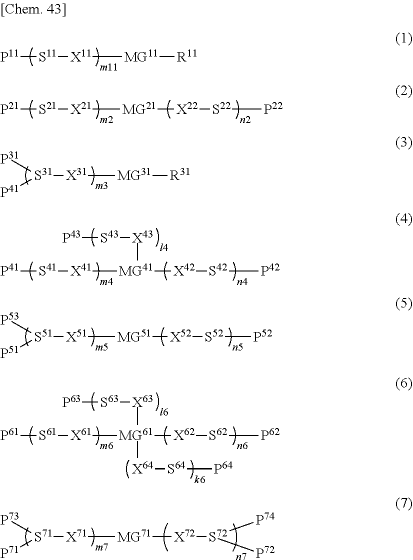

(in general formulas (1) to (7), P¹¹ to P⁷⁴ each represent a polymerizable group;

S¹¹ to S⁷² each represent a spacer group or a single bond; when a plurality of S¹¹s to S⁷²s are present, they may be the same or different;

X¹¹ to X⁷² each represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that each P—(S—X)— contains no —O—O—); when a plurality of X¹¹s to X⁷²s are present, they may be the same or different;

MG¹ to MG⁷¹ each independently represent formula (a):

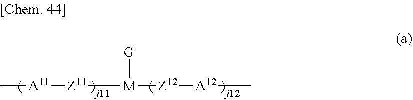

(wherein A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, each of which may be unsubstituted or substituted by at least one L³; when a plurality of A¹¹s and/or A¹²s are present, they may be the same or different;

Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF_{z}S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond; when a plurality of Z¹¹s and/or Z¹²s are present, they may be the same or different;

M represents a group selected from formula (M-1) to formula (M-11) below:

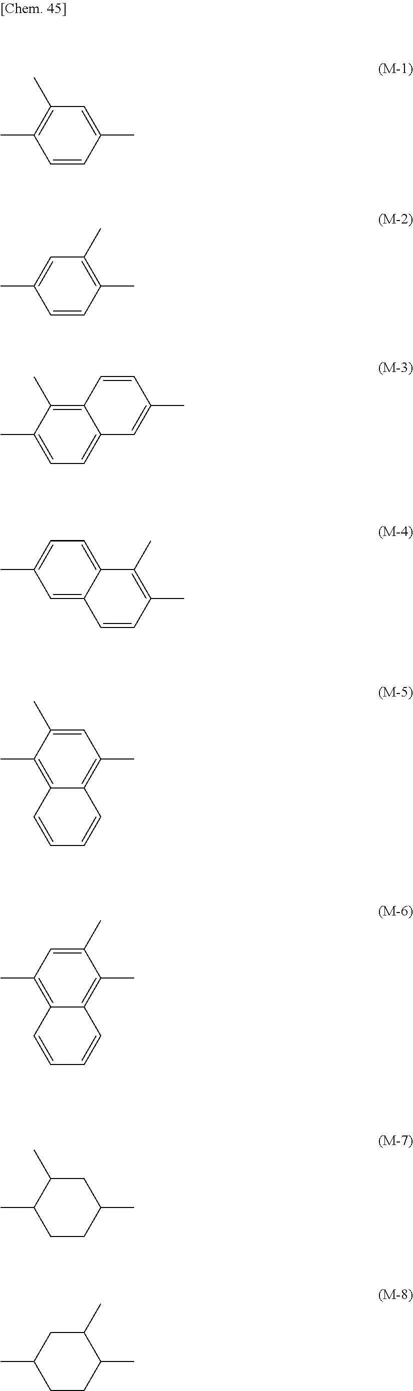

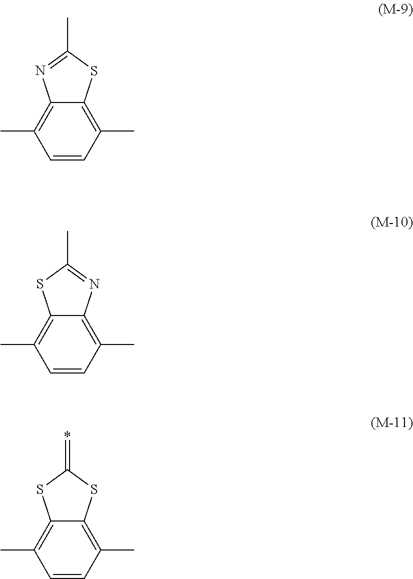

these groups may be unsubstituted or substituted by at least one L³;

G represents a group selected from formula (G-1) to formula (G-6) below:

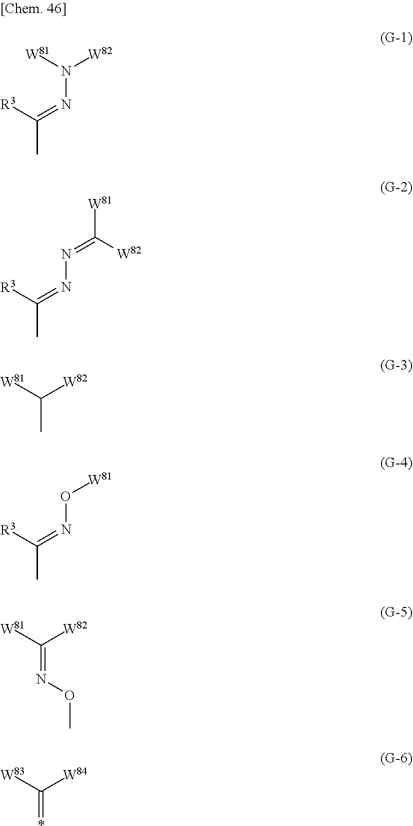

(wherein R³ represents a hydrogen atom or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by —O—, —S—, —CO—, —COO—, —OCO—, —CO—S—, —S—CO—, —O—CO—O—, —CO—NH—, —NH—CO—, or —C≡C—;

W⁸¹ represents a group that has at least one aromatic group and has 5 to 30 carbon atoms, the aromatic group being unsubstituted or optionally substituted by at least one L³;

W⁸² represents a hydrogen atom or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—; the meaning of W⁸² may be the same as the meaning of W⁸¹; W⁸¹ and W⁸² may be bonded together to form a single ring structure;

W⁸³ and W⁸⁴ each independently represent a halogen atom, a cyano group, a hydroxy group, a nitro group, a carboxyl group, a carbamoyloxy group, an amino group, a sulfamoyl group, a group having at least one aromatic group and having 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— group or two or more nonadjacent —CH₂— groups in each of the alkyl group, the cycloalkyl group, the alkenyl group, the cycloalkenyl group, the alkoxy group, the acyloxy group, and the alkylcarbonyloxy group being each independently optionally replaced by —O—, —S—, —CO—, —COO—, —OCO—, —CO—S—, —S—CO—, —O—CO—O—, —CO—NH—, —NH—CO—, or —C≡C—); when M is selected from formula (M-1) to formula (M-10) above, G is selected from formula (G-1) to formula (G-5); when M represents formula (M-11), G represents formula (G-6);

L³ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C≡C—; when a plurality of L³s are present in the compound, they may be the same or different;

j11 represents an integer from 1 to 5; j12 represents an integer of 1 to 5; and j11+j12 represents an integer from 2 to 5); R¹¹ and R³¹ each represent a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by —O—, —S—, —CO—, —COO—, —OCO—, —CO—S—, —S—CO—, —O—CO—O—, —CO—NH—, —NH—CO—, or —C≡C—; m11 represents an integer of 0 to 8; m2 to m7, n2 to n7, 14 to 16, and k6 each independently represent an integer from 0 to 5).

In general formula (1) to general formula (7), the polymerizable groups P¹¹ to P⁷⁴ preferably each represent a group selected from formula (P-1) formula (P-20) below.

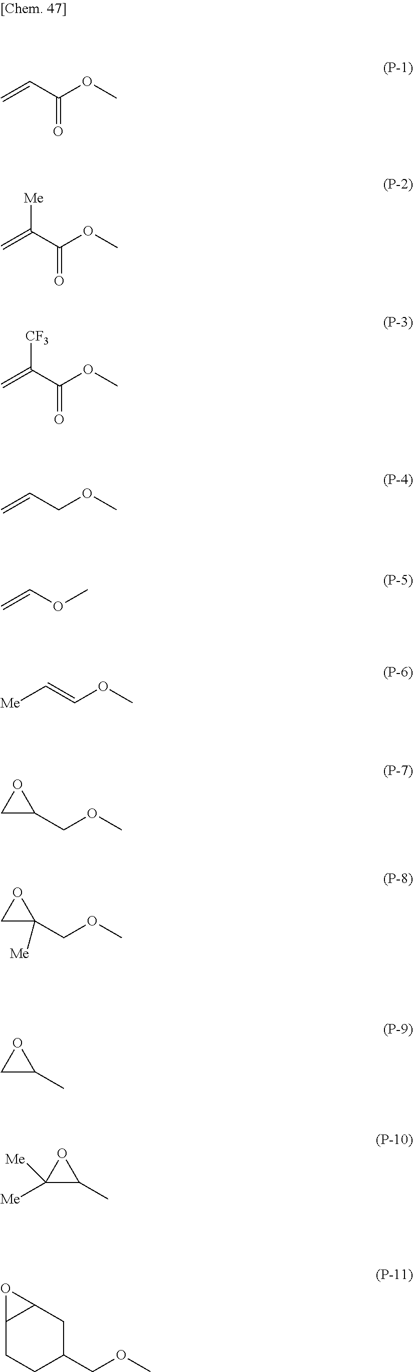

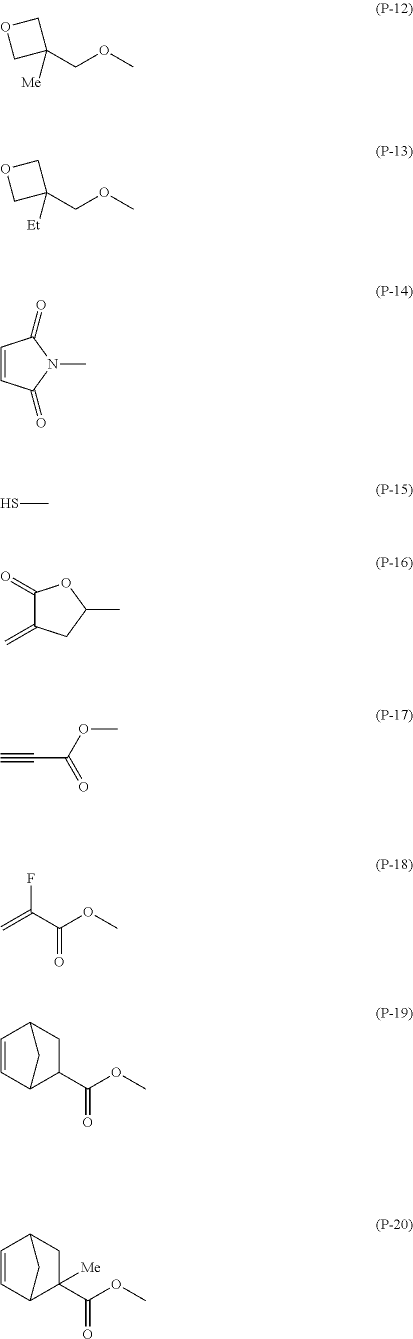

These polymerizable groups are polymerized by radical polymerization, radical addition polymerization, cationic polymerization, or anionic polymerization. In particular, when the polymerization method is UV polymerization, formula (P-1), formula (P-2), formula (P-3), formula (P-4), formula (P-5), formula (P-7), formula (P-11), formula (P-13), formula (P-15), or formula (P-18) is preferable, and formula (P-1), formula (P-2), formula (P-7), formula (P-11), or formula (P-13) is more preferable. Formula (P-1), formula (P-2) or formula (P-3) is still more preferable, and formula (P-1) or formula (P-2) is particularly preferable.

In general formula (1) to general formula (7), Sⁿ to S⁷² each represent a spacer group or a single bond. When a plurality of S¹¹s to S⁷²s are present, they may be the same or different. Preferably, the spacer group represents an alkylene group which has 1 to 20 carbon atoms and in which one —CH₂— group or two or more nonadjacent —CH₂— groups may be each independently replaced by —O—, —COO—, —OCO—, —OCO—O—, —CO—NH—, —NH—CO—, —CH═CH—, —C≡C—, or formula (S-1) below.

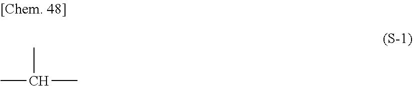

When a plurality of S's are present, they may be the same or different, more preferably each independently represent a single bond or an alkylene group which has 1 to 10 carbon atoms and in which one —CH₂— group or two or more nonadjacent —CH₂— groups may be each independently replaced by —O—, —COO—, or —OCO—, and still more preferably each independently represent a single bond or an alkylene group having 1 to 10 carbon atoms, in terms of availability of raw materials and ease of synthesis. When a plurality of S's are present, they may be the same or different and particularly preferably each independently represent an alkylene group having 1 to 8 carbon atoms.

In general formula (1) to general formula (7), X¹¹ to X⁷² each represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that each P—(S—X)— bond contains no —O—O—). When a plurality of X¹¹s to X⁷²s are present, they may be the same or different. In terms of availability of raw materials and ease of synthesis, when a plurality of X¹¹s to X⁷²s are present, they may be the same or different, preferably each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond, and more preferably each independently represent —O—, —OCH₂—, —CH₂O—, —COO—, —OCO—, —COO—CH₂CH₂—, —OCO—CH₂CH₂—, —CH₂CH₂—COO—, —CH₂CH₂—OCO—, or a single bond. When a plurality of X¹¹s to X⁷²s are present, they may be the same or different and particularly preferably each independently represent —O—, —COO—, —OCO—, or a single bond.

In formula (a) above, A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, each of which may be unsubstituted or substituted by at least one L³. When a plurality of A¹¹s and/or A¹²s are present, they may be the same or different. In terms of availability of raw materials and ease of synthesis, A¹¹ and A¹² preferably each independently represent a 1,4-phenylene group, a 1,4-cyclohexylene group, or naphthalene-2,6-diyl which may be unsubstituted or substituted by at least one L³, more preferably each independently represent a group selected from formula (A-1) to formula (A-11) below:

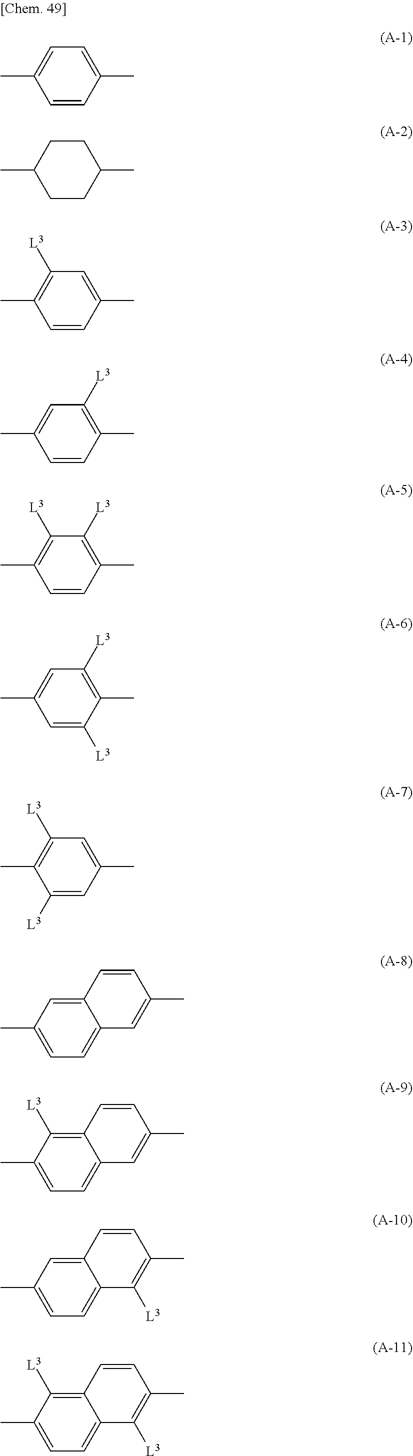

still more preferably each independently represent a group selected from formula (A-1) to formula (A-8), and particularly preferably each independently represent a group selected from formula (A-1) to formula (A-4).

In formula (a) above, Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond. When a plurality of Z¹¹s and/or Z¹²s are present, they may be the same or different. In terms of the liquid crystallinity of the compound, availability of raw materials, and ease of synthesis, Z¹¹ and Z¹² preferably each independently represent —OCH₂—, —CH_{z}O—, —COO—, —OCO—, —CF₂O—, —OCF₂—, —CH₂CH₂—, —CF₂CF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —CH═CH—, —CF═CF—, —C≡C—, or a single bond, more preferably each independently represent —OCH₂—, —CH₂O—, —CH₂CH₂—, —COO—, —OCO—, —COO—CH₂CH₂—, —OCO—CH₂CH₂—, —CH₂CH₂—COO—, —CH₂CH₂—OCO—, —CH═CH—, —C≡C—, or a single bond, still more preferably each independently represent —CH₂CH₂—, —COO—, —OCO—, —COO—CH₂CH₂—, —OCO—CH₂CH₂—, —CH₂CH₂—COO—, —CH₂CH₂—OCO—, or a single bond, and particularly preferably each independently represent —CH₂CH₂—, —COO—, —OCO—, or a single bond.

In formula (a) above, M represents a group selected from formula (M-1) to formula (M-11) below.

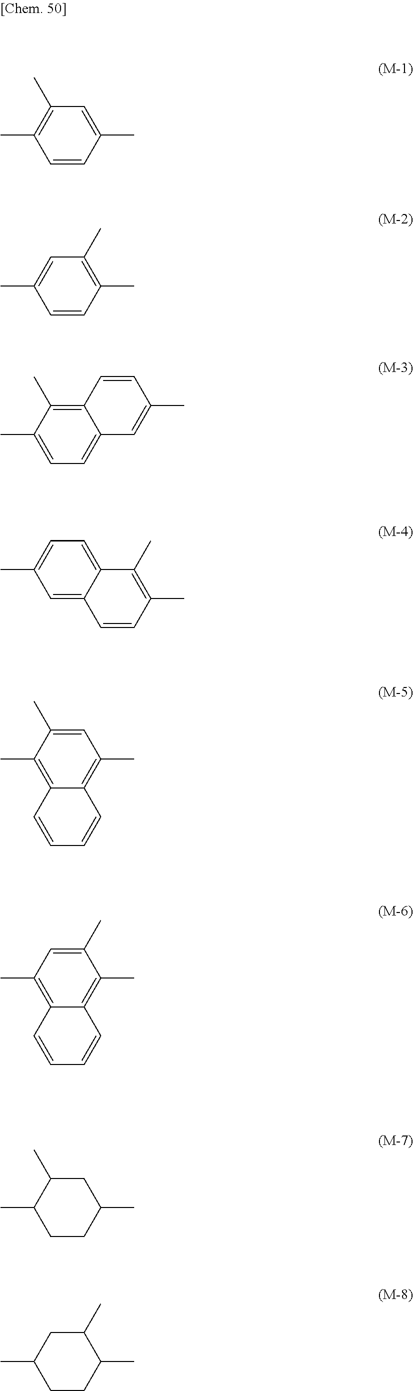

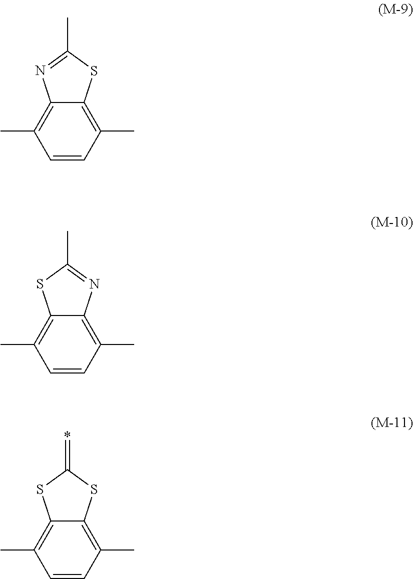

These groups may be unsubstituted or substituted by at least one L³. In terms of availability of raw materials and ease of synthesis, M preferably represents a group selected from formula (M-1) and formula (M-2) which may be unsubstituted or substituted by at least one L and unsubstituted formula (M-3) to unsubstituted formula (M-6), more preferably represents a group selected from formula (M-1) and formula (M-2) which may be unsubstituted or substituted by at least one L³, and particularly preferably represents a group selected from unsubstituted formula (M-1) and unsubstituted formula (M-2).

In general formula (1) to general formula (7), R¹¹ and R³¹ each independently represent a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group which has 1 to 20 carbon atoms and in which one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C—, any hydrogen atom in the alkyl group being optionally replaced by a fluorine atom. In terms of liquid crystallinity and ease of synthesis, R¹ and R³¹ preferably each independently represent a hydrogen atom, a fluorine atom, a chlorine atom, a cyano group, or a linear or branched alkyl group which has 1 to 12 carbon atoms and in which one —CH₂— group or two or more nonadjacent —CH₂— groups may be each independently replaced by —O—, —COO—, —OCO—, or —O—CO—O—, more preferably each independently represent a hydrogen atom, a fluorine atom, a chlorine atom, a cyano group, or a linear alkyl or alkoxy group having 1 to 12 carbon atoms, and particularly preferably each independently represent a linear alkyl or alkoxy group having 1 to 12 carbon atoms.

In formula (a) above, G represents a group selected from formula (G-1) to formula (G-6).

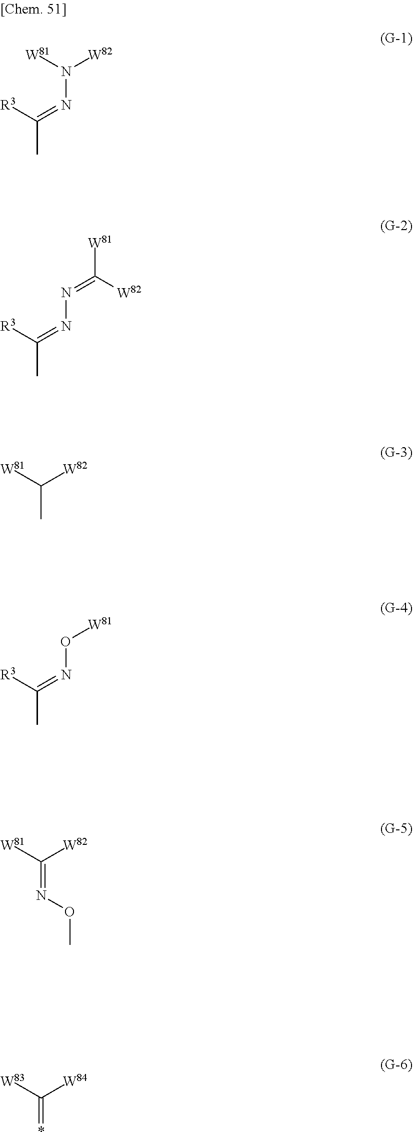

When M is selected from formula (M-1) to formula (M-10), G is selected from formula (G-1) to formula (G-5). When M represents formula (M-11), G represents formula (G-6). * in each of M and G represents a bonding portion. One of two bonds in M other than * is bonded to Z¹¹ or A¹¹ present, and the other one of the two bonds is bonded to Z¹² or A¹² present.

In formula (G-1) to formula (G-6), R³ represents a hydrogen atom or an alkyl group having 1 to 20 carbon atoms. The alkyl group may be linear or branched, and any hydrogen atom in the alkyl group may be replaced by a fluorine atom. One —CH₂— group or two or more nonadjacent —CH₂— groups in the alkyl group may be each independently replaced by —O—, —S—, —CO—, —COO—, —OCO—, —CO—S—, —S—CO—, —O—CO—O—, —CO—NH—, —NH—CO—, or —C≡C—.

In formula (G-1) to formula (G-6), W⁸¹ represents a group that has at least one aromatic group and has 5 to 30 carbon atoms, and this group may be unsubstituted or substituted by at least one L³.

In formula (G-1) to formula (G-6), W⁸² represents a hydrogen atom or an alkyl group having 1 to 20 carbon atoms. The alkyl group may be linear or branched, and any hydrogen atom in the alkyl group may be replaced by a fluorine atom. One —CH₂— group or two or more nonadjacent —CH₂— groups in the alkyl group may be each independently replaced by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—. The meaning of W³² may be the same as the meaning of W⁸¹, and W⁸¹ and W⁸² may be bonded together to form a single ring structure.

In formula (G-1) to formula (G-6), the aromatic group included in W⁸¹ may be an aromatic hydrocarbon group or a heteroaromatic group, and W⁸¹ may include both of them. These aromatic groups may be bonded through a single bond or a linking group (—OCO—, —COO—, —CO—, or —O—) or may form a condensed ring. W⁸¹ may include, in addition to the aromatic group, an acyclic structure and/or a cyclic structure other than the aromatic group. In terms of availability of raw materials and ease of synthesis, the aromatic group included in W⁸¹ represents a group selected from formula (W-1) to formula (W-19) below that may be unsubstituted or substituted by at least one L³:

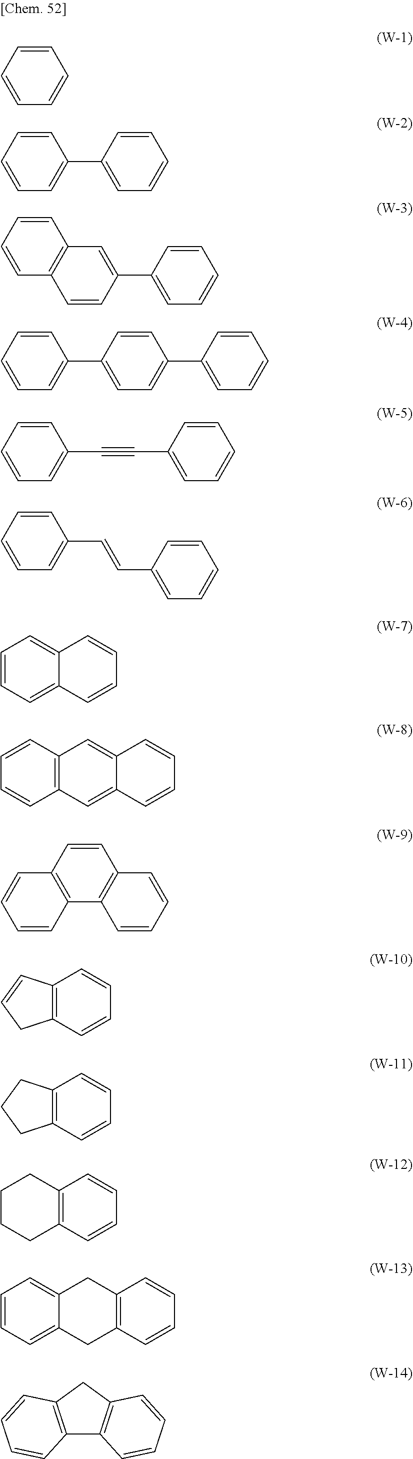

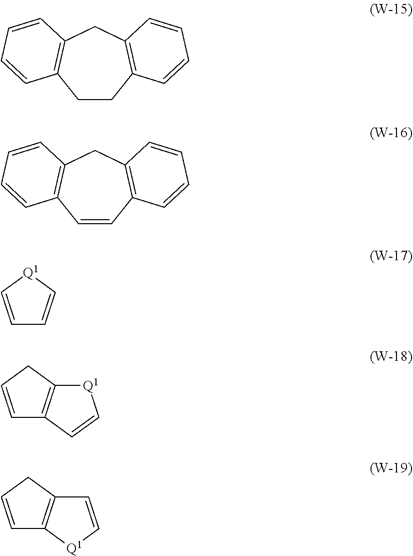

(wherein these groups may each have at least one bond at any position; two or more aromatic groups selected from these groups may be connected through a single bond to form a single group; and Q¹ represents —O—, —S—, —NR⁴— (wherein R⁴ represents a hydrogen atom or an alkyl group having 1 to 8 carbon atoms), or —CO—. In these aromatic groups, —CH═ groups may be each independently replaced by —N═, and —CH₂— groups may be each independently replaced by —O—, —S—, —NR⁴— (wherein R⁴ represents a hydrogen atom or an alkyl group having 1 to 8 carbon atoms), or —CO—. However, these groups contain no —O—O— bond).

The group represented by formula (W-1) is preferably a group selected from formula (W-1-1) to formula (W-1-8) below that may be unsubstituted or substituted by at least one L³:

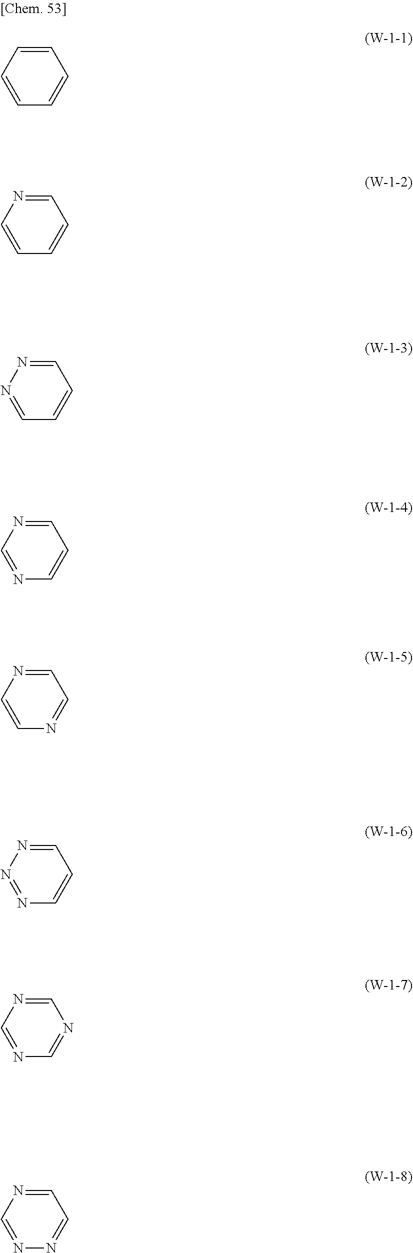

(wherein these groups may each have at least one bond at any position).

The group represented by formula (W-7) is preferably a group selected from formula (W-7-1) to formula (W-7-7) below that may be unsubstituted or substituted by at least one L³:

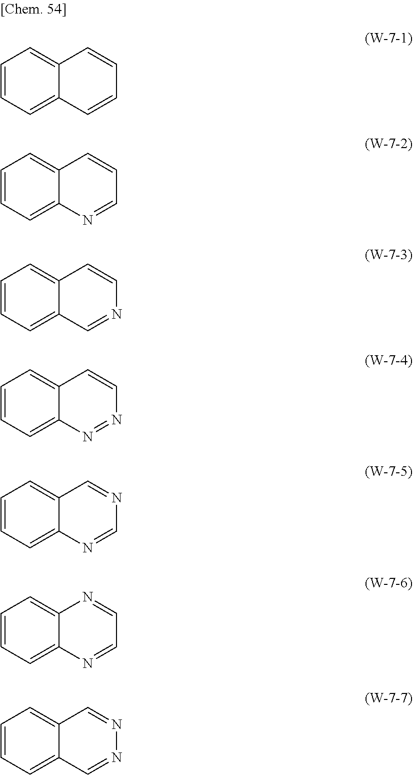

(wherein these groups may each have a bond at at least one position).

The group represented by formula (W-10) is preferably a group selected from formula (W-10-1) to formula (W-10-8) below that may be unsubstituted or substituted by at least one L³:

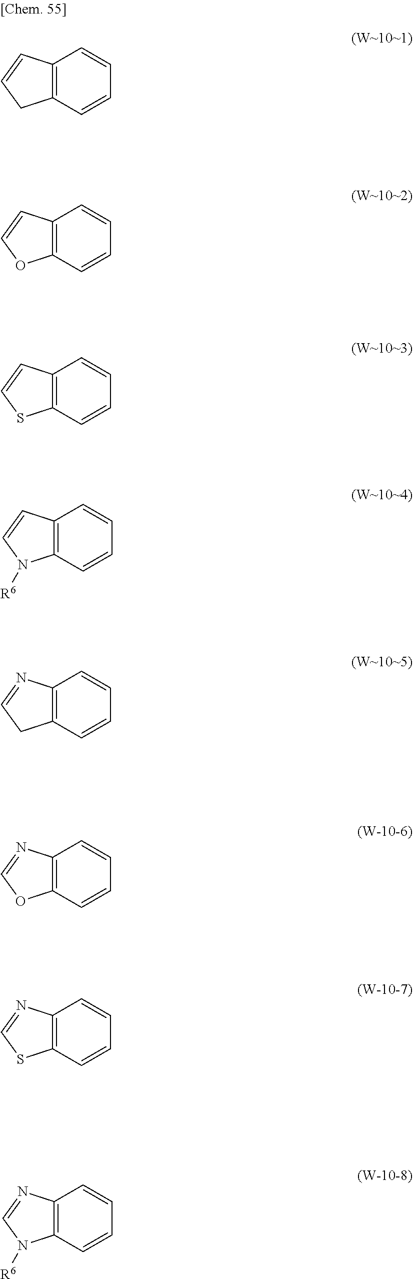

(wherein these groups may each have at least one bond at any position, and R⁶ represents a hydrogen atom or an alkyl group having 1 to 8 carbon atoms).

The group represented by formula (W-11) is preferably a group selected from formula (W-11-1) to formula (W-11-13) below that may be unsubstituted or substituted by at least one L³:

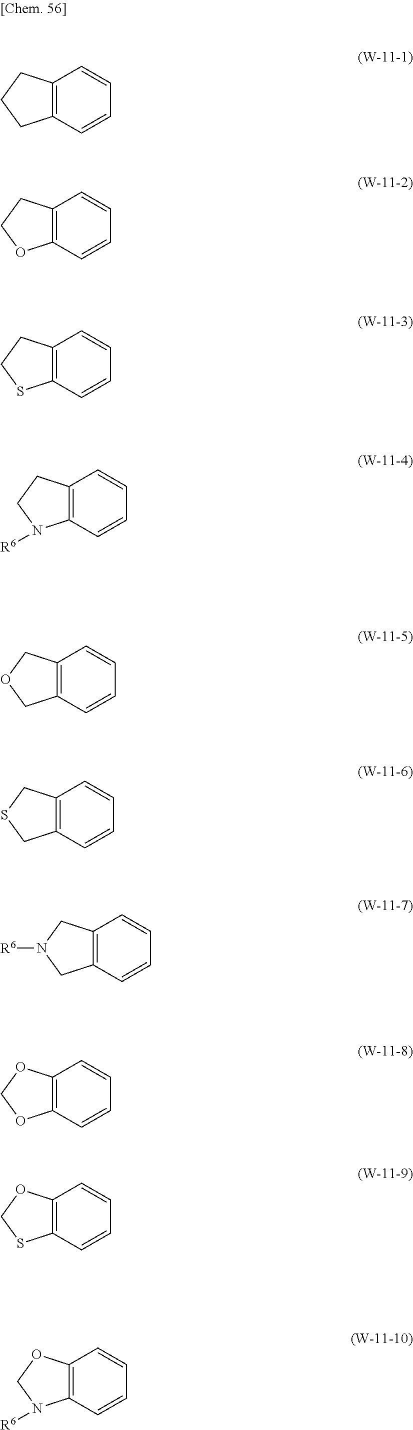

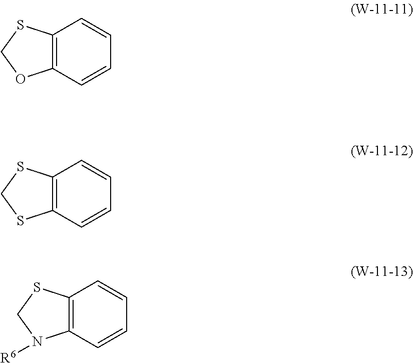

(wherein these groups may each have at least one bond at any position, and R⁶ represents a hydrogen atom or an alkyl group having 1 to 8 carbon atoms).

The group represented by formula (W-12) is preferably a group selected from formula (W-12-1) to formula (W-12-19) below that may be unsubstituted or substituted by at least one L:

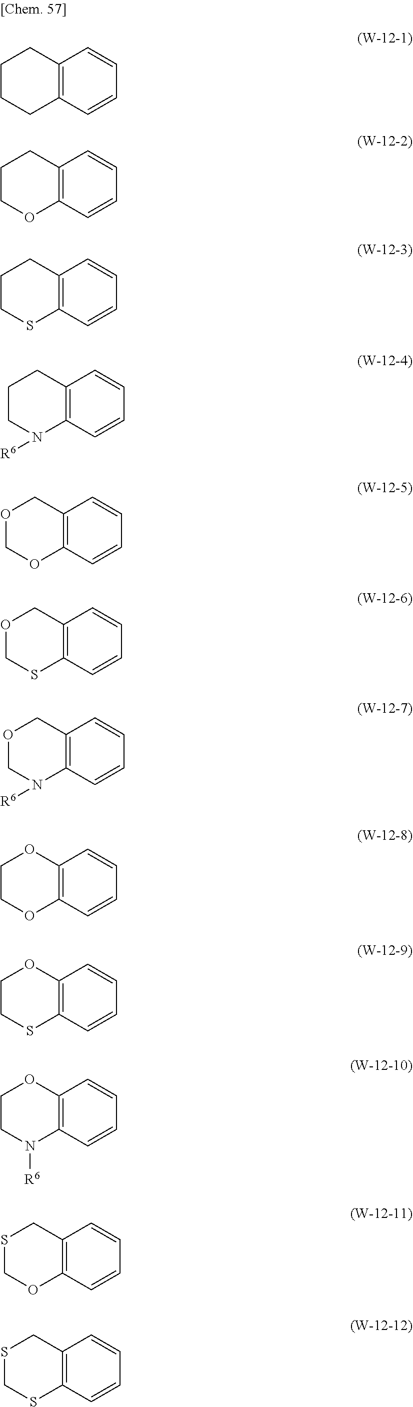

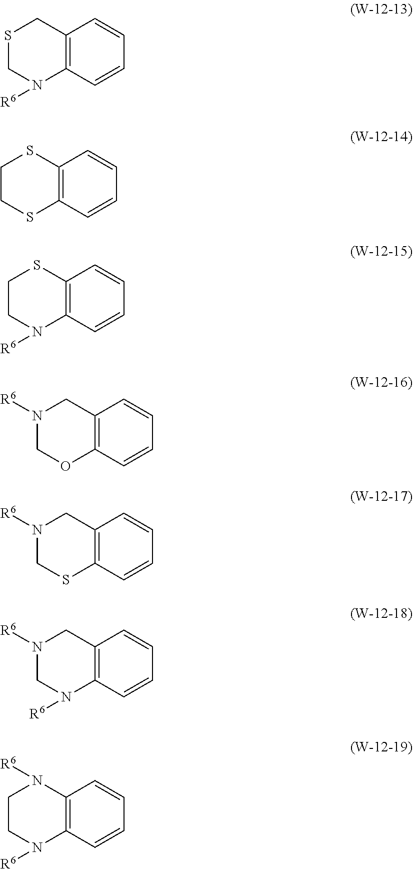

(wherein these groups may each have at least one bond at any position; R^{b} represents a hydrogen atom or an alkyl group having 1 to 8 carbon atoms; and when a plurality of R⁶s are present, they may be the same or different).

The group represented by formula (W-13) is preferably a group selected from formula (W-13-1) to formula (W-13-10) below that may be unsubstituted or substituted by at least one L:

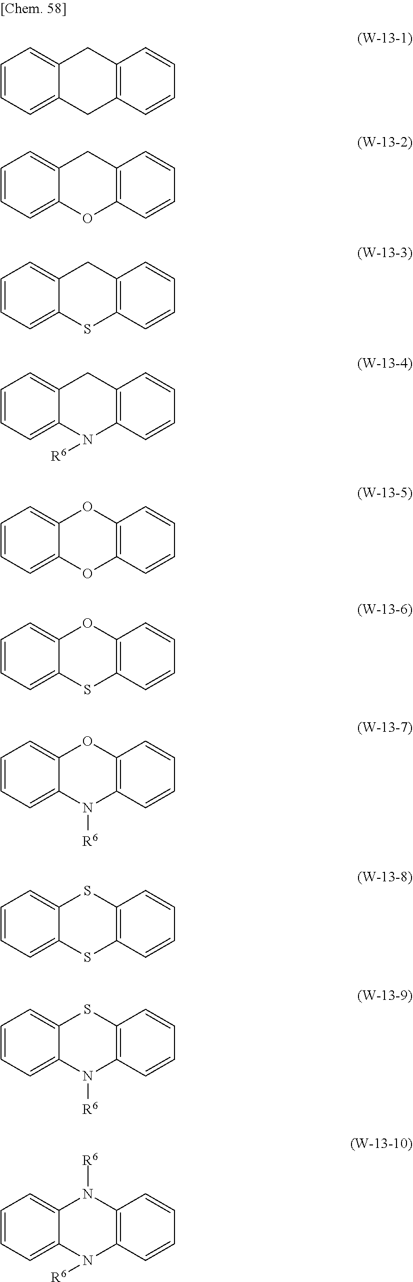

(wherein these groups may each have at least one bond at any position; R⁶ represents a hydrogen atom or an alkyl group having 1 to 8 carbon atoms; and when a plurality of R⁶s are present, they may be the same or different).

The group represented by formula (W-14) is preferably a group selected from formula (W-14-1) to formula (W-14-4) below that may be unsubstituted or substituted by at least one L:

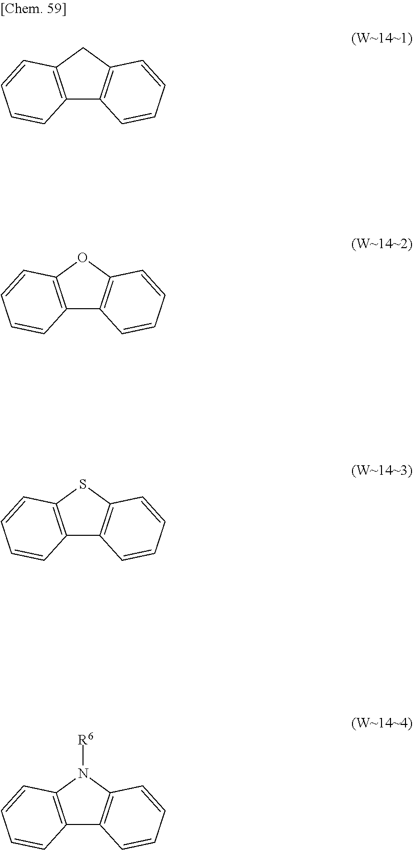

(wherein these groups may each have at least one bond at any position, and R⁶ represents a hydrogen atom or an alkyl group having 1 to 8 carbon atoms).

The group represented by formula (W-15) is preferably a group selected from formula (W-15-1) to formula (W-15-18) below that may be unsubstituted or substituted by at least one L³:

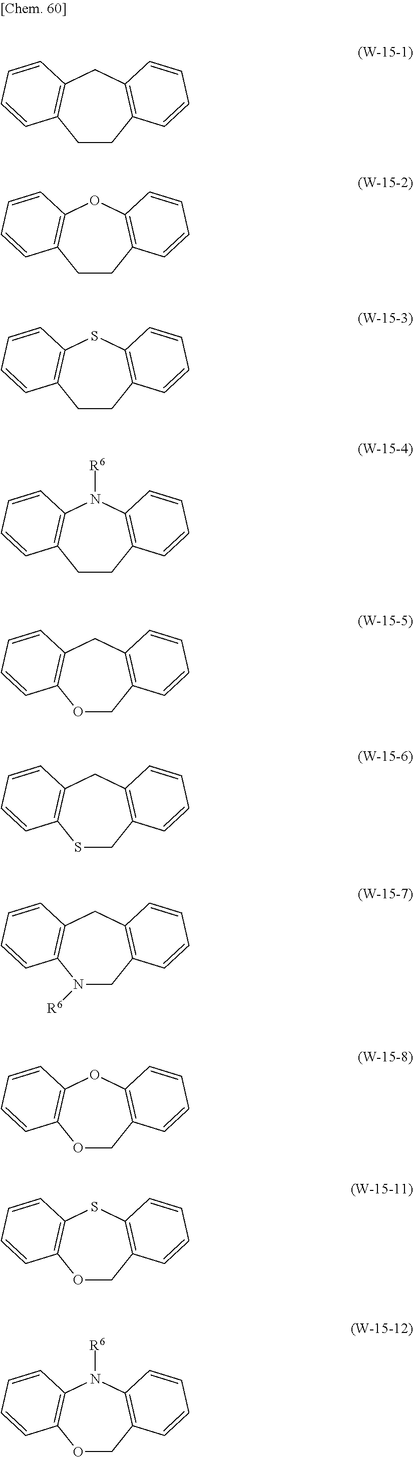

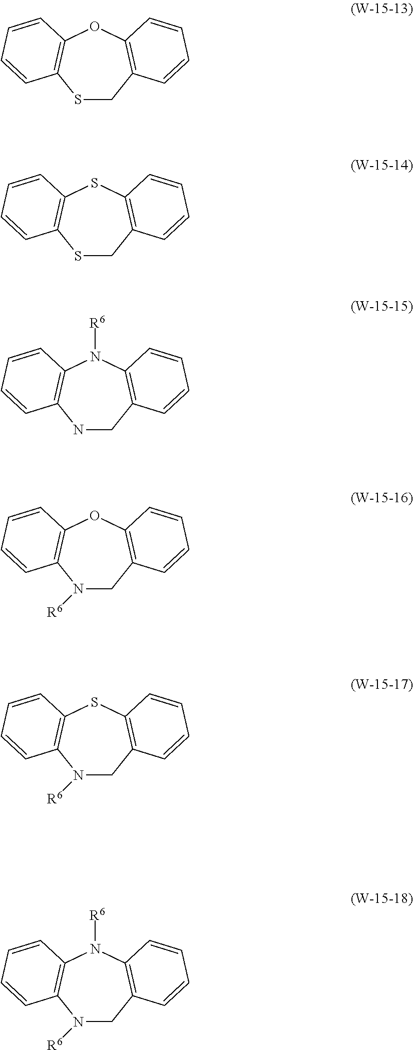

(wherein these groups may each have at least one bond at any position, and R⁶ represents a hydrogen atom or an alkyl group having 1 to 8 carbon atoms).

The group represented by formula (W-16) is preferably a group selected from formula (W-16-1) to formula (W-16-4) below that may be unsubstituted or substituted by at least one L³:

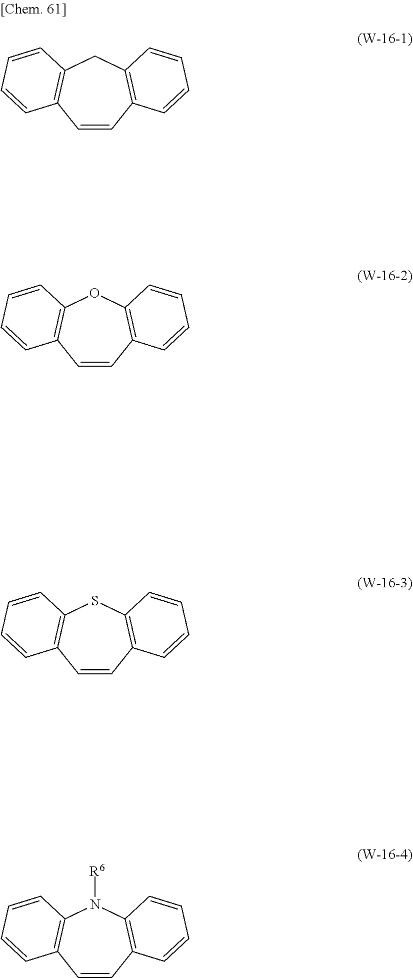

(wherein these groups may each have at least one bond at any position, and R⁶ represents a hydrogen atom or an alkyl group having 1 to 8 carbon atoms).

The group represented by formula (W-17) is preferably a group selected from formula (W-17-1) to formula (W-17-6) below that may be unsubstituted or substituted by at least one L³:

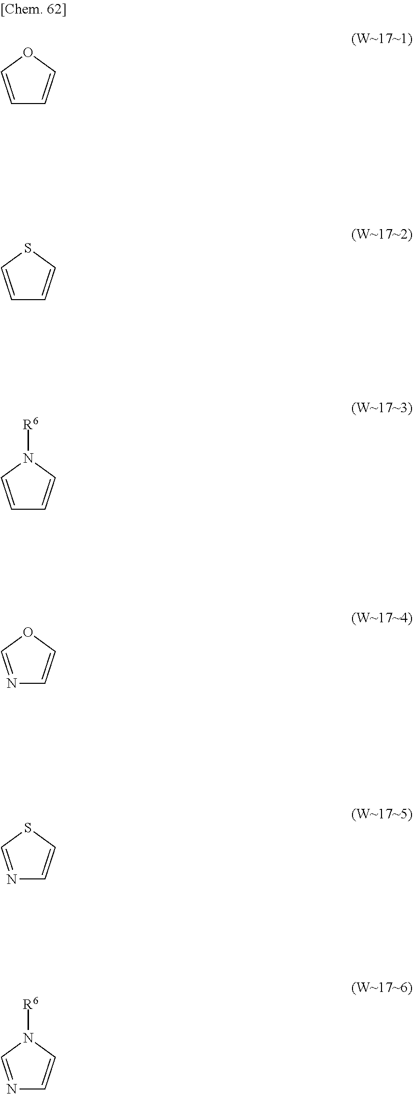

(wherein these groups may each have at least one bond at any position, and R⁶ represents a hydrogen atom or an alkyl group having 1 to 8 carbon atoms).

The group represented by formula (W-18) is preferably a group selected from formula (W-18-1) to formula (W-18-6) below that may be unsubstituted or substituted by at least one L³:

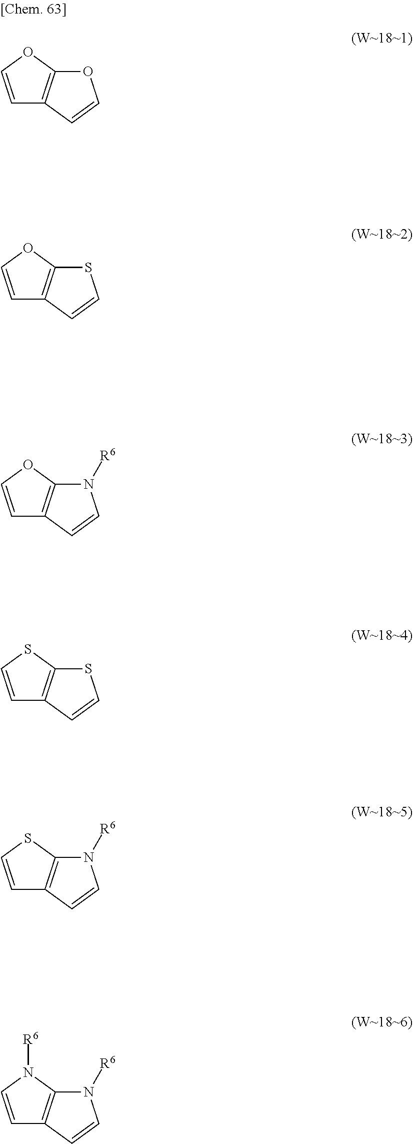

(wherein these groups may each have at least one bond at any position; R⁶ represents a hydrogen atom or an alkyl group having 1 to 8 carbon atoms; and when a plurality of R's are present, they may be the same or different).

The group represented by formula (W-19) is preferably a group selected from formula (W-19-1) to formula (W-19-9) below that may be unsubstituted or substituted by at least one L³:

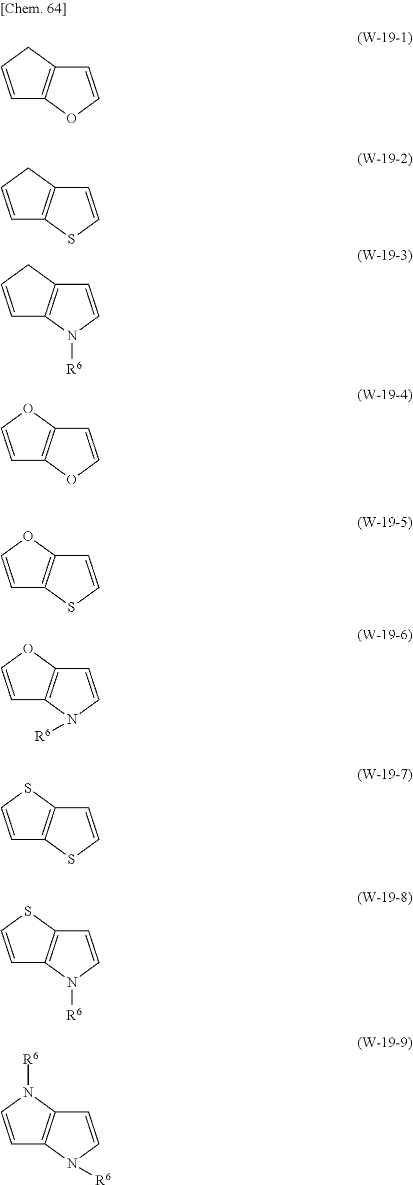

(wherein these groups may each have at least one bond at any position; R⁶ represents a hydrogen atom or an alkyl group having 1 to 8 carbon atoms; and when a plurality of R⁶s are present, they may be the same or different).

The aromatic group included in W⁸¹ is more preferably a group selected from formula (W-1-1), formula (W-7-1), formula (W-7-2), formula (W-7-7), formula (W-8), formula (W-10-6), formula (W-10-7), formula (W-10-8), formula (W-11-8), formula (W-11-9), formula (W-11-10), formula (W-11-11), formula (W-11-12), and formula (W-11-13) that may be unsubstituted or substituted by at least one L³ and is particularly preferably a group selected from formula (W-1-1), formula (W-7-1), formula (W-7-2), formula (W-7-7), formula (W-10-6), formula (W-10-7), and formula (W-10-8) that may be unsubstituted or substituted by at least one L³.

Preferably, W⁸¹ represents a group selected from formula (W-a-1) to formula (W-a-6) below:

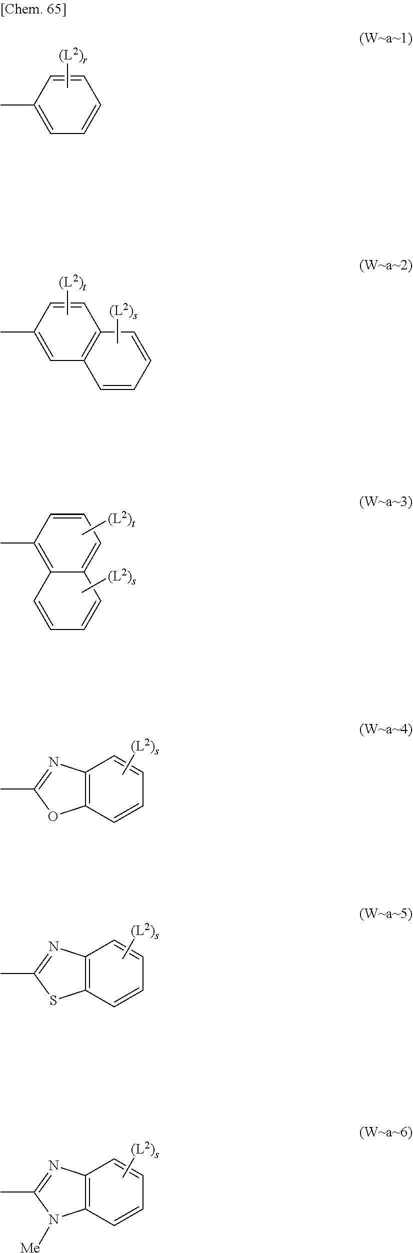

(wherein r represents an integer from 0 to 5; s represents an integer from 0 to 4; and t represents an integer from 0 to 3).

W⁸² represents a hydrogen atom or a linear or branched alkyl group which has 1 to 20 carbon atoms and in which one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and any hydrogen atom in the alkyl group may be replaced by a fluorine atom. The meaning of W⁸² may be the same as the meaning of W⁸¹, and W⁸¹ and W⁸² may together form a ring structure. In terms of availability of raw materials and ease of synthesis, W⁸² preferably represents a hydrogen atom or a linear or branched alkyl group which has 1 to 20 carbon atoms, in which any hydrogen atom may be replaced by a fluorine atom, and in which one —CH₂— group or two or more nonadjacent —CH₂— groups may be each independently replaced by —O—, —CO—, —COO—, —OCO—, —CH═CH—COO—, —OCO—CH═CH—, —CH═CH—, —CF═CF—, or —C≡C—, more preferably represents a hydrogen atom or a linear or branched alkyl group which has 1 to 20 carbon atoms, and particularly preferably represents a hydrogen atom or a linear alkyl group having 1 to 12 carbon atoms. When the meaning of W⁸² is the same as the meaning of W⁸¹, W⁸² and W⁸¹ may be the same or different, and preferred groups for W⁸² are the same as those described for W⁸¹.

When W⁸¹ and W⁸² together form a ring structure, a ring group represented by —NW⁸¹W⁸² is preferably a group selected from formula (W-b-1) to formula (W-b-42) below that may be unsubstituted or substituted by at least one L³:

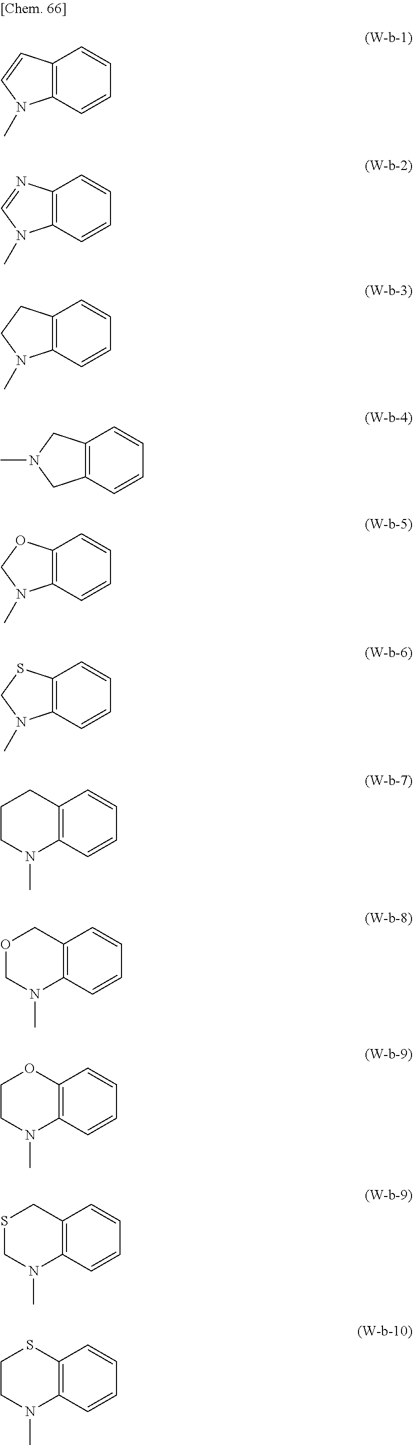

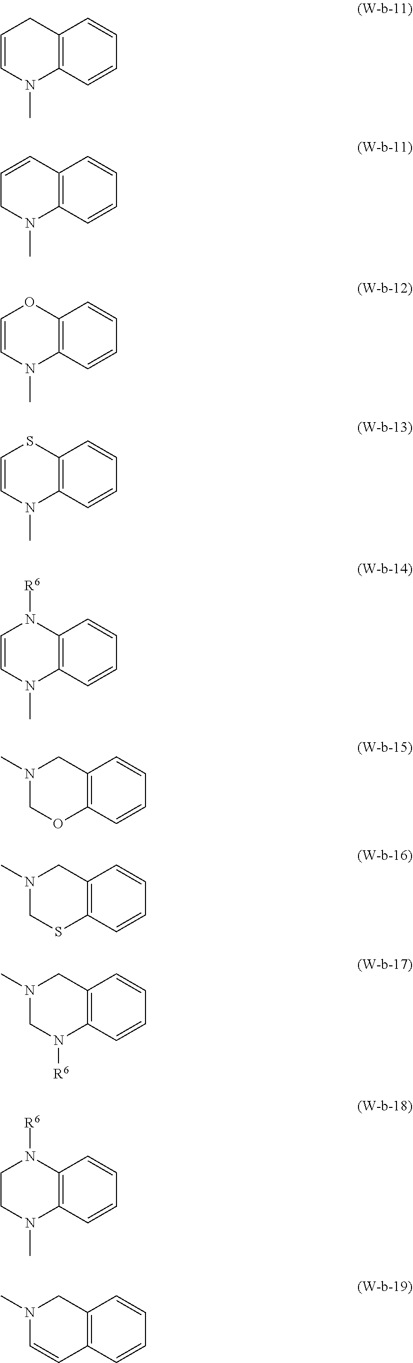

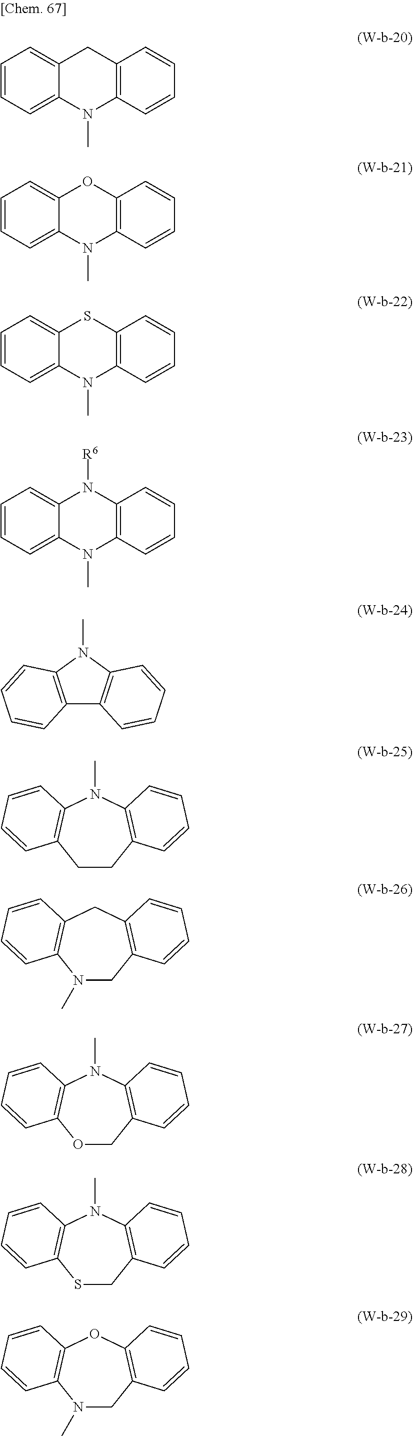

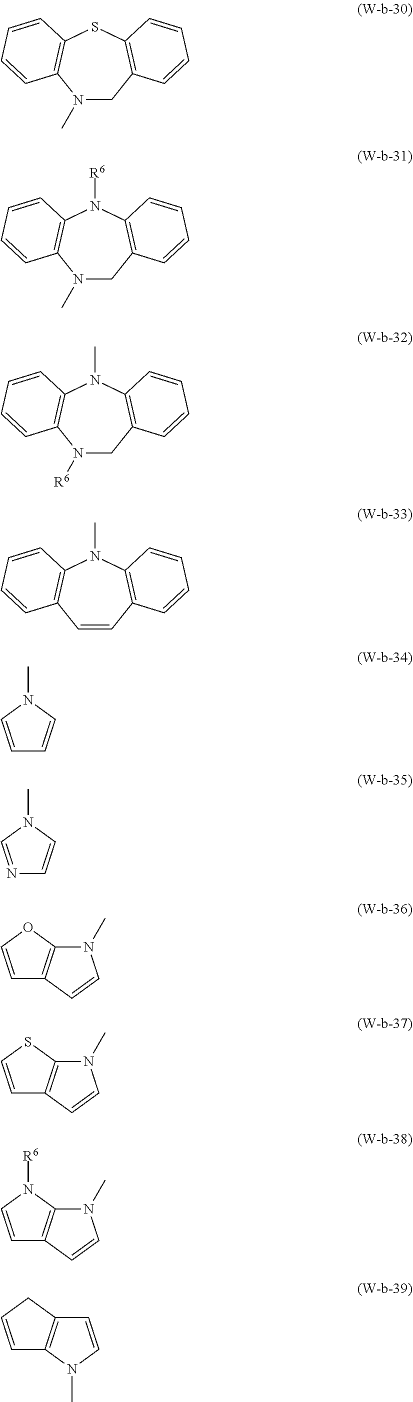

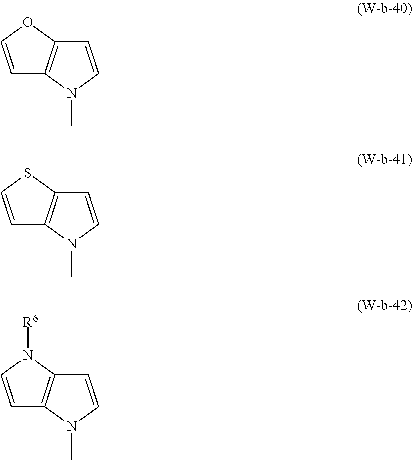

(wherein R⁶ represents a hydrogen atom or an alkyl group having 1 to 8 carbon atoms).

When W⁸¹ and W⁸² together form a ring structure, the ring group represented by —NW⁸¹W⁸² is particularly preferably a group selected from formula (W-b-20), formula (W-b-21), formula (W-b-22), formula (W-b-23), formula (W-b-24), formula (W-b-25), and formula (W-b-33) that may be unsubstituted or substituted by at least one L³, in terms of availability of raw materials and ease of synthesis.

When W⁸¹ and W⁸² together form a ring structure, a ring group represented by ═CW⁸¹W⁸² is preferably a group selected from formula (W-c-1) to formula (W-c-81) below that may be unsubstituted or substituted by at least one L³:

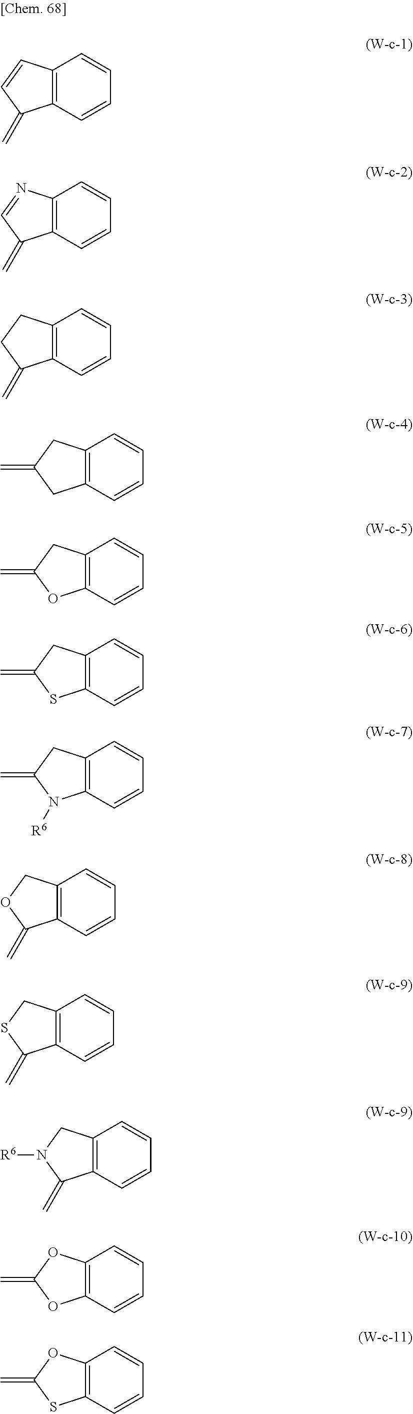

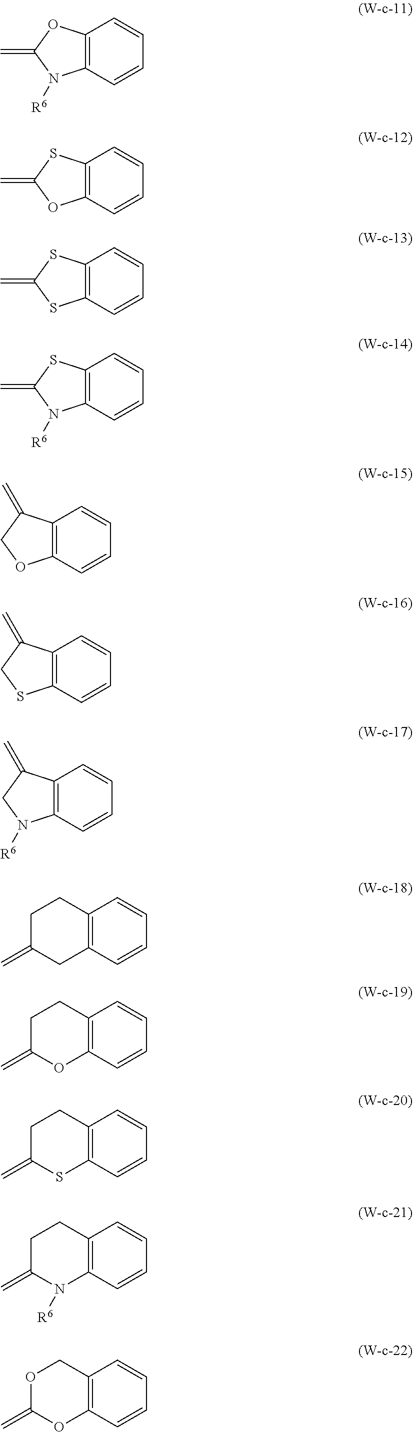

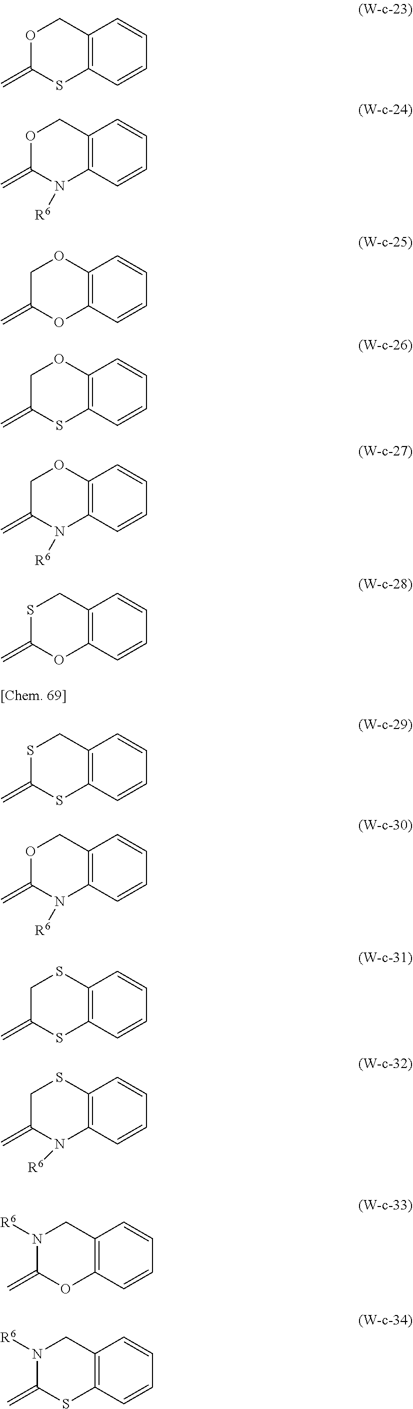

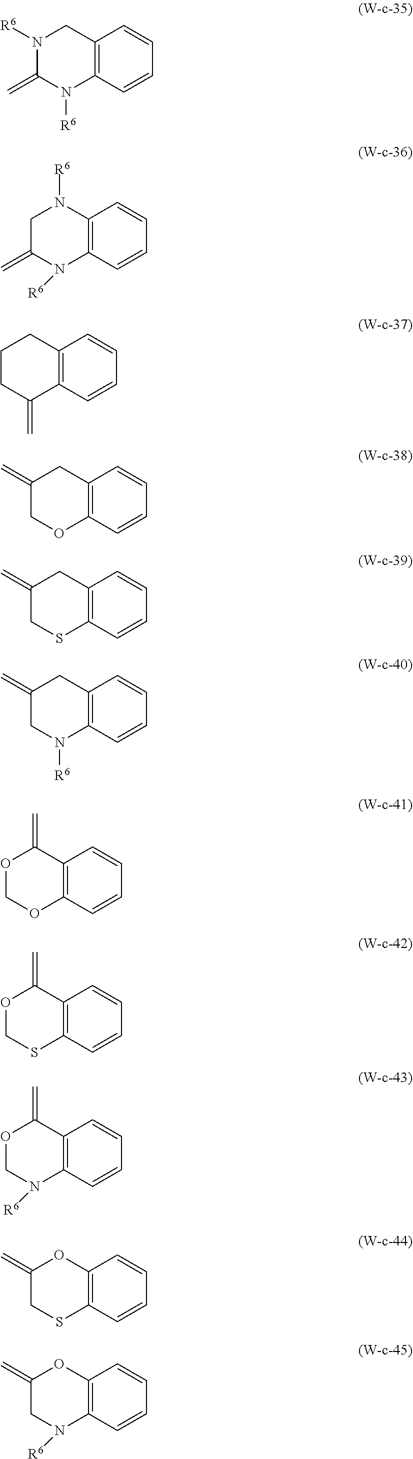

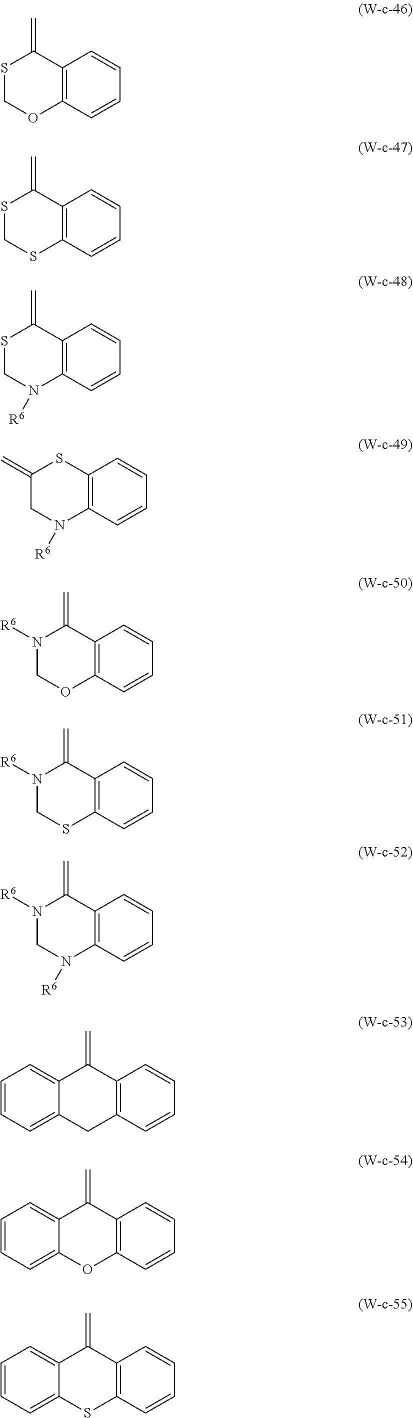

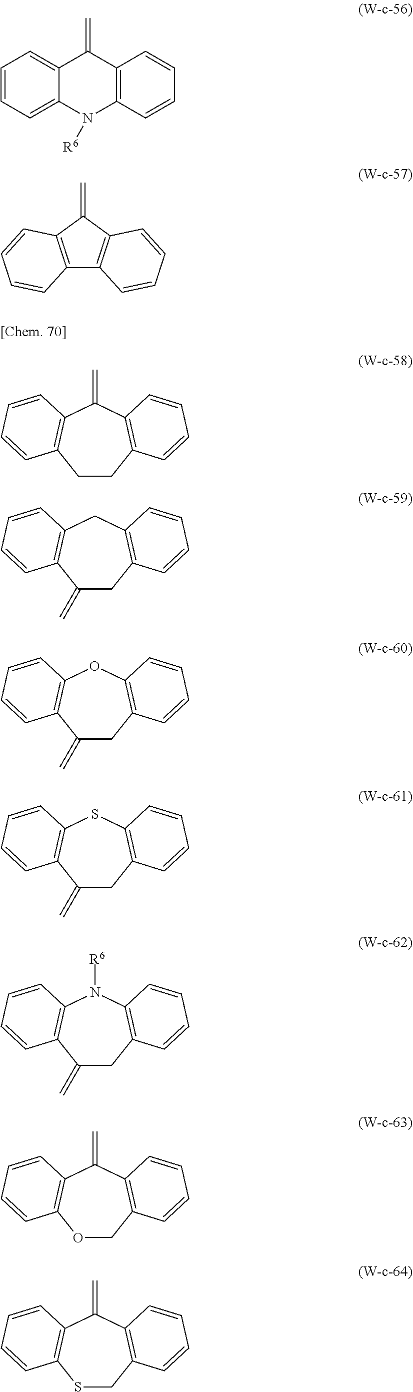

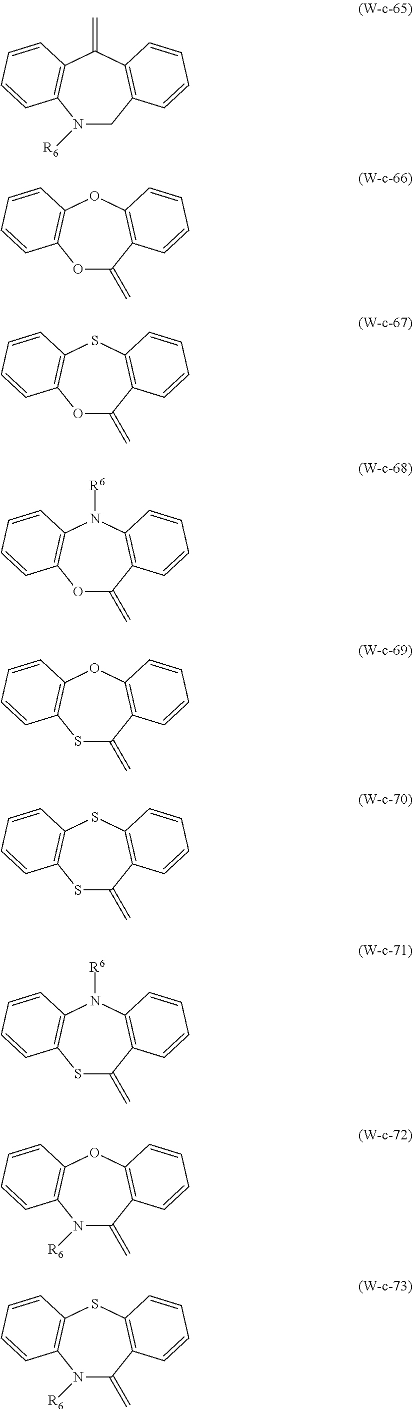

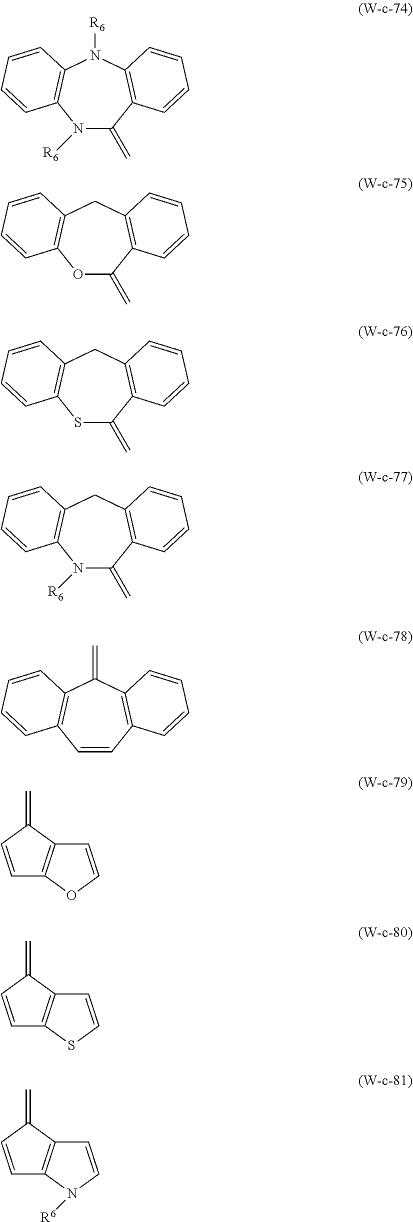

(wherein R⁶ represents a hydrogen atom or an alkyl group having 1 to 8 carbon atoms; and, when a plurality of R⁶s are present, they may be the same or different).

When W⁸¹ and W⁸² together form a ring structure, the ring group represented by ═CW⁸¹W⁸² is particularly preferably a group selected from formula (W-c-11), formula (W-c-12), formula (W-c-13), formula (W-c-14), formula (W-c-53), formula (W-c-54), formula (W-c-55), formula (W-c-56), formula (W-c-57), and formula (W-c-78) that may be unsubstituted or substituted by at least one L³, in terms of availability of raw materials and ease of synthesis.

The total number of a electrons contained in W⁸¹ and W⁸² is preferably 4 to 24, in terms of wavelength dispersion properties, storage stability, liquid crystallinity, and ease of synthesis.

W⁸³ and W⁸⁴ each independently represent a halogen atom, a cyano group, a hydroxy group, a nitro group, a carboxyl group, a carbamoyloxy group, an amino group, a sulfamoyl group, a group having at least one aromatic group and having 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms. In the alkyl group, the cycloalkyl group, the alkenyl group, the cycloalkenyl group, the alkoxy group, the acyloxy group, and the alkylcarbonyloxy group, one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C—. W⁸³ is more preferably a group selected from a cyano group, a nitro group, a carboxyl group, and alkyl, alkenyl, acyloxy, and alkylcarbonyloxy groups which have 1 to 20 carbon atoms and in which one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C— and is particularly preferably a group selected from a cyano group, a carboxyl group, and alkyl, alkenyl, acyloxy, and alkylcarbonyloxy groups which have 1 to 20 carbon atoms and in which one —CH₂— group or two or more nonadjacent —CH₂— groups may be each independently replaced by —CO—, —COO—, —OCO—, —O—CO—O—, —CO—NH—, —NH—CO—, and —C≡C—. W⁸′ is more preferably a group selected from a cyano group, a nitro group, a carboxyl group, and alkyl, alkenyl, acyloxy, and alkylcarbonyloxy groups which have 1 to 20 carbon atoms and in which one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, or —C≡C— and is particularly preferably a group selected from a cyano group, a carboxyl group, and alkyl, alkenyl, acyloxy, and alkylcarbonyloxy groups which have 1 to 20 carbon atoms and in which one —CH₂— group or two or more nonadjacent —CH₂— groups may be each independently replaced by —CO—, —COO—, —OCO—, —O—CO—O—, —CO—NH—, —NH—CO—, or —C≡C—.

L³ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or a linear or branched alkyl group which has 1 to 20 carbon atoms and in which one —CH₂— group or two or more nonadjacent —CH₂— groups may be each independently replaced by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—. In this alkyl group, any hydrogen atom may be replaced by a fluorine atom. In terms of liquid crystallinity and ease of synthesis, L³ preferably represents a fluorine atom, a chlorine atom, a pentafluorosulfuranyl group, a nitro group, a methylamino group, a dimethylamino group, a diethylamino group, a diisopropylamino group, or a linear or branched alkyl group which has 1 to 20 carbon atoms, in which any hydrogen atom may be replaced by a fluorine atom, and in which one —CH₂— group or two or more nonadjacent —CH₂— groups may be each independently replaced by a group selected from —O—, —S—, —CO—, —COO—, —OCO—, —O—CO—O—, —CH═CH—, —CF═CF—, and —C≡C—. More preferably, L³ represents a fluorine atom, a chlorine atom, or a linear or branched alkyl group which has 1 to 12 carbon atoms, in which any hydrogen atom may be replaced by a fluorine atom, and in which one —CH₂— group or two or more nonadjacent —CH₂— groups may be each independently replaced by a group selected from —O—, —COO—, and —OCO—. Still more preferably, L³ represents a fluorine atom, a chlorine atom, or a linear or branched alkyl or alkoxy group which has 1 to 12 carbon atoms and in which any hydrogen atom may be replaced by a fluorine atom. Particularly preferably, L³ represents a fluorine atom, a chlorine atom, a linear alkyl group having 1 to 8 carbon atoms, or a linear alkoxy group having 1 to 8 carbon atoms.

In general formula (1), m11 represents an integer of 0 to 8. In terms of liquid crystallinity, availability of raw materials, and ease of synthesis, n represents preferably an integer from 0 to 4, more preferably an integer from 0 to 2, still more preferably 0 or 1, and particularly preferably 1.

In general formula (2) to general formula (7), m2 to m7 each independently represent an integer from 0 to 5. In terms of liquid crystallinity, availability of raw materials, and ease of synthesis, m2 to m7 each independently represent preferably an integer from 0 to 4, more preferably an integer from 0 to 2, still more preferably 0 or 1, and particularly preferably 1.

In general formula (a), j11 and j12 each independently represent an integer from 1 to 5, and j11+j12 represents an integer from 2 to 5. In terms of liquid crystallinity, ease of synthesis, and storage stability, j11 and j12 each independently represent preferably an integer from 1 to 4, more preferably an integer from 1 to 3, and particularly preferably 1 or 2. Preferably, j11+j12 represents an integer from 2 to 4.

Specifically, the compound represented by general formula (1) is preferably compounds represented by formula (1-a-1) to formula (1-a-88) below.

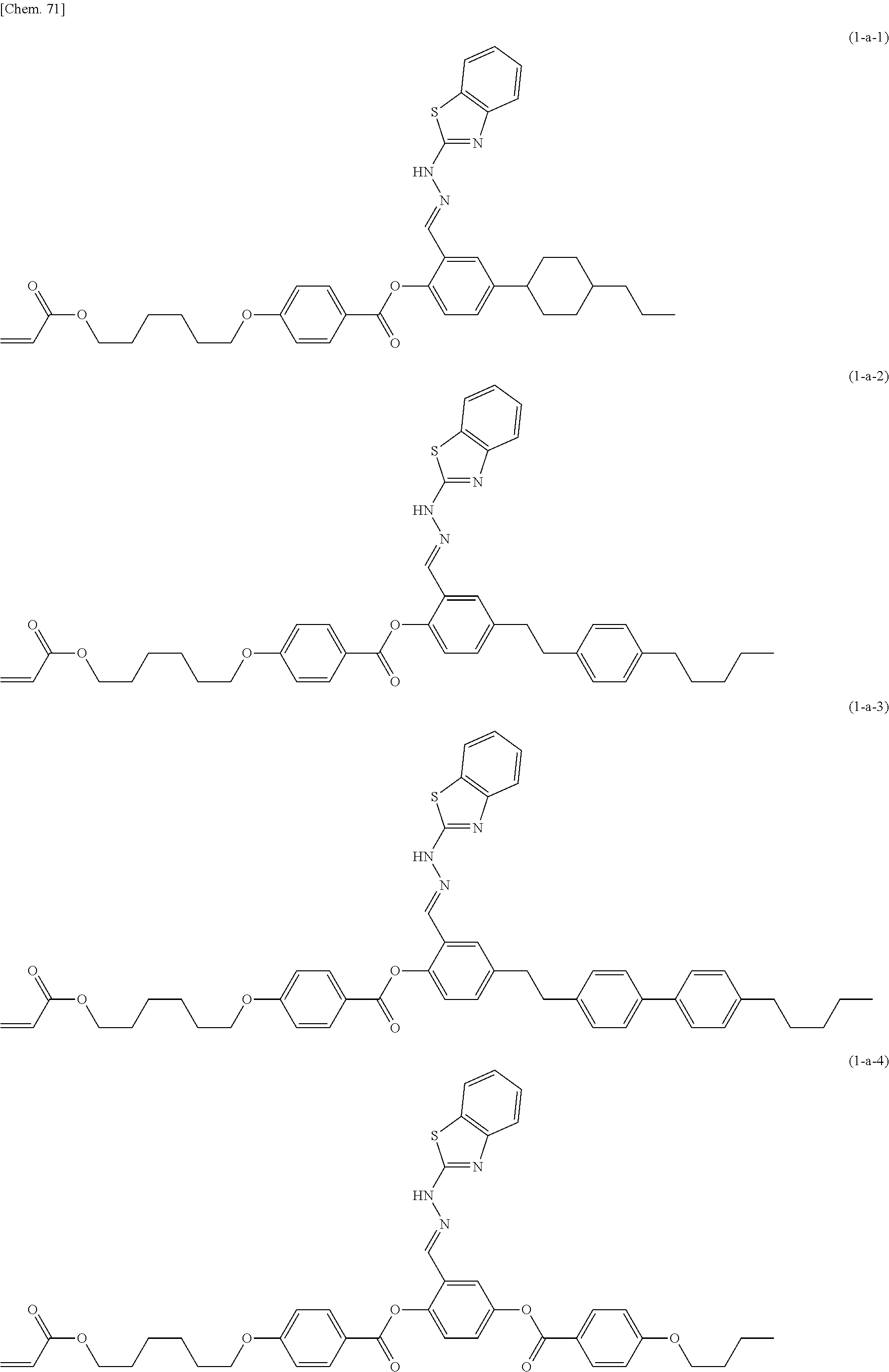

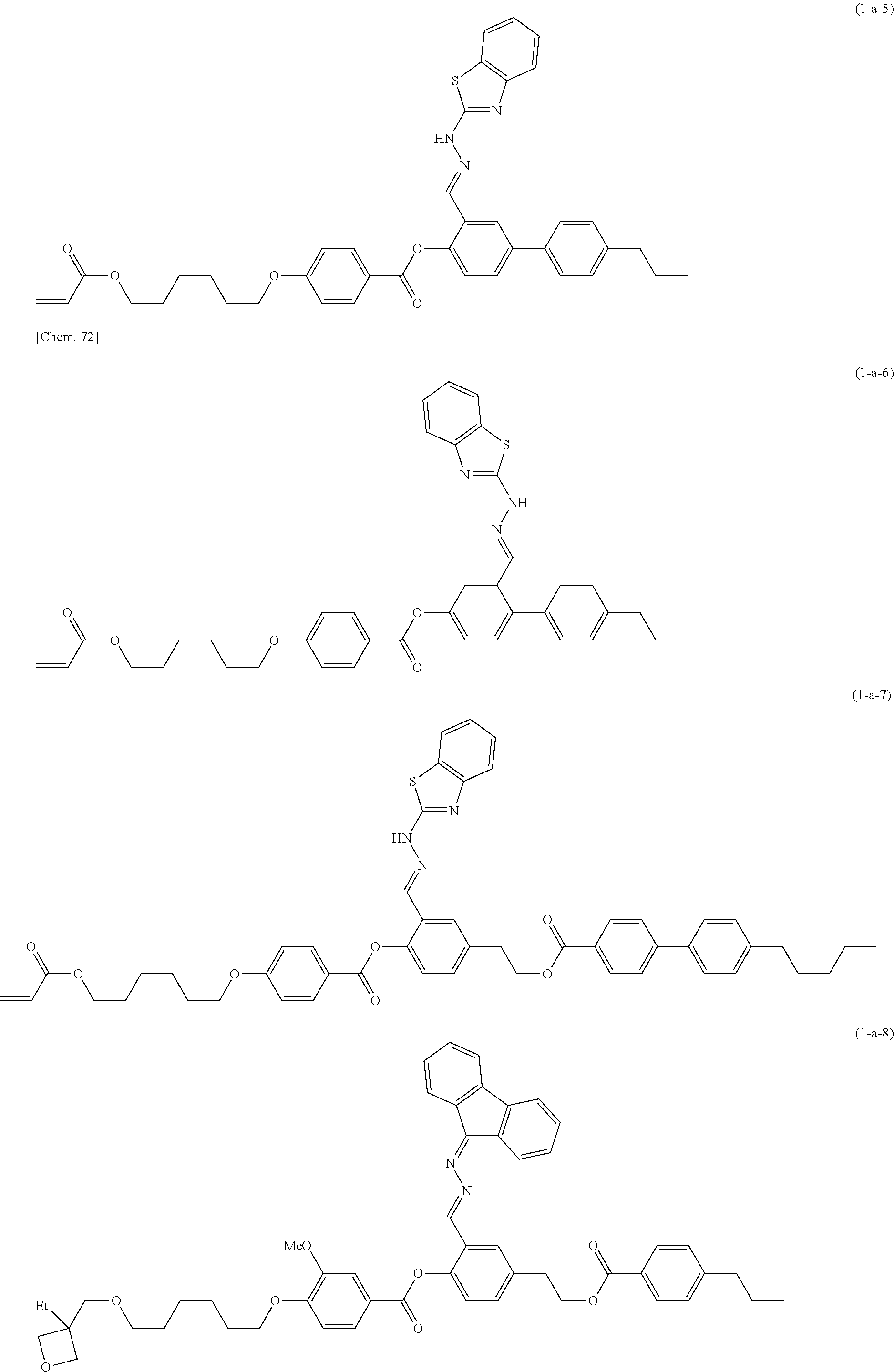

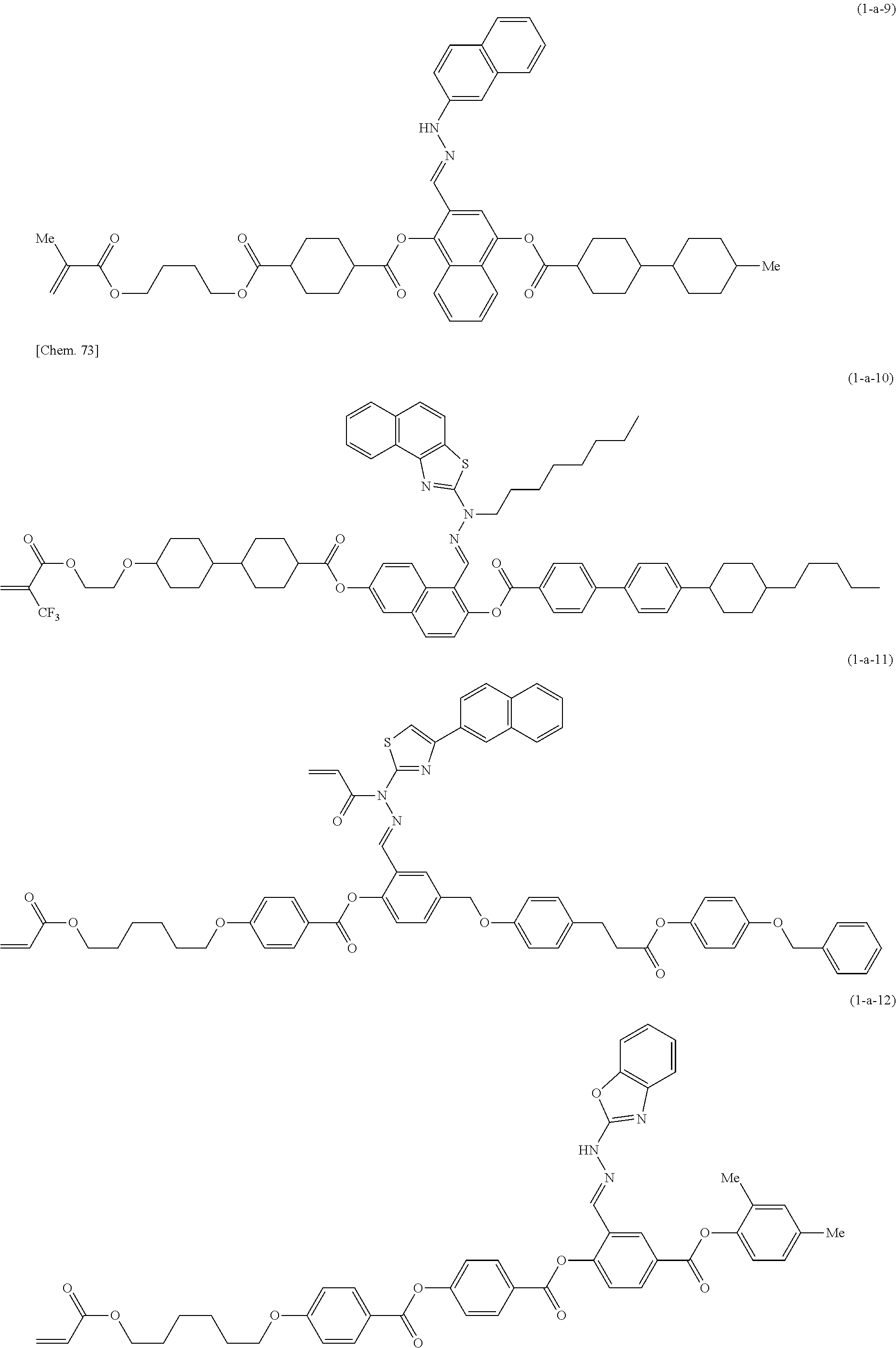

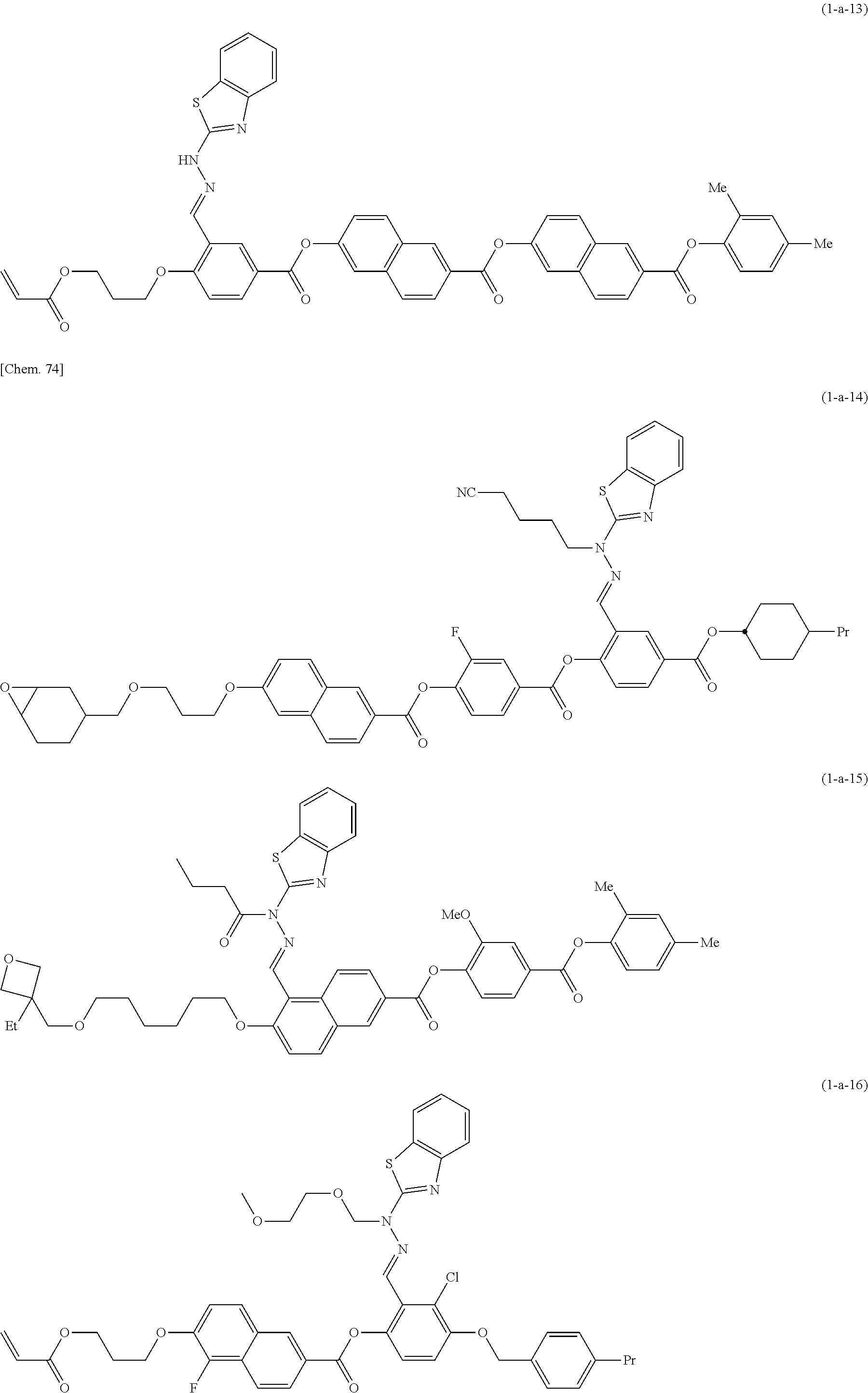

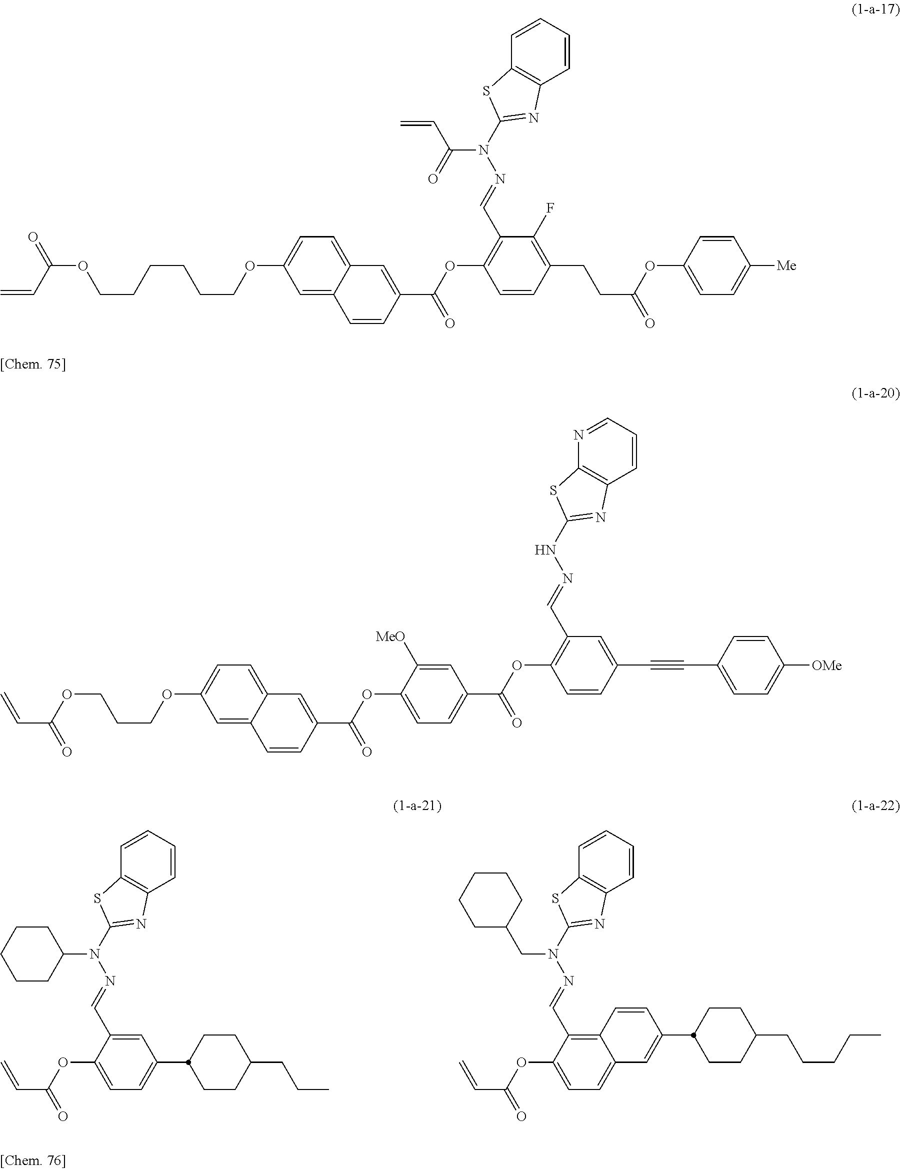

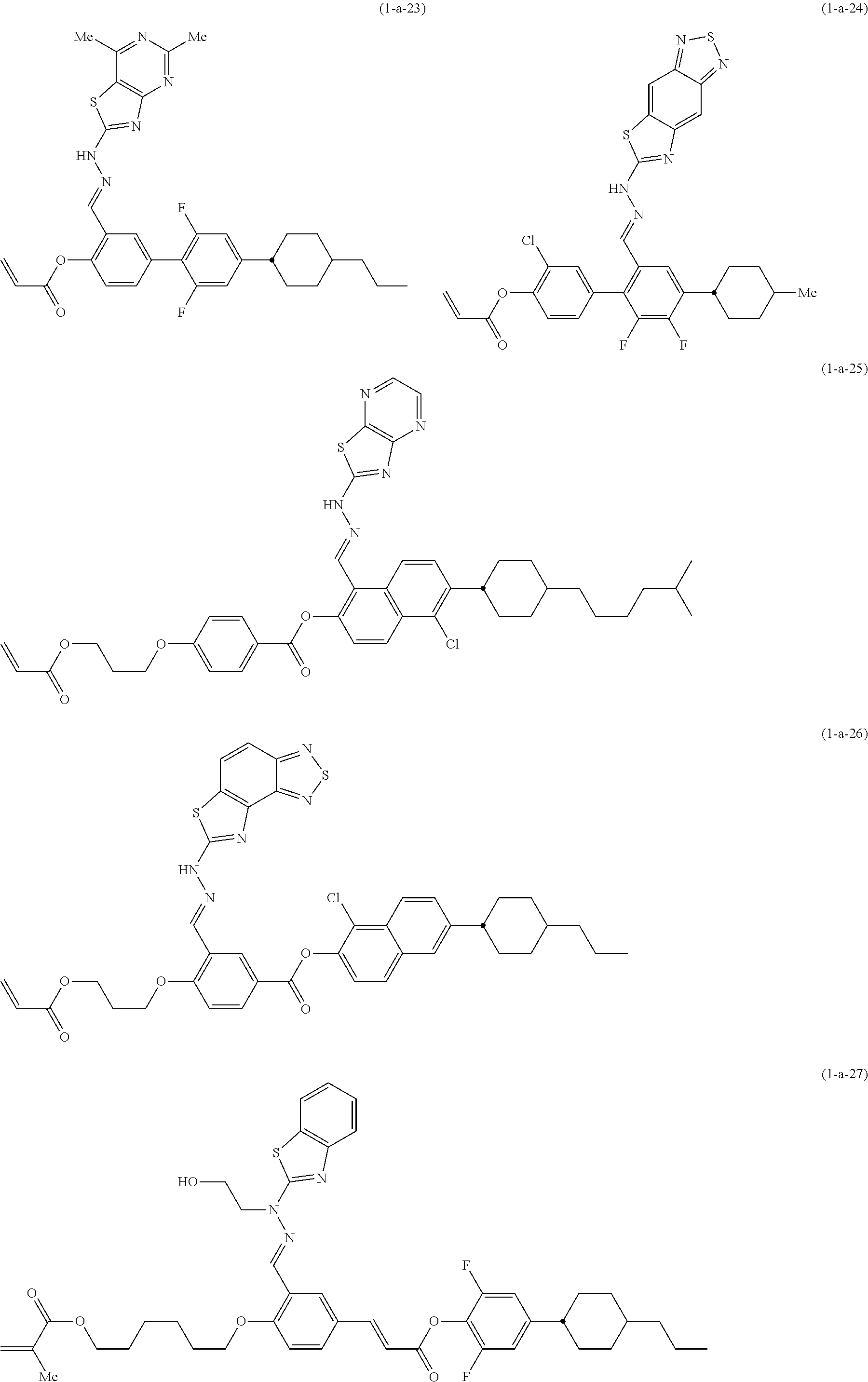

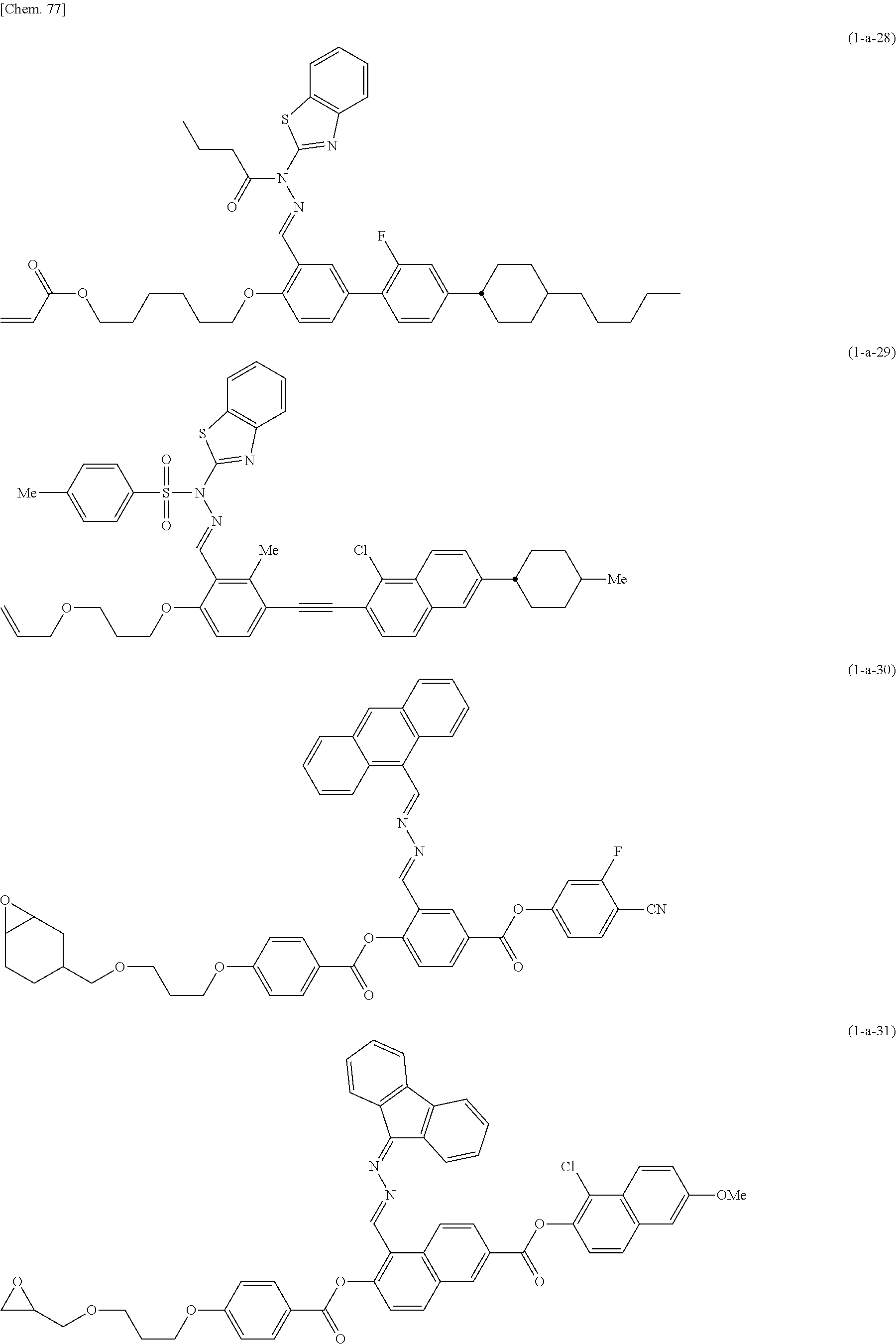

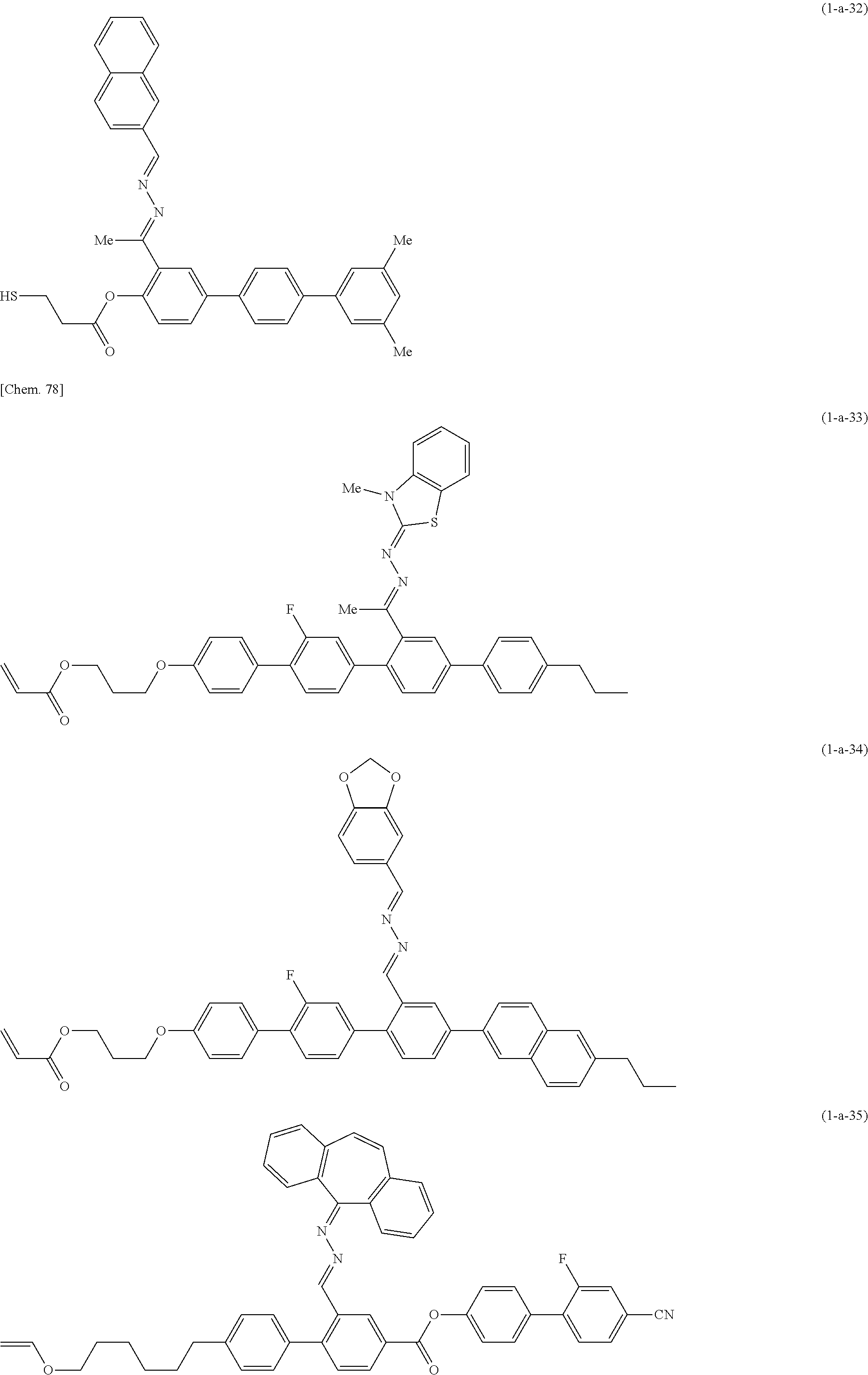

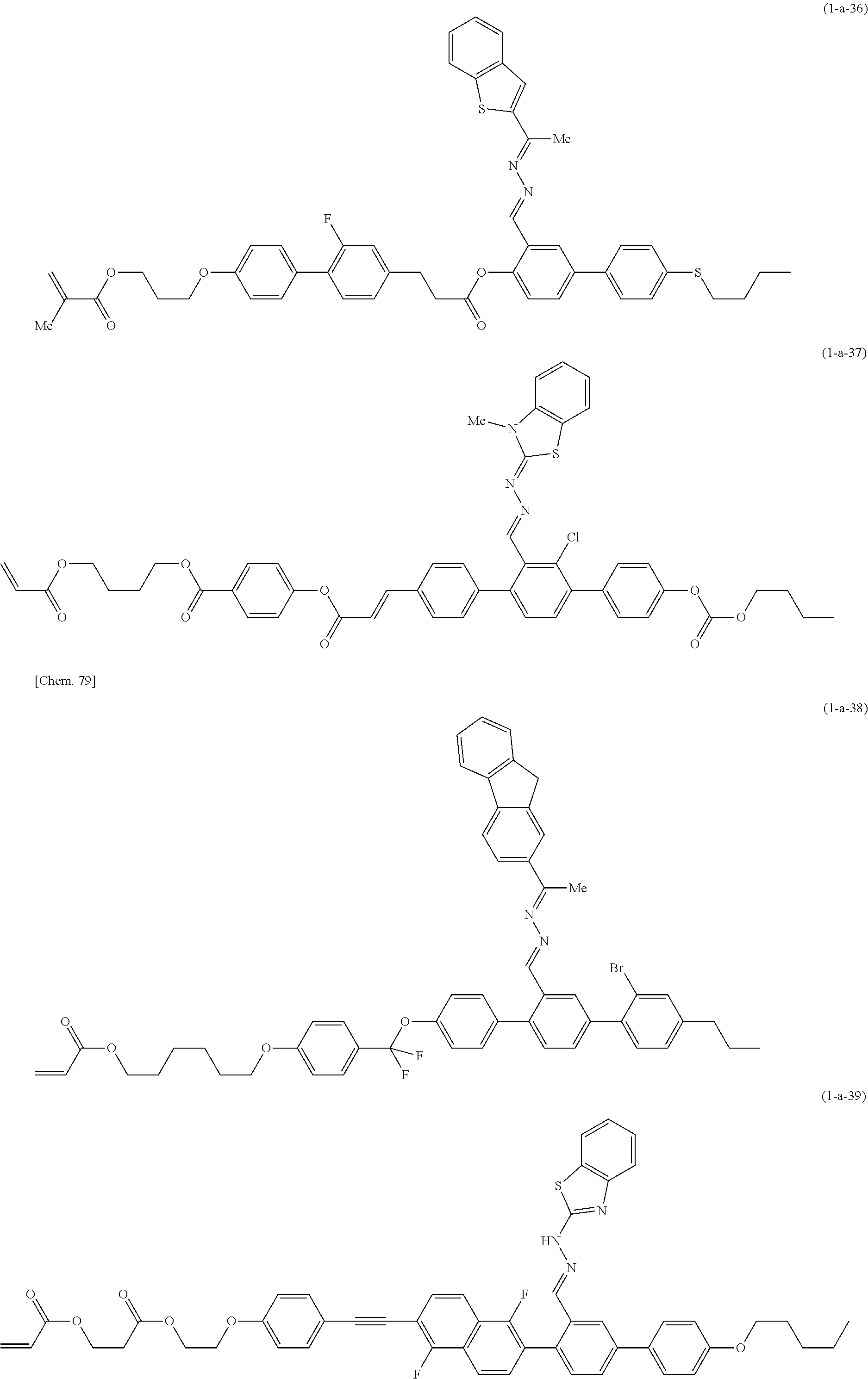

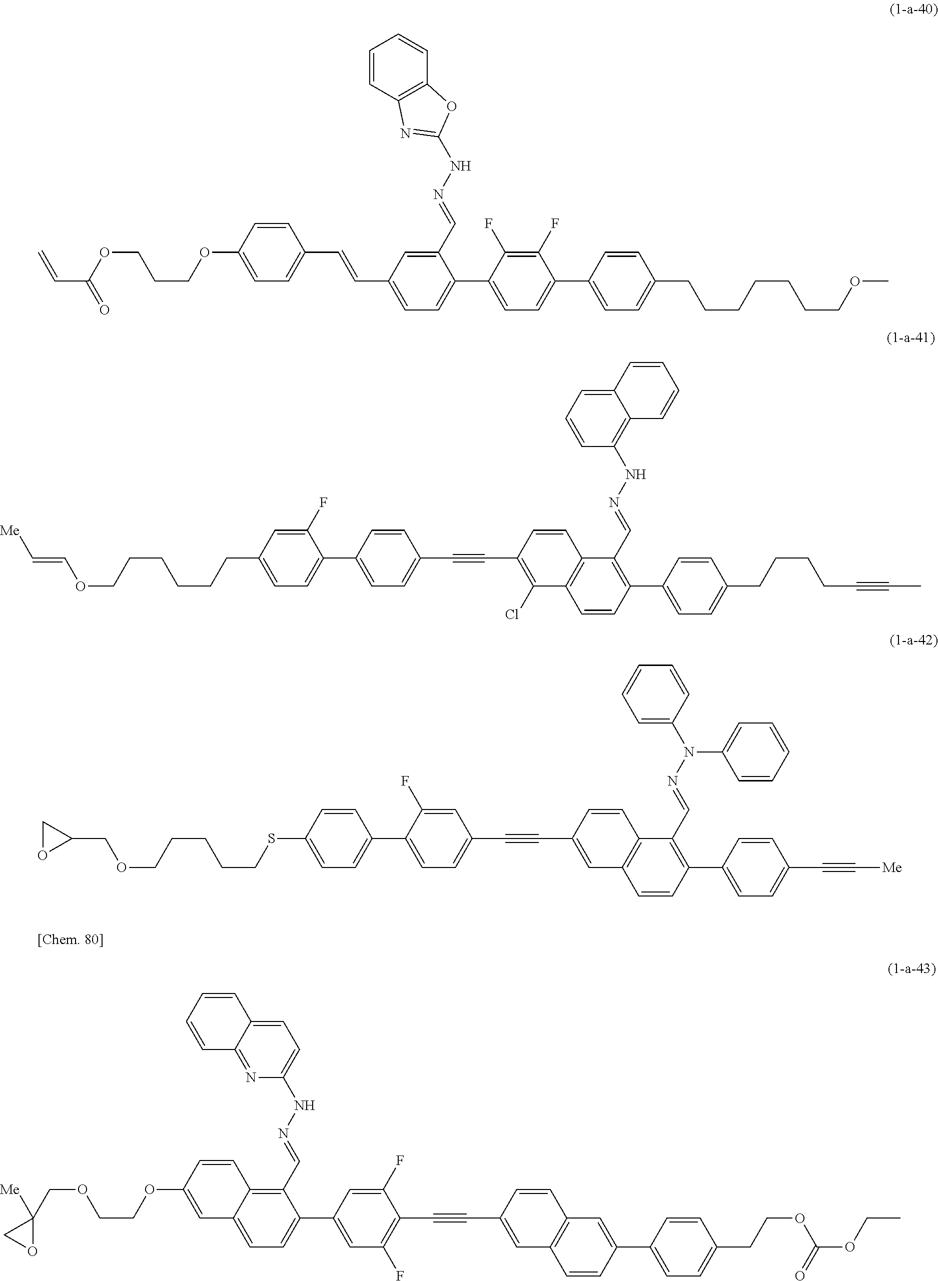

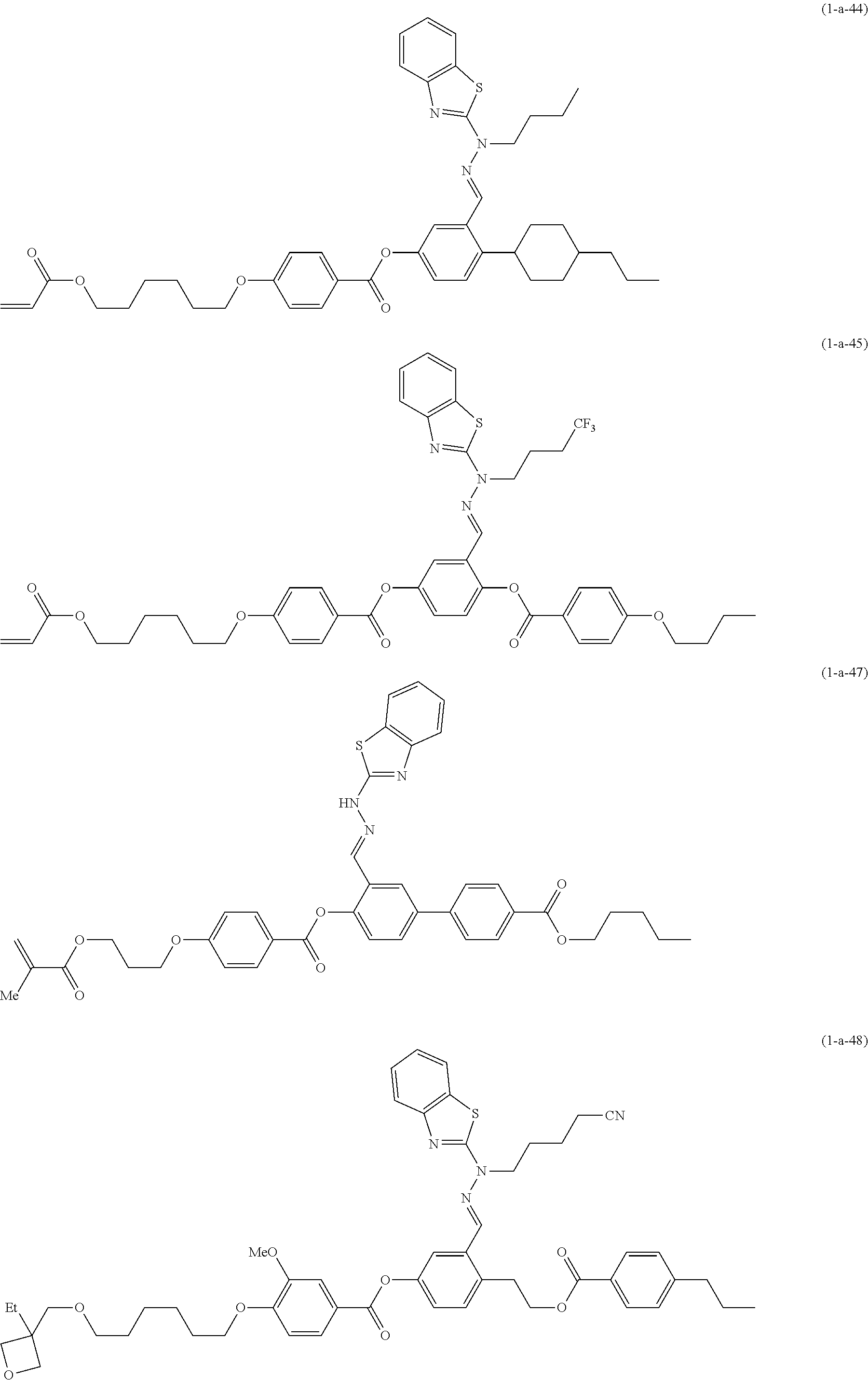

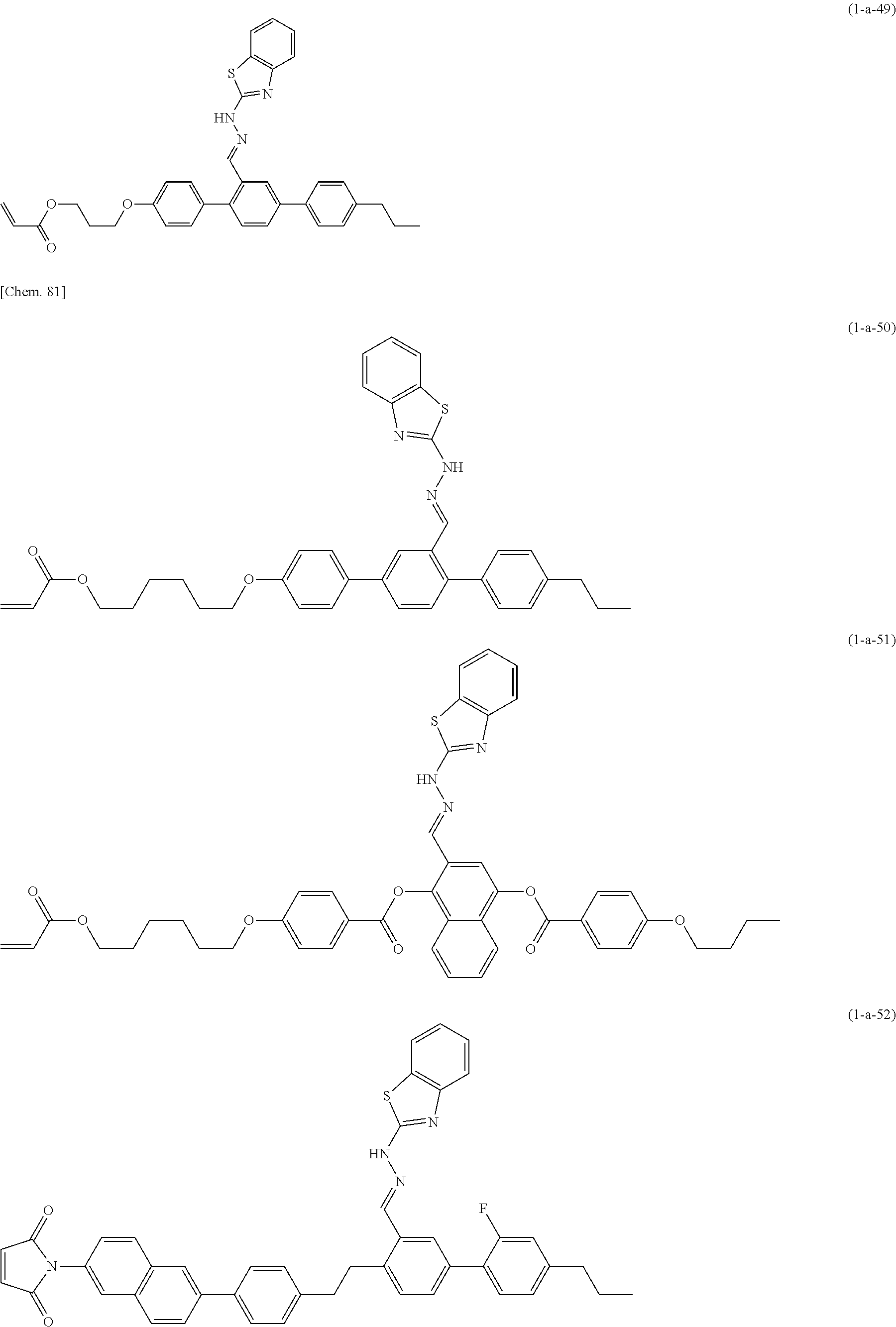

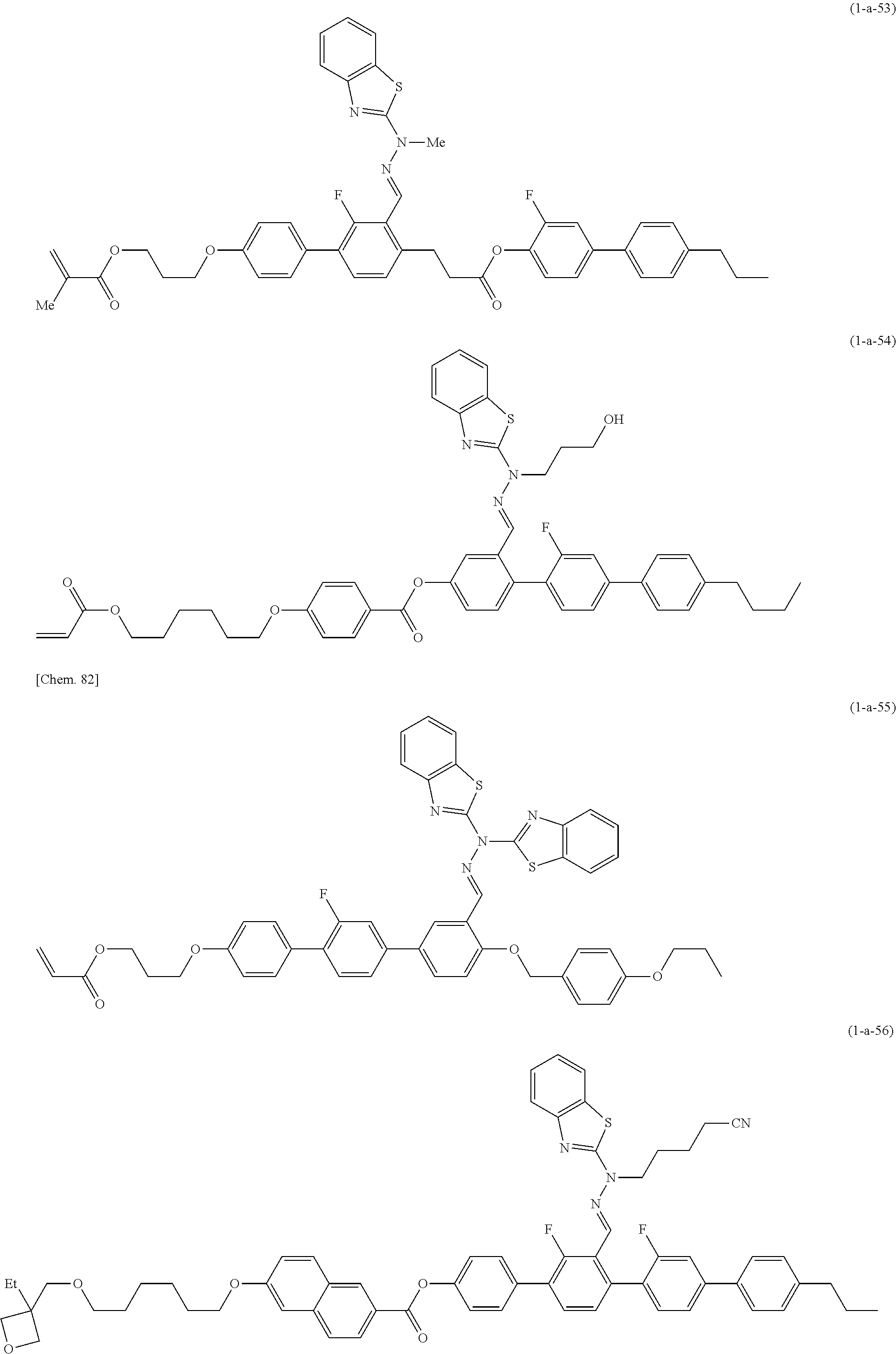

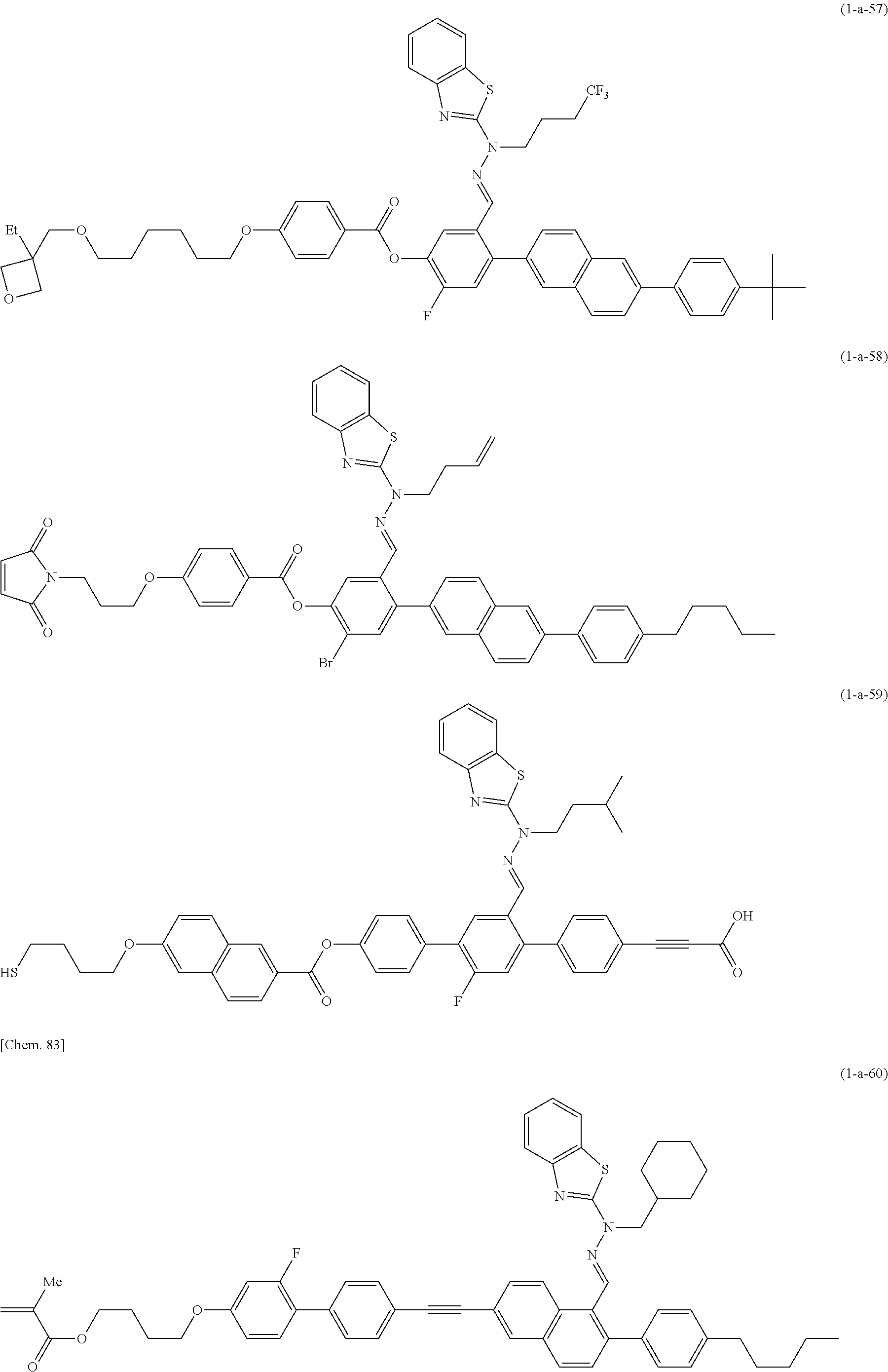

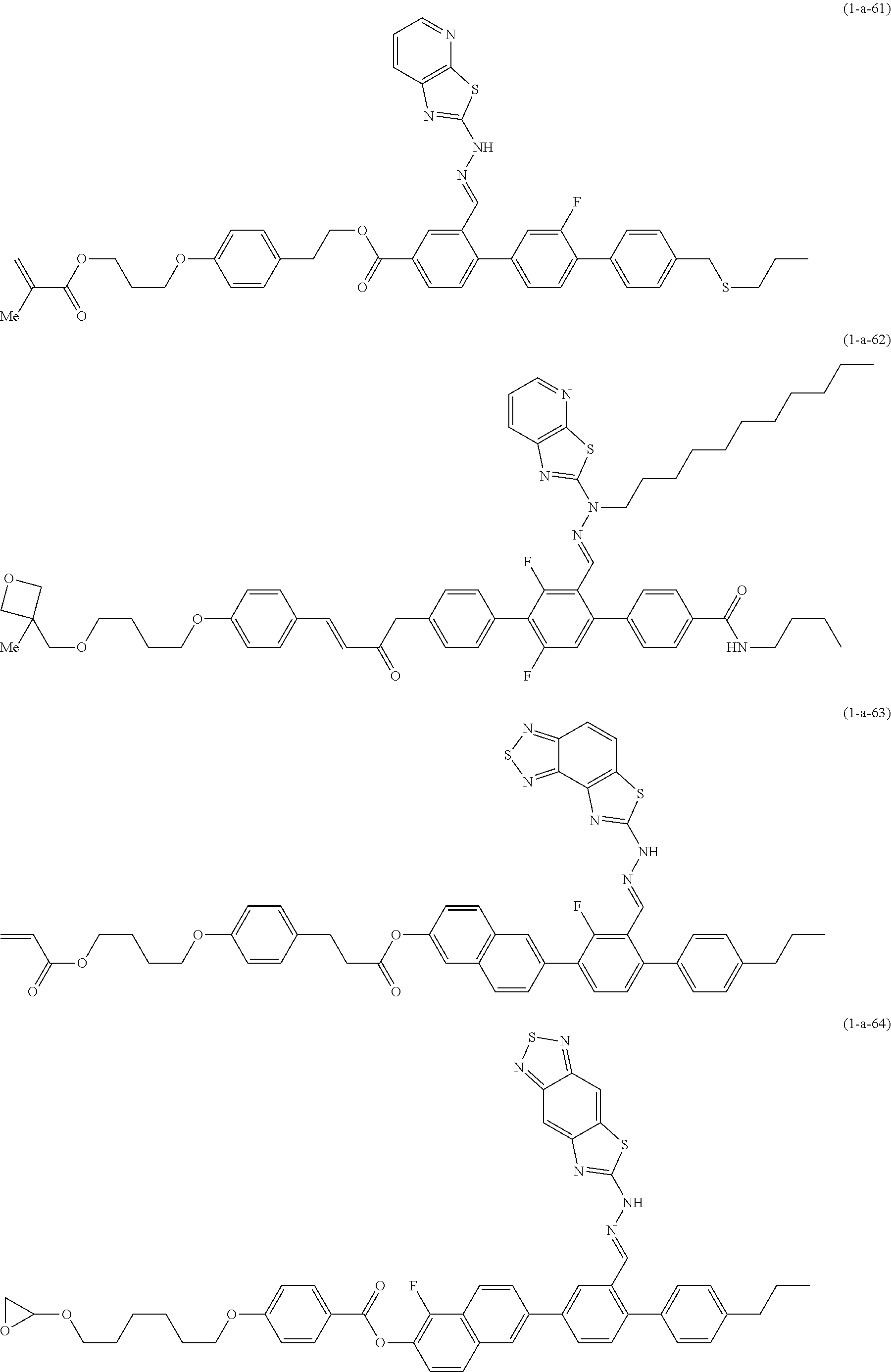

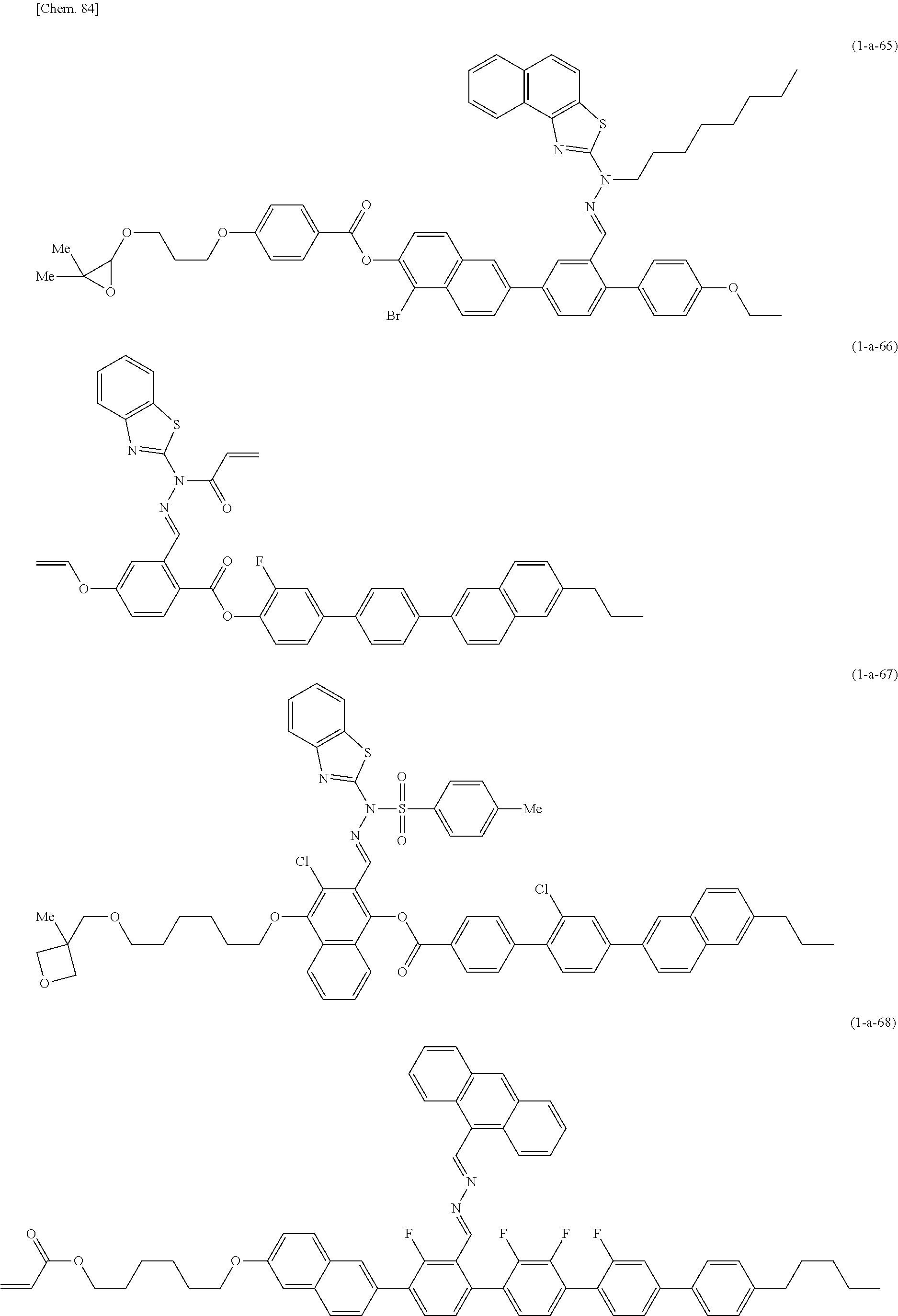

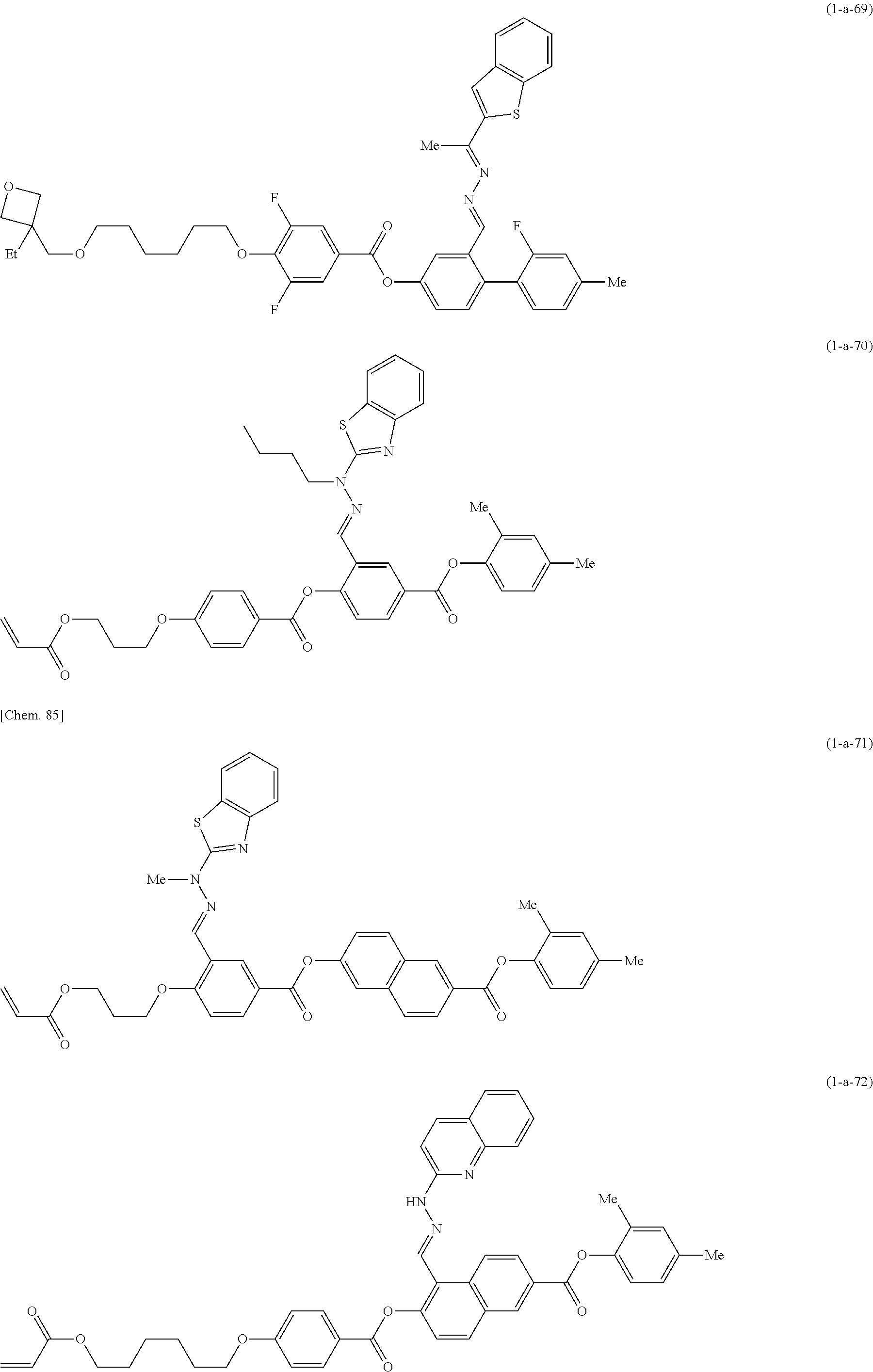

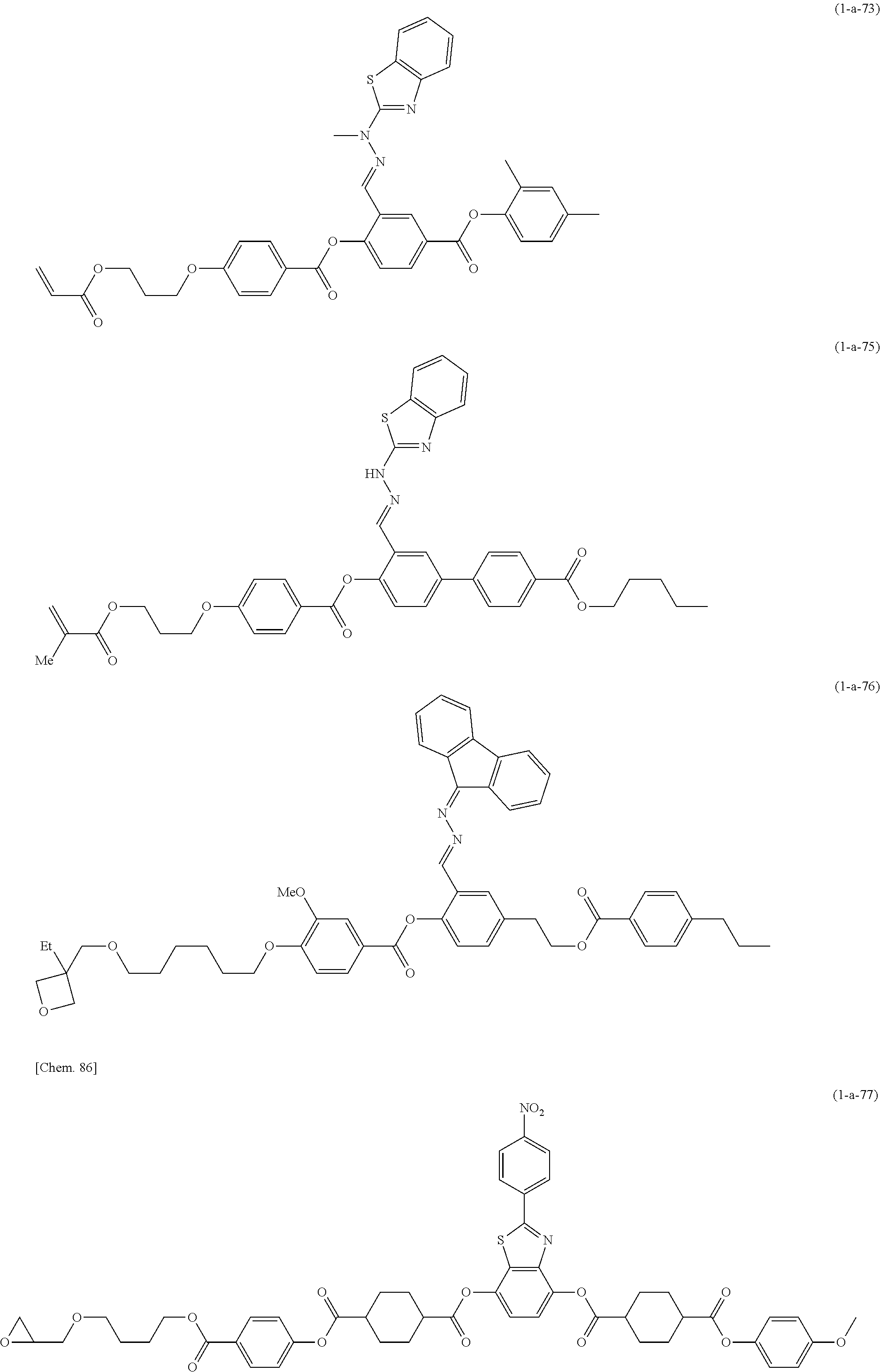

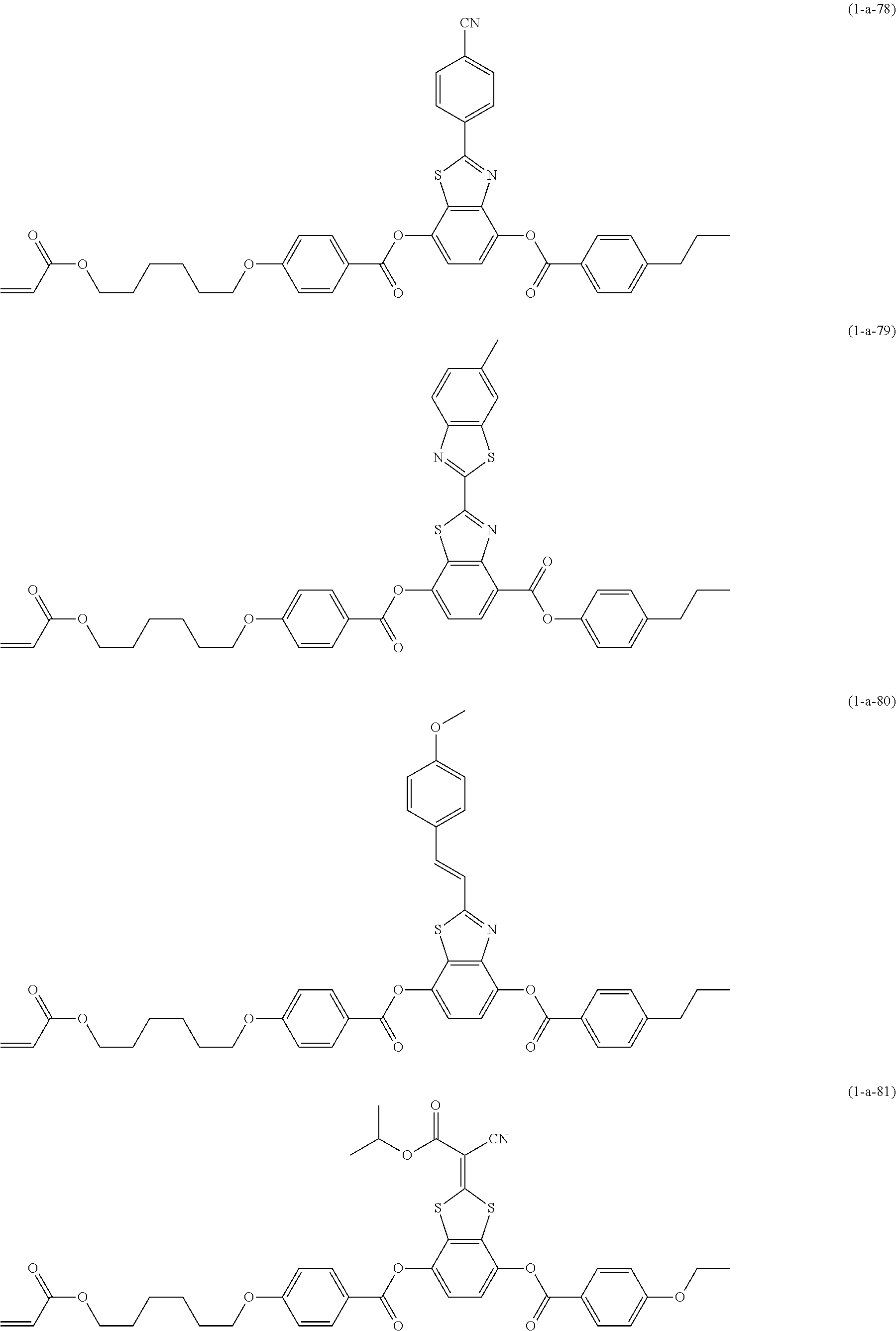

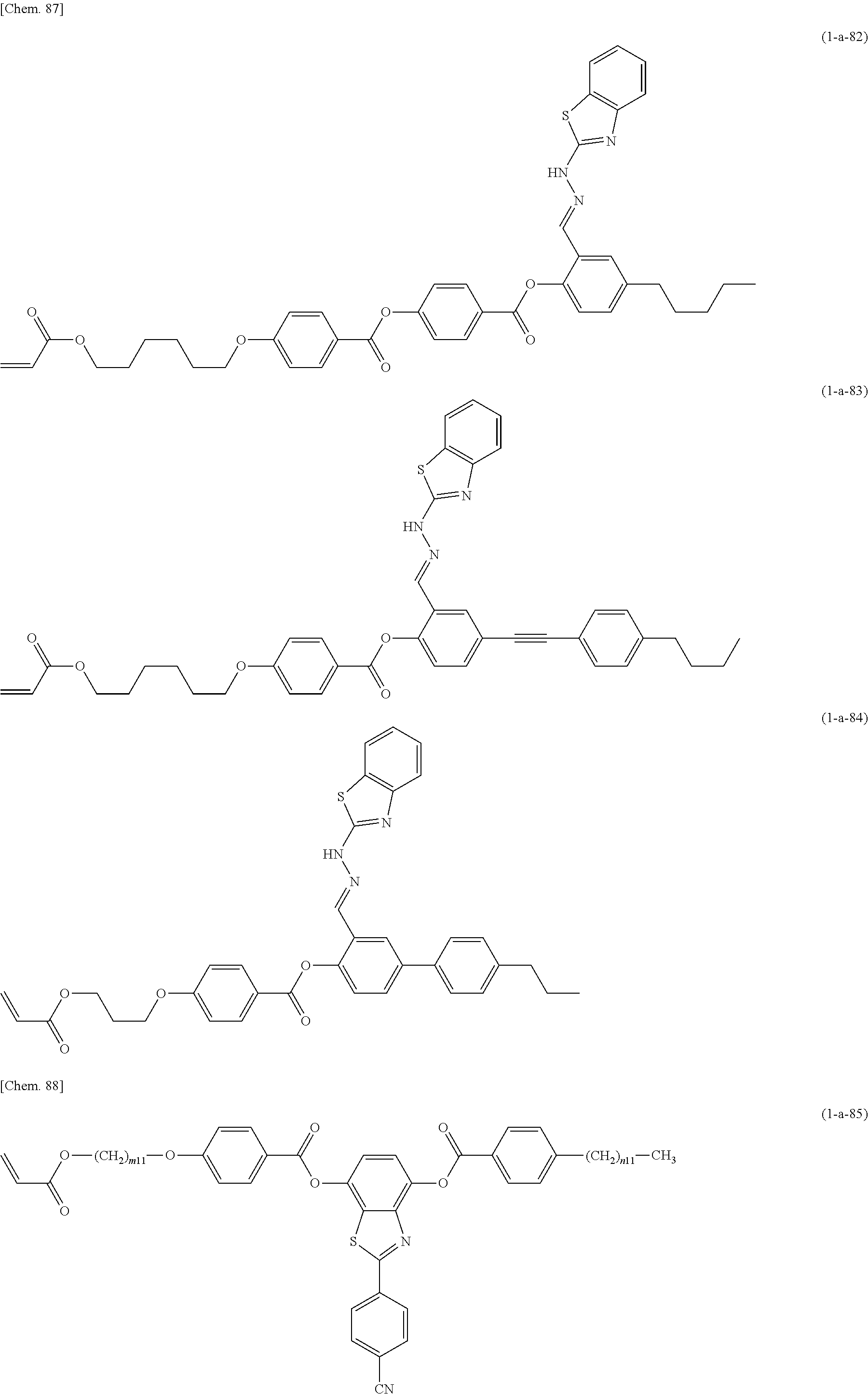

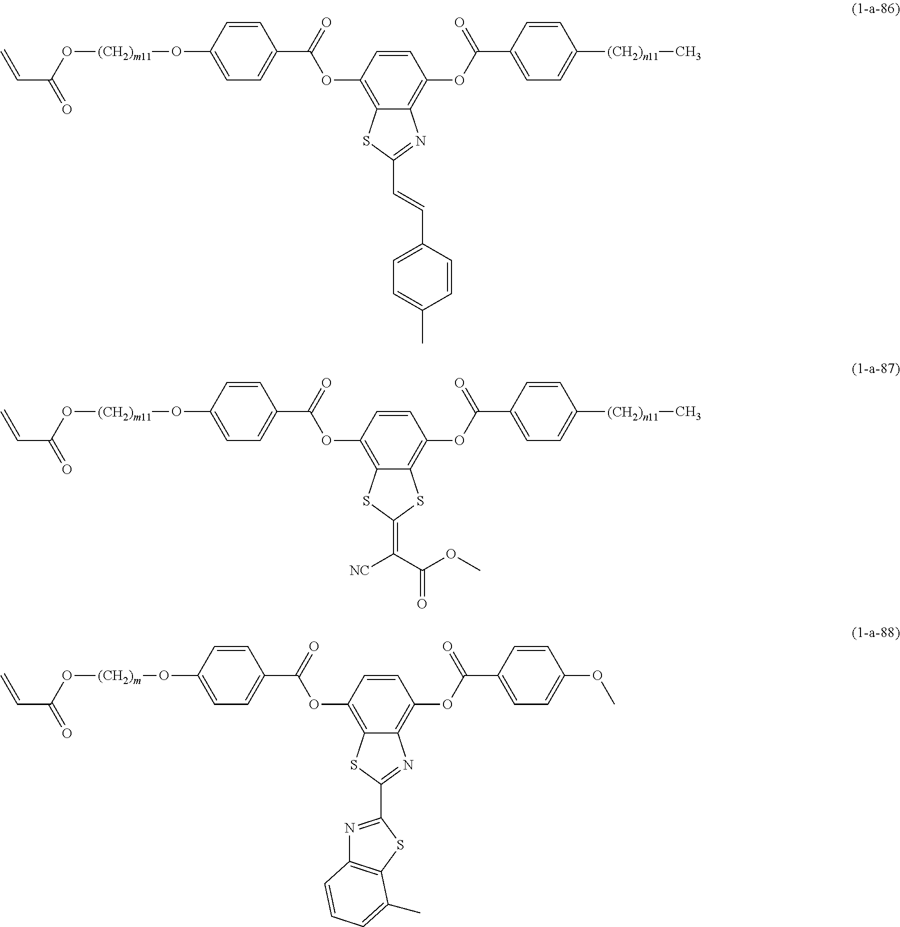

These liquid crystalline compounds may be used alone or as a mixture of two or more.

Specifically, the compound represented by general formula (2) is preferably compounds represented by formula (2-a-1) to formula (2-a-45) below:

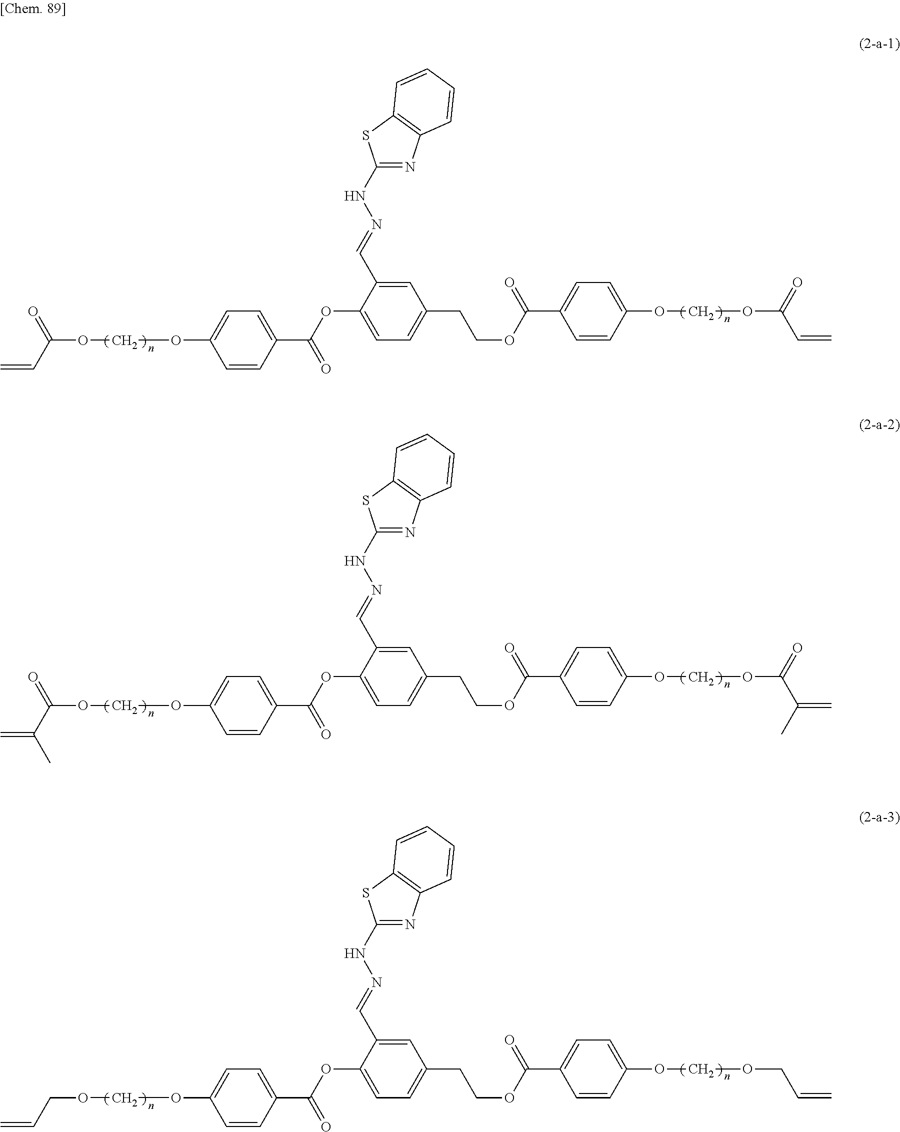

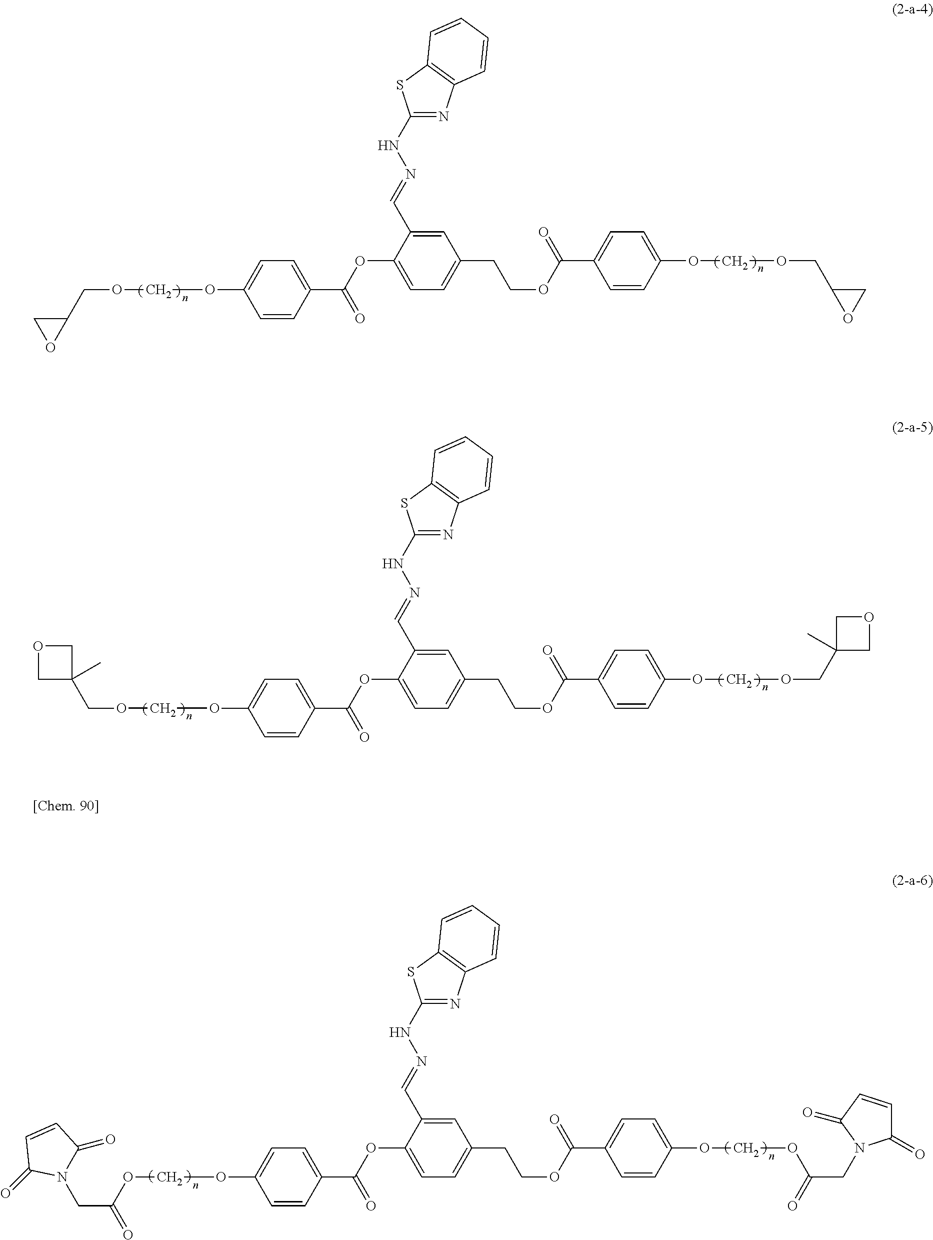

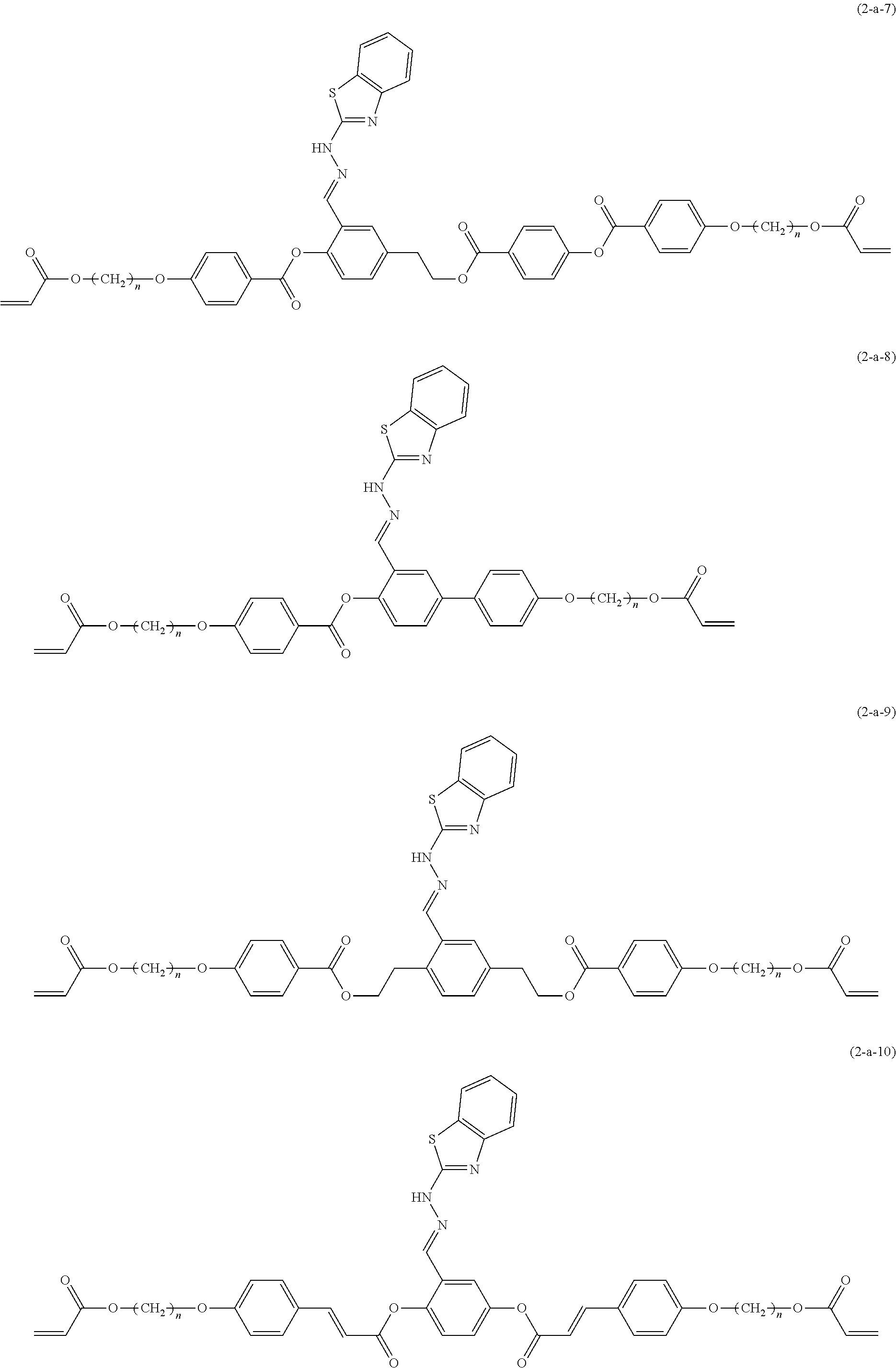

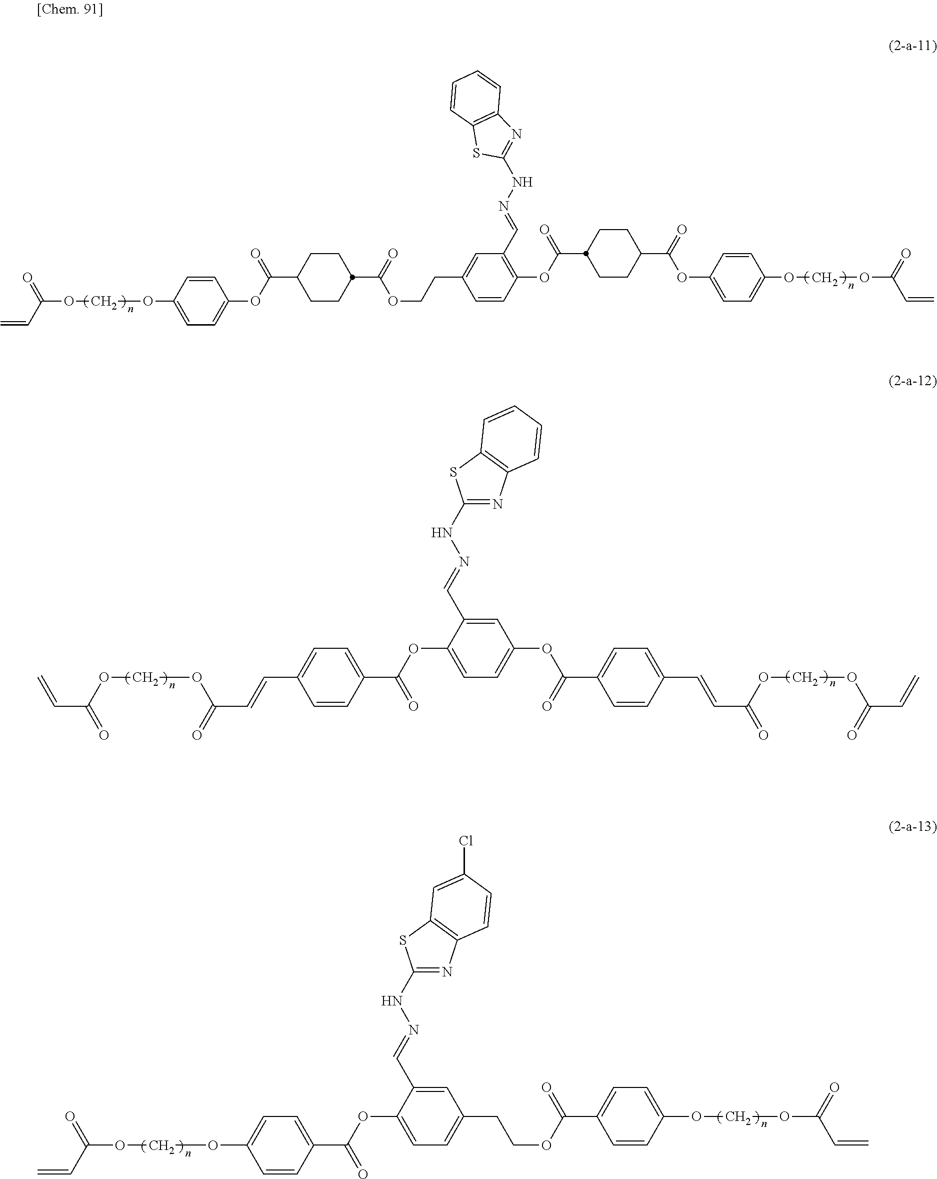

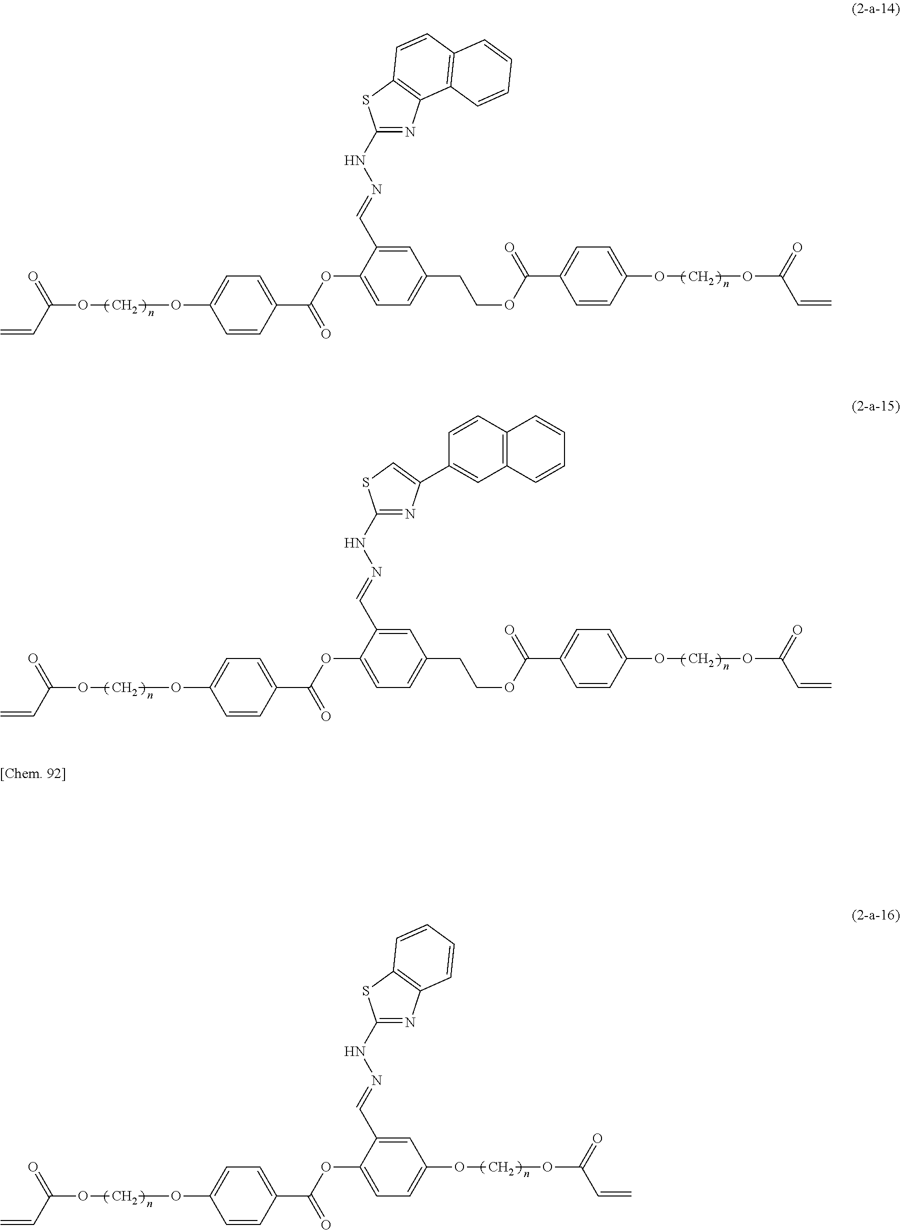

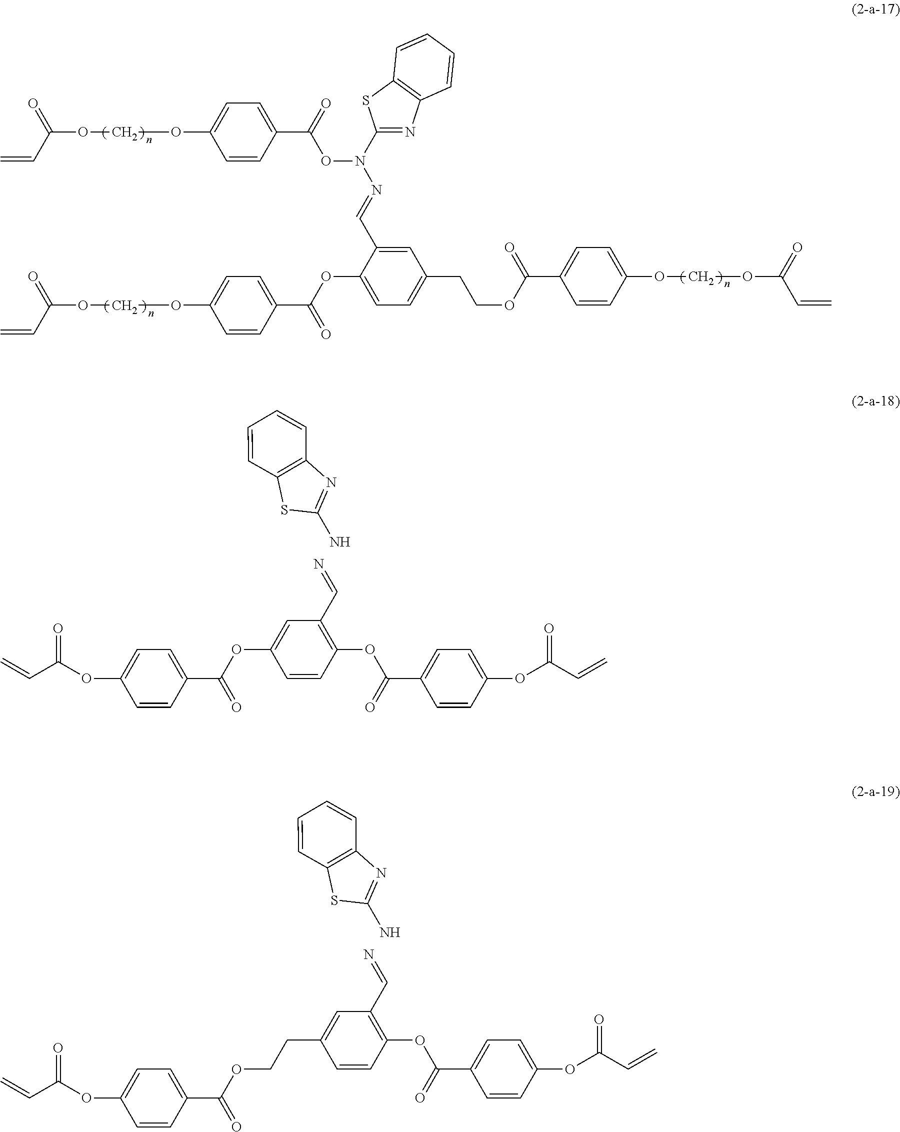

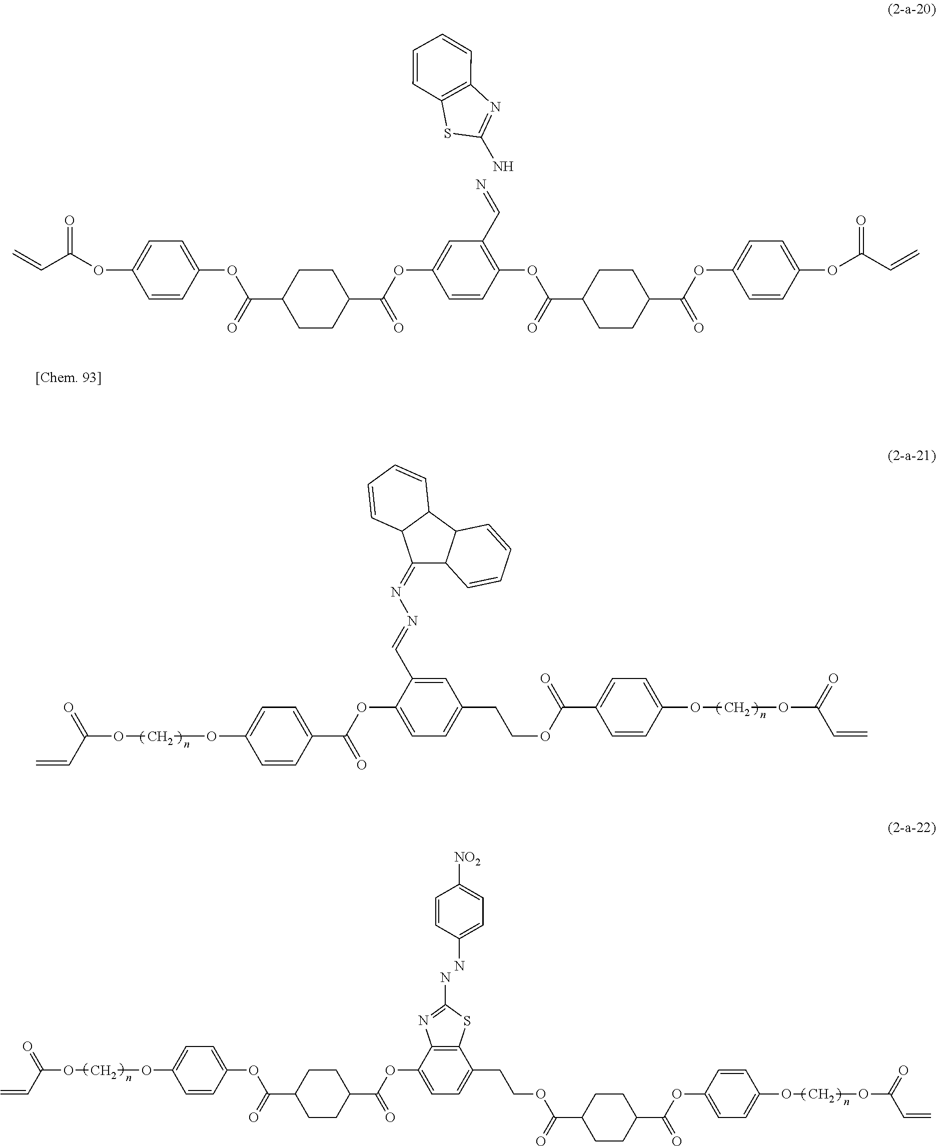

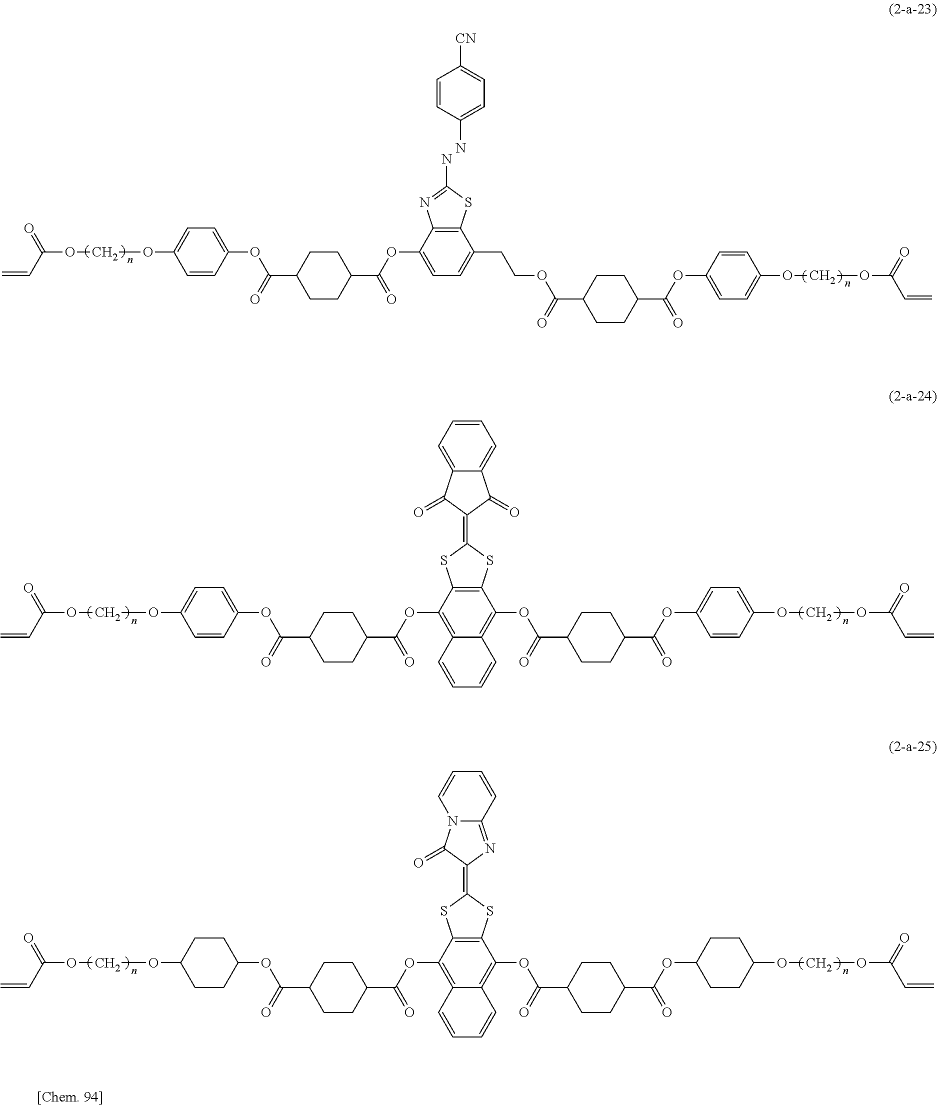

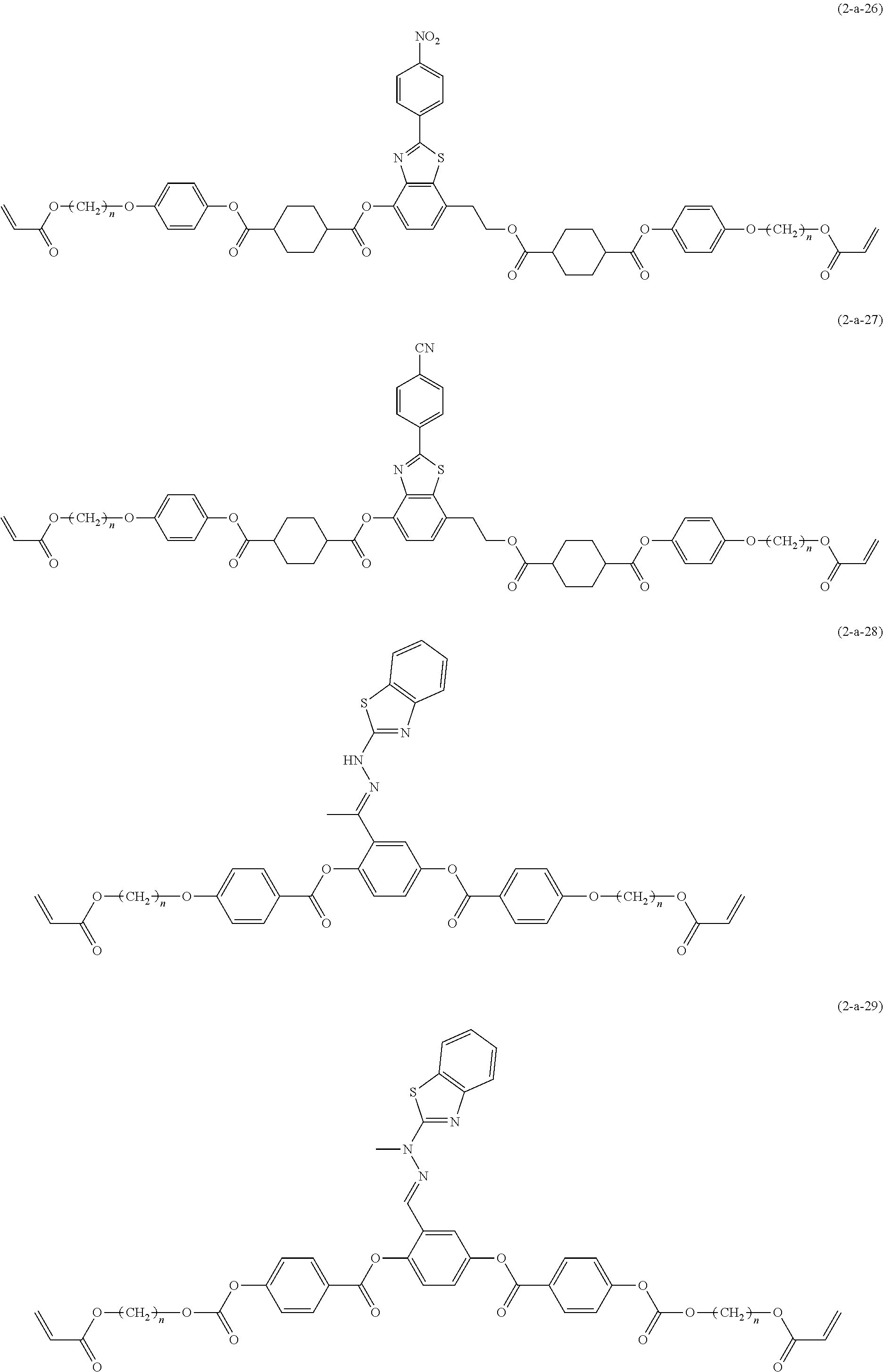

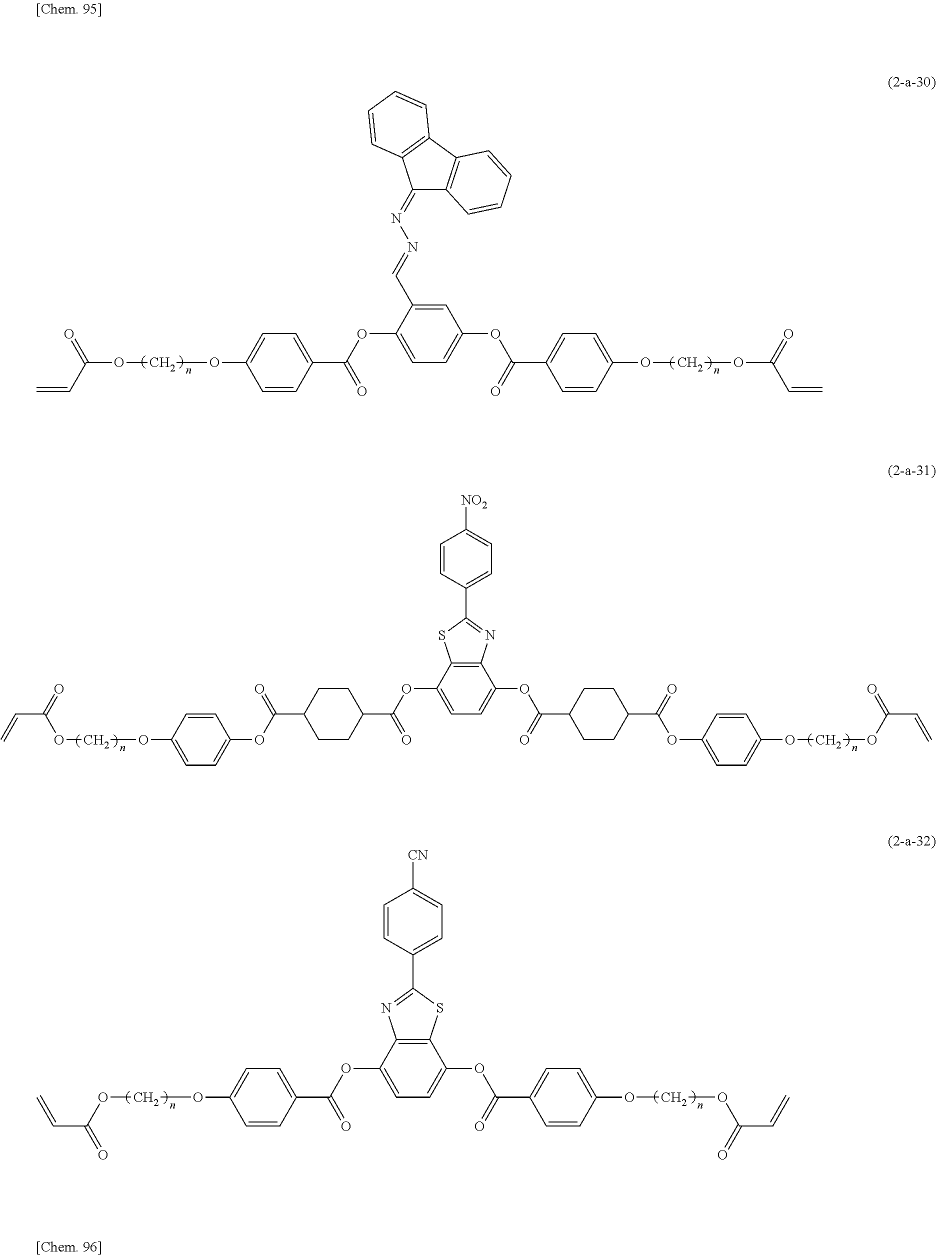

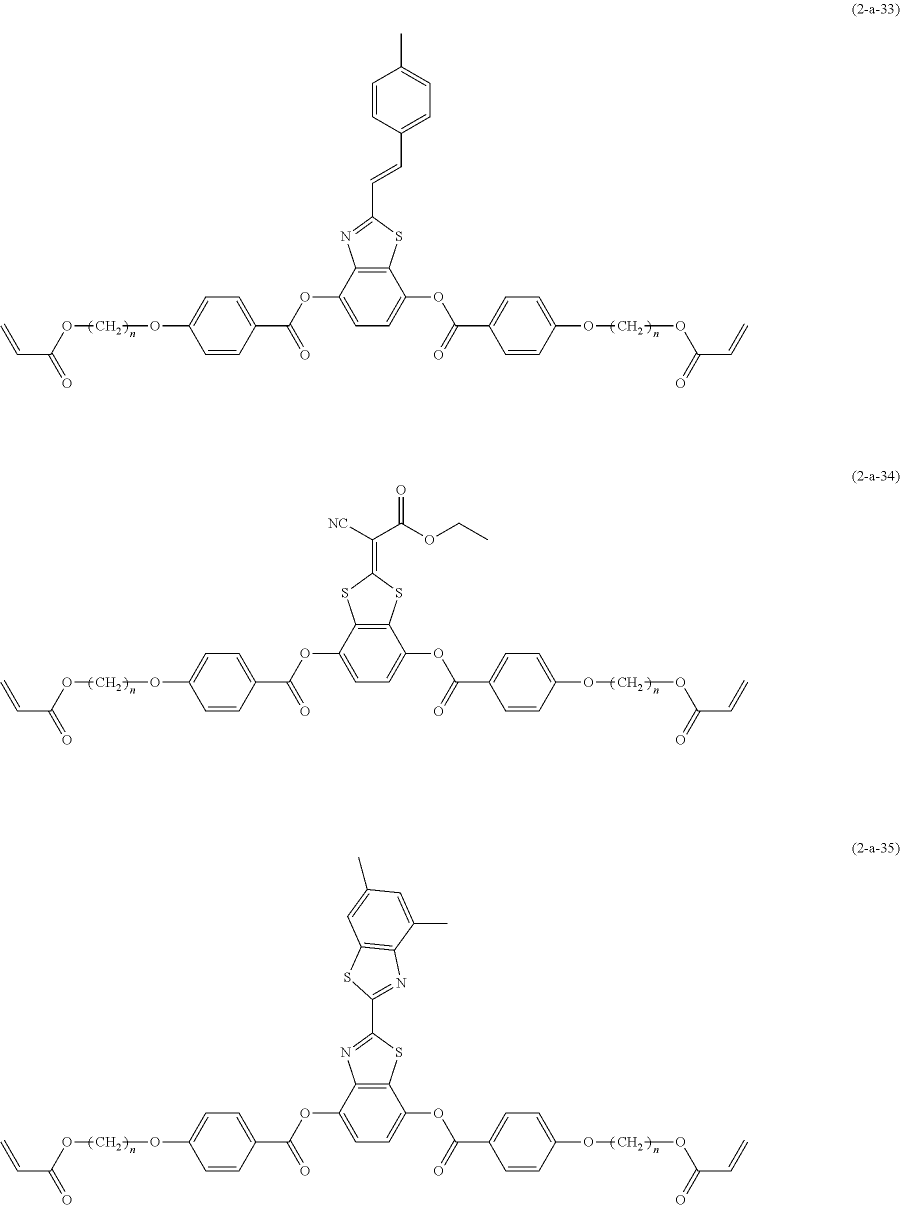

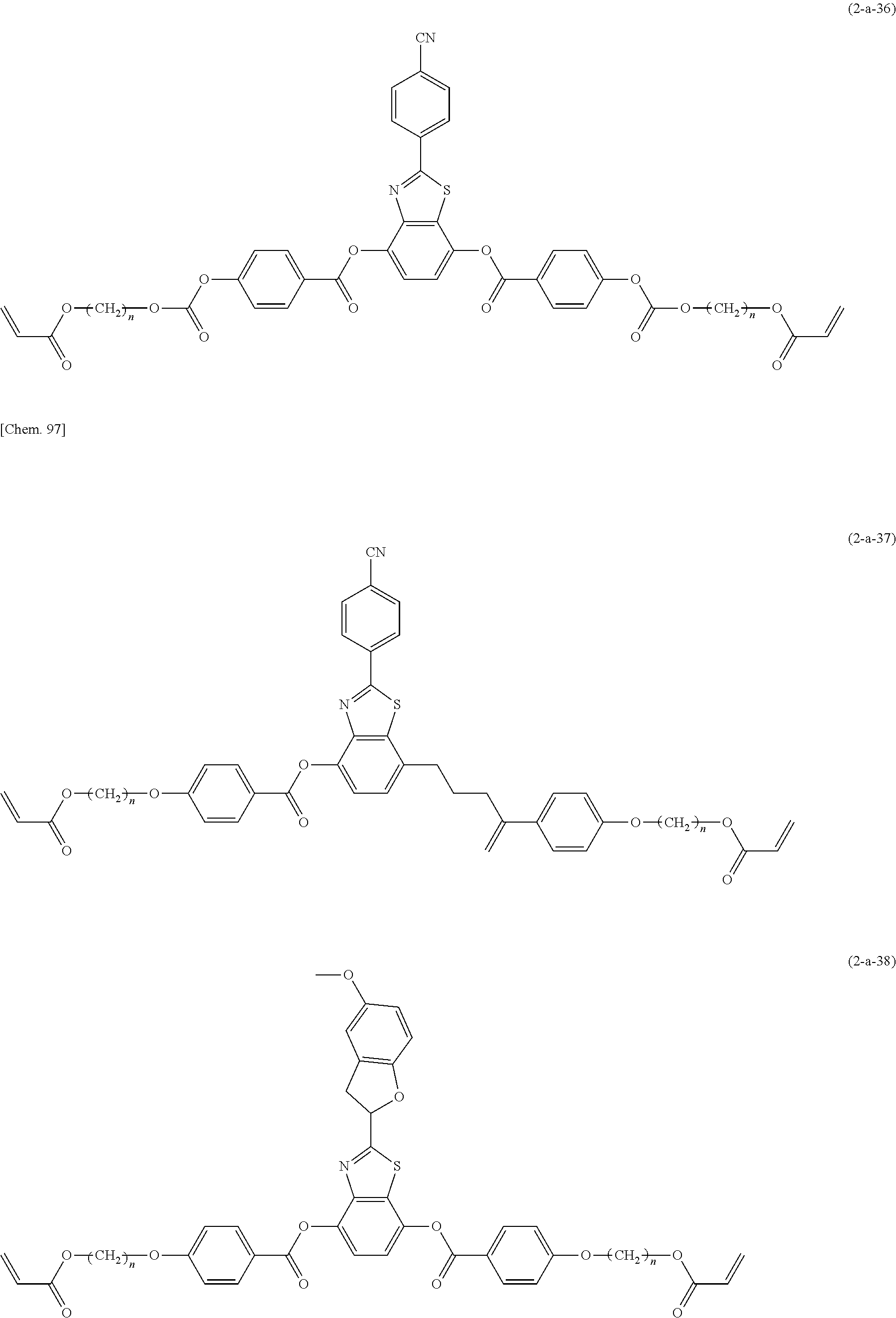

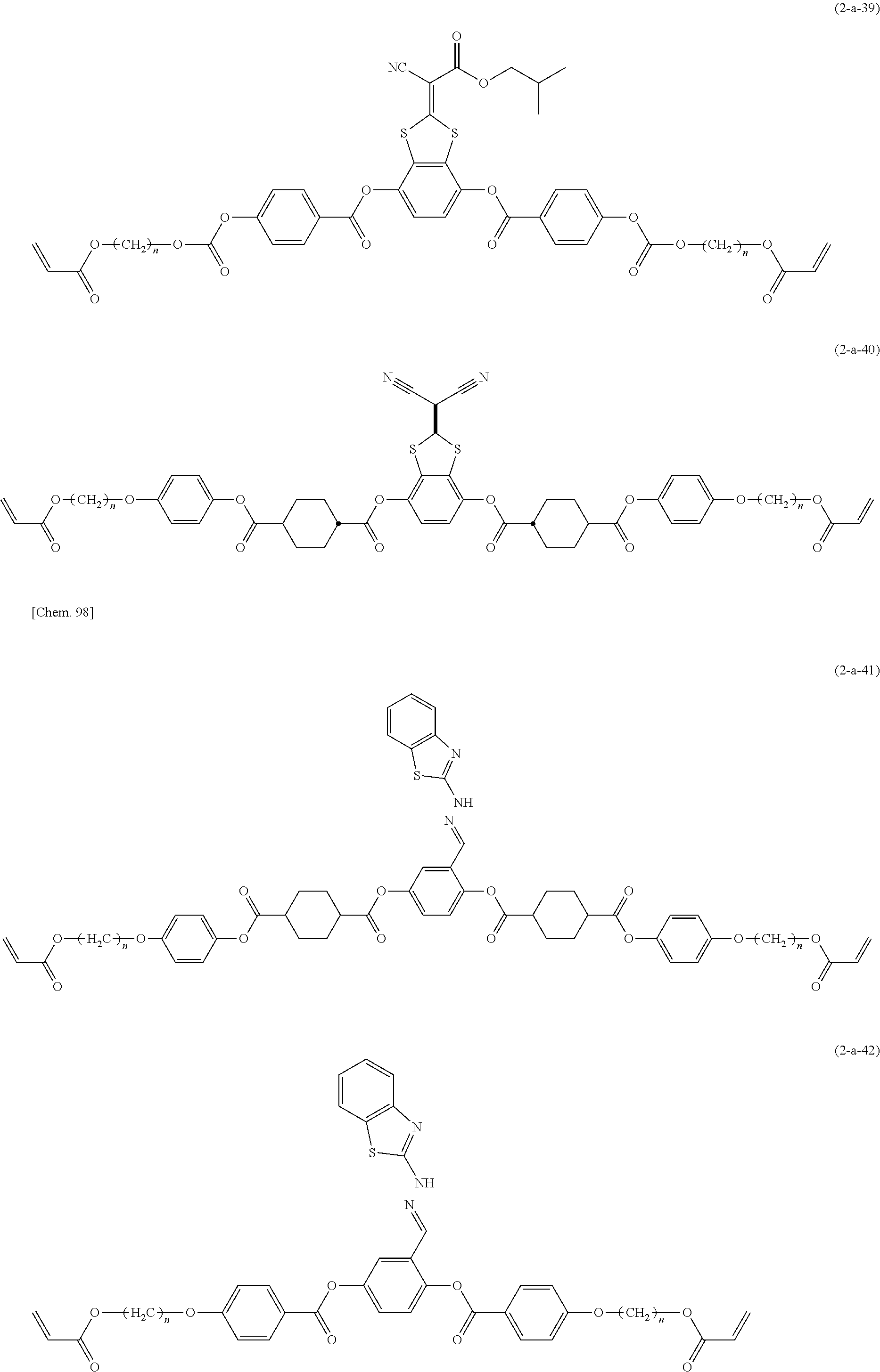

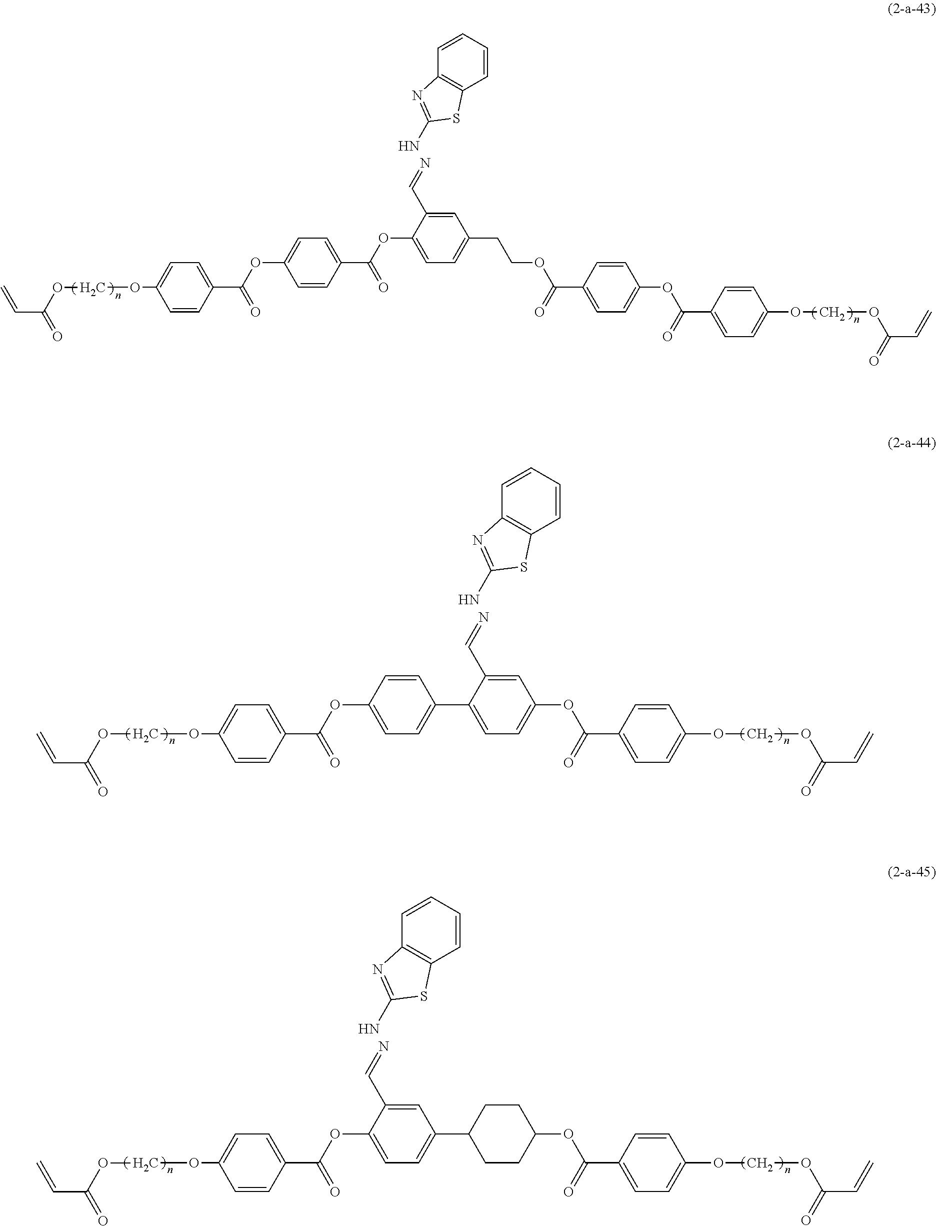

(wherein n represents an integer of 1 to 10). These liquid crystalline compounds may be used alone or as a mixture of two or more.

Specifically, the compound represented by general formula (3) is preferably compounds represented by formula (3-a-1) to formula (3-a-17) below.

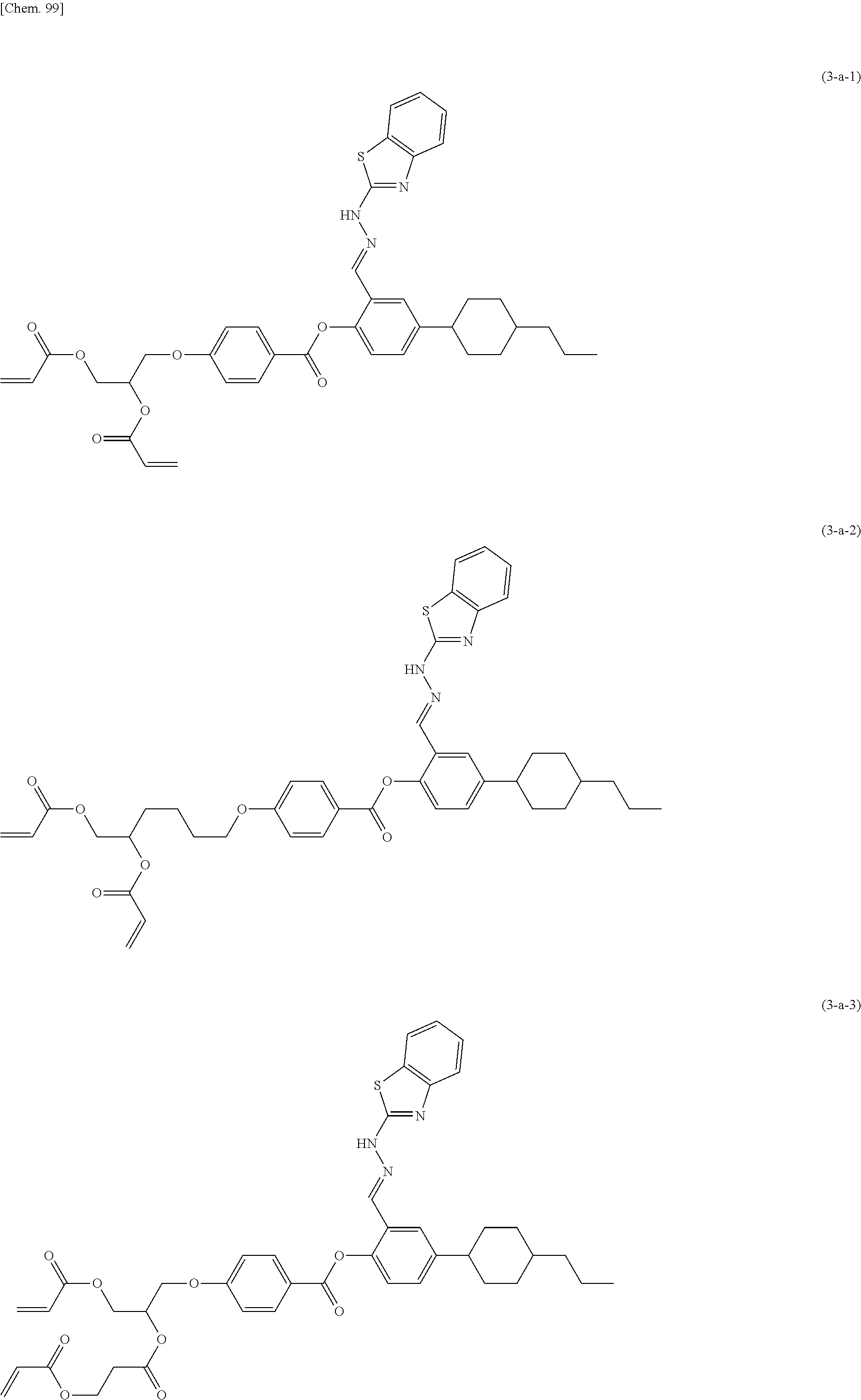

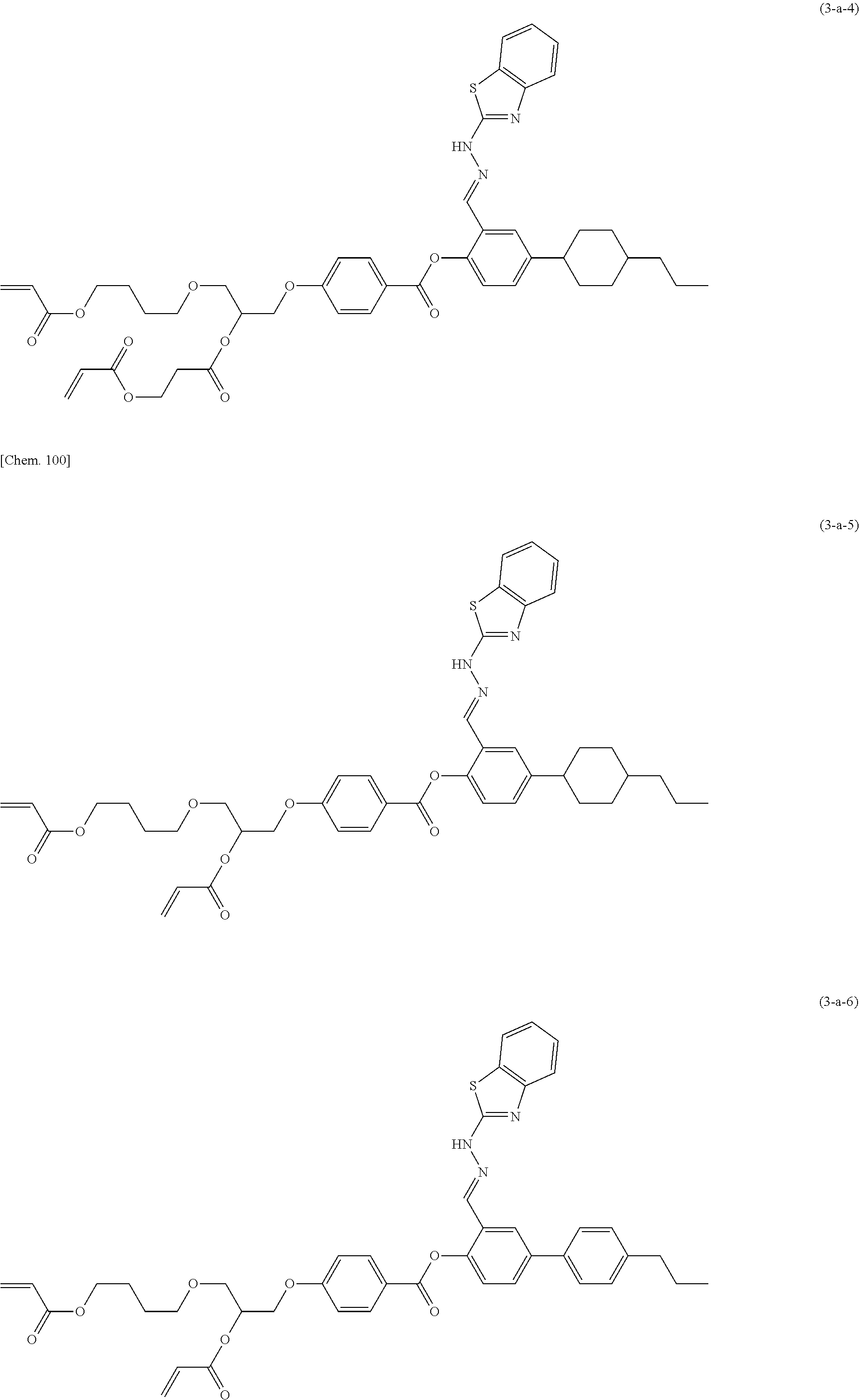

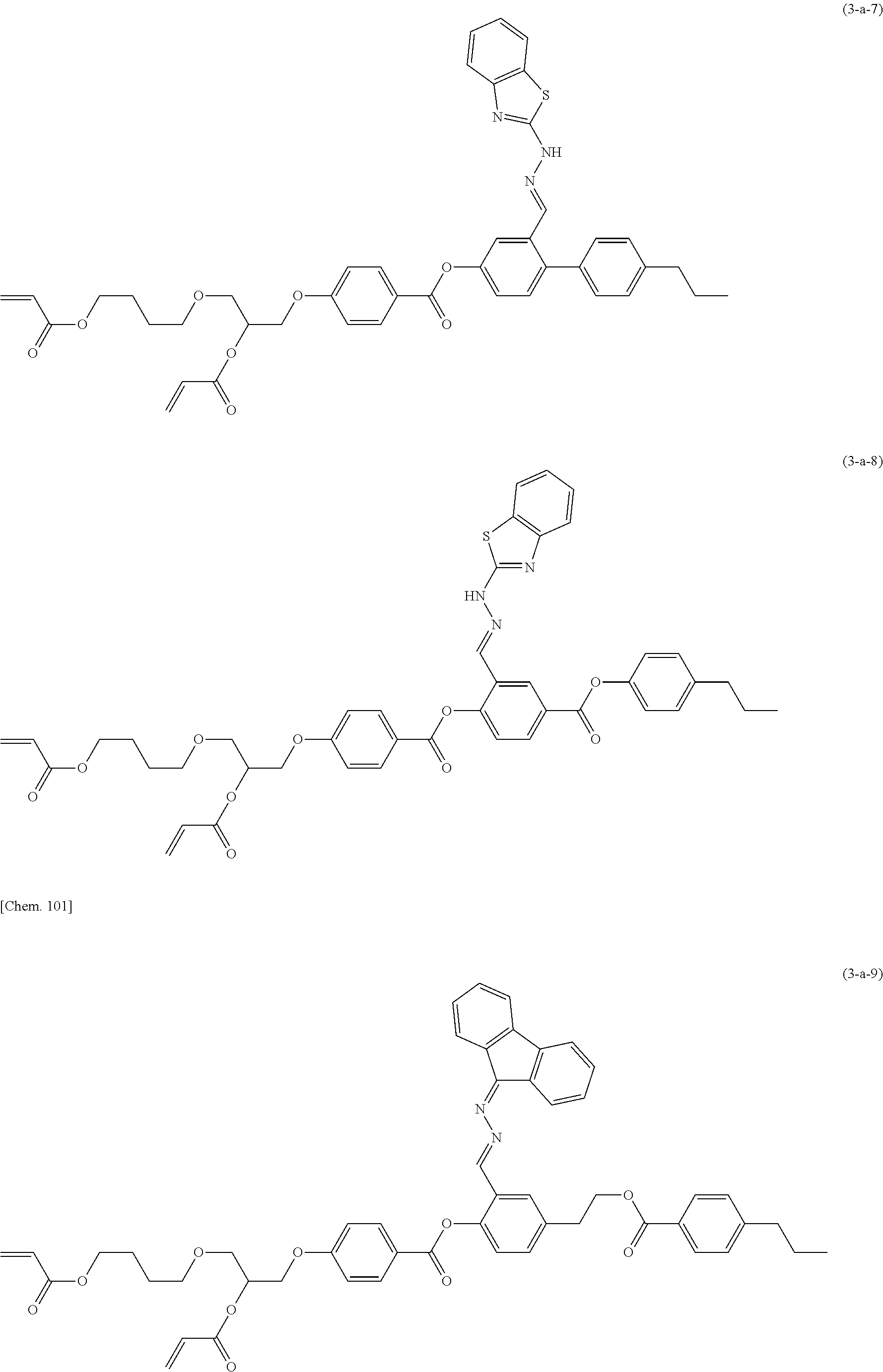

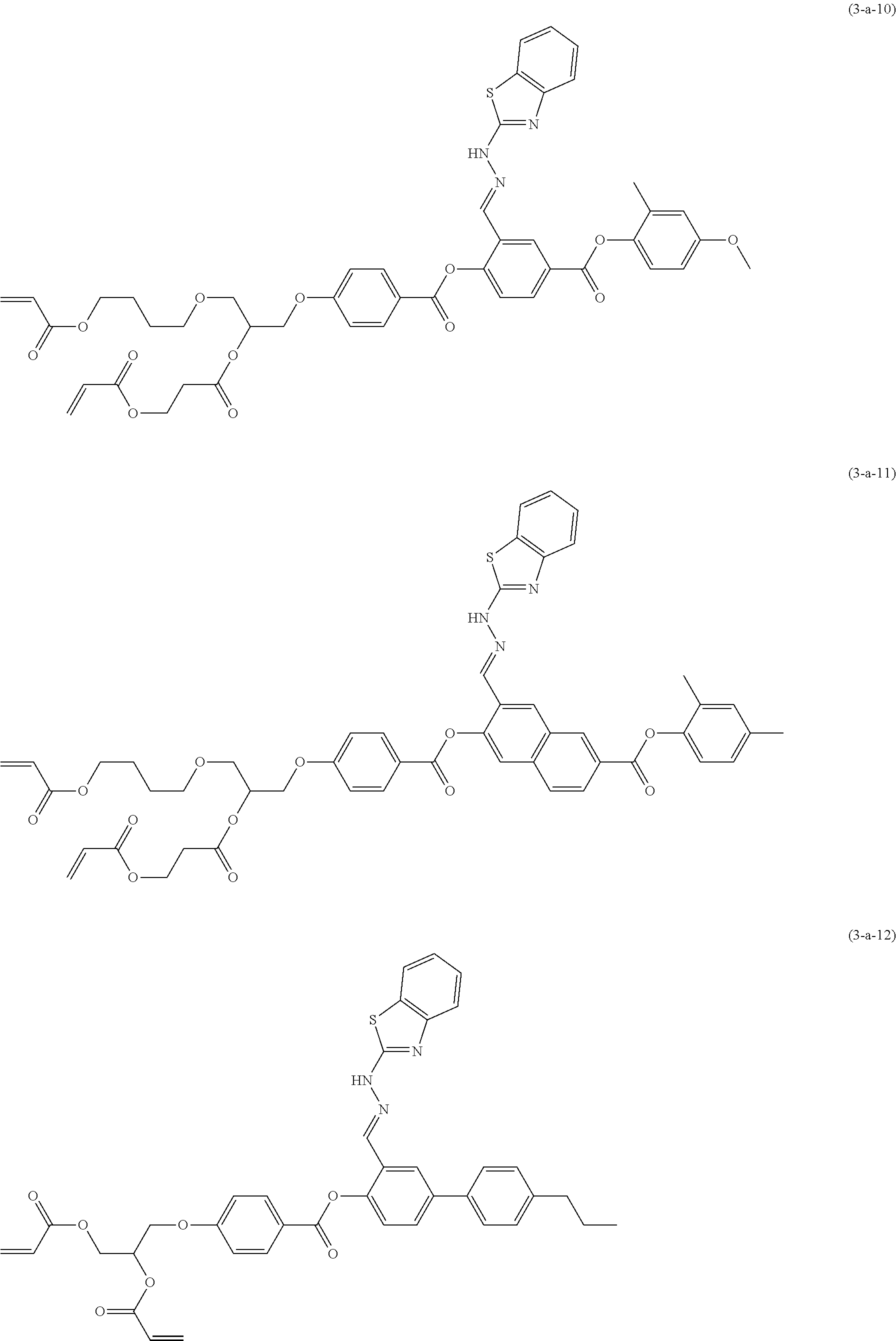

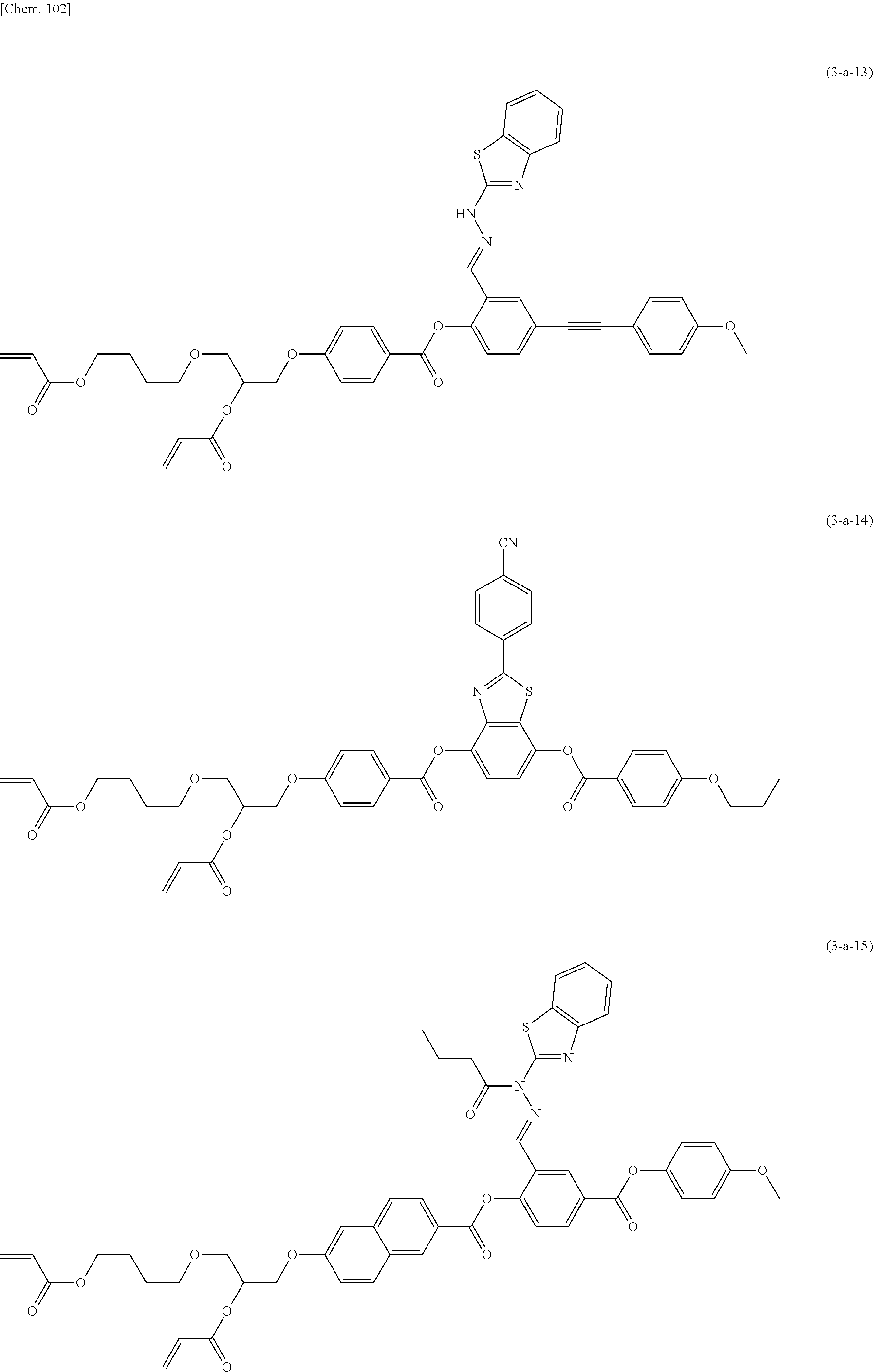

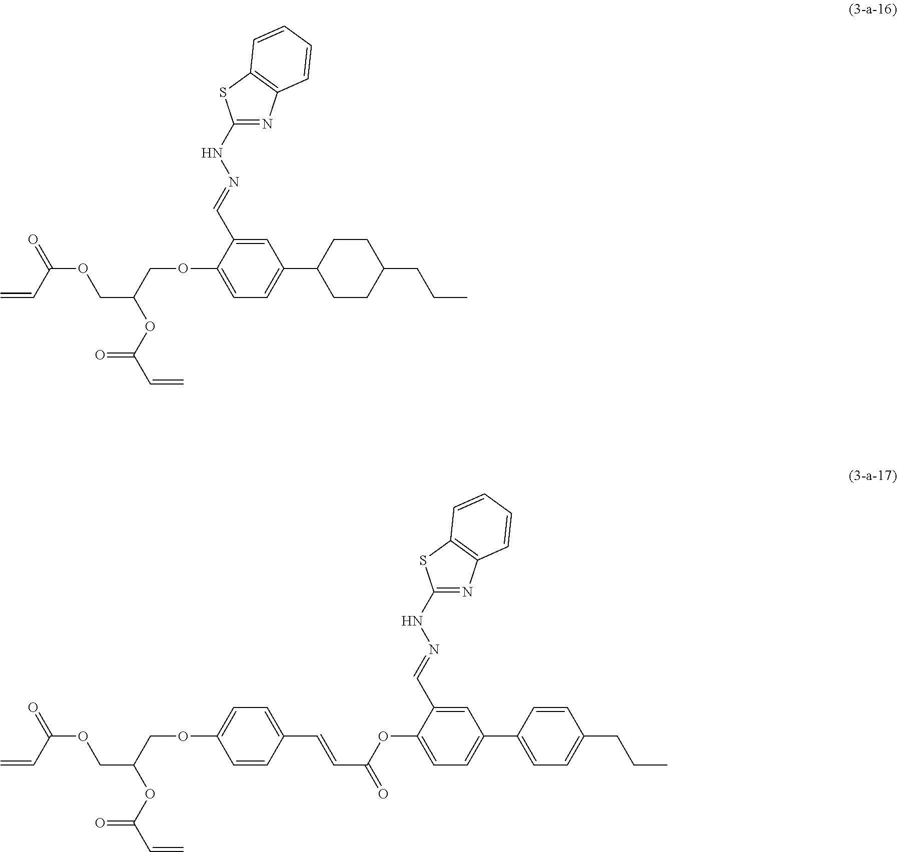

These liquid crystalline compounds may be used alone or as a mixture of two or more.

Specifically, the compound represented by general formula (4) is preferably compounds represented by formula (4-a-1) to formula (4-a-26) below:

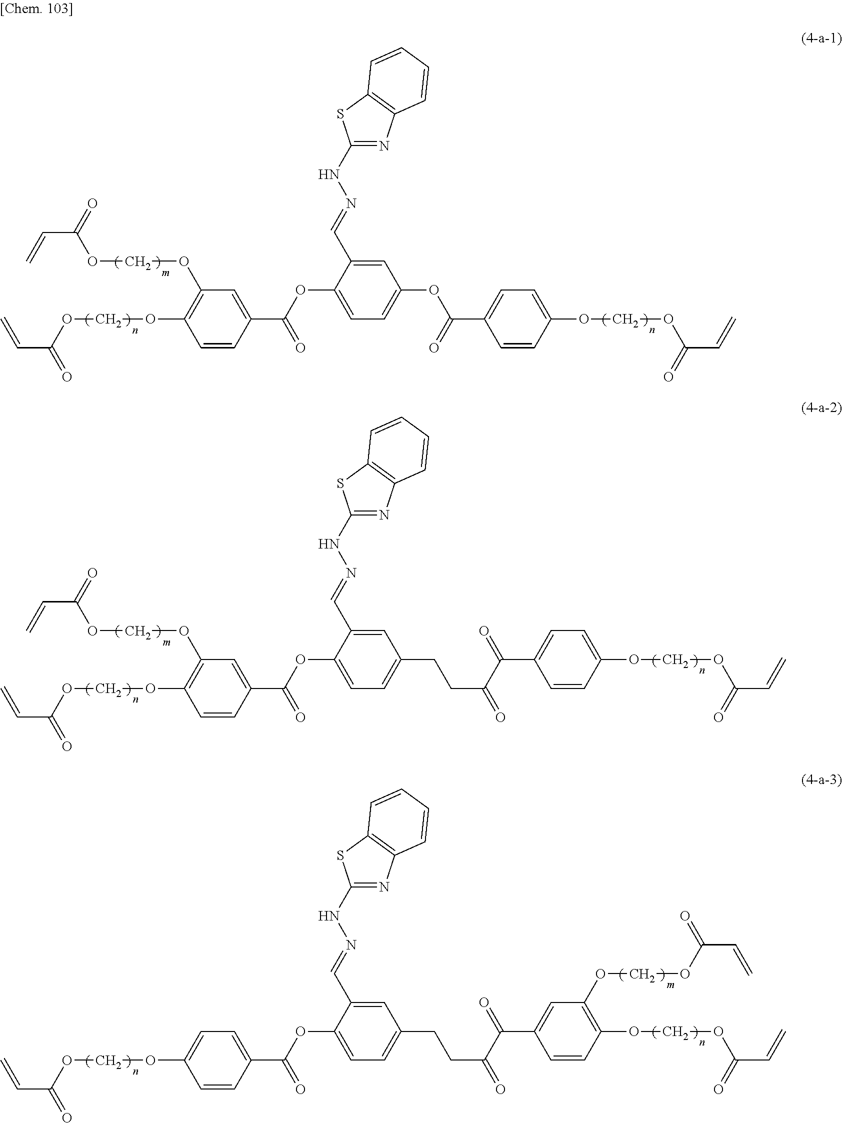

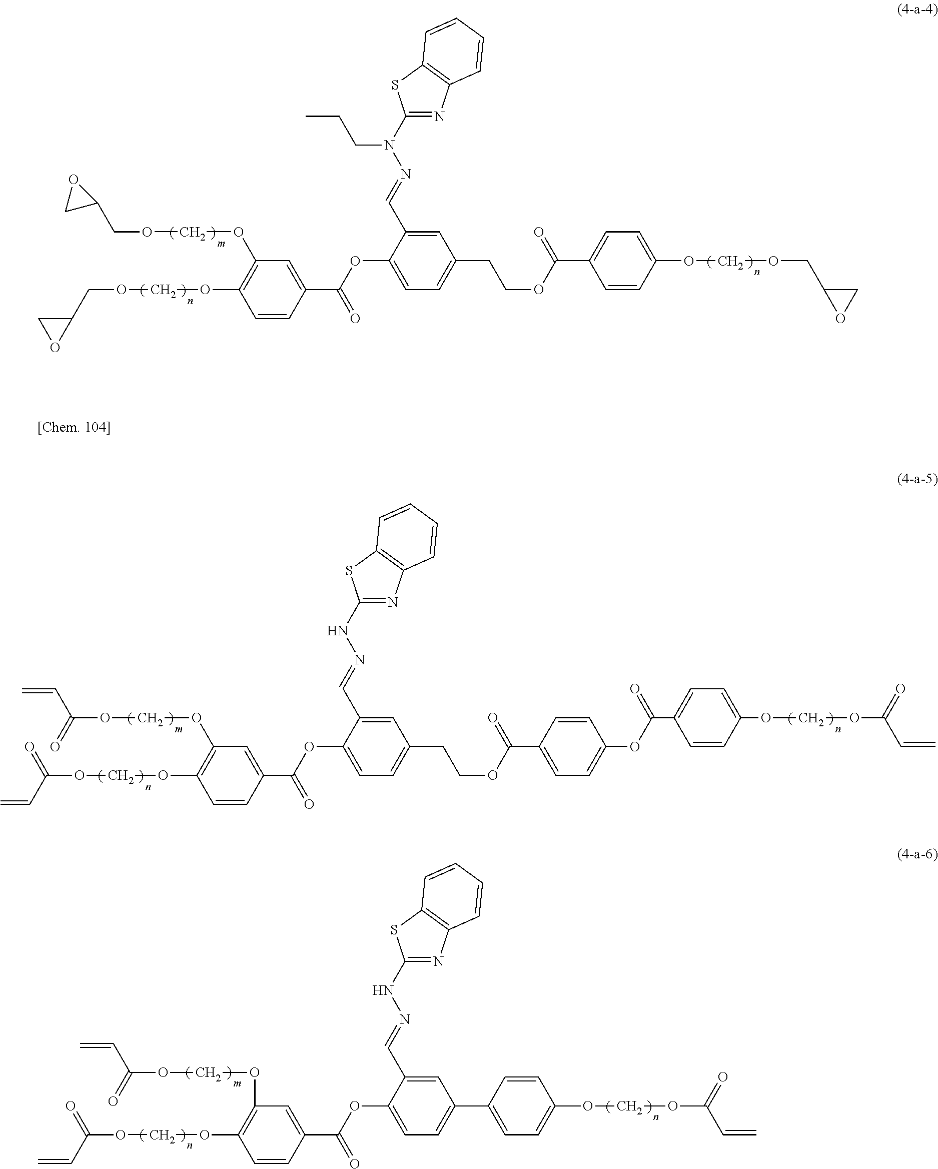

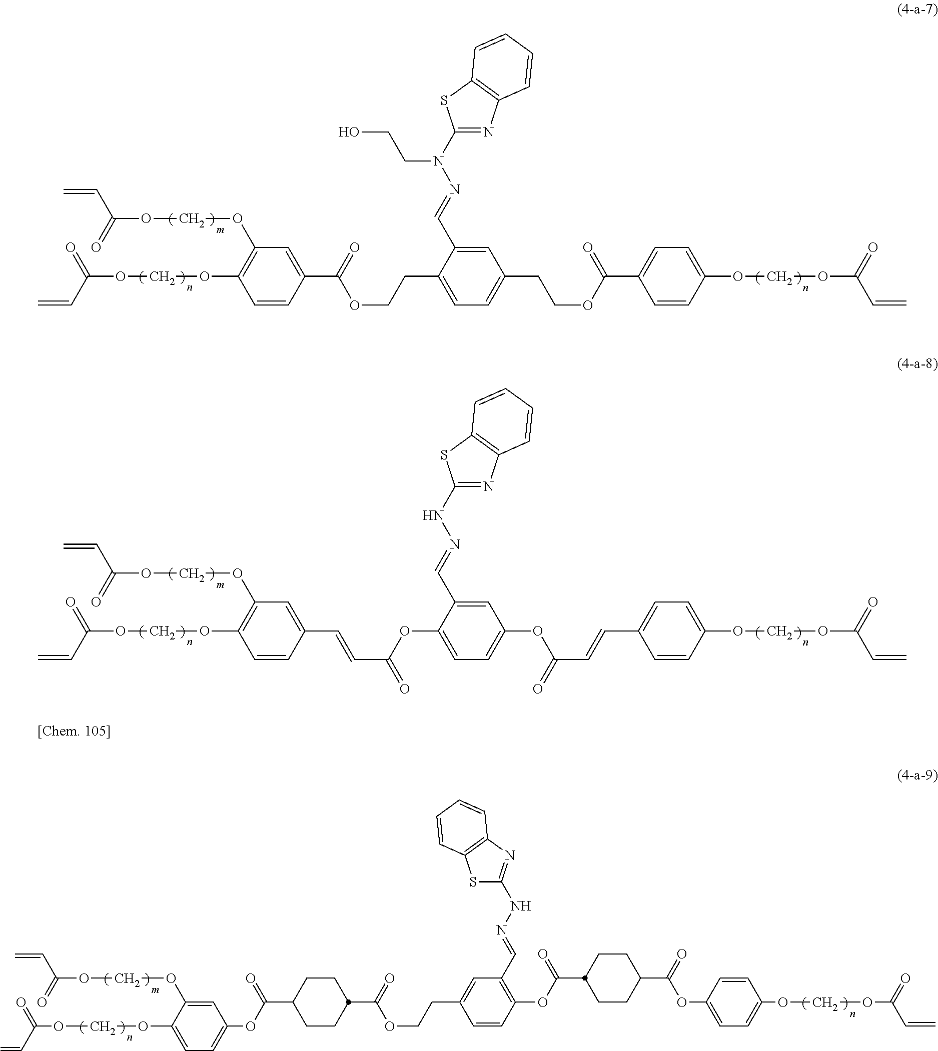

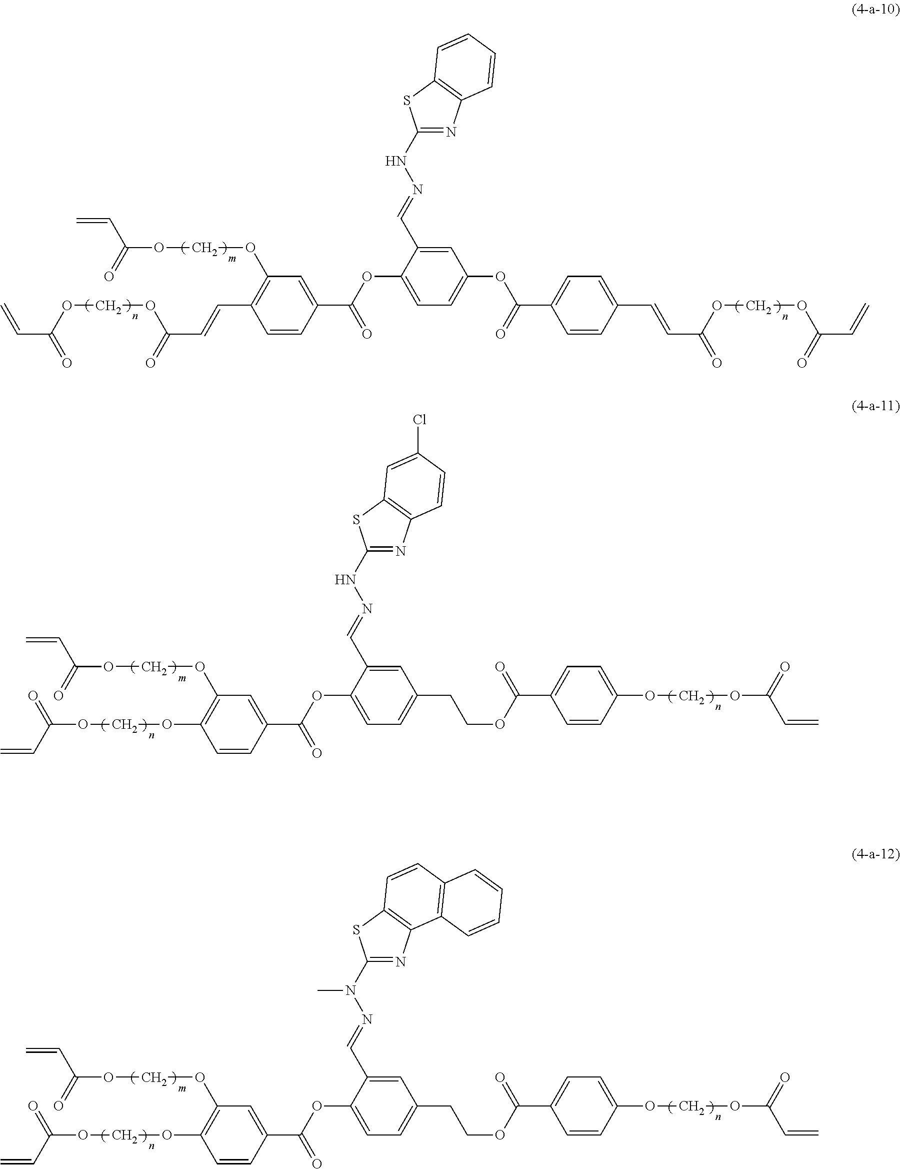

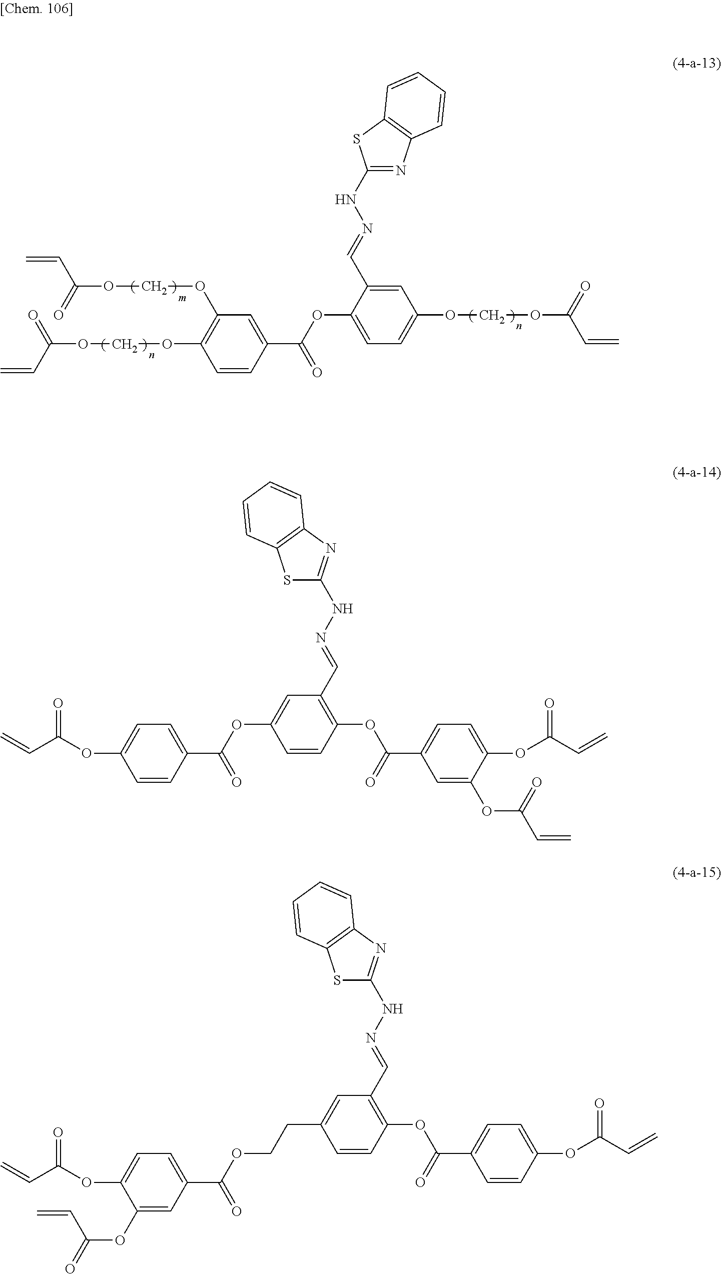

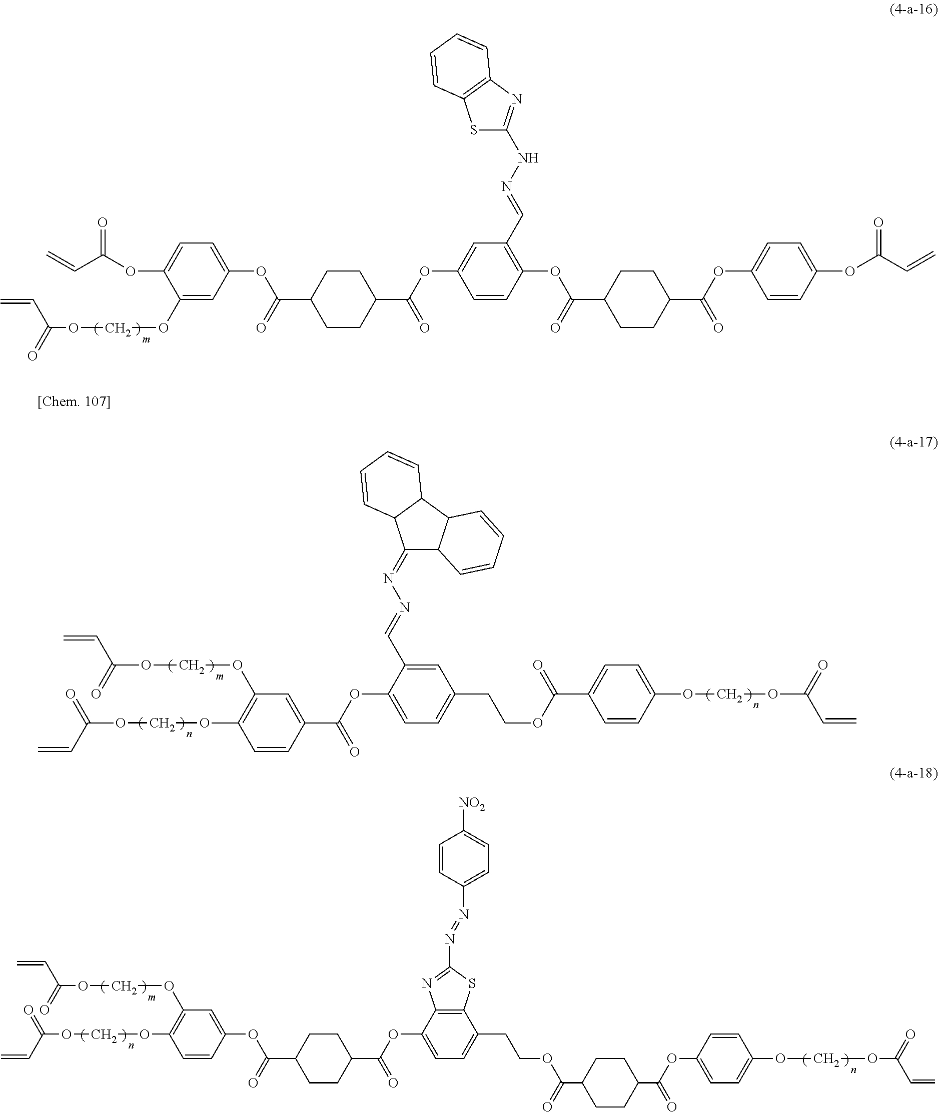

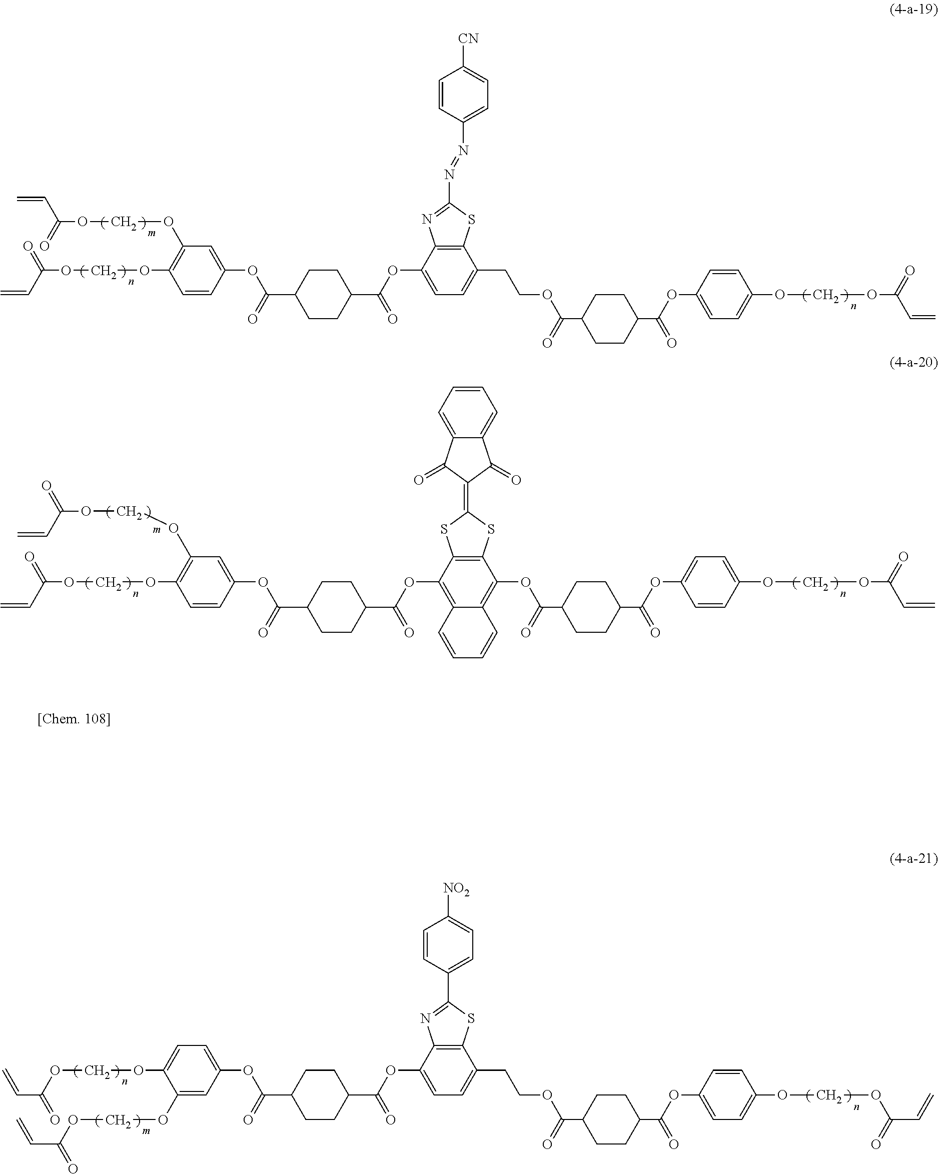

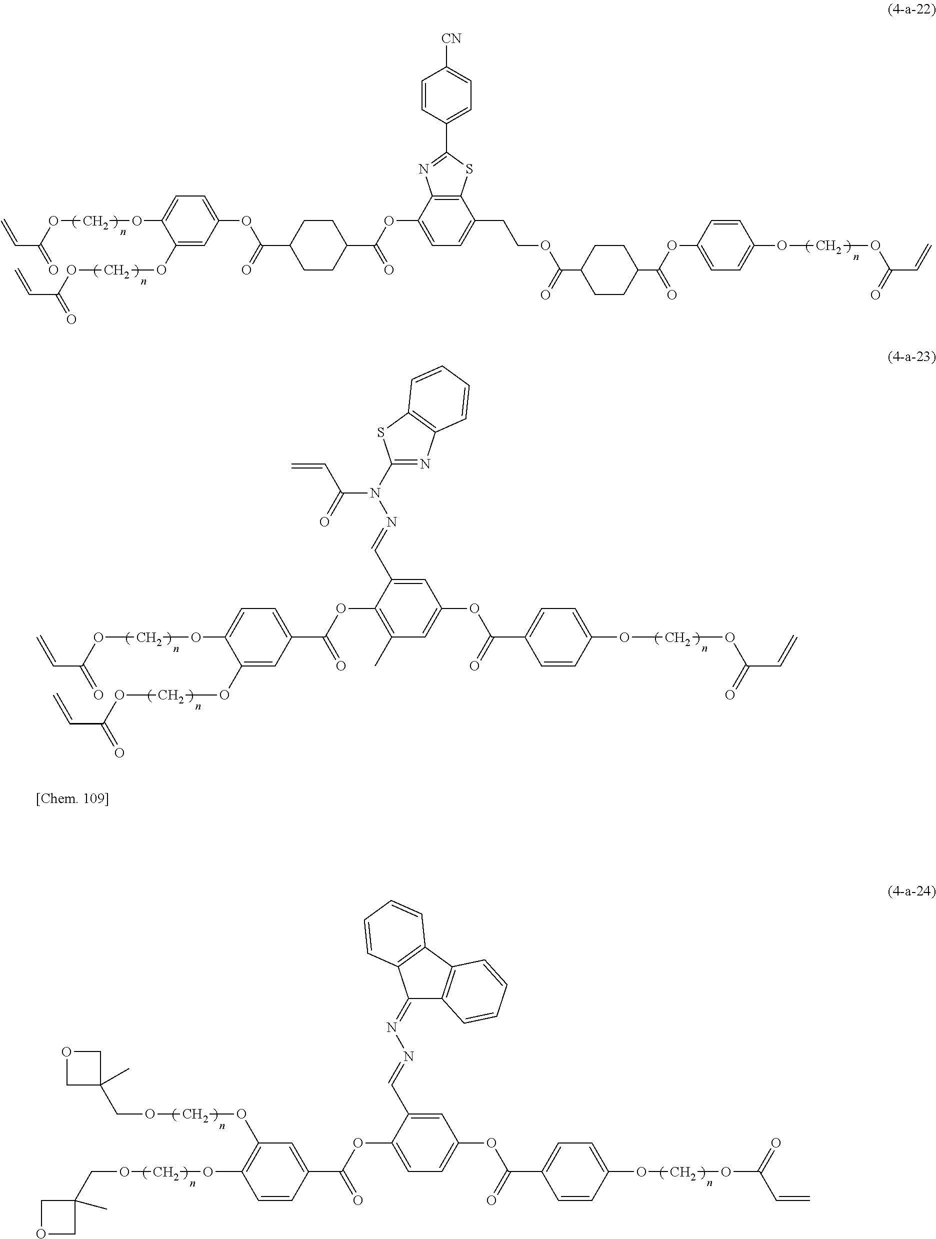

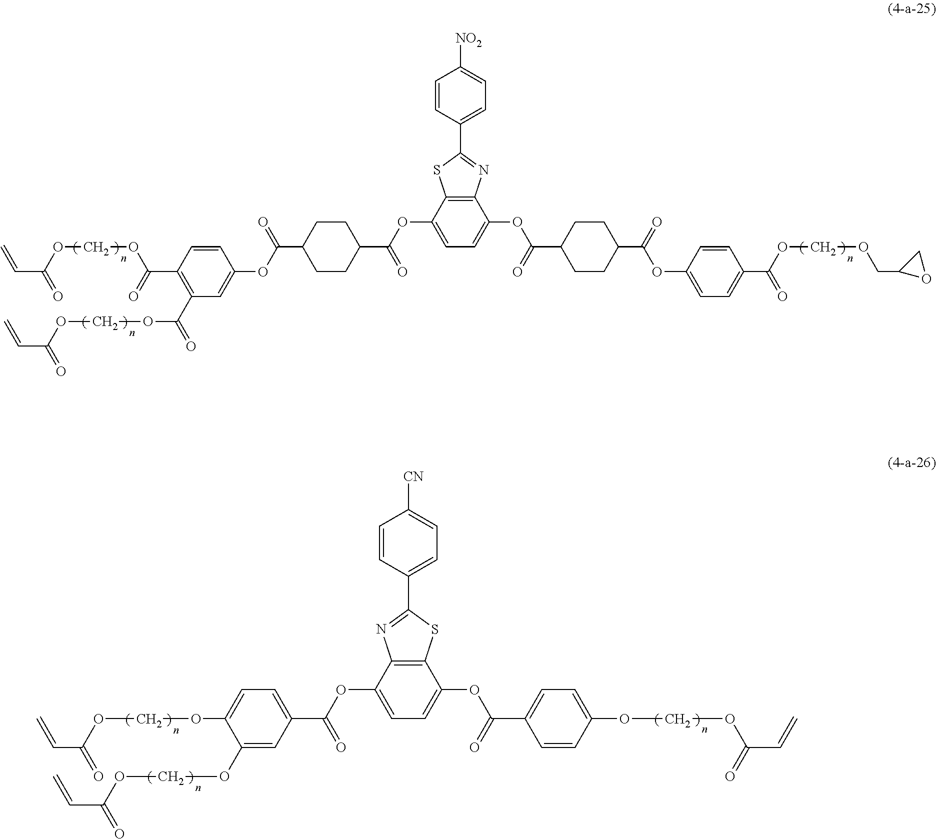

(wherein m and n each independently represent an integer of 1 to 10). These liquid crystalline compounds may be used alone or as a mixture of two or more.

Specifically, the compound represented by general formula (5) is preferably compounds represented by formula (5-a-1) to formula (5-a-29) below:

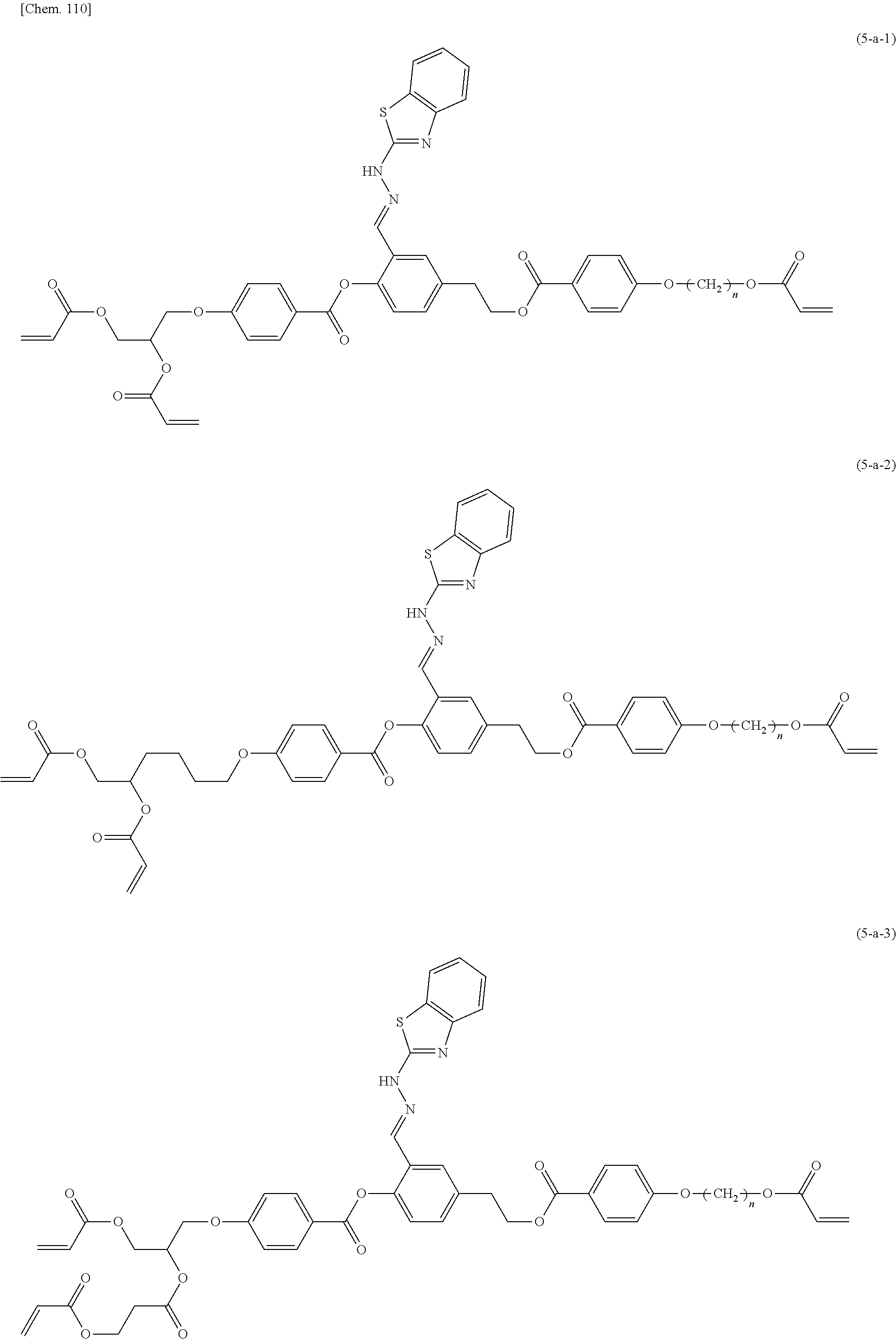

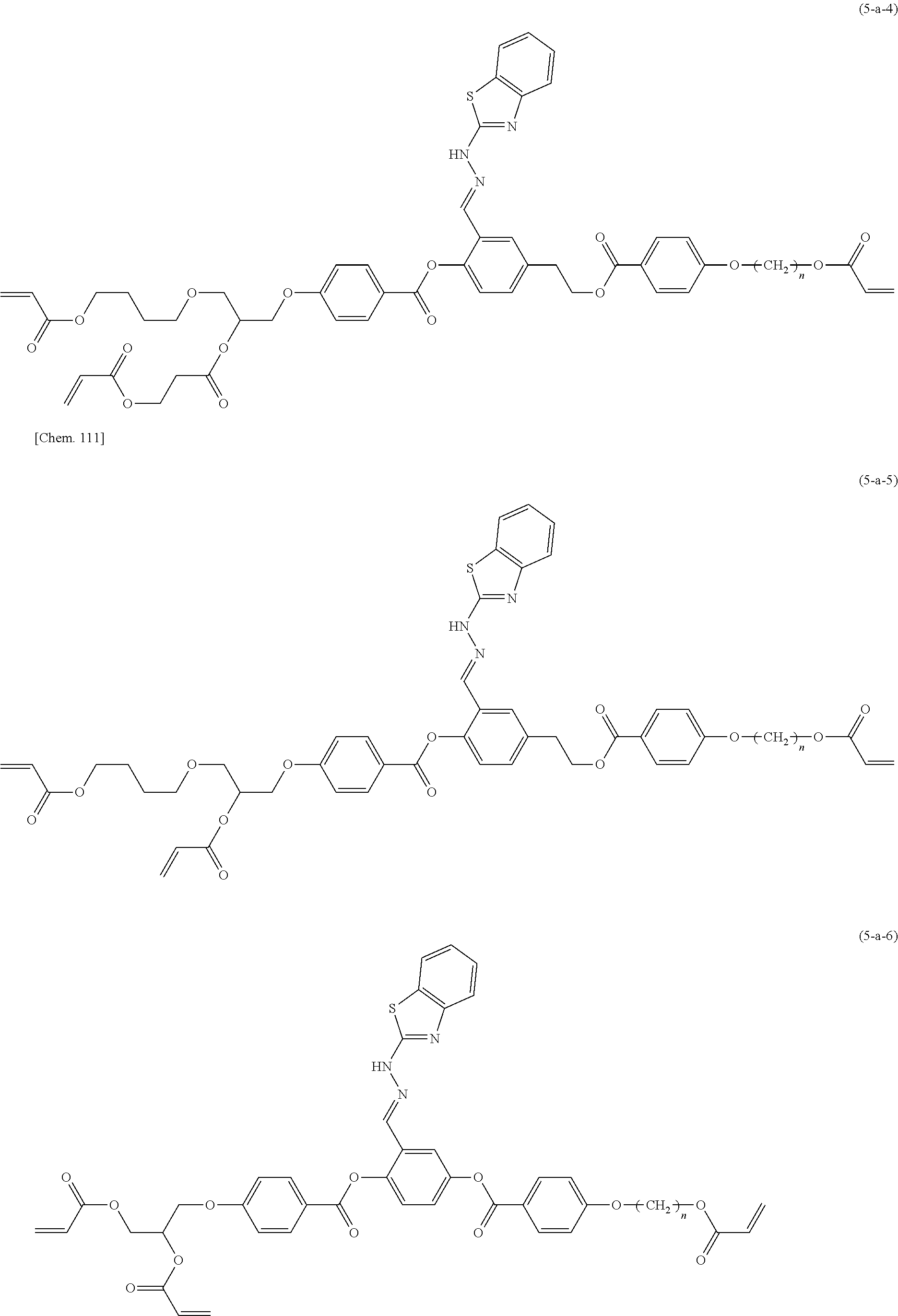

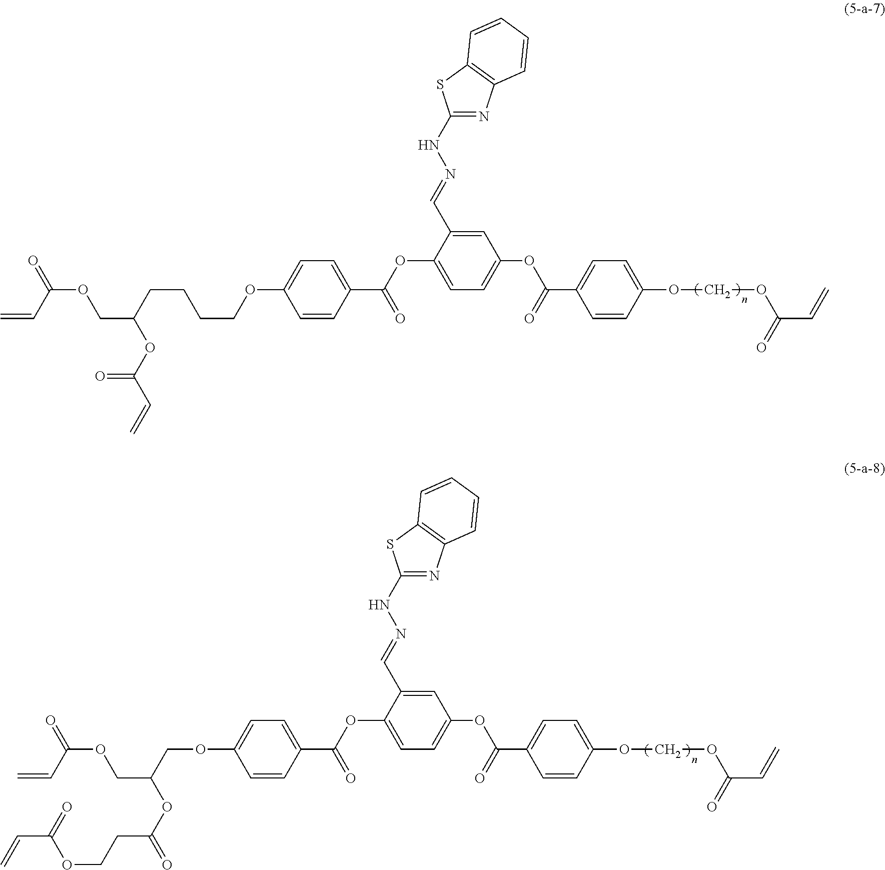

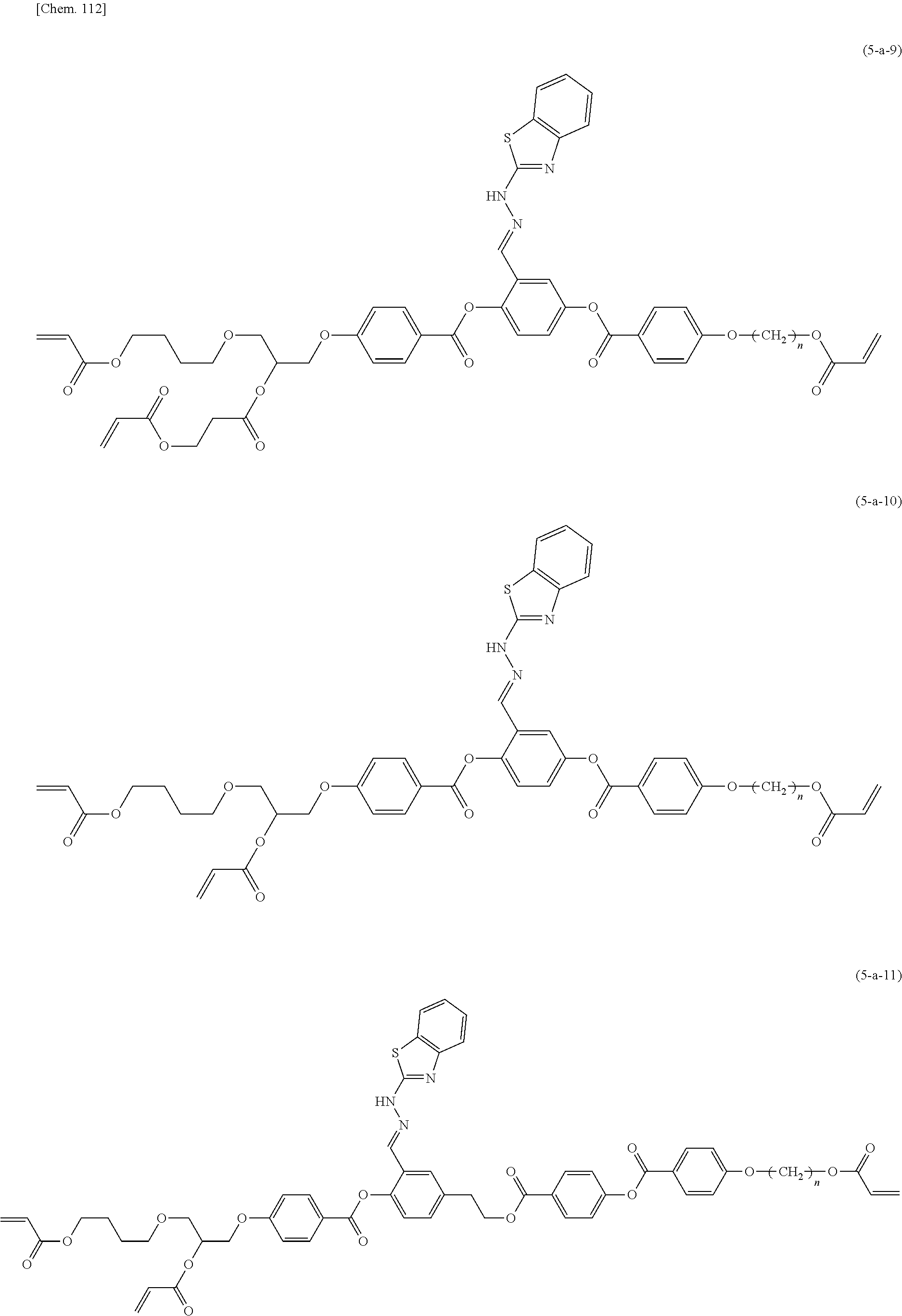

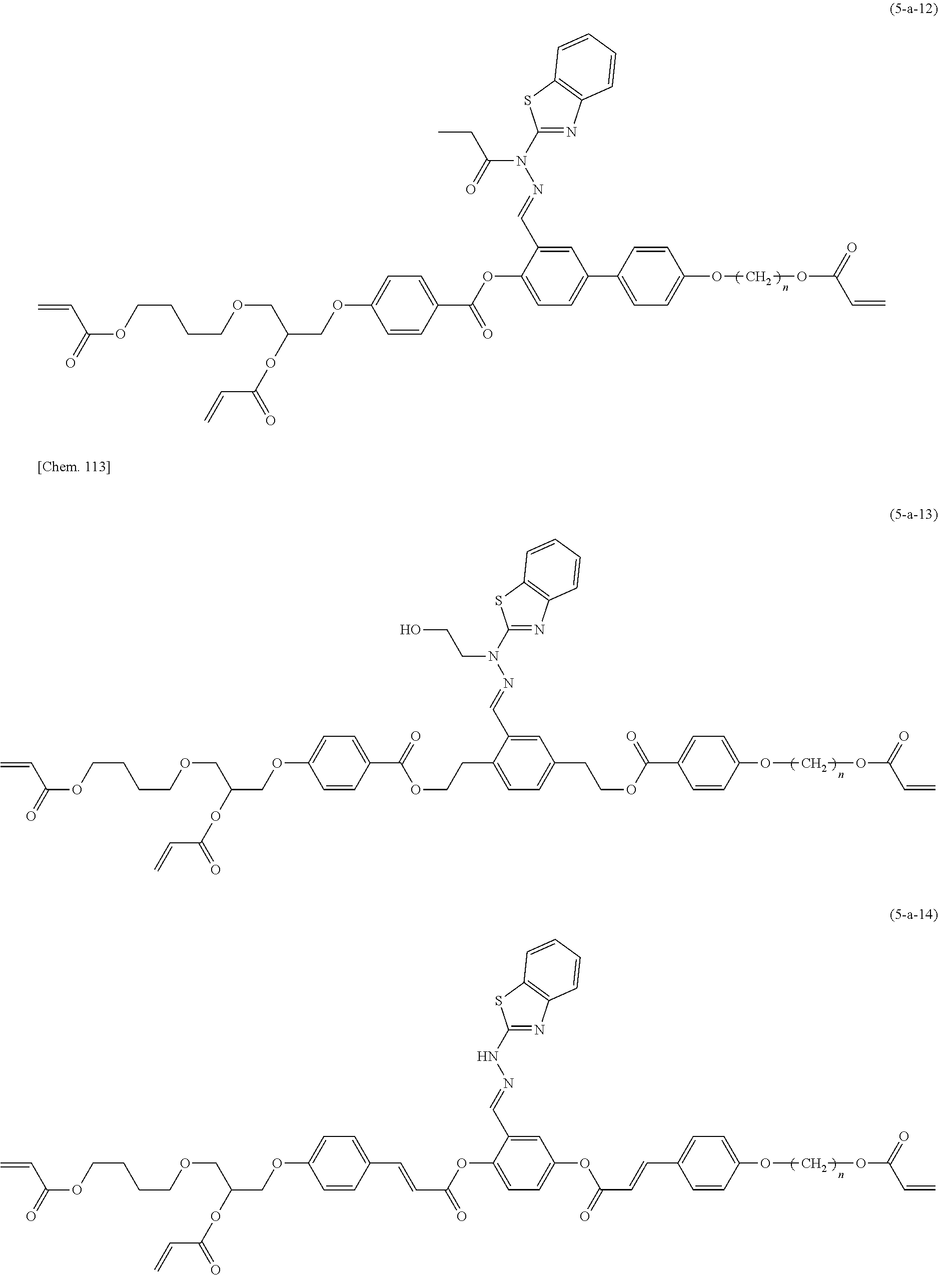

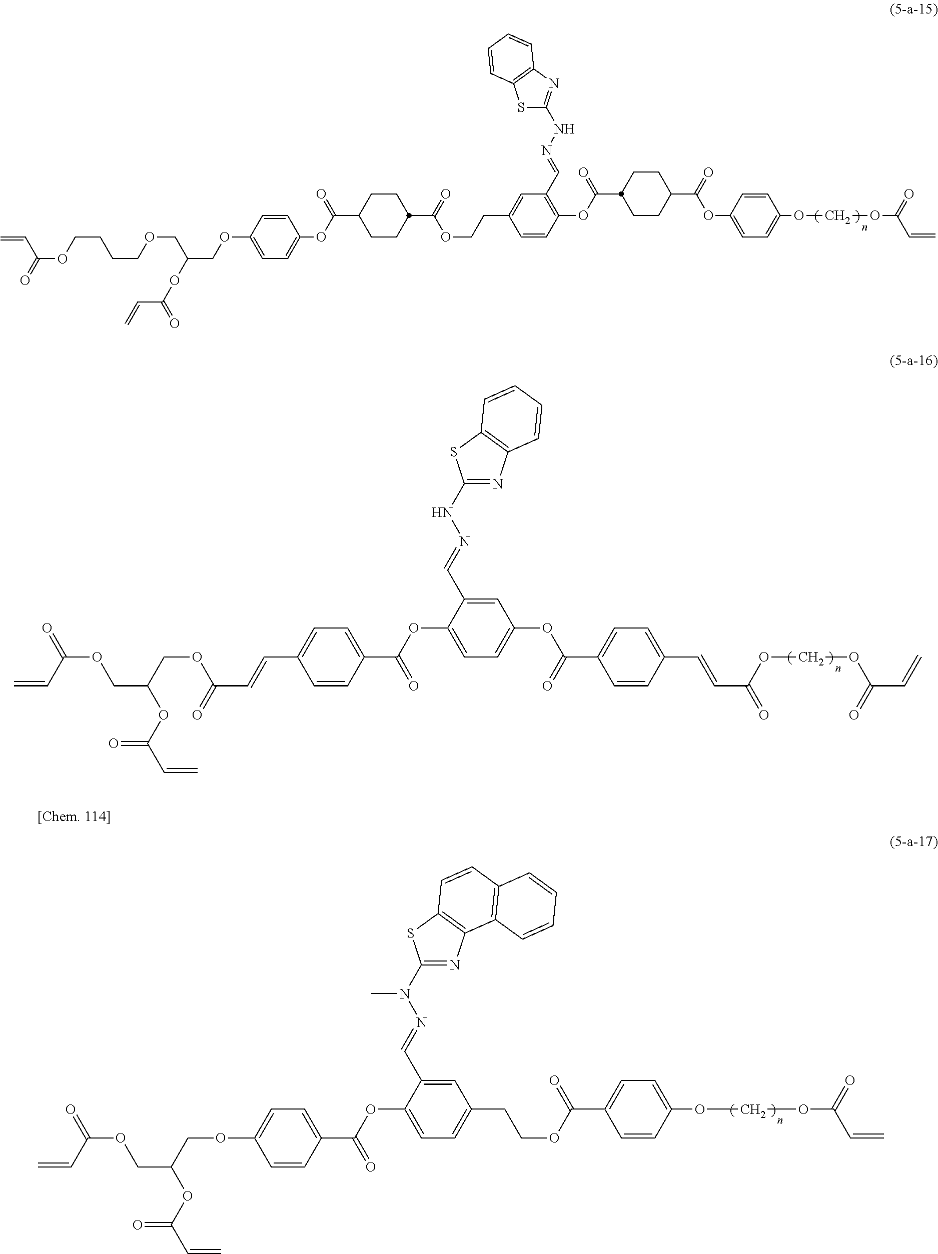

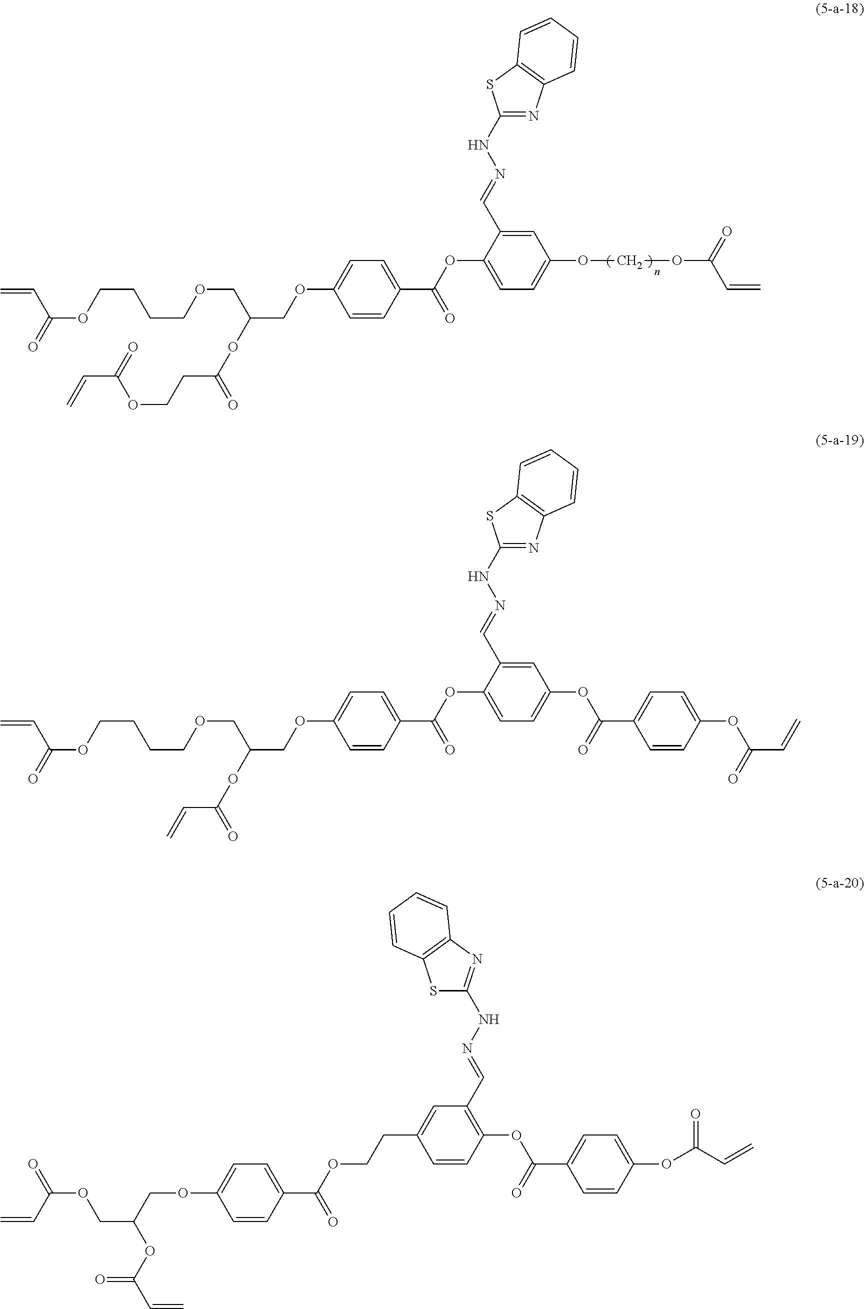

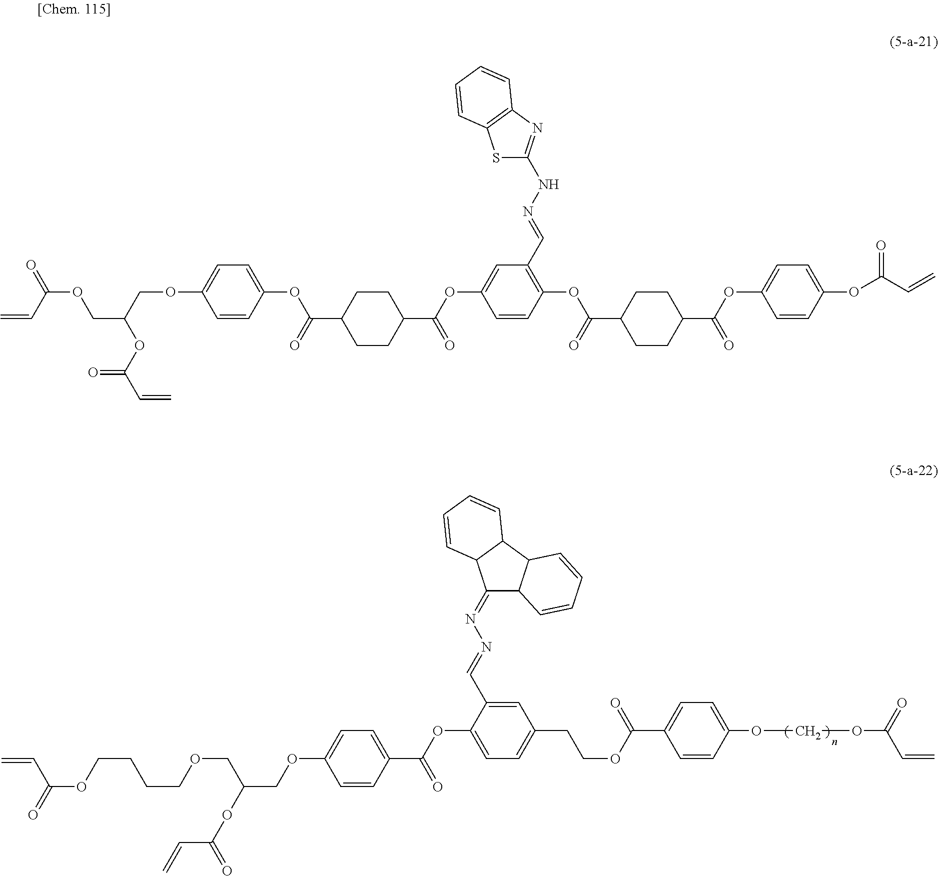

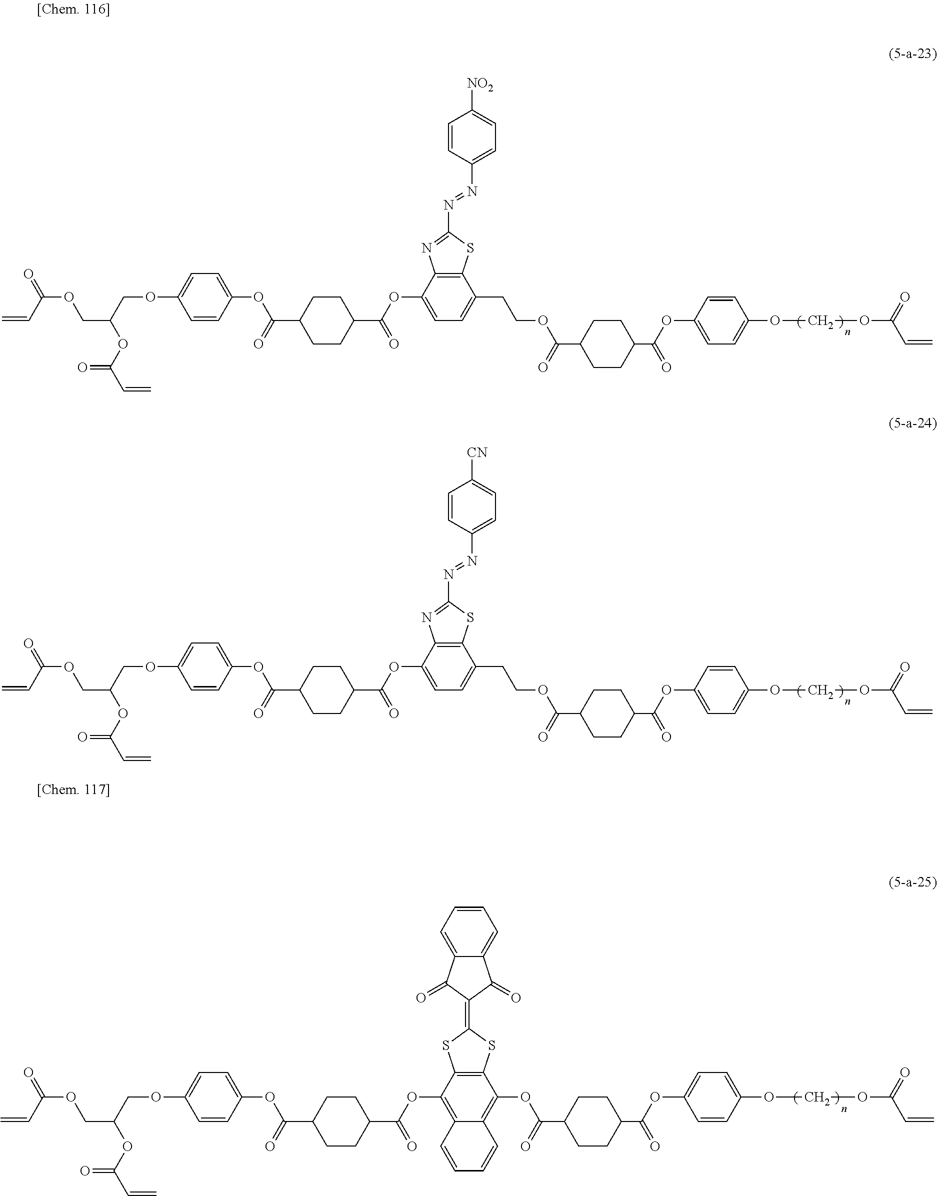

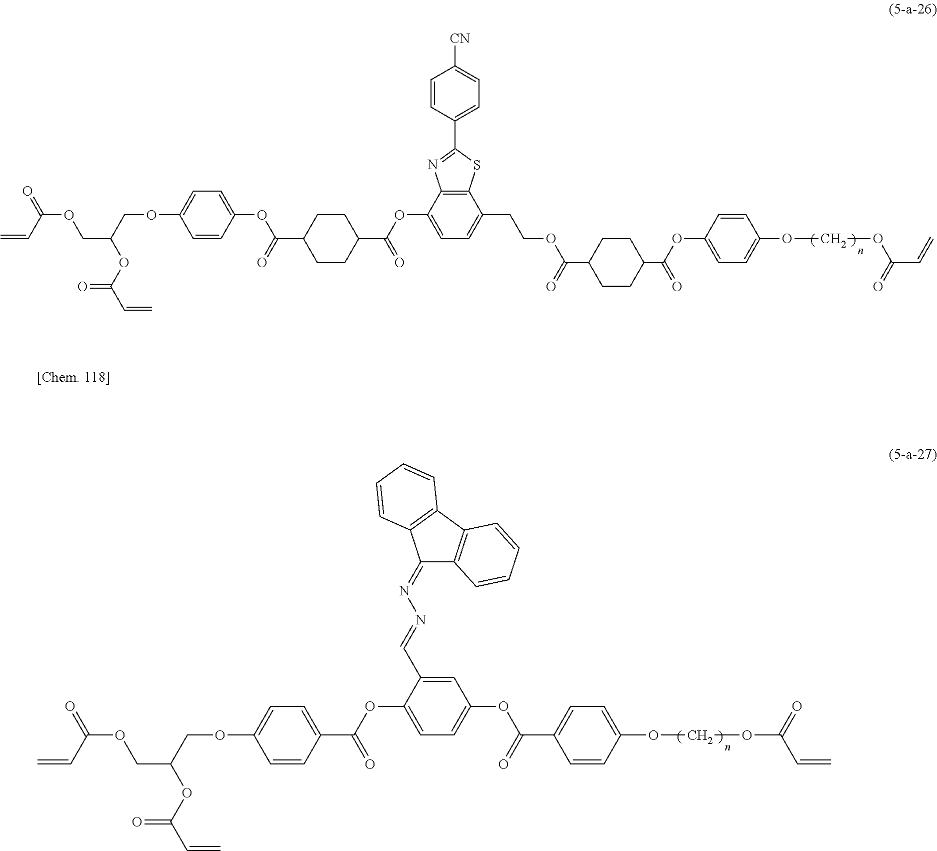

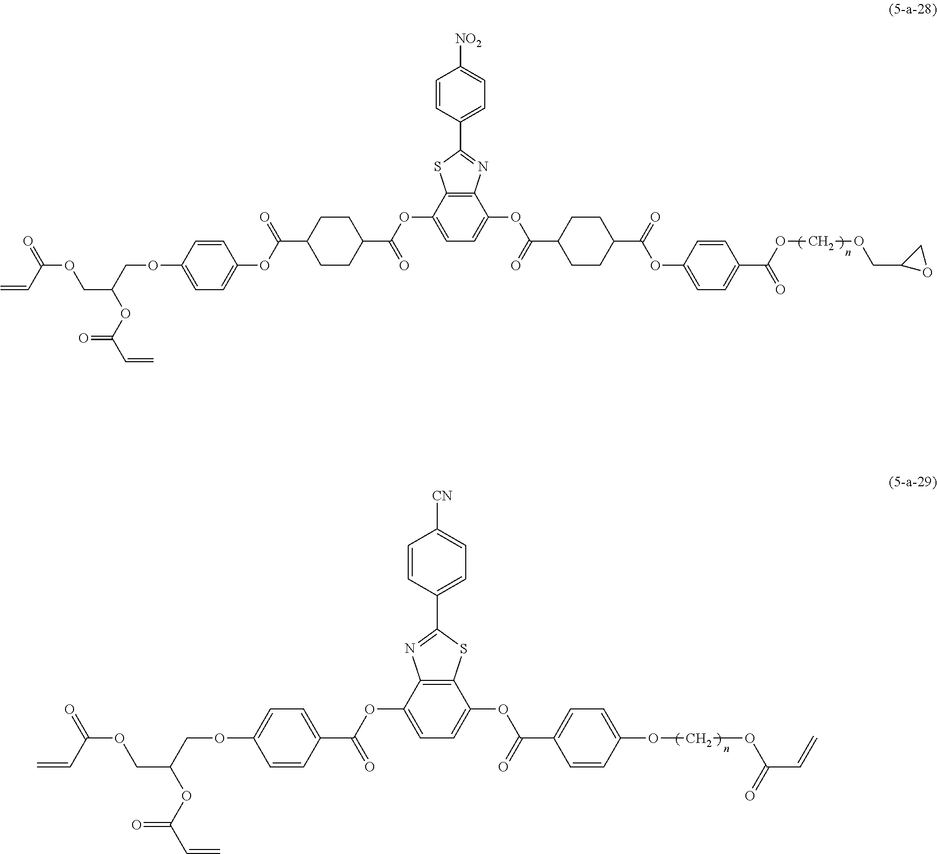

(wherein n represents the integer of 1 to 10). These liquid crystalline compounds may be used alone or as a mixture of two or more.

Specifically, the compound represented by general formula (6) is preferably compounds represented by formula (6-a-1) to formula (6-a-25) below:

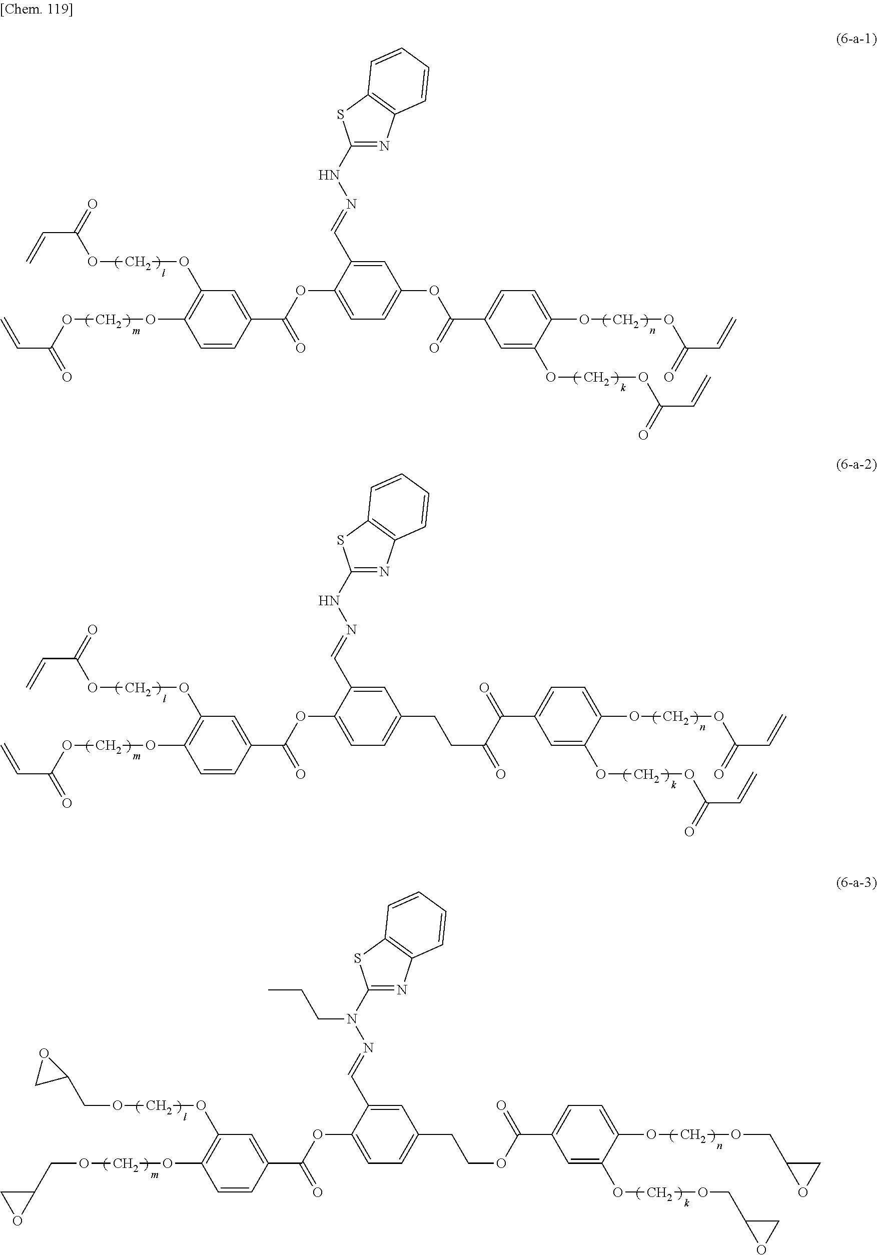

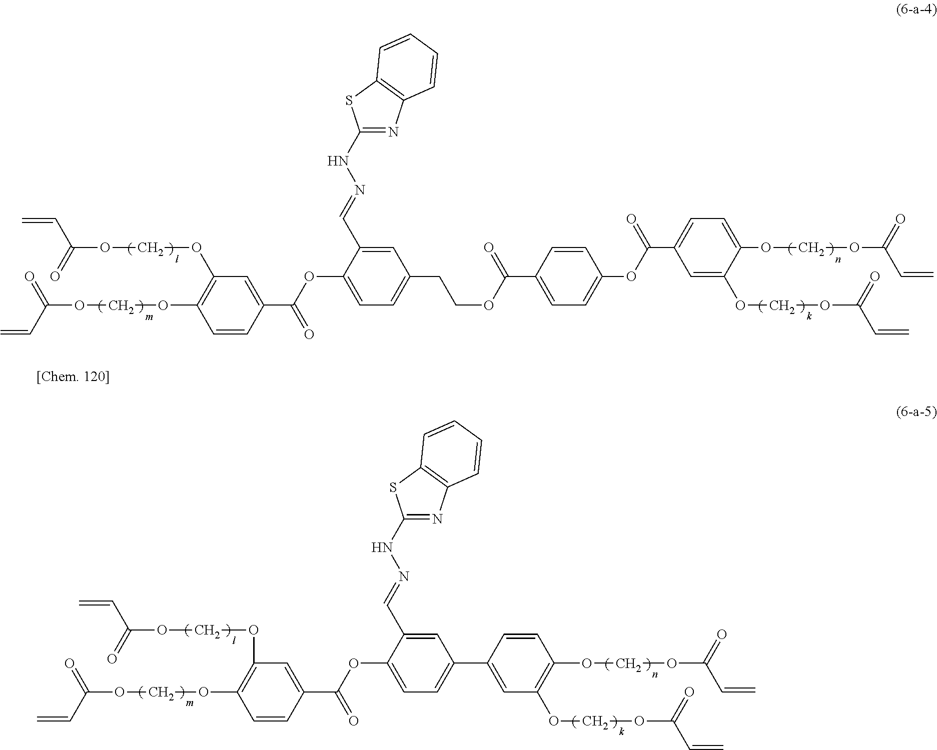

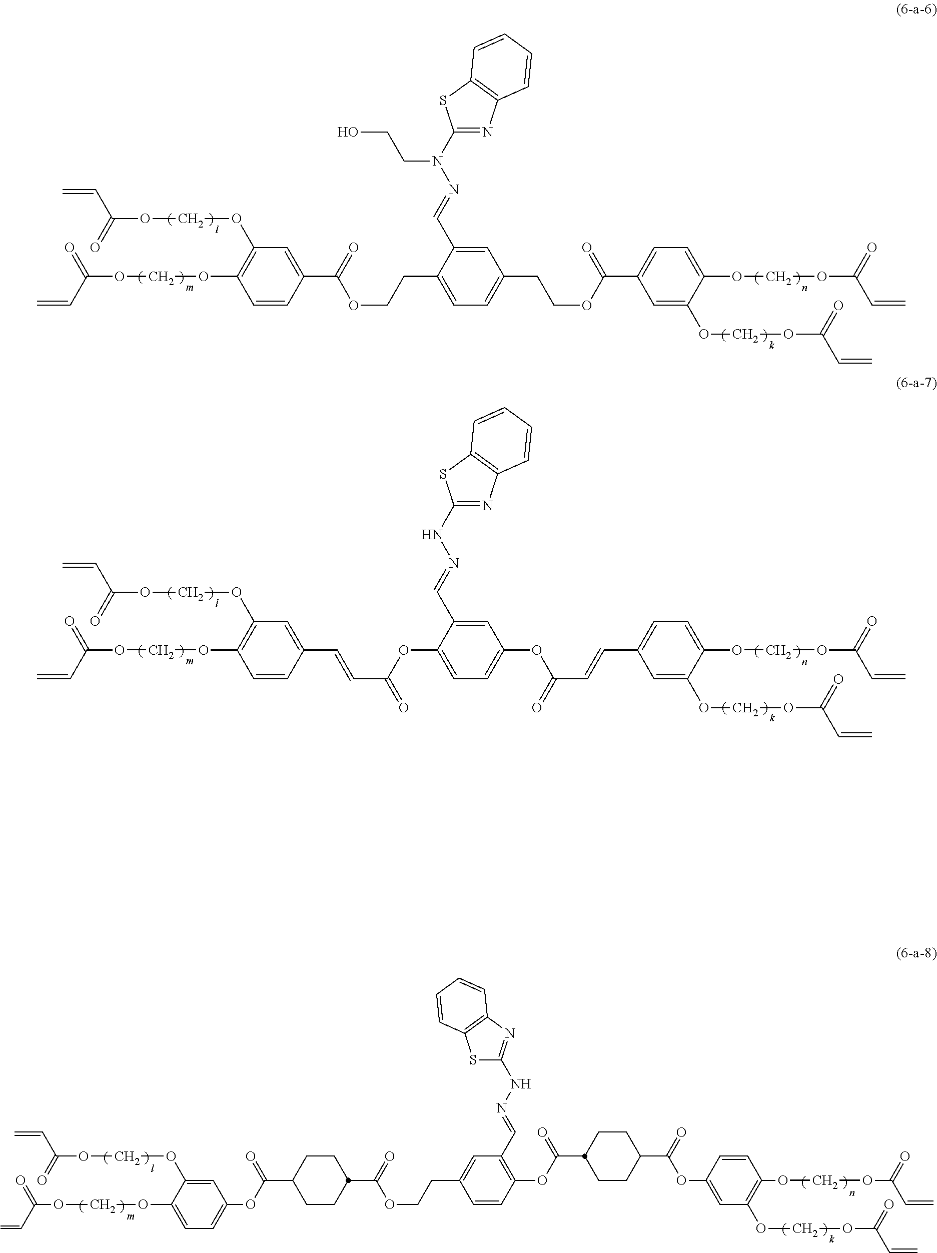

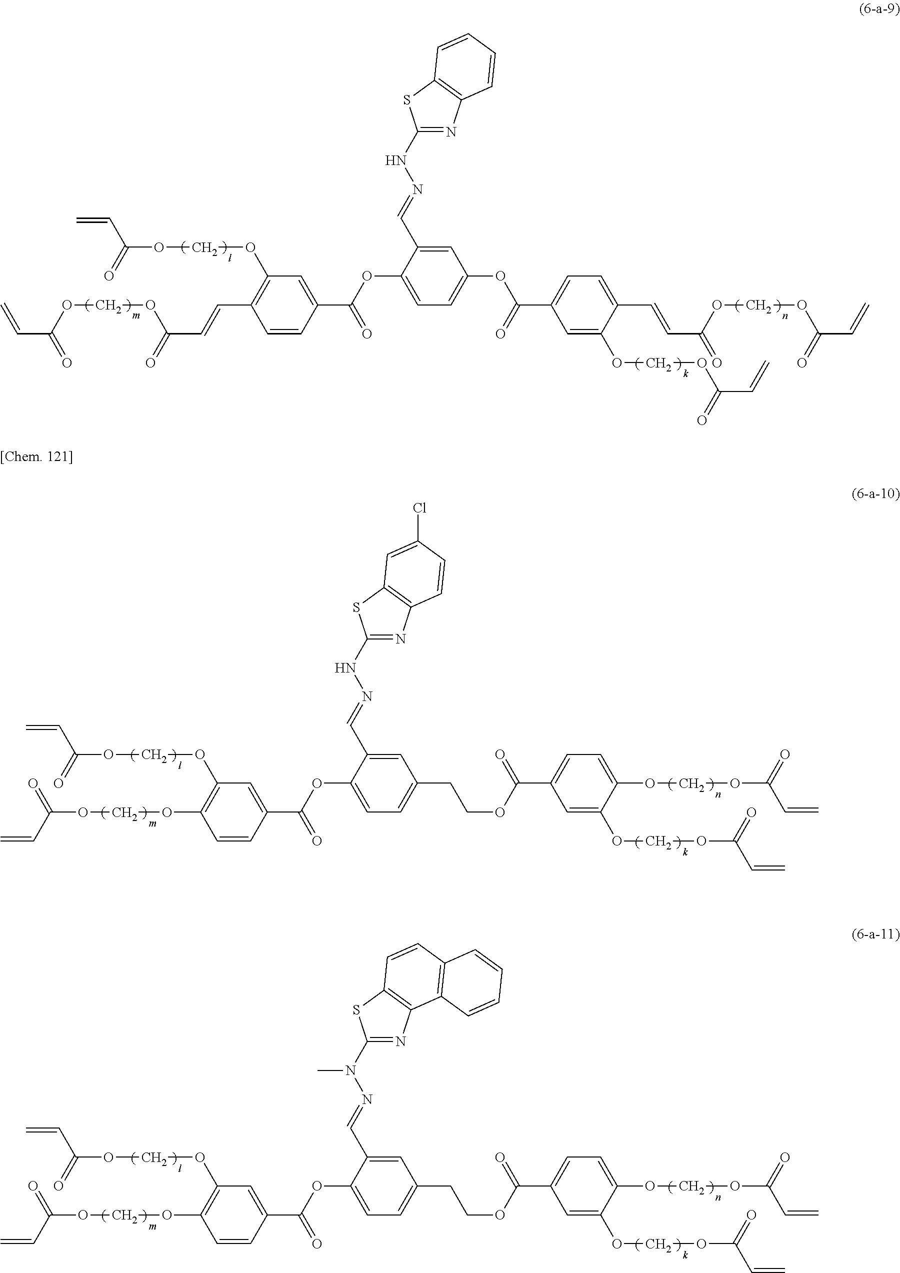

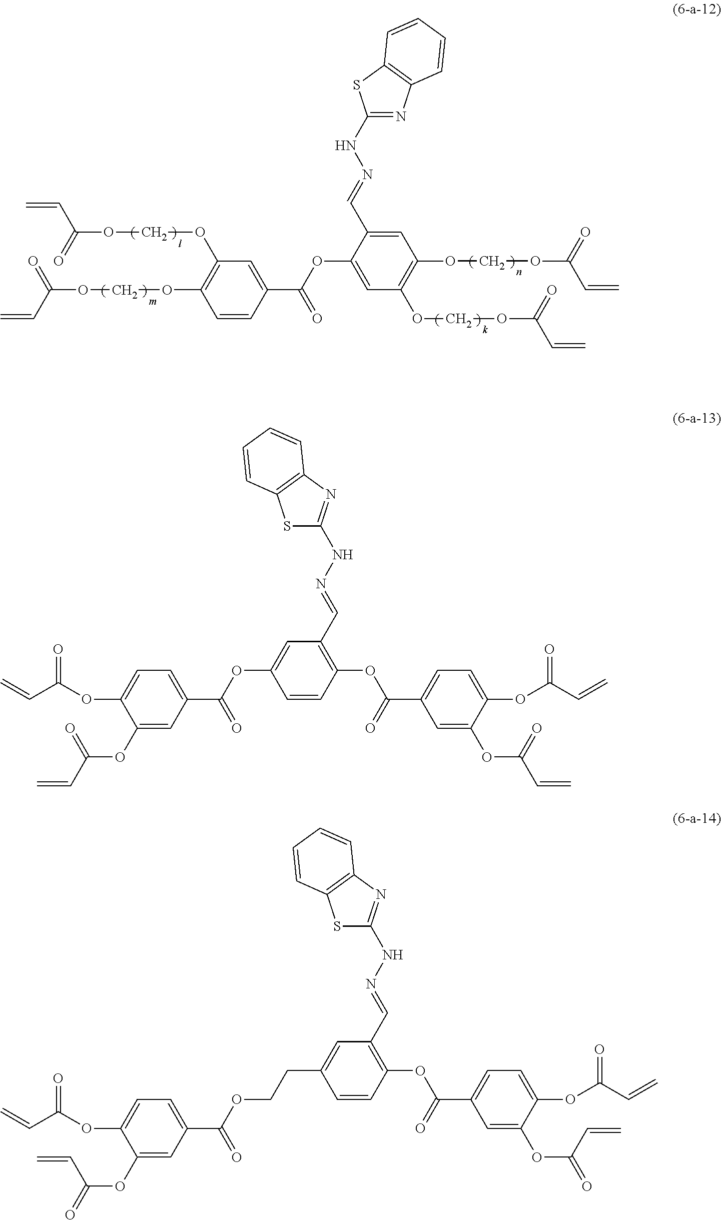

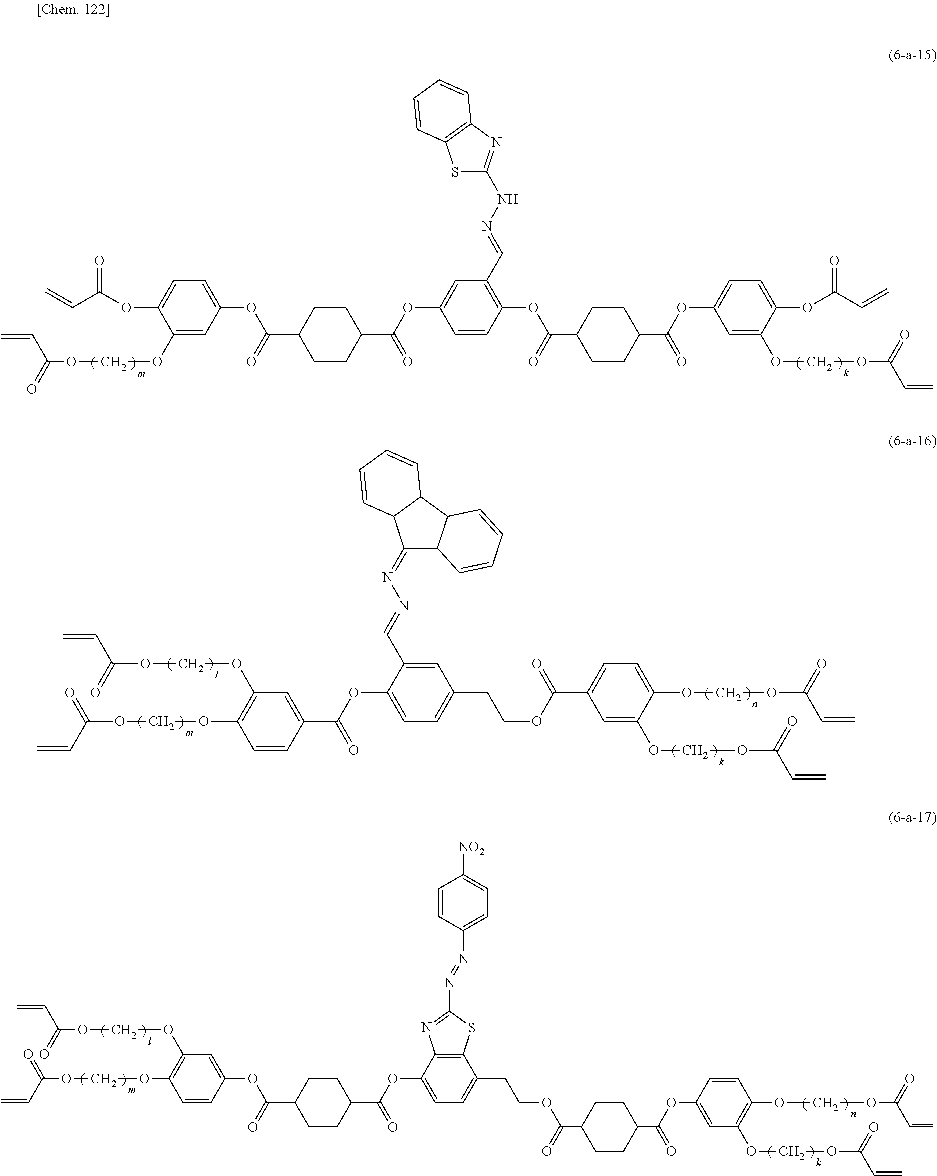

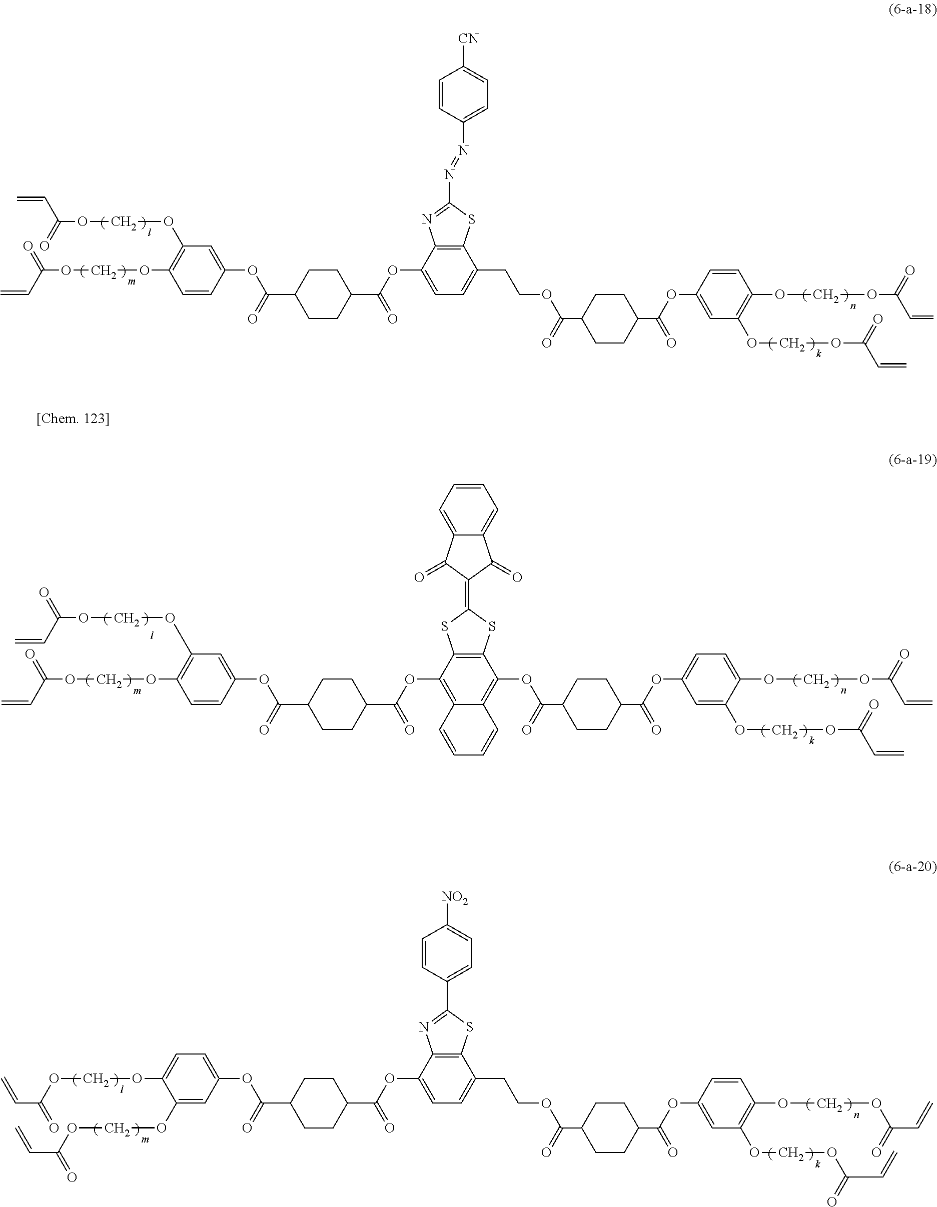

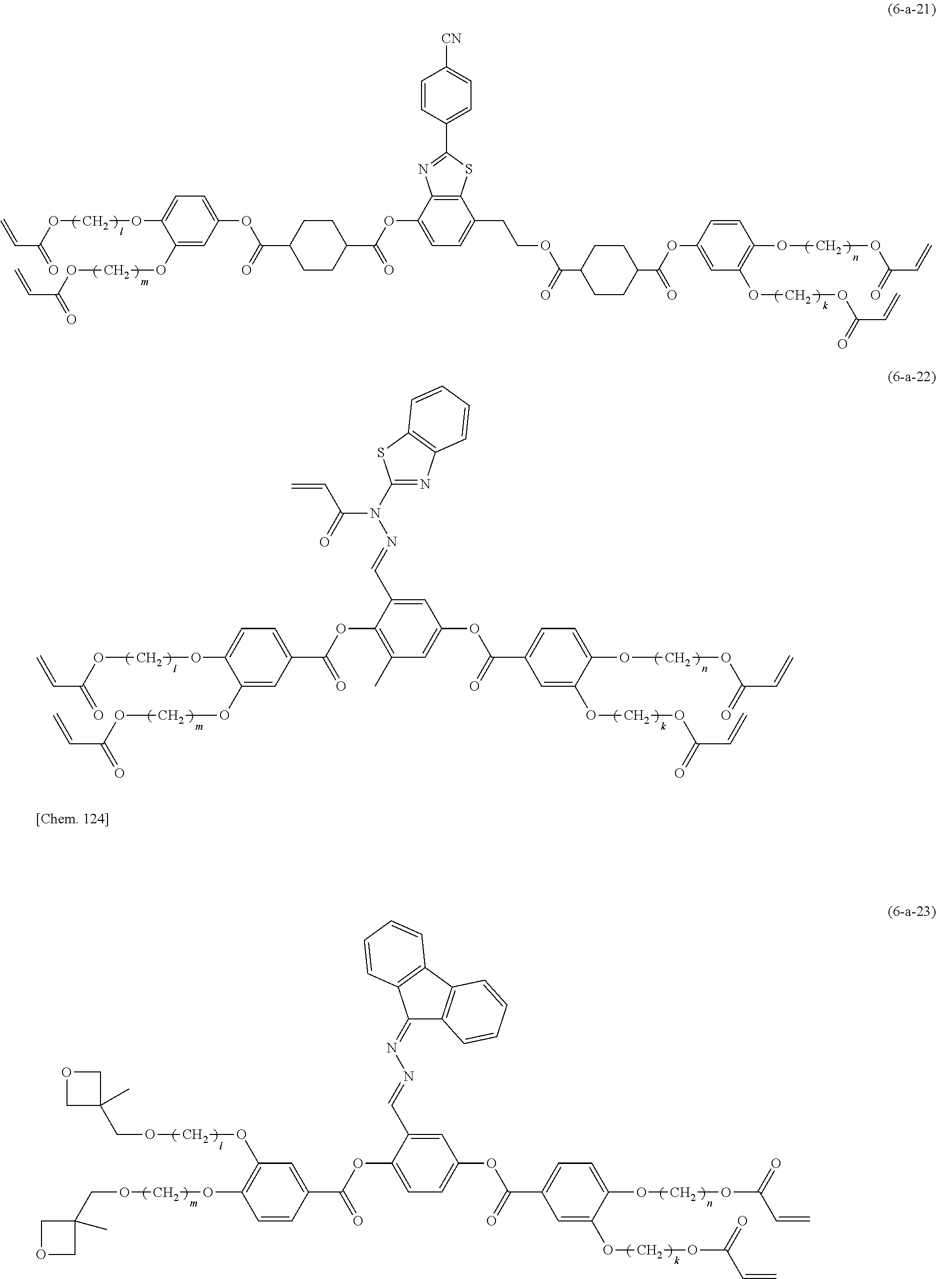

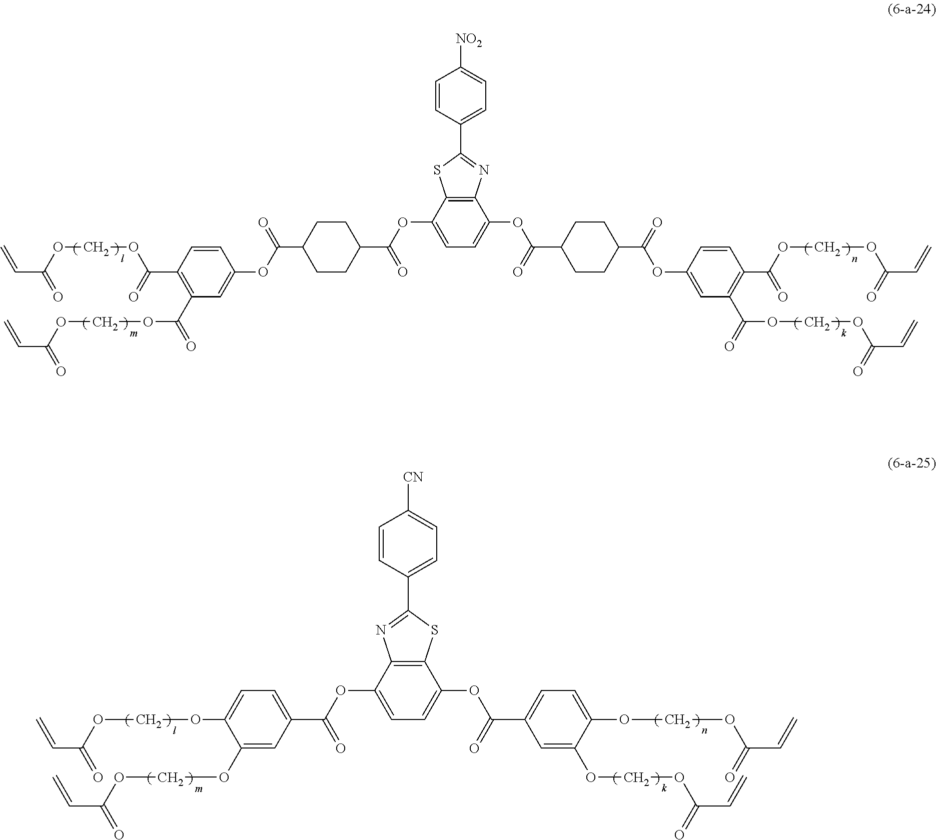

(wherein k, l, m, and n each independently represent the integer of 1 to 10). These liquid crystalline compounds may be used alone or as a mixture of two or more.

Specifically, the compound represented by general formula (7) is preferably compounds represented by formula (7-a-1) to formula (7-a-26) below.

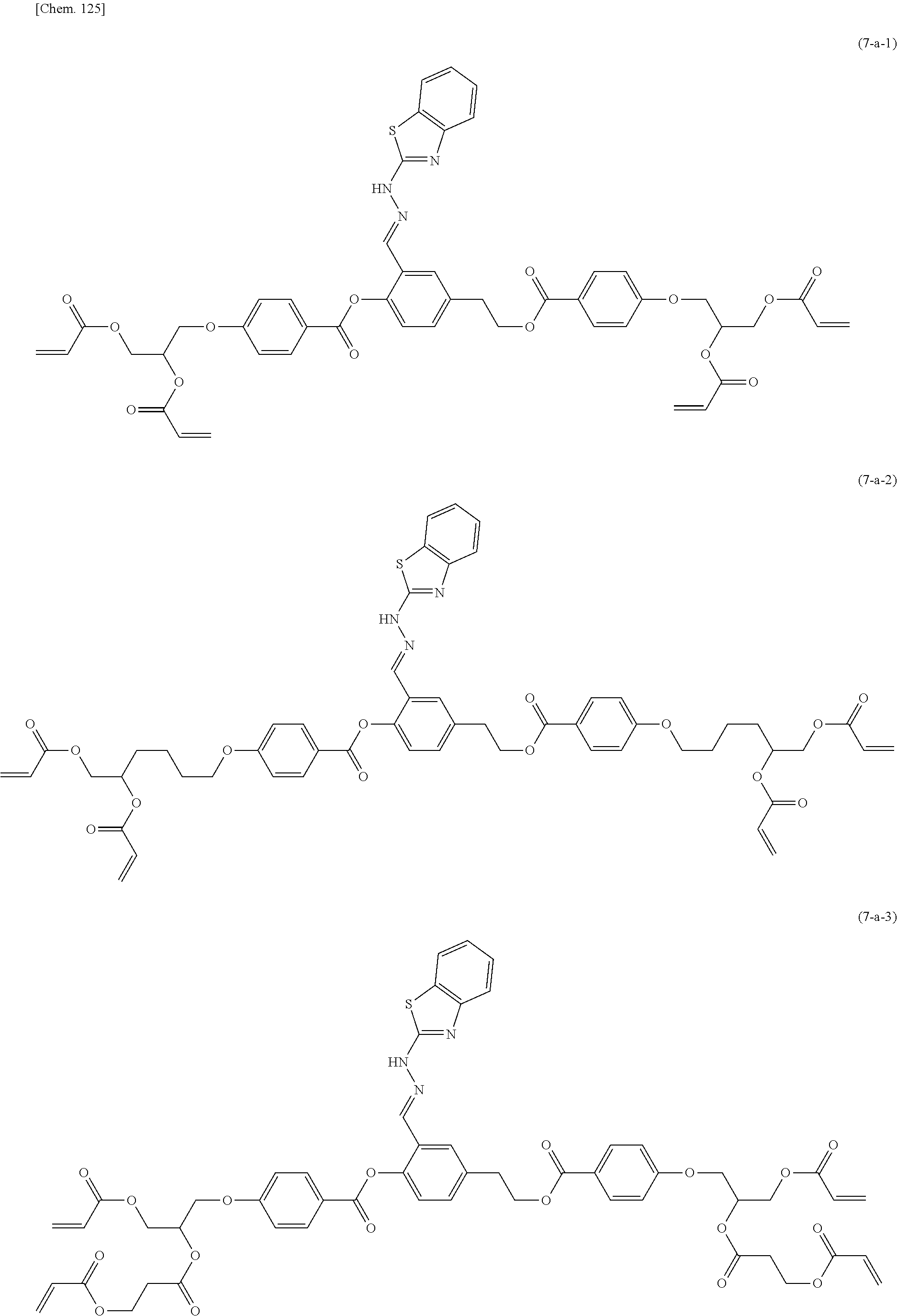

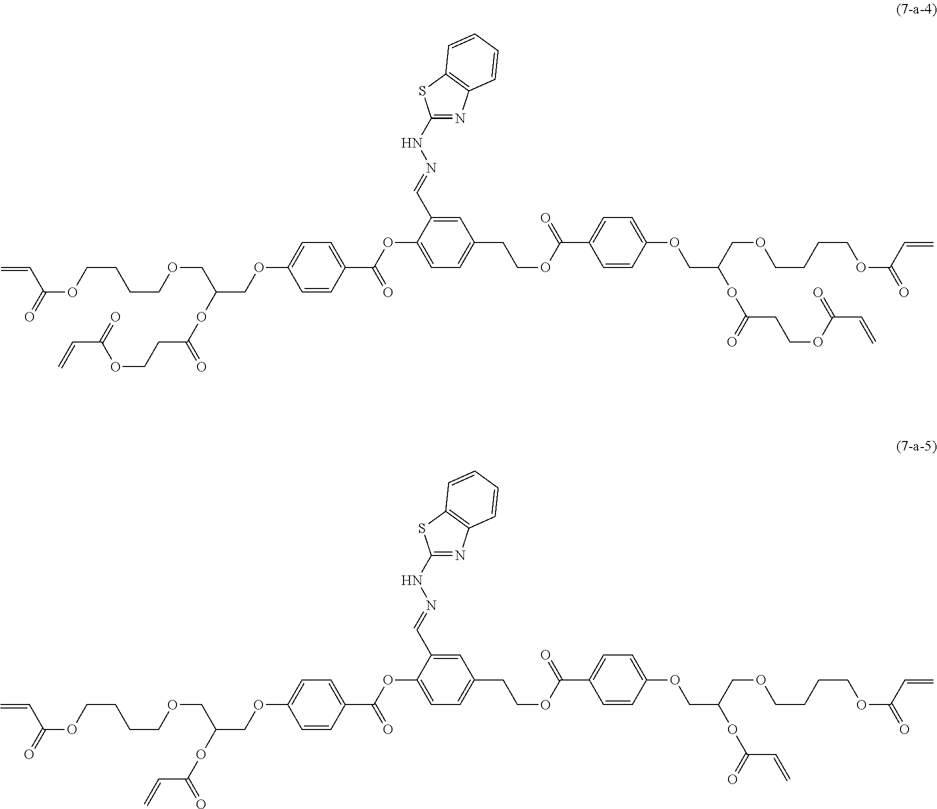

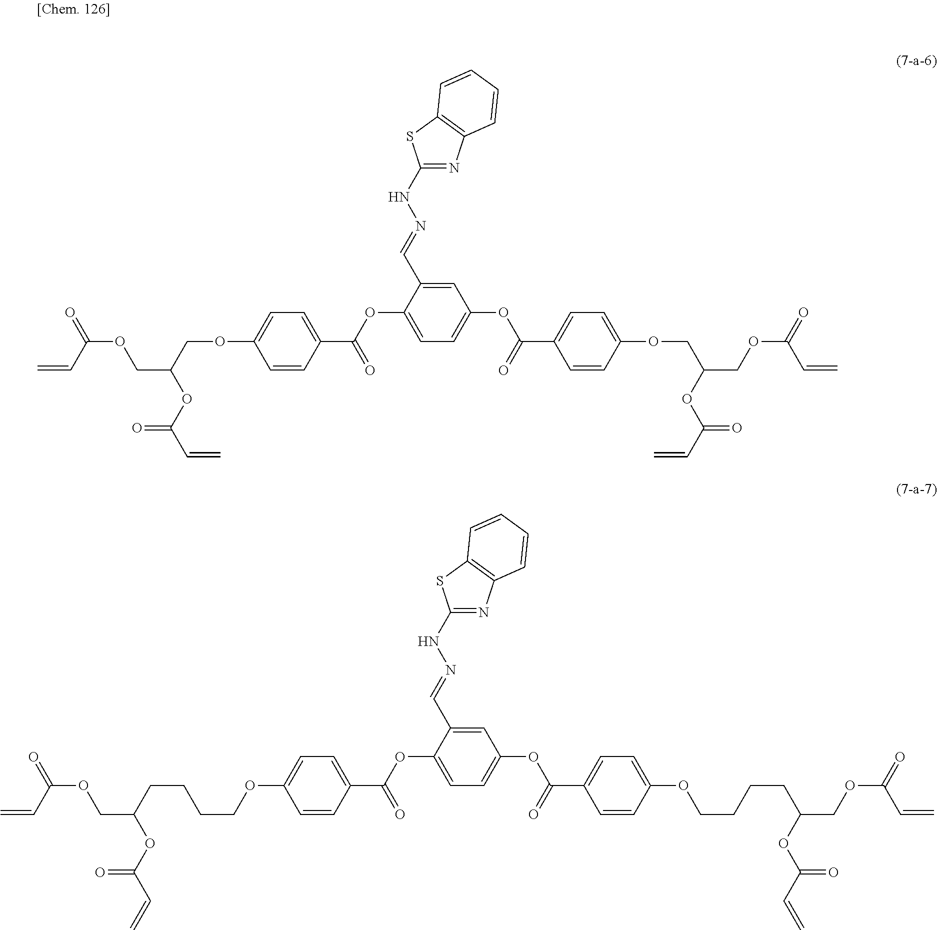

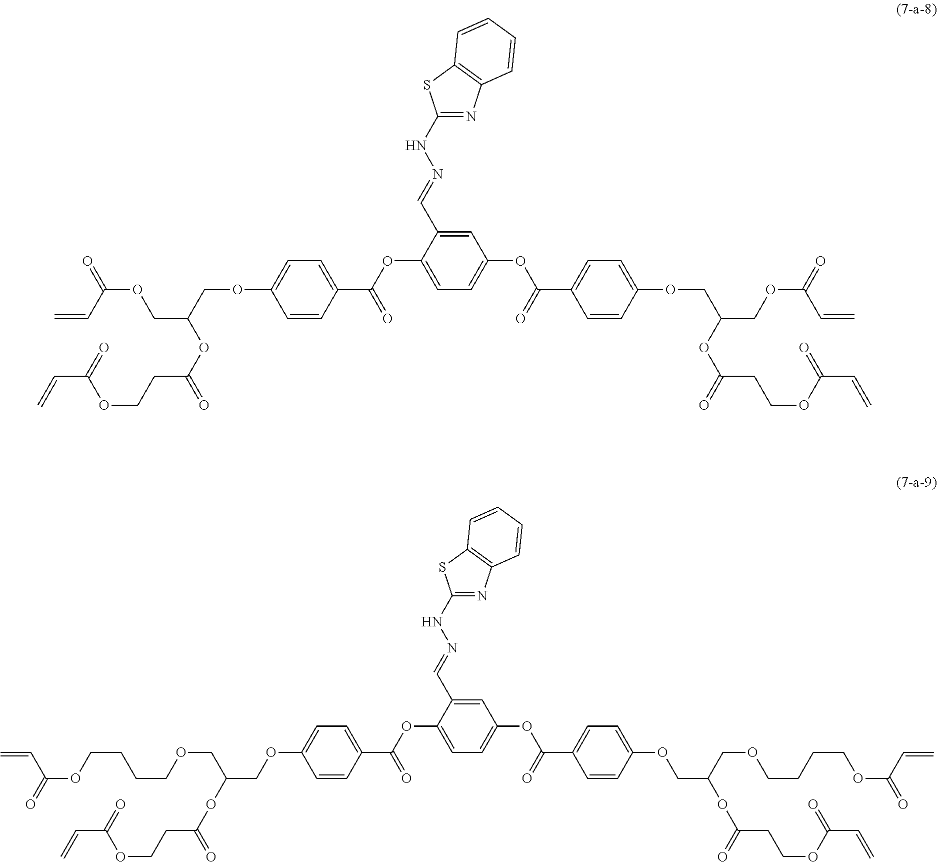

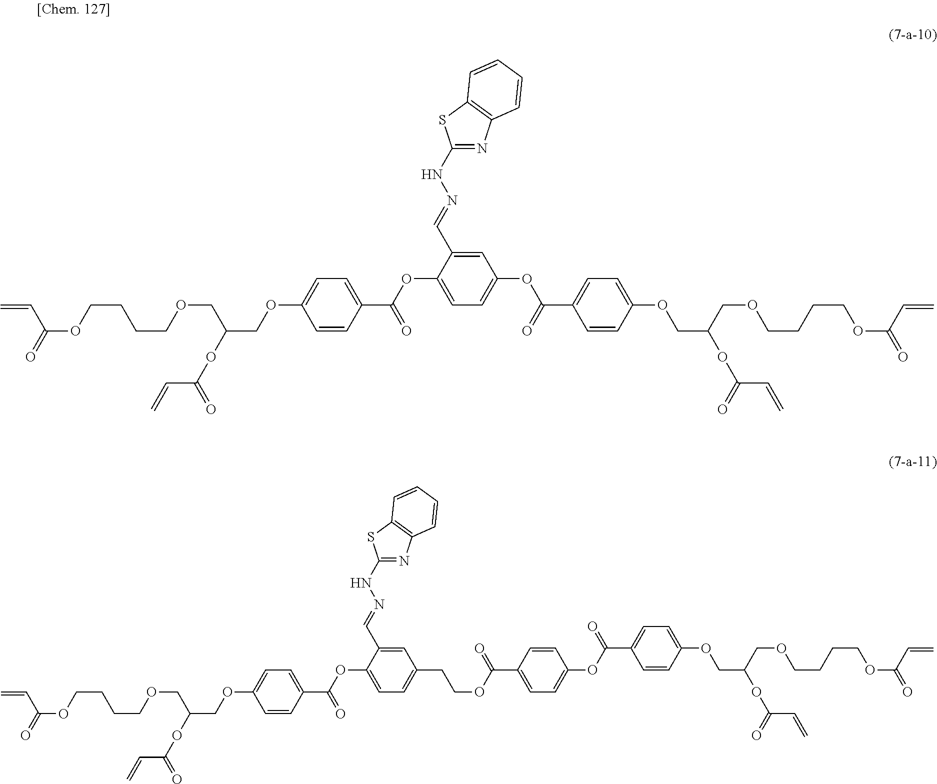

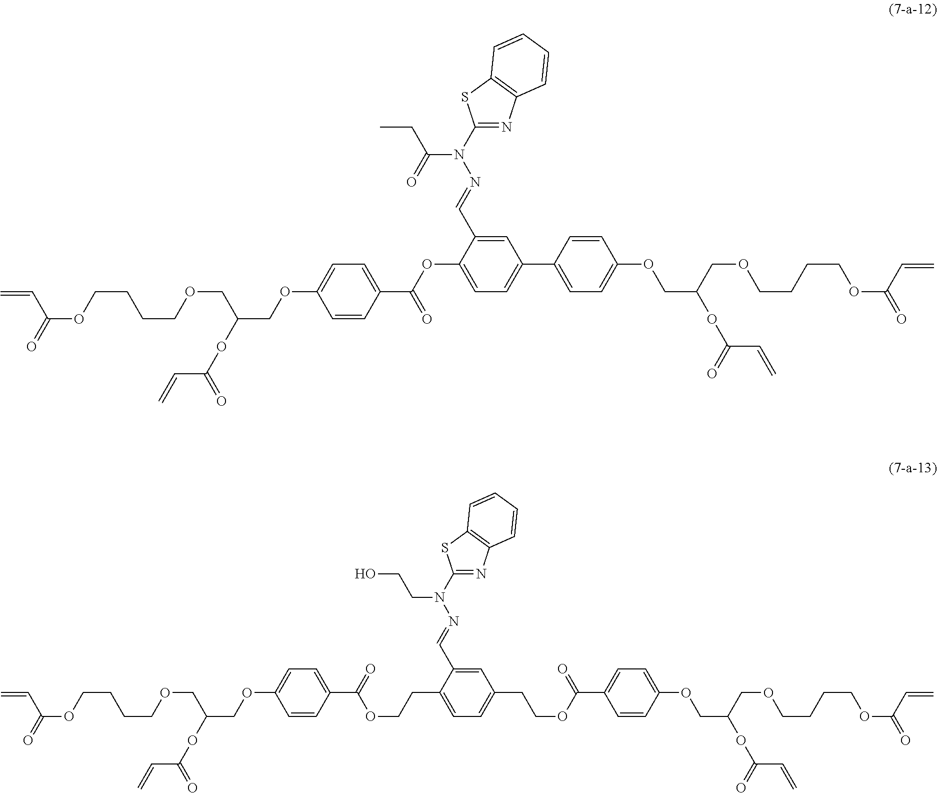

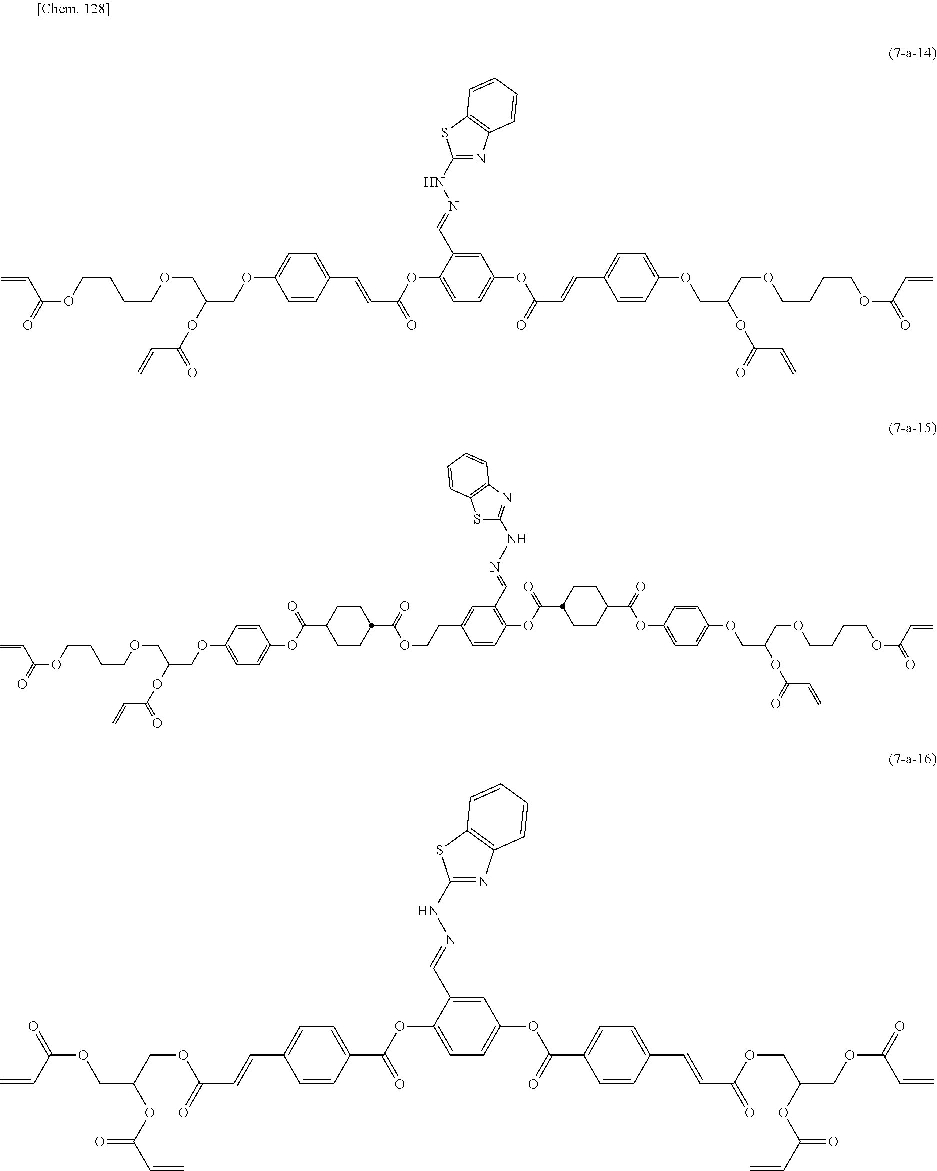

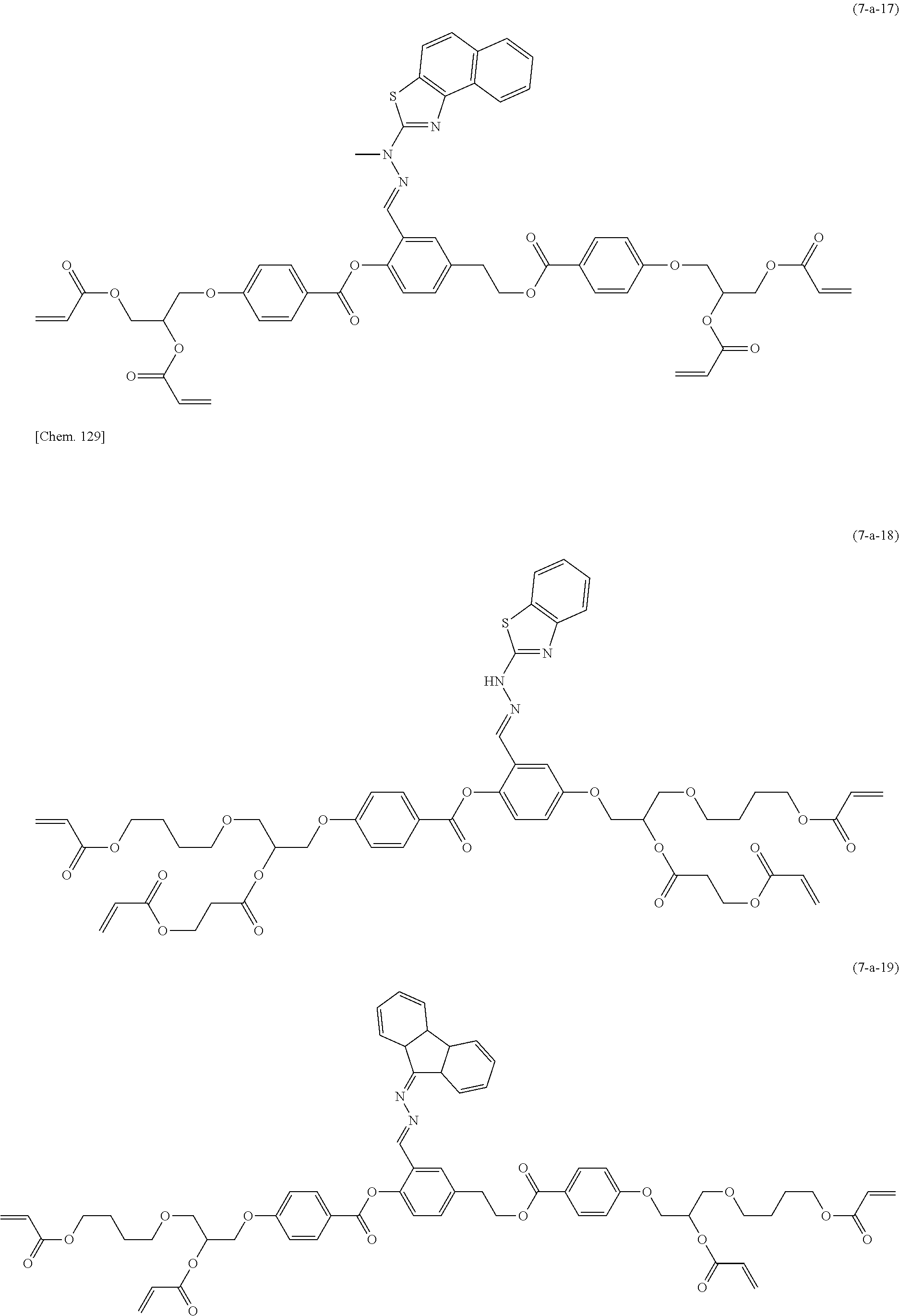

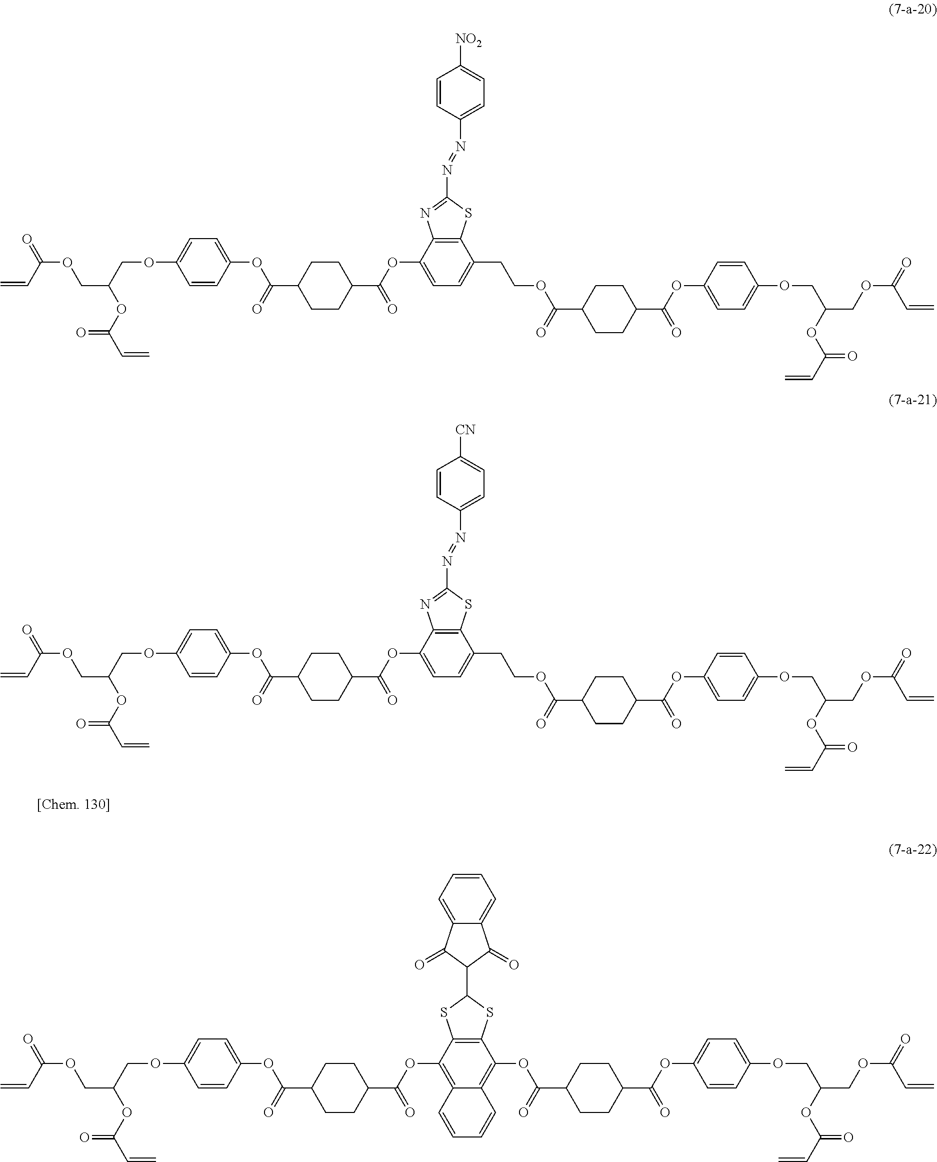

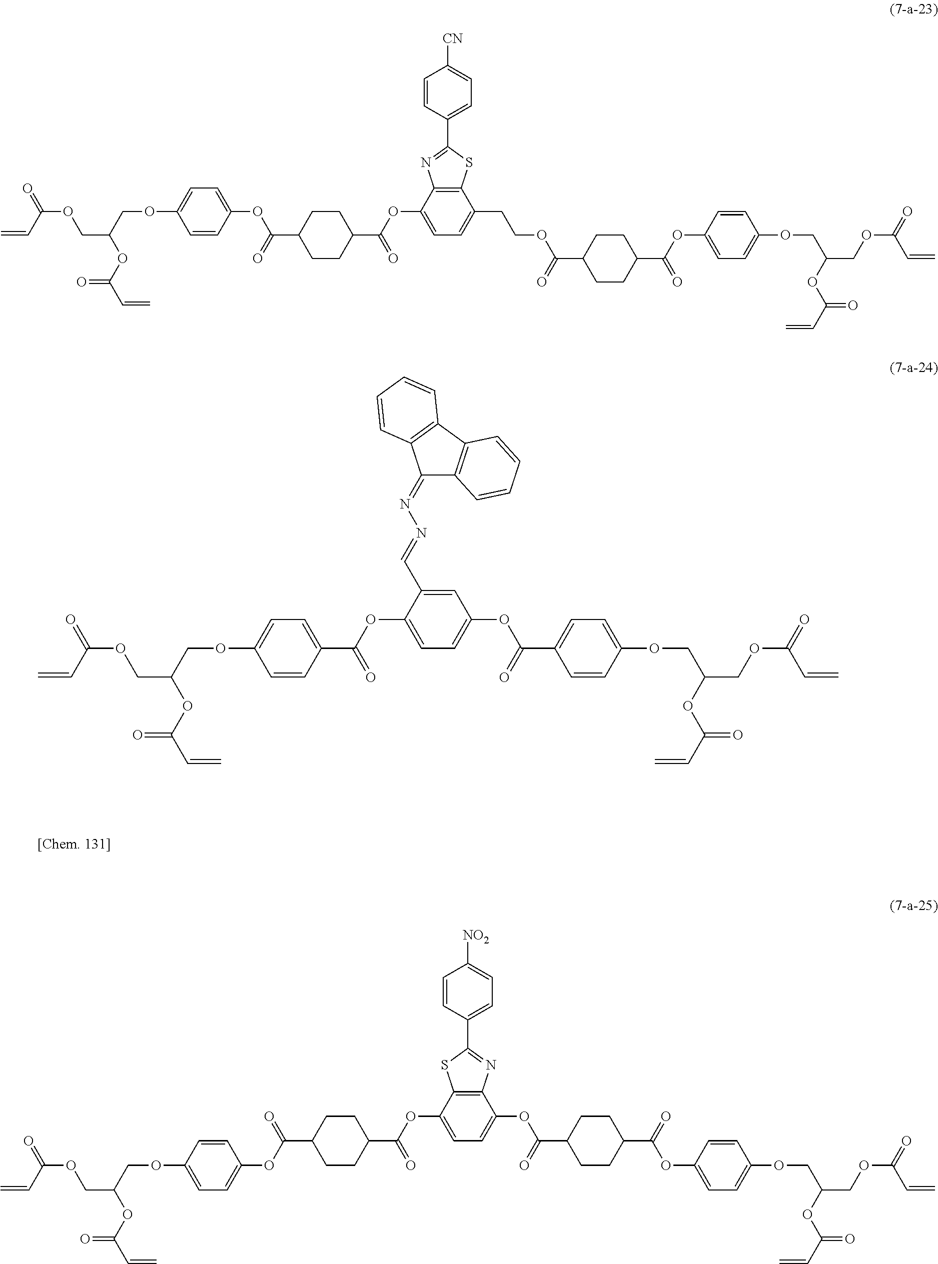

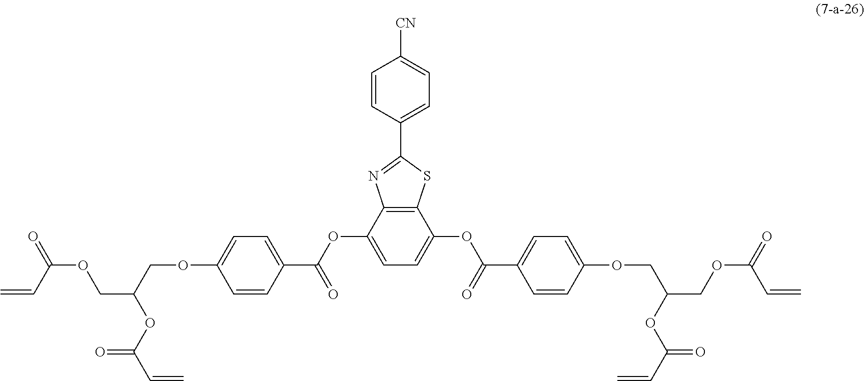

These liquid crystalline compounds may be used alone or as a mixture of two or more.

### (Second Retardation Layer)

The second retardation layer is an optical film that satisfies nx≅ny<nz (where nz represents a refractive index in the thickness direction; nx represents an in-plane refractive index in an in-plane direction in which the in-plane refractive index is maximum; and ny represents an in-plane refractive index in an in-plane direction orthogonal to the direction for nx). The second retardation layer is formed from a polymerizable composition that uses at least one of the compounds represented by general formula (1) to general formula (7) and satisfying (formula 1) described above and/or uses at least one compound B selected from those represented by general formula (1-b) and/or general formula (2-b) and satisfying (formula 2) above. In terms of cost, the second retardation layer is preferably formed from a polymerizable composition that uses only at least one compound B selected from those represented by general formula (1-b) and/or general formula (2-b) and satisfying (formula 2).

### (Chiral Compound)

The polymerizable compositions used to produce the first and second retardation films in the present invention may contain a chiral compound for the purpose of obtaining a chiral nematic phase. It is unnecessary for the chiral compound itself to exhibit liquid crystallinity, and the chiral compound may or may not have a polymerizable group. The helical direction of the chiral compound may be appropriately selected according to the application purpose of the polymer.

No particular limitation is imposed on the chiral compound having a polymerizable group. A commonly used chiral compound may be used, but a chiral compound having a large helical twisting power (HTP) is preferred. The polymerizable group is preferably a vinyl group, a vinyloxy group, an allyl group, an allyloxy group, an acryloyloxy group, a methacryloyloxy group, a glycidyl group, or an oxetanyl group and is particularly preferably an acryloyloxy group, a glycidyl group, or an oxetanyl group.

The amount of the chiral compound added must be appropriately controlled according to the helical twisting power of the compound. The amount of the chiral compound contained is preferably 0.1 to 5.0% by mass, more preferably 0.2 to 3.0% by mass, and particularly preferably 0.5 to 2.0% by mass with respect to the total mass of the chiral compound and a liquid crystalline compound having a polymerizable group.

Specific examples of the chiral compound include compounds represented by general formula (10-1) to formula (10-4) below, but the chiral compound is not limited to the compounds represented by the general formulas below.

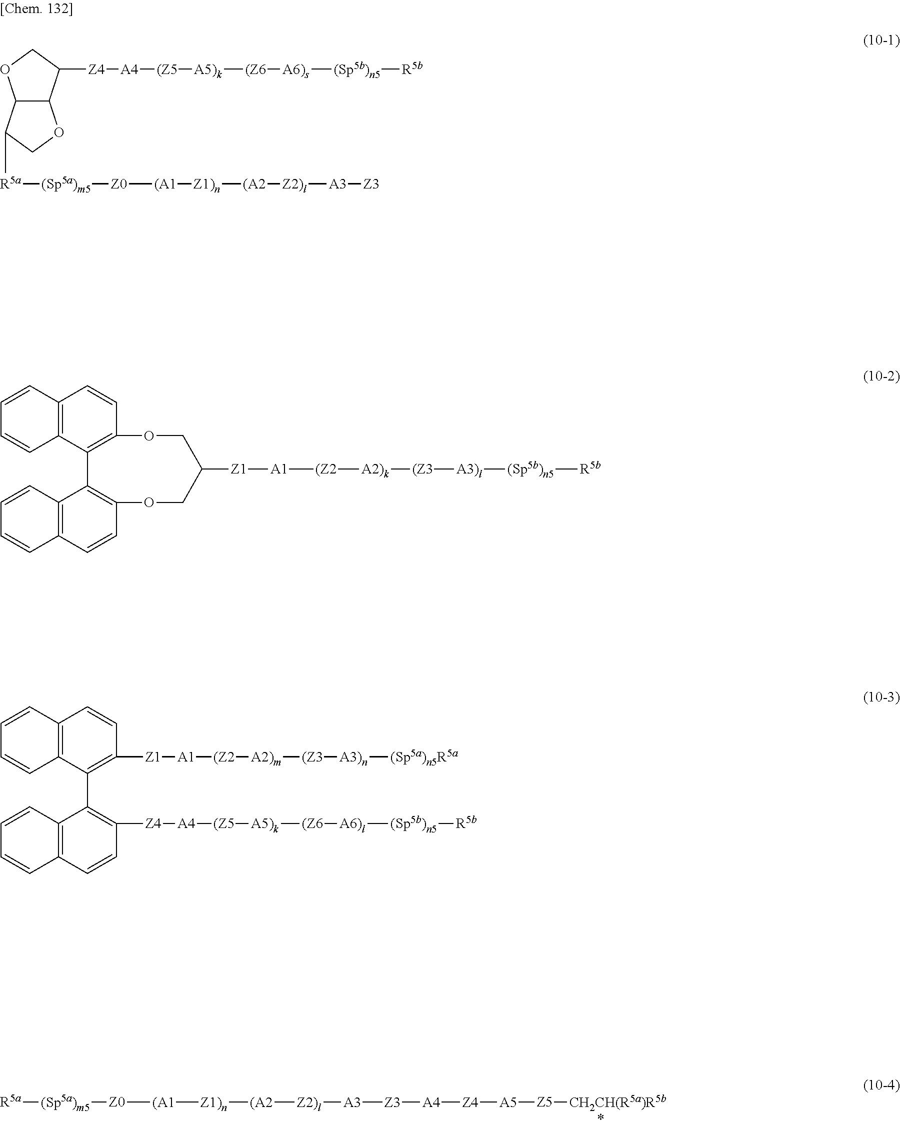

In the above formulas, Sp^{5a} and Sp^{Sb} each independently represent an alkylene group having 0 to 18 carbon atoms, and the alkylene group may be substituted by at least one halogen atom, a CN group, or an alkyl group having 1 to 8 carbon atoms and having a polymerizable functional group. One CH₂ group or two or more nonadjacent CH₂ groups in the alkyl group may be each independently replaced by —O—, —S—, —NH—, —N(CH₃)—, —CO—, —COO—, —OCO—, —OCOO—, —SCO—, —COS—, or —C≡C—, provided that no oxygen atoms are mutually bonded.

A1, A2, A3, A4, A5, and A6 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group. n, l, and k each independently represent 0 or 1, provided that 0≤n+l+k≤3.

m5 represents 0 or 1.

Z0, Z1, Z2, Z3, Z4, Z5, and Z6 each independently represent —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, —CONH—, —NHCO—, an alkyl group having 2 to 10 carbon atoms and optionally having a halogen atom, or a single bond.

R^{5a} and R^{5b} each represent a hydrogen atom, a halogen atom, a cyano group, or an alkyl group having 1 to 18 carbon atoms. The alkyl group may be substituted by at least one halogen atom or CN. One CH₂ group or two or more nonadjacent CH₂ groups in the alkyl group may be each independently replaced by —O—, —S—, —NH—, —N(CH₃)—, —CO—, —COO—, —OCO—, —OCOO—, —SCO—, —COS—, or —C≡C—, provided that no oxygen atoms are mutually bonded. Alternatively, R^{5a} and R^{5b} each represent general formula (10-a):

[Chem. 133]

—P^{5a} (10-a)

(wherein P^{5a} represents a polymerizable group).

P^{5a} represents a substituent selected from polymerizable groups represented by formula (P-1) to formula (P-20) below.

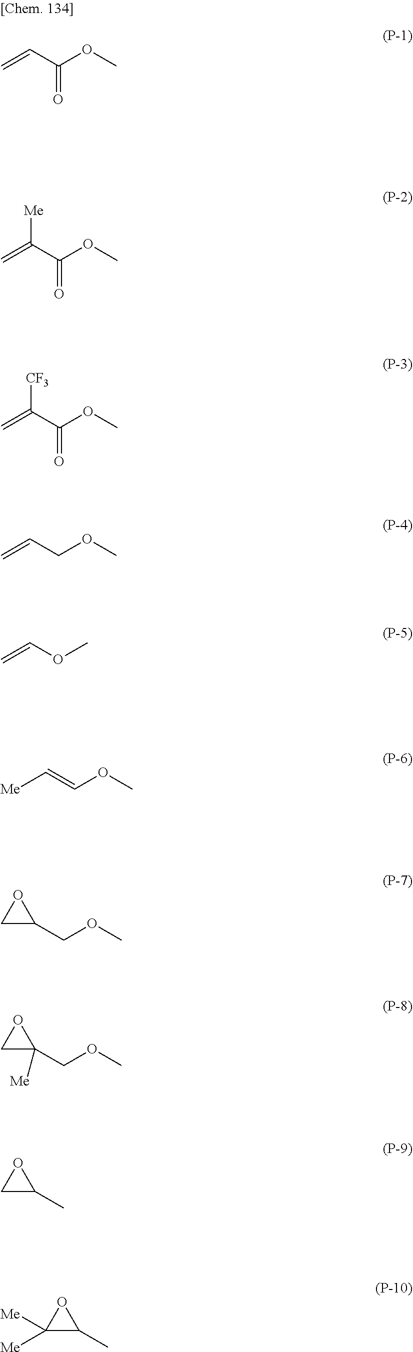

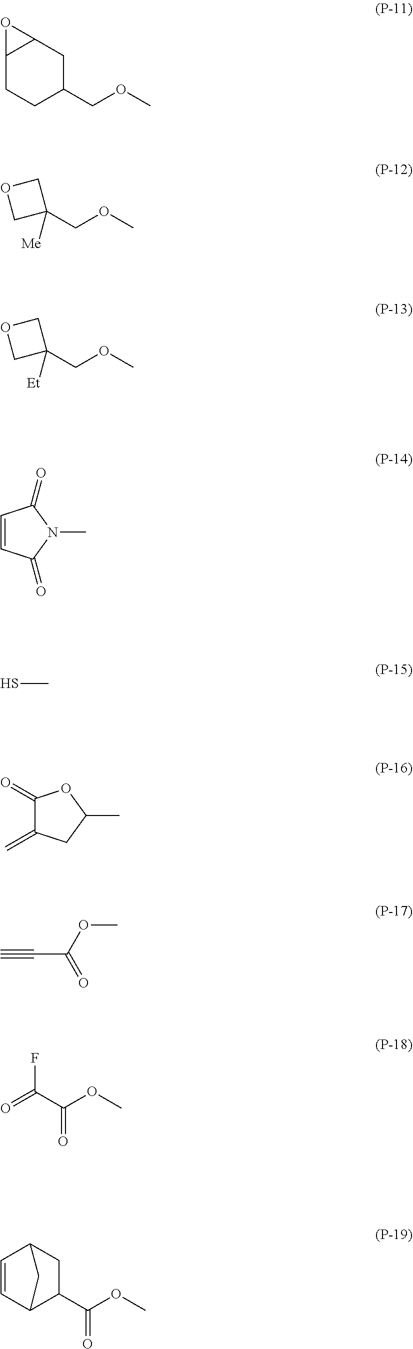

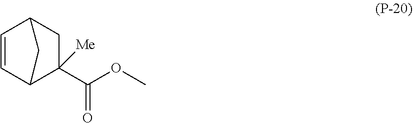

Other specific examples of the chiral compound include compounds represented by general formula (10-5) to formula (10-35) below.

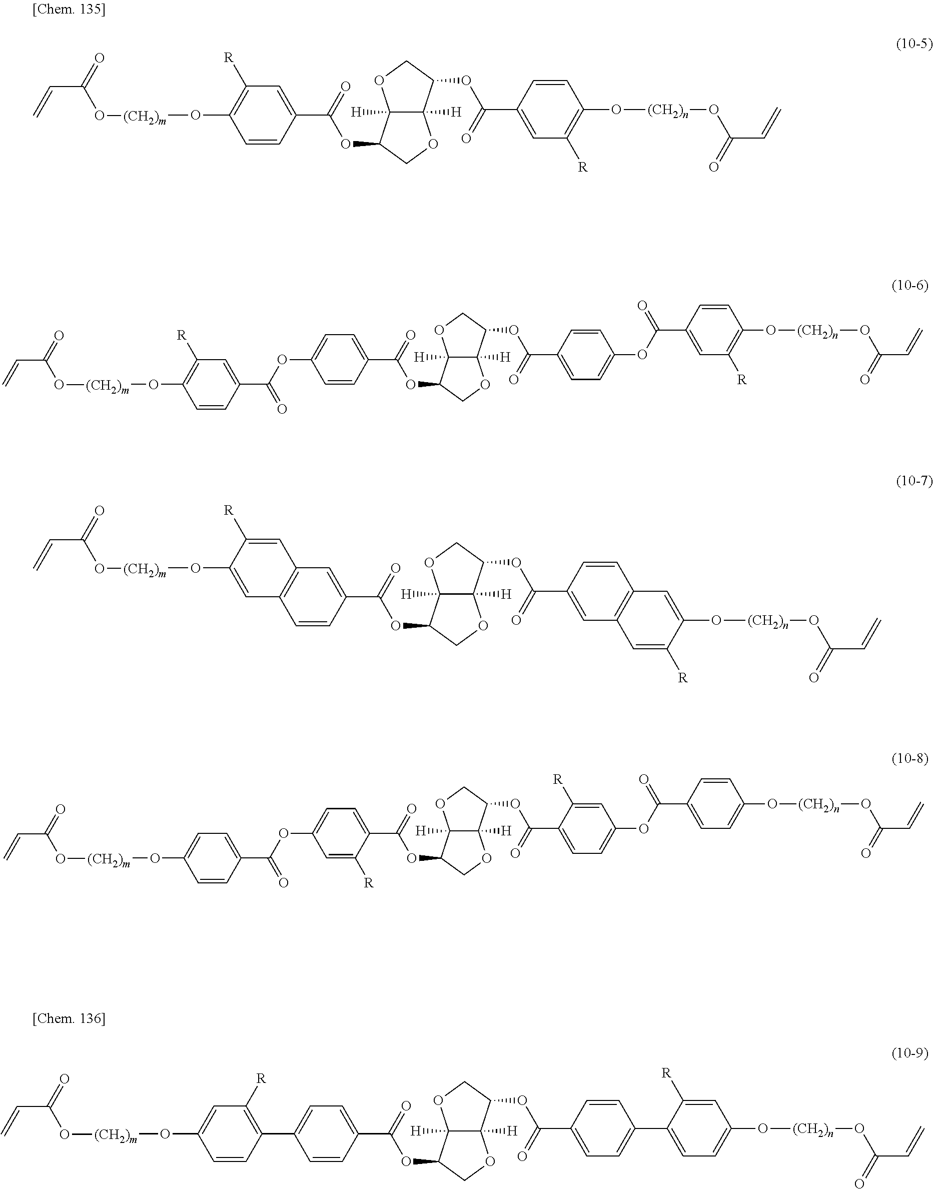

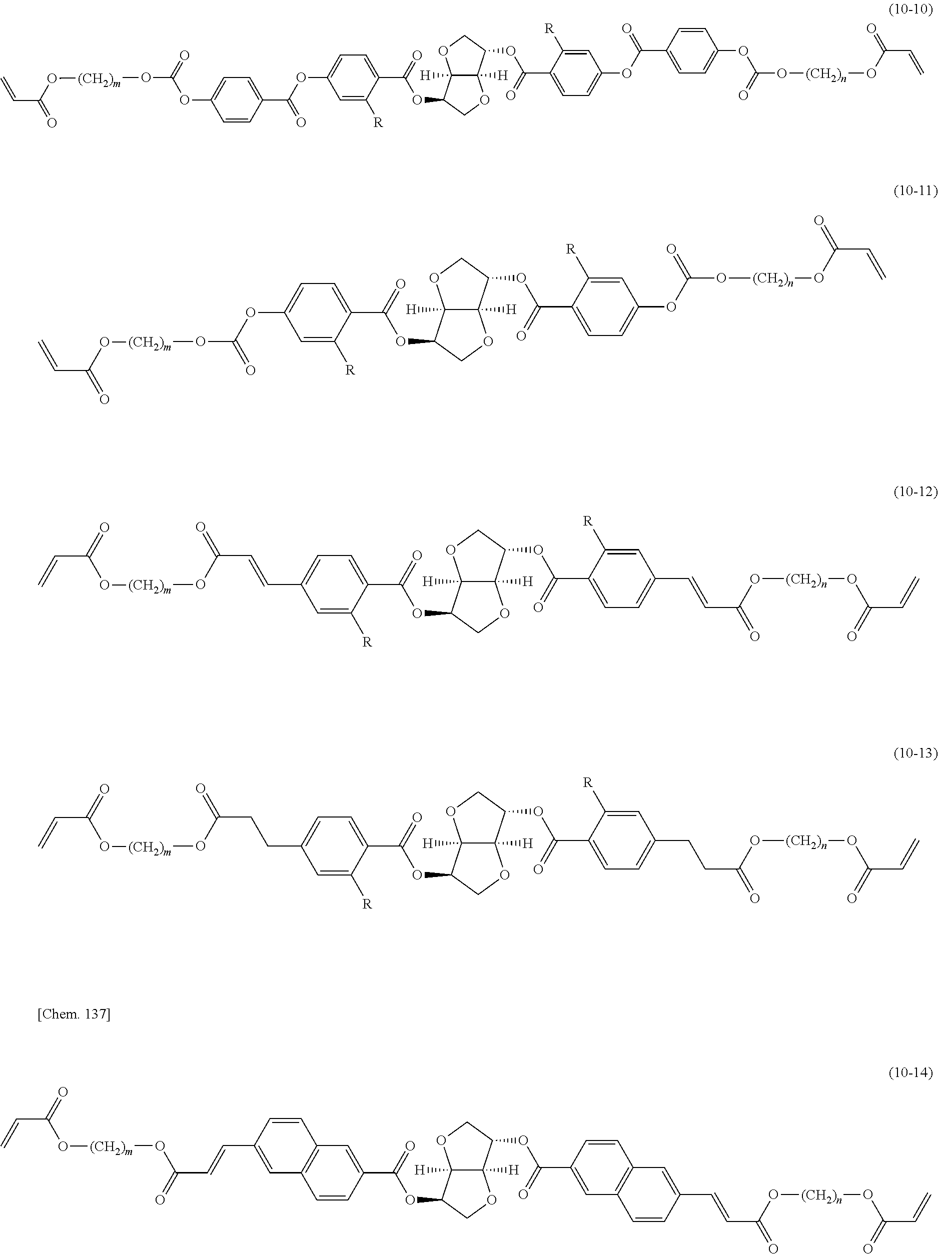

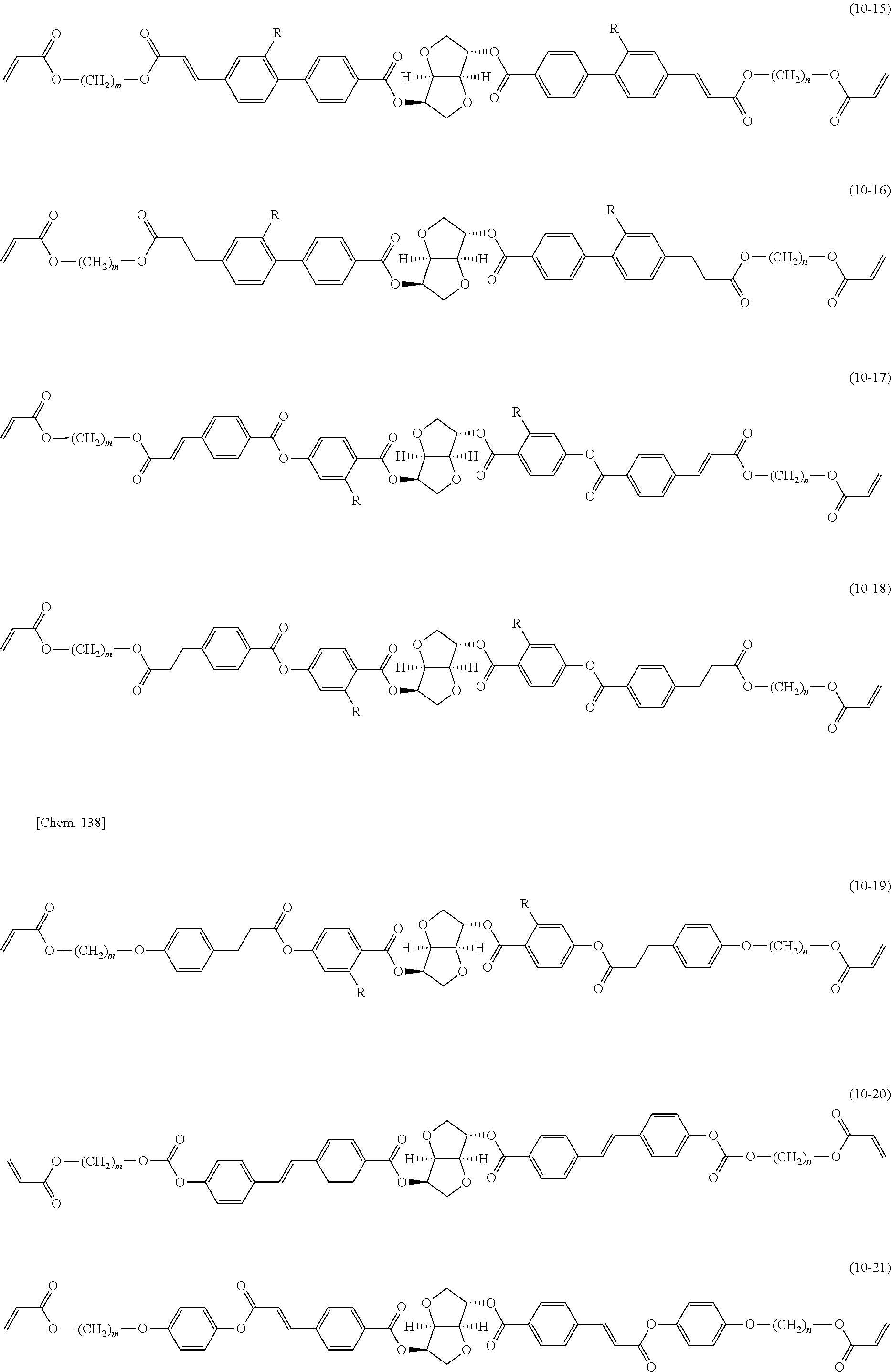

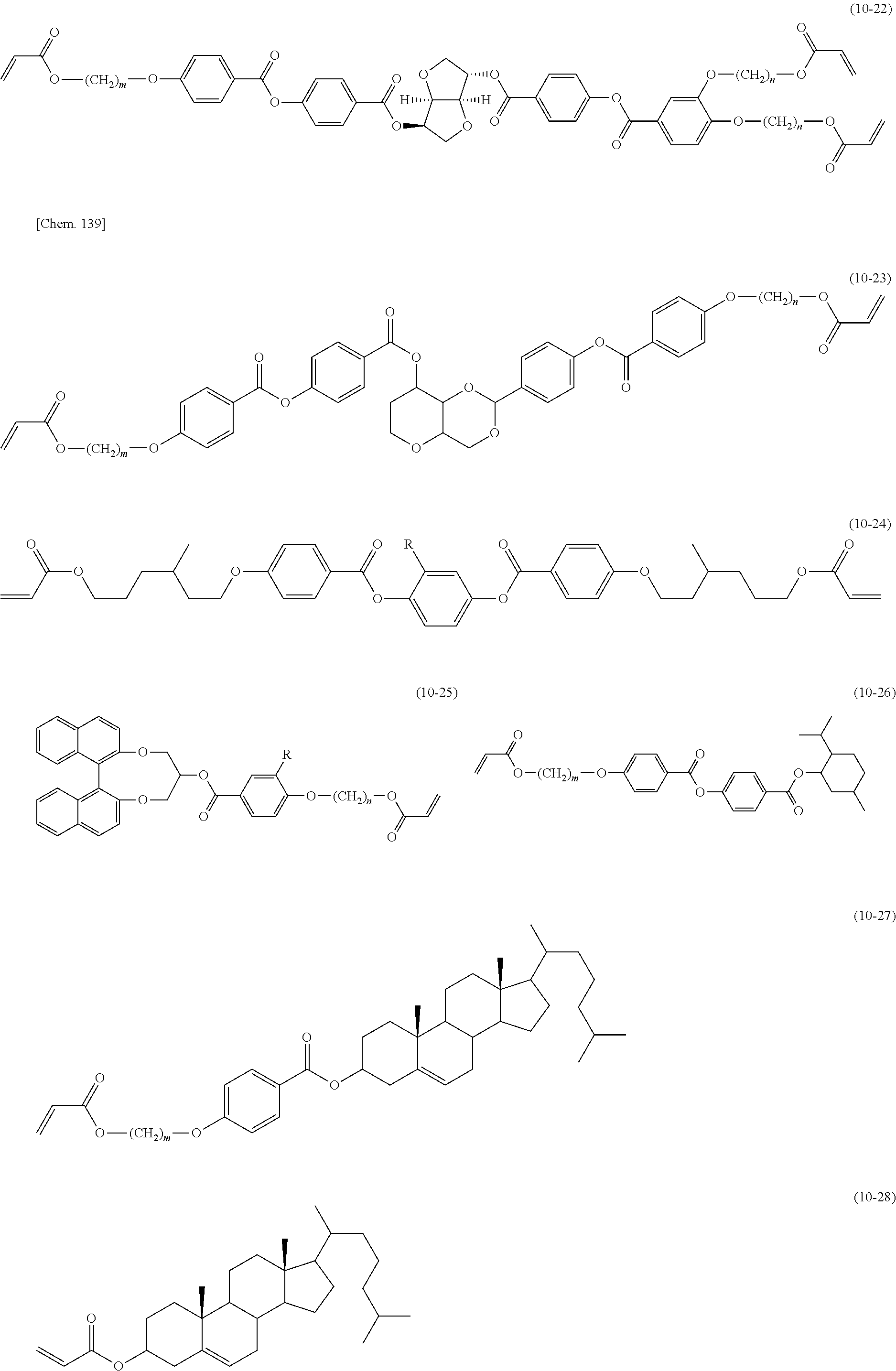

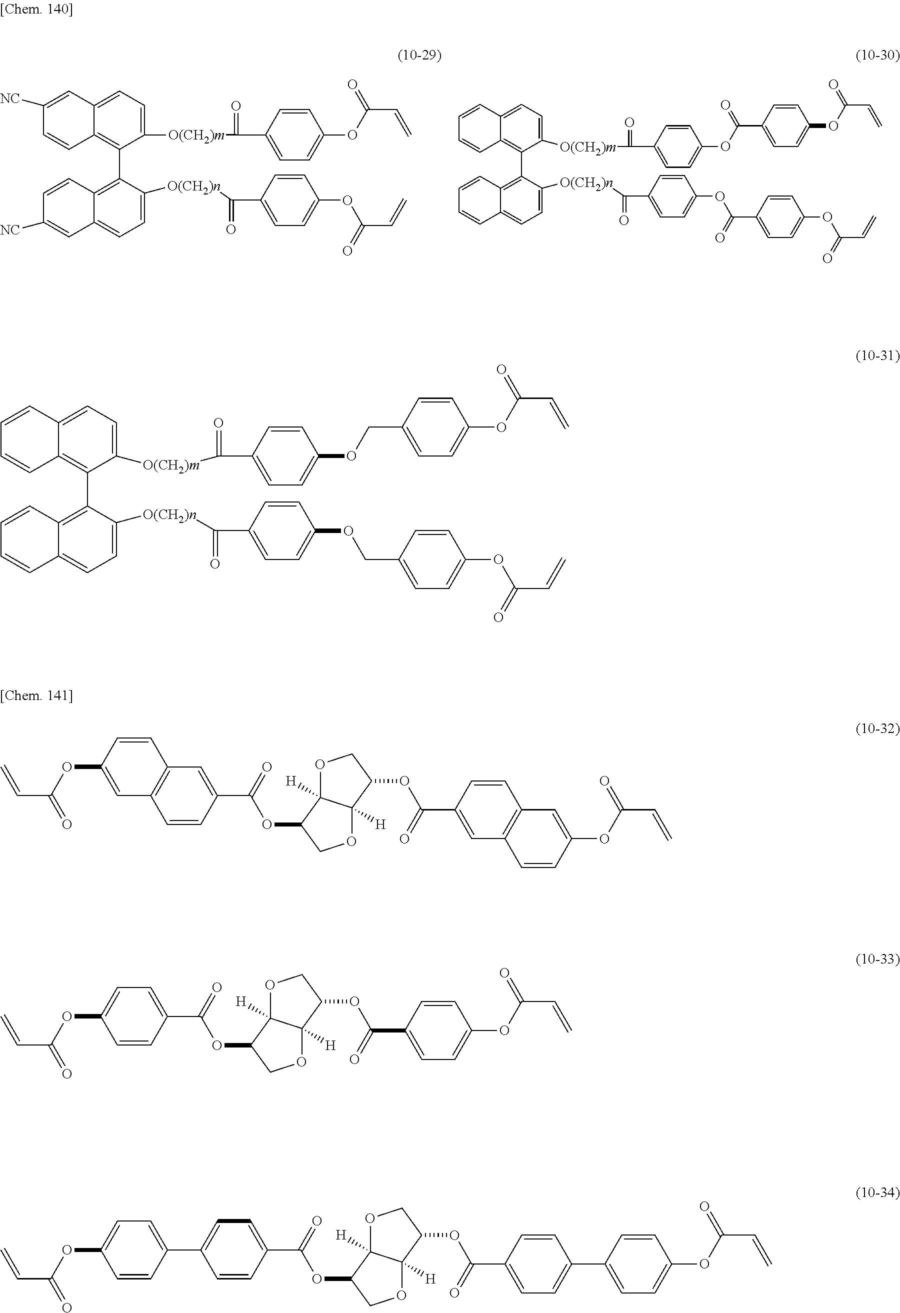

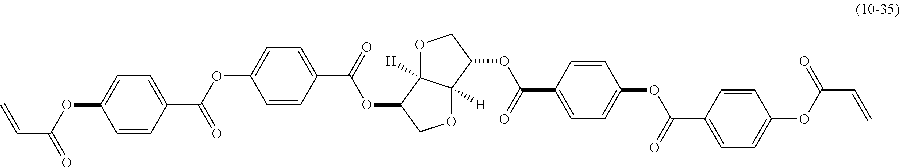

In the above formulas, m and n each independently represent an integer of 1 to 10, and R represents a hydrogen atom, an alkyl group having 1 to 10 carbon atoms, or a fluorine atom. When a plurality of Rs are present, they may be the same or different.

Specific examples of the chiral compound having no polymerizable group include: cholesterol pelargonate and cholesterol stearate each of which has a cholesteryl group as a chiral group; “CB-15” and “C-15” manufactured by BDH, “S-1011” and “S-1082” manufactured by Merck, and “CM-19,” “CM-20,” and “CM” manufactured by Chisso Corporation each of which has a 2-methylbutyl group as a chiral group; and “S-811” manufactured by Merck and “CM-21” and “CM-22” manufactured by Chisso Corporation each of which has a 1-methylheptyl group as a chiral group.

When the chiral compound is added, the amount of the chiral compound added is controlled such that a value obtained by dividing the thickness (d) of the polymer to be obtained by the helix pitch (P) of the polymer, i.e., (d/P), is in the range of preferably 0.1 to 100 and more preferably 0.1 to 20, but this depends on the intended purpose of the polymer of the polymerizable composition.

### (Polymerization Initiator)

The polymerizable compositions used to produce the first and second retardation films in the present invention may optionally contain an initiator. The polymerization initiator used for the polymerizable compositions is used to polymerize the polymerizable compositions used in the present invention. No particular limitation is imposed on the photopolymerization initiator used when each polymerizable composition is polymerized by irradiation with light. A commonly used photopolymerization initiator may be used so long as the aligned state of each polymerizable compound in each polymerizable composition used is not inhibited.

Examples of the photopolymerization initiator include: 1-hydroxycyclohexyl phenyl ketone “IRGACURE 184”, 1-(4-isopropylphenyl)-2-hydroxy-2-methylpropan-1-one “DAROCUR 1116”, 2-methyl-1-[(methylthio)phenyl]-2-morpholinopropan-1-one “IRGACURE 907”, 2,2-dimethoxy-1,2-diphenylethan-1-one “IRGACURE 651”, 2-benzyl-2-dimethylamino-1-(4-morpholinophenyl)-butanone “IRGACURE 369”, 2-dimethylamino-2-(4-methylbenzyl)-1-(4-morpholino-phenyl)butan-1-one “IRGACURE 379”, 2,2-dimethoxy-1,2-diphenylethan-1-one, bis(2,4,6-trimethylbenzoyl)-diphenylphosphine oxide “LUCIRIN TPO”, 2,4,6-trimethylbenzoyl-phenyl-phosphine oxide “IRGACURE 819”, 1,2-octanedione, 1-[4-(phenylthio)-,2-(O-benzoyloxime)], ethanone “IRGACURE OXE 01”), and 1-[9-ethyl-6-(2-methylbenzoyl)-9H-carbazole-3-yl]-,1-(O-acetyloxime) “IRGACURE OXE 02” (these are manufactured by BASF); a mixture of 2,4-diethylthioxanthone (“KAYACURE DETX” manufactured by Nippon Kayaku Co., Ltd.) and p-dimethylaminobenzoic acid ethyl ester (“KAYACURE EPA” manufactured by Nippon Kayaku Co., Ltd.); a mixture of isopropylthioxanthone (“QUANTACURE-ITX” manufactured by Ward Blenkinsop) and p-dimethylaminobenzoic acid ethyl ester; “Esacure ONE,” “Esacure KIP150,” “Esacure KIP160,” “Esacure 1001M,” “Esacure A198,” “Esacure KIP IT,” “Esacure KTO46,” and “Esacure TZT” (manufactured by Lamberti); and “Speedcure BMS,” “Speedcure PBZ,” and “Benzophenone” from LAMBSON. A photo-acid generator may be used as a photo-cationic initiator. Examples of the photo-acid generator include diazodisulfone-based compounds, triphenylsulfonium-based compounds, phenylsulfone-based compounds, sulfonylpyridine-based compounds, triazine-based compounds, and diphenyliodonium compounds.

The content of the photopolymerization initiator is preferably 0.1 to 10% by mass and particularly preferably 1 to 6% by mass with respect to the total mass of the polymerizable compounds contained in the polymerizable composition. One photopolymerization initiator may be used, or a mixture of two or more may be used.

A commonly used thermal polymerization initiator may be used for thermal polymerization. Examples of the thermal polymerization initiator that can be used include: organic peroxides such as methyl acetoacetate peroxide, cumene hydroperoxide, benzoyl peroxide, bis(4-t-butylcyclohexyl)peroxydicarbonate, t-butylperoxybenzoate, methyl ethyl ketone peroxide, 1,1-bis(t-hexylperoxy)3,3,5-trimethylcyclohexane, p-pentahydroperoxide, t-butyl hydroperoxide, dicumyl peroxide, isobutyl peroxide, di(3-methyl-3-methoxybutyl)peroxydicarbonate, and 1,1-bis(t-butylperoxy)cyclohexane; azonitrile compounds such as 2,2′-azobisisobutyronitrile and 2,2′-azobis(2,4-dimethylvaleronitrile); azoamidine compounds such as 2,2′-azobis(2-methyl-N-phenylpropione-amidine)dihydrochloride; azoamide compounds such as 2,2′azobis(2-methyl-N-[1,1-bis(hydroxymethyl)-2-hydroxyethyl]propionamide); and alkylazo compounds such as 2,2′azobis(2,4,4-trimethylpentane). The content of the thermal polymerization initiator is preferably 0.1 to 10 mass % and particularly preferably 1 to 6% by mass. These may be used alone or as a mixture of two or more.

### (Polymerization Inhibitor)

The polymerizable compositions used to produce the first and second retardation films in the present invention may contain a polymerization inhibitor. When the polymerization inhibitor is used, unnecessary polymerization during storage of the polymerizable compositions at high temperature is prevented, and sufficient storage stability can be obtained. Moreover, when an optical film is formed, heat resistance can be imparted to the coating, so that sufficient durability can be obtained.

Preferably, the polymerization inhibitor is a phenolic polymerization inhibitor.

The phenolic polymerization inhibitor is preferably hydroquinone, methoxyphenol, methylhydroquinone, tert-butylhydroquinone, or tert-butylcatechol.

The content of the polymerization inhibitor is preferably 0.01 to 1% by mass and particularly preferably 0.01 to 0.5% by mass with respect to the total mass of polymerizable compounds contained in a polymerizable composition. One polymerization inhibitor may be used, or a mixture of two or more may be used.

When the polymerization inhibitor is dissolved in a polymerizable composition, it is preferable that, when polymerizable compounds are dissolved in an organic solvent under heating and stirring, the polymerization inhibitor is dissolved together with the polymerizable compounds. Alternatively, after the polymerizable compounds are dissolved in the organic solvent under heating and stirring, the polymerization inhibitor may be added to and dissolved in the polymerizable composition.

### (Additives)

In the polymerizable compositions used to produce the first and second retardation films in the present invention, general-purpose additives may be used according to the intended purpose. For example, additives such as an antioxidant, an ultraviolet absorber, a leveling agent, an alignment controlling agent, a chain transfer agent, an infrared absorber, a thixotropic agent, an antistatic agent, a pigment, a filler, a chiral compound, a non-liquid crystalline compound having a polymerizable group, other liquid crystal compounds, and an alignment material may be added so long as the alignment of the liquid crystal is not significantly impaired.

### (Antioxidant)

The polymerizable compositions used to produce the first and second retardation films in the present invention may optionally contain an antioxidant etc. Examples of such compounds include hydroquinone derivatives, nitrosoamine-based polymerization inhibitors, and hindered phenol-based antioxidants. More specific examples of such compounds include: tert-butylhydroquinone; “Q-1300” and “Q-1301” available from Wako Pure Chemical Industries, Ltd.; pentaerythritol tetrakis[3-(3,5-di-tert-butyl-4-hydroxyphenyl)propionate “IRGANOX 1010,” thiodiethylene bis[3-(3,5-di-tert-butyl-4-hydroxyphenyl)propionate “IRGANOX 1035,” octadecyl-3-(3,5-di-tert-butyl-4-hydroxyphenyl)propionate “IRGANOX 1076,” “IRGANOX 1135,” “IRGANOX 1330,” 4,6-bis(octylthiomethyl)-o-cresol “IRGANOX 1520L,” “IRGANOX 1726,” “IRGANOX 245,” “IRGANOX 259,” “IRGANOX 3114,” “IRGANOX 3790,” “IRGANOX 5057,” and “IRGANOX 565” (these are manufactured by BASF); ADEKA STAB AO-20, AO-30, AO-40, AO-50, AO-60, and AO-80 manufactured by ADEKA CORPORATION; and SUMILIZER BHT, SUMILIZER BBM-S, and SUMILIZER GA-80 available from Sumitomo Chemical Co., Ltd.

The amount of the antioxidant added is preferably 0.01 to 2.0% by mass and more preferably 0.05 to 1.0% by mass with respect to the total mass of polymerizable compounds contained in a polymerizable composition.

### (Ultraviolet Absorber)

The polymerizable compositions used to produce the first and second retardation films in the present invention may optionally contain an ultraviolet absorber and a light stabilizer. No particular limitation is imposed on the ultraviolet absorber used and the light stabilizer used. It is preferable to use an ultraviolet absorber and a light stabilizer that can improve the light fastness of the retardation film.

Examples of the ultraviolet absorber include: 2-(2-hydroxy-5-t-butylphenyl)-2H-benzotriazole “TINUVIN PS,” “TINUVIN 99-2,” “TINUVIN 109,” “TINUVIN 213,” “TINUVIN 234,” “TINUVIN 326,” “TINUVIN 328,” “TINUVIN 329,” “TINUVIN 384-2,” “TINUVIN 571,” 2-(2H-benzotriazol-2-yl)-4,6-bis(l-methyl-1-phenylethyl)phenol “TINUVIN 900,” 2-(2H-benzotriazol-2-yl)-6-(1-methyl-1-phenylethyl)-4-(1,1,3,3-tetramethylbutyl)phenol “TINUVIN 928,” “TINUVIN 1130,” “TINUVIN 400,” “TINUVIN 405,” 2,4-bis[2-hydroxy-4-butoxyphenyl]-6-(2,4-dibutoxyphenyl)-1,3,5-triazine “TINUVIN 460,” “TINUVIN 479,” and “TINUVIN 5236” (these are manufactured by BASF); and “ADEKA STAB LA-32,” “ADEKA STAB LA-34,” “ADEKA STAB LA-36,” “ADEKA STAB LA-31,” “ADEKA STAB 1413,” and “ADEKA STAB LA-51” (these are manufactured by ADEKA CORPORATION).

Examples of the light stabilizer include: “TINUVIN 111FDL,” “TINUVIN 123,” “TINUVIN 144,” “TINUVIN 152,” “TINUVIN 292,” “TINUVIN 622,” “TINUVIN 770,” “TINUVIN 765,” “TINUVIN 780,” “TINUVIN 905,” “TINUVIN 5100,” “TINUVIN 5050,” “TINUVIN 5060,” “TINUVIN 5151,” “CHIMASSORB 119FL,” “CHIMASSORB 944FL,” and “CHIMASSORB 944LD” (these are manufactured by BASF); and “ADEKA STAB LA-52,” “ADEKA STAB LA-57,” “ADEKA STAB LA-62,” “ADEKA STAB LA-67,” “ADEKA STAB LA-63P,” “ADEKA STAB LA-68LD,” “ADEKA STAB LA-77,” “ADEKA STAB LA-82,” and “ADEKA STAB LA-87” (these are manufactured by ADEKA CORPORATION).

### (Leveling Agent)

The polymerizable compositions used to produce the first and second retardation films in the present invention may optionally contain a leveling agent. No particular limitation is imposed on the leveling agent used. Preferably, the leveling agent used can reduce unevenness in the thickness of a thin film used as the retardation film. Examples of the leveling agent include alkyl carboxylates, alkyl phosphates, alkyl sulfonates, fluoroalkyl carboxylates, fluoroalkyl phosphates, fluoroalkyl sulfonates, polyoxyethylene derivatives, fluoroalkyl ethylene oxide derivatives, polyethylene glycol derivatives, alkyl ammonium salts, and fluoroalkyl ammonium salts.

Specific examples of the leveling agent include: “MEGAFACE F-114,” “MEGAFACE F-251,” “MEGAFACE F-281,” “MEGAFACE F-410,” “MEGAFACE F-430,” “MEGAFACE F-444,” “MEGAFACE F-472SF,” “MEGAFACE F-477,” “MEGAFACE F-510,” “MEGAFACE F-511,” “MEGAFACE F-552,” “MEGAFACE F-553,” “MEGAFACE F-554,” “MEGAFACE F-555,” “MEGAFACE F-556,” “MEGAFACE F-557,” “MEGAFACE F-558,” “MEGAFACE F-559,” “MEGAFACE F-560,” “MEGAFACE F-561,” “MEGAFACE F-562,” “MEGAFACE F-563,” “MEGAFACE F-565,” “MEGAFACE F-567,” “MEGAFACE F-568,” “MEGAFACE F-569,” “MEGAFACE F-570,” “MEGAFACE F-571,” “MEGAFACE R-40,” “MEGAFACE R-41,” “MEGAFACE R-43,” “MEGAFACE R-94,” “MEGAFACE RS-72-K,” “MEGAFACE RS-75,” “MEGAFACE RS-76-E,” “MEGAFACE RS-76-NS,” “MEGAFACE RS-90,” “MEGAFACE EXP. TF-1367,” “MEGAFACE EXP. TF1437,” “MEGAFACE EXP. TF1537,” and “MEGAFACE EXP.TF-2066” (manufactured by DIC Corporation);

“FTERGENT 100,” “FTERGENT 100C,” “FTERGENT 110,” “FTERGENT 150,” “FTERGENT 150CH,” “FTERGENT 100A-K,” “FTERGENT 300,” “FTERGENT 310,” “FTERGENT 320,” “FTERGENT 400SW,” “FTERGENT 251,” “FTERGENT 215M,” “FTERGENT 212M,” “FTERGENT 215M,” “FTERGENT 250,” “FTERGENT 222F,” “FTERGENT 212D,” “FTX-218,” “FTERGENT 209F,” “FTERGENT 245F,” “FTERGENT 208G,” “FTERGENT 240G,” “FTERGENT 212P,” “FTERGENT 220P,” “FTERGENT 228P,” “DFX-18,” “FTERGENT 601AD,” “FTERGENT 602A,” “FTERGENT 650A,” “FTERGENT 750FM,” “FTX-730FM,” “FTERGENT 730FL,” “FTERGENT 710FS,” “FTERGENT 710FM,” “FTERGENT 710FL,” “FTERGENT 750LL,” “FTX-730LS,” and “FTERGENT 730LM,” (manufactured by NEOS Company Limited);
“BYK-300,” “BYK-302,” “BYK-306,” “BYK-307,” “BYK-310,” “BYK-315,” “BYK-320,” “BYK-322,” “BYK-323,” “BYK-325,” “BYK-330,” “BYK-331,” “BYK-333,” “BYK-337,” “BYK-340,” “BYK-344,” “BYK-370,” “BYK-375,” “BYK-377,” “BYK-350,” “BYK-352,” “BYK-354,” “BYK-355,” “BYK-356,” “BYK-358N,” “BYK-361N,” “BYK-357,” “BYK-390,” “BYK-392,” “BYK-UV3500,” “BYK-UV3510,” “BYK-UV3570,” and “BYK-Silclean 3700” (manufactured by BYK Japan KK);
“TEGO Rad 2100,” “TEGO Rad 2011,” “TEGO Rad 2200N,” “TEGO Rad 2250,” “TEGO Rad 2300,” “TEGO Rad 2500,” “TEGO Rad 2600,” “TEGO Rad 2650,” “TEGO Rad 2700,” “TEGO Flow 300,” “TEGO Flow 370,” “TEGO Flow 425,” “TEGO Flow ATF2,” “TEGO Flow ZFS 460,” “TEGO Glide 100,” “TEGO Glide 110,” “TEGO Glide 130,” “TEGO Glide 410,” “TEGO Glide 411,” “TEGO Glide 415,” “TEGO Glide 432,” “TEGO Glide 440,” “TEGO Glide 450,” “TEGO Glide 482,” “TEGO Glide A115,” “TEGO Glide B1484,” “TEGO Glide ZG400,” “TEGO Twin 4000,” “TEGO Twin 4100,” “TEGO Twin 4200,” “TEGO Wet 240,” “TEGO Wet 250,” “TEGO Wet 260,” “TEGO Wet 265,” “TEGO Wet 270,” “TEGO Wet 280,” “TEGO Wet 500,” “TEGO Wet 505,” “TEGO Wet 510,” “TEGO Wet 520,” and “TEGO Wet KL245” (manufactured by Evonik Industries); “FC-4430” and “FC-4432” (manufactured by 3M Japan Limited); “UNIDYNE NS” (manufactured by DAIKIN INDUSTRIES, Ltd.); “SURFLON S-241,” “SURFLON S-242,” “SURFLON S-243,” “SURFLON S-420,” “SURFLON S-611,” “SURFLON S-651,” and “SURFLON S-386” (manufactured by AGC SEIMI CHEMICAL Co., Ltd.); “DISPARLON OX-880EF,” “DISPARLON OX-881,” “DISPARLON OX-883,” “DISPARLON OX-77EF,” “DISPARLON OX-710,” “DISPARLON 1922,” “DISPARLON 1927,” “DISPARLON 1958,” “DISPARLON P-410EF,” “DISPARLON P-420,” “DISPARLON P-425,” “DISPARLON PD-7,” “DISPARLON 1970,” “DISPARLON 230,” “DISPARLON LF-1980,” “DISPARLON LF-1982,” “DISPARLON LF-1983,” “DISPARLON LF-1084,” “DISPARLON LF-1985,” “DISPARLON LHP-90,” “DISPARLON LHP-91,” “DISPARLON LHP-95,” “DISPARLON LHP-96,” “DISPARLON OX-715,” “DISPARLON 1930N,” “DISPARLON 1931,” “DISPARLON 1933,” “DISPARLON 1934,” “DISPARLON 1711EF,” “DISPARLON 1751N,” “DISPARLON 1761,” “DISPARLON LS-009,” “DISPARLON LS-001,” and “DISPARLON LS-050” (manufactured by Kusumoto Chemicals, Ltd.); “PF-151N,” “PF-636,” “PF-6320,” “PF-656,” “PF-6520,” “PF-652-NF,” and “PF-3320” (manufactured by OMNOVA SOLUTIONS); “POLYFLOW No. 7,” “POLYFLOW No. 50E,” “POLYFLOW No. 50EHF,” “POLYFLOW No. 54N,” “POLYFLOW No. 75,” “POLYFLOW No. 77,” “POLYFLOW No. 85,” “POLYFLOW No. 85HF,” “POLYFLOW No. 90,” “POLYFLOW No. 90D-50,” “POLYFLOW No. 95,” “POLYFLOW No. 99C,” “POLYFLOW KL-400K,” “POLYFLOW KL-400HF,” “POLYFLOW KL-401,” “POLYFLOW KL-402,” “POLYFLOW KL-403,” “POLYFLOW KL-404,” “POLYFLOW KL-100,” “POLYFLOW LE-604,” “POLYFLOW KL-700,” “FLOWLEN AC-300,” “FLOWLEN AC-303,” “FLOWLEN AC-324,” “FLOWLEN AC-326F,” “FLOWLEN AC-530,” “FLOWLEN AC-903,” “FLOWLEN AC-903HF,” “FLOWLEN AC-1160,” “FLOWLEN AC-1190,” “FLOWLEN AC-2000,” “FLOWLEN AC-2300C,” “FLOWLEN AO-82,” “FLOWLEN AO-98,” and “FLOWLEN AO-108” (manufactured by KYOEISHA CHEMICAL Co., Ltd.); and “L-7001,” “L-7002,” “8032 ADDITIVE,” “57 ADDITIVE,” “L-7064,” “FZ-2110,” “FZ-2105,” “67 ADDITIVE,” and “8616 ADDITIVE” (manufactured by Toray Dow Silicone Co., Ltd.).

The amount of the leveling agent added is preferably 0.01 to 2% by mass and more preferably 0.05 to 0.5% by mass with respect to the total mass of polymerizable compounds used in a polymerizable composition.

By appropriately selecting the type and amount of the leveling agent added, the tilt angle of the retardation film formed from the polymerizable compositions at its air interface can be controlled.

### (Alignment Controlling Agent)

The polymerizable compositions used to produce the retardation film of the present invention may contain an alignment controlling agent in order to control the alignment state of the polymerizable compounds. Examples of the alignment controlling agent used include those that allow the liquid crystalline compounds to align in a substantially horizontal manner, a substantially vertical manner, and a substantially hybrid manner with respect to a substrate. Examples of the alignment controlling agent used when a chiral compound is added include those that allow the liquid crystalline compounds to align in a substantially planar manner. A surfactant may induce horizontal alignment or planar alignment. However, no particular limitation is imposed on the alignment controlling agent so long as the intended alignment state is induced, and a commonly used alignment controlling agent may be used.

Examples of such an alignment controlling agent include a compound having a repeating unit represented by general formula (8) below, having a weight average molecular weight of from 100 to 1,000,000 inclusive, and having the effect of effectively reducing the tilt angle of a retardation film to be formed at its air interface:

[Chem. 142]

\CR¹¹R¹²—CR¹³R¹⁴ (8)

(wherein R¹¹, R¹², R¹³, and R¹⁴ each independently represent a hydrogen atom, a halogen atom, or a hydrocarbon group having 1 to 20 carbon atoms, and at least one hydrogen atom in the hydrocarbon group may be replaced by a halogen atom).

Other examples of the alignment controlling agent include rod-shaped liquid crystalline compounds modified with fluoroalkyl groups, disk-shaped liquid crystalline compounds, and polymerizable compounds having long-chain aliphatic alkyl groups optionally having a branch structure.

Examples of the compound having the effect of effectively increasing the tilt angle of a retardation film to be formed at its air interface include cellulose nitrate, cellulose acetate, cellulose propionate, cellulose butyrate, rod-shaped liquid crystalline compounds modified with heteroaromatic ring salts, and rod-shaped liquid crystalline compounds modified with cyano groups and cyanoalkyl groups.

### (Chain Transfer Agent)

The polymerizable compositions used in the present invention may contain a chain transfer agent in order to further improve adhesion of the polymers or the retardation film to a substrate. Examples of the chain transfer agent include: aromatic hydrocarbons; halogenated hydrocarbons such as chloroform, carbon tetrachloride, carbon tetrabromide, and bromotrichloromethane; mercaptan compounds such as octyl mercaptan, n-butyl mercaptan, n-pentyl mercaptan, n-hexadecyl mercaptan, n-tetradecyl mercaptan, n-dodecyl mercaptan, t-tetradecyl mercaptan, and t-dodecyl mercaptan; thiol compounds such as hexanedithiol, decanedithiol, 1,4-butanediol bisthiopropionate, 1,4-butanediol bisthioglycolate, ethylene glycol bisthioglycolate, ethylene glycol bisthiopropionate, trimethylolpropane tristhioglycolate, trimethylolpropane tristhiopropionate, trimethylolpropane tris(3-mercaptobutyrate), pentaerythritol tetrakisthioglycolate, pentaerythritol tetrakisthiopropionate, trimercaptopropionic acid tris(2-hydroxyethyl)isocyanurate, 1,4-dimethylmercaptobenzene, 2,4,6-trimercapto-s-triazine, and 2-(N,N-dibutylamino)-4,6-dimercapto-s-triazine; sulfide compounds such as dimethylxanthogen disulfide, diethylxanthogen disulfide, diisopropylxanthogen disulfide, tetramethylthiuram disulfide, tetraethylthiuram disulfide, and tetrabutylthiuram disulfide; N,N-dimethylaniline; N,N-divinylaniline; pentaphenylethane; an α-methylstyrene dimer; acrolein; allyl alcohol; terpinolene; α-terpinene, γ-terpinene, and dipentene. Of these, 2,4-diphenyl-4-methyl-1-pentene and thiol compounds are more preferred.

Specifically, compounds represented by general formulas (9-1) to (9-12) below are preferred.

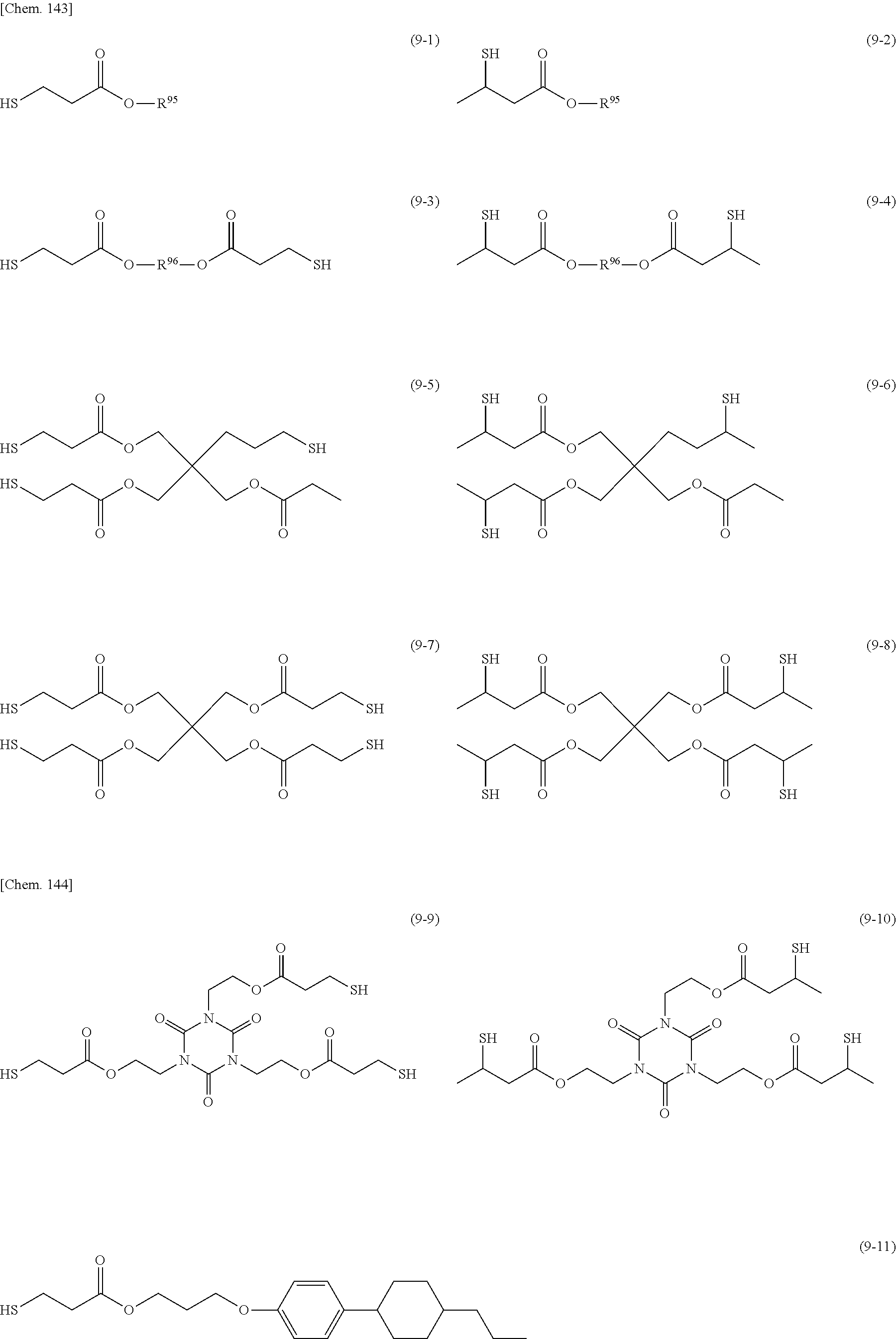

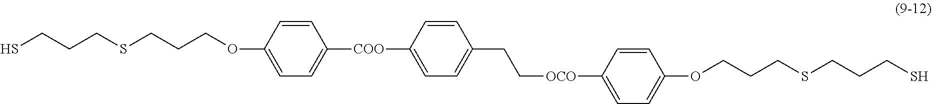

In these formulas, R⁹⁵ represents an alkyl group having 2 to 18 carbon atoms. The alkyl group may be linear or branched, and at least one methylene group in the alkyl group is optionally replaced by an oxygen atom, a sulfur atom, —CO—, —OCO—, —COO—, or —CH═CH—, provided that no oxygen atom is bonded directly to a sulfur atom. R⁹⁶ represents an alkylene group having 2 to 18 carbon atoms, and at least one methylene group in the alkylene group is optionally replaced by an oxygen atom, a sulfur atom, —CO—, —OCO—, —COO—, or —CH═CH—, provided that no oxygen atom is bonded directly to a sulfur atom.

Preferably, the chain transfer agent is added in the step of mixing polymerizable compounds with an organic solvent under heating and stirring to prepare a polymerizable solution. However, the chain transfer agent may be added in the subsequent step of mixing the polymerization initiator with the polymerizable solution or in both the steps.

The amount of the chain transfer agent added is preferably 0.5 to 10% by mass and more preferably 1.0 to 5.0% by mass with respect to the total mass of polymerizable compounds contained in a polymerizable composition.

To control physical properties, a non-polymerizable liquid crystal compound etc. may also be added optionally. Preferably, the non-polymerizable liquid crystal compound is added in the step of mixing the polymerizable compounds with the organic solvent under heating and stirring to prepare a polymerizable solution. However, the non-polymerizable liquid crystal compound etc. may be added in the subsequent step of mixing the polymerization initiator with the polymerizable solution or in both the steps. The amount of these compounds added is preferably 20% by mass or less, more preferably 10% by mass or less, and still more preferably 5% by mass or less with respect to the mass of the polymerizable composition.

### (Infrared Absorber)

The polymerizable compositions used to produce the first and second retardation films in the present invention may optionally contain an infrared absorber. No particular limitation is imposed on the infrared absorber used, and a commonly used infrared absorber may be contained so long as the alignment is not disturbed.

Examples of the infrared absorber include cyanine compounds, phthalocyanine compounds, naphthoquinone compounds, dithiol compounds, diimmonium compounds, azo compounds, and aluminum salts.

Specific examples include: a diimmonium salt-type infrared absorber “NIR-IM1” and an aluminum salt-type infrared absorber “NIR-AM1” (manufactured by Nagase ChemteX Corporation); “Karenz IR-T” and “Karenz IR-13F” (manufactured by Showa Denko K.K.); “YKR-2200” and “YKR-2100” (manufactured by Yamamoto Chemicals, Inc.); and “IRA 908,” “IRA 931,” “IRA 955,” and “IRA 1034” (INDECO).

### (Antistatic Agent)

The polymerizable compositions used to produce the first and second retardation films in the present invention may optionally contain an antistatic agent. No particular limitation is imposed on the antistatic agent used, and a commonly used antistatic agent may be contained so long as the alignment is not disturbed.

Examples of the antistatic agent include macromolecular compounds having at least one sulfonate group or phosphate group in their molecule, compounds including a quaternary ammonium salt, and surfactants having a polymerizable group.

Of these, surfactants having a polymerizable group are preferred. Examples of anionic surfactants having a polymerizable group include: alkyl ether-based surfactants such as “Antox SAD,” “Antox MS-2N” (manufactured by Nippon Nyukazai Co., Ltd.), “AQUALON KH-05,” “AQUALON KH-10,” “AQUALON KH-20,” “AQUALON KH-0530,” “AQUALON KH-1025” (manufactured by DAI-ICHI KOGYO SEIYAKU Co., Ltd.), “ADEKA REASOAP SR-10N,” “ADEKA REASOAP SR-20N” (manufactured by ADEKA CORPORATION), and “LATEMUL PD-104” (manufactured by Kao Corporation); sulfosuccinate-based surfactants such as “LATEMUL S-120,” “LATEMUL S-120A,” “LATEMUL S-180P,” “LATEMUL S-180A” (manufactured by Kao Corporation), and “ELEMINOL JS-2” (manufactured by Sanyo Chemical Industries, Ltd.); alkyl phenyl ether- and alkyl phenyl ester-based surfactants such as “AQUALON H-2855A,” “AQUALON H-3855B,” “AQOALON H-3855C,” “AQUALON H-3856,” “AQUALON HS-05,” “AQOALON HS-10,” “AQUALON HS-20,” “AQUALON HS-30,” “AQUALON HS-1025,” “AQUALON BC-05,” “AQUALON BC-10,” “AQUALON BC-20,” “AQUALON BC-1025,” “AQUALON BC-2020” (manufactured by DAI-ICHI KOGYO SEIYAKU Co., Ltd.) “ADEKA REASOAP SDX-222,” “ADEKA REASOAP SDX-223,” “ADEKA REASOAP SDX-232,” “ADEKA REASOAP SDX-233,” “ADEKA REASOAP SDX-259,” “ADEKA REASOAP SE-10N,” and “ADEKA REASOAP SE-20N” (manufactured by ADEKA CORPORATION); (meth)acrylate sulfate-based surfactants such as “Antox MS-60,” “Antox MS-2N” (manufactured by Nippon Nyukazai Co., Ltd.), and “ELEMINOL RS-30” (manufactured by Sanyo Chemical Industries, Ltd.); and phosphate-based surfactants such as “H-3330P” (manufactured by DAI-ICHI KOGYO SEIYAKU Co., Ltd.) and “ADEKA REASOAP PP-70” (manufactured by ADEKA CORPORATION).

Examples of nonionic surfactants having a polymerizable group include: alkyl ether-based surfactants such as “Antox LMA-20,” “Antox LMA-27,” “Antox EMH-20,” “Antox LMH-20,” “Antox SMH-20” (manufactured by Nippon Nyukazai Co., Ltd.), “ADEKA REASOAP ER-10,” “ADEKA REASOAP ER-20,” “ADEKA REASOAP ER-30,” “ADEKA REASOAP ER-40” (manufactured by ADEKA CORPORATION), “LATEMUL PD-420,” “LATEMUL PD-430,” and “LATEMUL PD-450” (manufactured by Kao Corporation); alkyl phenyl ether- and alkyl phenyl ester-based surfactants such as “AQUALON RN-10,” “AQUALON RN-20,” “AQUALON RN-30,” “AQUALON RN-50,” “AQUALON RN-2025” (manufactured by DAI-ICHI KOGYO SEIYAKU Co., Ltd.), “ADEKA REASOAP NE-10,” “ADEKA REASOAP NE-20,” “ADEKA REASOAP NE-30,” and “ADEKA REASOAP NE-40” (manufactured by ADEKA CORPORATION); and (meth)acrylate sulfate-based surfactants such as “RMA-564,” “RMA-568,” and “RMA-1114” (manufactured by Nippon Nyukazai Co., Ltd.).

Other examples of the antistatic agent include polyethylene glycol (meth)acrylate, methoxypolyethylene glycol (meth)acrylate, ethoxypolyethylene glycol (meth)acrylate, propoxypolyethylene glycol (meth)acrylate, n-butoxypolyethylene glycol (meth)acrylate, n-pentoxypolyethylene glycol (meth)acrylate, phenoxypolyethylene glycol (meth)acrylate, polypropylene glycol (meth)acrylate, methoxypolypropylene glycol (meth)acrylate, ethoxypolypropylene glycol (meth)acrylate, propoxypolypropylene glycol (meth)acrylate, n-butoxypolypropylene glycol (meth)acrylate, n-pentoxypolypropylene glycol (meth)acrylate, phenoxypolypropylene glycol (meth)acrylate, polytetramethylene glycol (meth)acrylate, methoxypolytetramethylene glycol (meth)acrylate, phenoxytetraethylene glycol (meth)acrylate, hexaethylene glycol (meth)acrylate, and methoxyhexaethylene glycol (meth)acrylate.

Only one antistatic agent may be used, or a combination of two or more antistatic agents may be used. The amount of the antistatic agent added is preferably 0.001 to 10% by weight and more preferably 0.01 to 5% by weight with respect to the total weight of polymerizable compounds contained in a polymerizable composition.

### (Pigment)

The polymerizable compositions used to produce the first and second retardation films in the present invention may optionally contain a pigment. No particular limitation is imposed on the pigment used, and a commonly used pigment may be used so long as the alignment is not disturbed.

Examples of the pigment include dichroic pigments and fluorescent pigments. Examples of the dichroic and fluorescent pigments include polyazo pigments, anthraquinone pigments, cyanine pigments, phthalocyanine pigments, perylene pigments, perinone pigments, and squarylium pigments. From the viewpoint of addition, the pigment is preferably a pigment having liquid crystallinity.

Examples of the pigment that can be used include pigments described in U.S. Pat. No. 2,400,877, pigments described in Dreyer J. F., Phys. and Colloid Chem., 1948, 52, 808., “The Fixing of Molecular Orientation,” pigments described in Dreyer J. F., Journal de Physique, 1969, 4, 114., “Light Polarization from Films of Lyotropic Nematic Liquid Crystals,” pigments described in J. Lydon, “Chromonics” in “Handbook of Liquid Crystals Vol. 2B: Low Molecular Weight Liquid Crystals II,” D. Demus, J. Goodby, G. W. Gray, H. W. Spiessm, V. Vill ed., Willey-VCH, P. 981-1007 (1998), pigments described in Dichroic Dyes for Liquid Crystal Display, A. V. Ivashchenko, CRC Press, 1994, and pigments described in “Novel Development of Functional Pigment Market,” Chapter 1, p. 1, 1994, CMC Publishing Co., Ltd.

Examples of the dichroic pigments include formula (d-1) to formula (d-8) below.

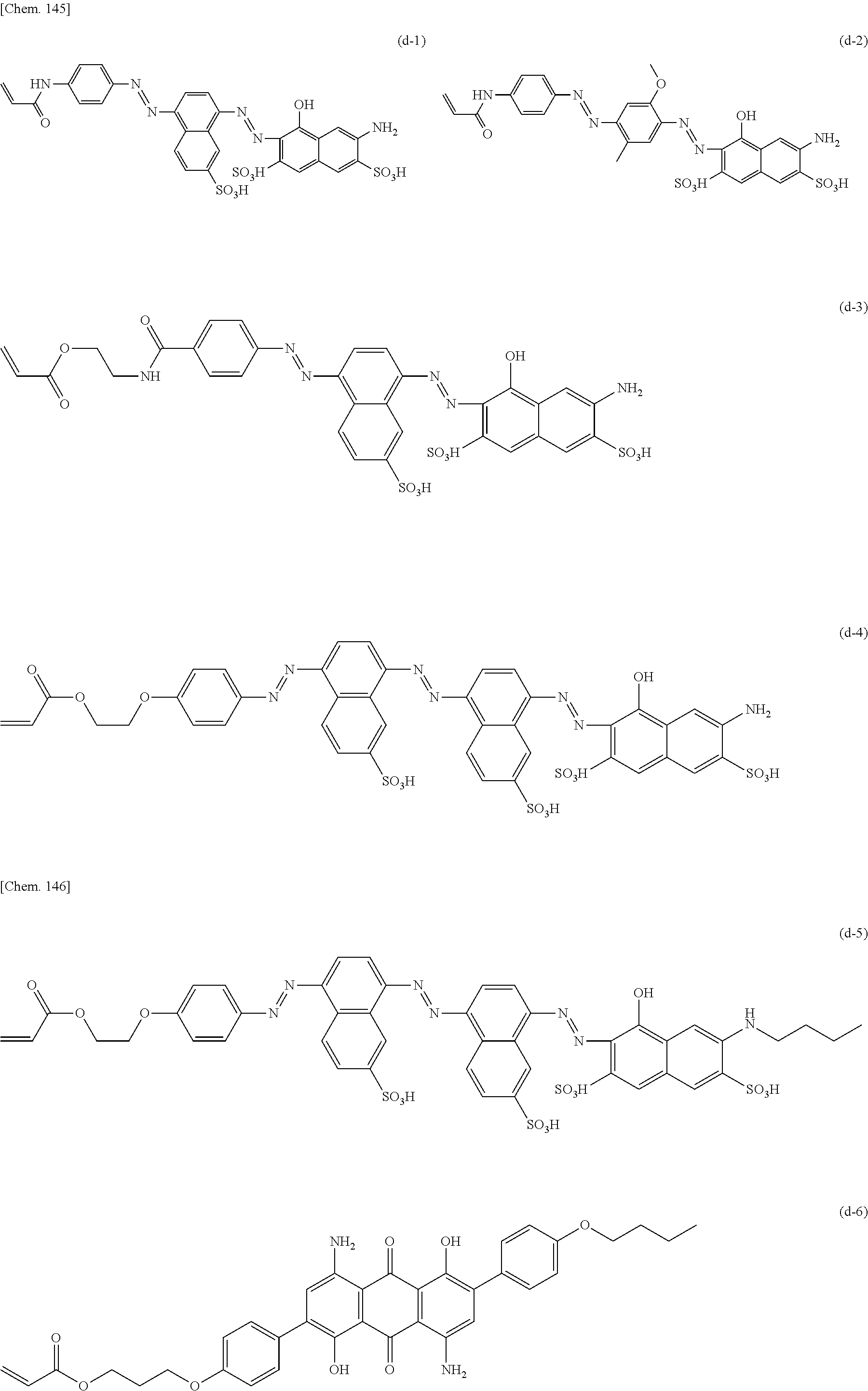

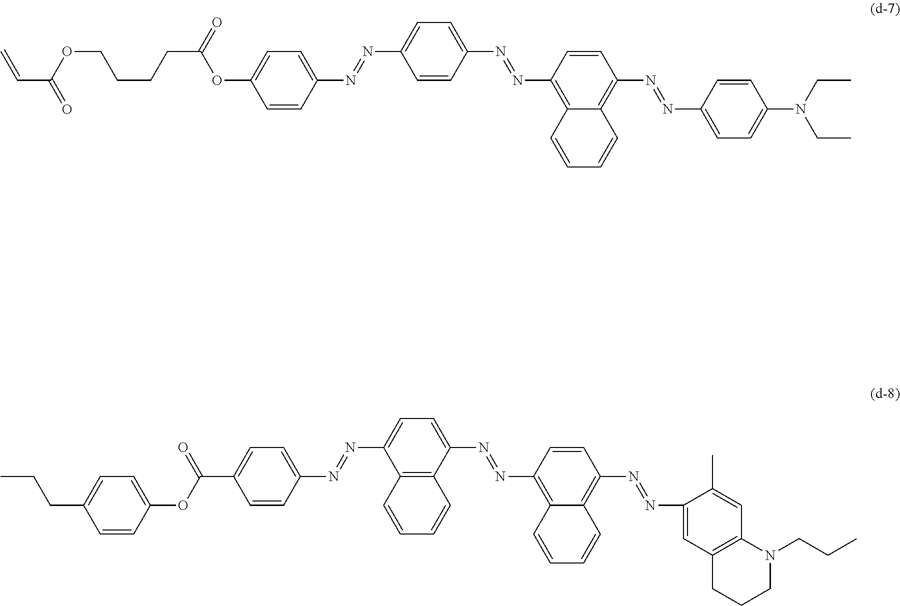

The amount of the pigment such as the dichroic pigment added is preferably 0.001 to 10% by weight and more preferably 0.01 to 5% by weight with respect to the total weight of polymerizable compounds contained in a polymerizable composition.

### (Filler)

The polymerizable compositions used to produce the first and second retardation films in the present invention may optionally contain a filler. No particular limitation is imposed on the filler used, and a commonly used filler may be used so long as the thermal conductivity of the polymers to be obtained is not impaired.

Examples of the filler include: inorganic fillers such as alumina, titanium white, aluminum hydroxide, talc, clay, mica, barium titanate, zinc oxide, and glass fibers; metal powders such as silver powder and copper powder; thermal conductive fillers such as aluminum nitride, boron nitride, silicon nitride, gallium nitride, silicon carbide, magnesia (magnesium oxide), alumina (aluminum oxide), crystalline silica (silicon oxide), and fused silica (silicon oxide); and silver nanoparticles.

### (Non-Liquid Crystalline Compound Having Polymerizable Group)

A compound that has a polymerizable group but is not a liquid crystal compound may be added to the polymerizable compositions used to produce the first and second retardation films in the present invention. No particular limitation is imposed on the above compound, so long as the compound used is commonly recognized as a polymerizable monomer or a polymerizable oligomer in the present technical field. When the non-liquid crystalline compound is added, its amount is preferably 15% by mass or less and more preferably 10% by mass or less with respect to the total amount of polymerizable compounds used in a polymerizable composition.

Specific examples include: mono(meth)acrylates such as methyl (meth)acrylate, ethyl (meth)acrylate, 2-hydroxyethyl acrylate, propyl (meth)acrylate, 2-hydroxypropyl (meth)acrylate, butyl (meth)acrylate, isobutyl (meth)acrylate, 4-hydroxybutyl (meth)acrylate, 2-hydroxybutyl (meth)acrylate, octyl (meth)acrylate, 2-ethylhexyl (meth)acrylate, dodecyl (meth)acrylate, stearyl (meth)acrylate, cyclohexyl (meth)acrylate, dicyclopentanyloxylethyl (meth)acrylate, isobornyloxylethyl (meth)acrylate, isobornyl (meth)acrylate, adamantyl (meth)acrylate, dimethyladamantyl (meth)acrylate, dicyclopentanyl (meth)acrylate, dicyclopentenyl (meth)acrylate, methoxyethyl (meth)acrylate, ethylcarbitol (meth)acrylate, tetrahydrofurfuryl (meth)acrylate, benzyl (meth)acrylate, phenoxyethyl (meth)acrylate, 2-phenoxydiethylene glycol (meth)acrylate, 2-hydroxy-3-phenoxyethyl (meth)acrylate, (2-methyl-2-ethyl-1,3-dioxolan-4-yl)methyl (meth)acrylate, (3-ethyloxetan-3-yl)methyl (meth)acrylate, o-phenylphenolethoxy (meth)acrylate, dimethylamino (meth)acrylate, diethylamino (meth)acrylate, 2,2,3,3,3-pentafluoropropyl (meth)acrylate, 2,2,3,4,4,4-hexafluorobutyl (meth)acrylate, 2,2,3,3,4,4,4-heptafluorobutyl (meth)acrylate, 2-(perfluorobutyl)ethyl (meth)acrylate, 2-(perfluorohexyl)ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H-1-(trifluoromethyl)trifluoroethyl (meth)acrylate, 1H,1H,3H-hexafluorobutyl (meth)acrylate, 1,2,2,2-tetrafluoro-1-(trifluoromethyl)ethyl (meth)acrylate, 1H, 1H-pentadecafluorooctyl (meth)acrylate, 1H,1H,2H,2H-tridecafluorooctyl (meth)acrylate, 2-(meth)acryloyloxyethyl phthalate, 2-(meth)acryloyloxyethylhexahydro phthalate, glycidyl (meth)acrylate, 2-(meth)acryloyloxyethyl phosphate, acryloylmorpholine, dimethylacrylamide, dimethylaminopropylacrylamide, isopropylacrylamide, diethylacrylamide, hydroxyethylacrylamide, and N-acryloyloxyethylhexahydrophthalimide; diacrylates such as 1,4-butanediol di(meth)acrylate, 1,6-hexanediol di(meth)acrylate, 1,9-nonanediol di(meth)acrylate, neopentyldiol di(meth)acrylate, tripropylene glycol di(meth)acrylate, ethylene glycol di(meth)acrylate, diethylene glycol di(meth)acrylate, triethylene glycol di(meth)acrylate, ethylene oxide-modified bisphenol A di(meth)acrylate, tricyclodecanedimethanol di(meth)acrylate, 9,9-bis[4-(2-acryloyloxyethoxy)phenyl]fluorene, glycerin di(meth)acrylate, 2-hydroxy-3-acryloyloxypropyl methacrylate, an acrylic acid adduct of 1,6-hexanediol diglycidyl ether, and an acrylic acid adduct of 1,4-butanediol diglycidyl ether; tri(meth)acrylates such as trimethylolpropane tri(meth)acrylate, ethoxylated isocyanuric acid triacrylate, pentaerythritol tri(meth)acrylate, and s-caprolactone-modified tris-(2-acryloyloxyethyl)isocyanurate; tetra(meth)acrylates such as pentaerythritol tetra(meth)acrylate and ditrimethylolpropane tetra(meth)acrylate; dipentaerythritol hexa(meth)acrylate; oligomer-type (meth)acrylates; various urethane acrylates; various macromonomers; epoxy compounds such as ethylene glycol diglycidyl ether, diethylene glycol diglycidyl ether, propylene glycol diglycidyl ether, neopentyl glycol diglycidyl ether, 1,6-hexanediol diglycidyl ether, glycerin diglycidyl ether, and bisphenol A diglycidyl ether; and maleimide. These may be used alone or may be used as a mixture of two or more.

### (Alignment Material)

The polymerizable compositions used to produce the first and second retardation films in the present invention may contain an alignment material that improves alignment of the films, for the purpose of improving the alignment. The alignment material used may be any commonly used alignment material so long as it is soluble in a solvent that can dissolve the liquid crystalline compounds having a polymerizable group and used in the polymerizable compositions. The alignment material may be added in such an amount that the alignment is not significantly impaired. Specifically, the amount of the alignment material is preferably 0.05 to 30% by weight, more preferably 0.5 to 15% by weight, and particularly preferably 1 to 10% by weight with respect to the total weight of polymerizable compounds contained in a polymerizable liquid crystal composition.

Specific examples of the alignment material include photoisomerizable or photodimerizable compounds such as polyimides, polyamides, BCB (benzocyclobutene polymers), polyvinyl alcohols, polycarbonates, polystyrenes, polyphenylene ethers, polyarylates, polyethylene terephthalates, polyethersulfones, epoxy resins, epoxy acrylate resins, acrylic resins, coumarin compounds, chalcone compounds, cinnamate compounds, fulgide compounds, anthraquinone compounds, azo compounds, and arylethene compounds. Of these, materials aligned by UV irradiation or visible light irradiation (photo-alignment materials) are preferred.

Examples of the photo-alignment material include: polyimides having cyclic alkanes; wholly aromatic polyarylates; polyvinyl cinnamate and a polyvinyl ester of p-methoxycinnamic acid shown in Japanese Unexamined Patent Application Publication No. 5-232473; cinnamate derivatives shown in Japanese Unexamined Patent Application Publications Nos. 6-287453 and 6-289374; and maleimide derivatives shown in Japanese Unexamined Patent Application Publication No. 2002-265541. Preferred specific examples include compounds represented by formula (12-1) to formula (12-7) below:

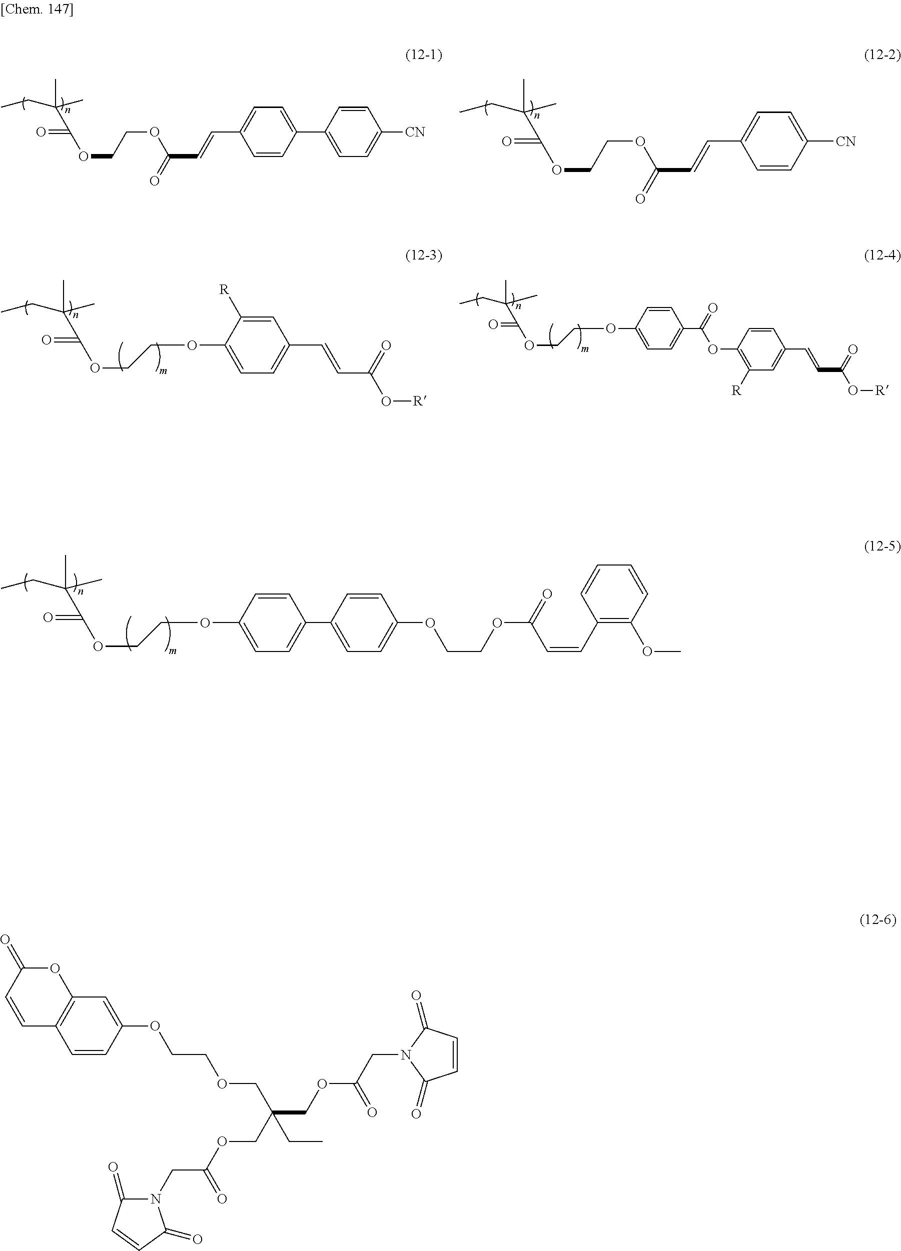

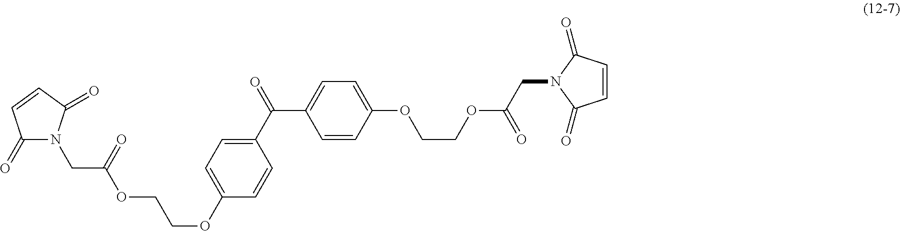

(wherein R represents a hydrogen atom, a halogen atom, an alkyl group having 1 to 3 carbon atoms, an alkoxy group, or a nitro group; R′ represents a hydrogen atom or an alkyl group having 1 to 10 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by —O—, —S—, —CO—, —COO—, —OCO—, —CO—S—, —S—CO—, —O—CO—O—, —CO—NH—, —NH—CO—, or —C≡C—; and a terminal CH₃ may be replaced by CF₃, CCl₃, a cyano group, a nitro group, an isocyano group, or a thioisocyano group; n represents 4 to 100,000; and m represents an integer of 1 to 10).

### (Retardation Film and Method for Producing Retardation Film)

### (Retardation Film)

Each of the first and second retardation films in the present invention can be obtained by applying a corresponding one of the polymerizable compositions used to produce the first and second retardation films in the present invention to a substrate or a substrate having an alignment function, aligning liquid crystal molecules in the polymerizable liquid crystal composition uniformly while a nematic phase or a smectic phase is maintained, and then polymerizing the polymerizable composition.

### (Substrate)

No particular limitation is imposed on the substrate used for the first and second retardation films in the present invention, so long as the substrate is commonly used for liquid crystal display devices, organic light-emitting display devices, other display devices, optical components, coloring agents, markings, printed materials, and optical films and formed of a heat resistant material that can resist heat during drying after application of a polymerizable composition solution. Examples of such a substrate include glass substrates, metal substrates, ceramic substrates, and organic materials such as plastic substrate and paper. In particular, when the substrate is formed of an organic material, examples of the organic material include cellulose derivatives, polyolefins, polyesters, polycarbonates, polyacrylates, polyarylates, polyethersulfones, polyimides, polyphenylene sulfides, polyphenylene ethers, nylon, and polystyrenes. Of these, plastic substrates such as polyesters, polystyrenes, polyolefins, cellulose derivatives, polyarylates, and polycarbonates are preferred. The shape of the substrate may be a flat plate shape and may also be a shape with a curved surface. The substrate may optionally include an electrode layer and may optionally have an antireflective function or a reflecting function.

To improve the ease of application of the polymerizable compositions used to produce the first and second retardation films in the present invention and to improve the adhesion to the polymers, the substrate may be subjected to surface treatment. Examples of the surface treatment include ozone treatment, plasma treatment, corona treatment, and silane coupling treatment. To control light transmittance and light reflectance, an organic thin film, an inorganic oxide thin film, a metal thin film, etc. may be provided on the surface of the substrate by, for example, vapor deposition. To give optical added value, the substrate may be a pickup lens, a rod lens, an optical disk, a retardation film, a light diffusion film, a color filter, etc. In particular, a pickup lens, a retardation film, a light diffusion film, and a color filter are preferable because the added value is high.

### (Alignment Treatment)

To allow the polymerizable compositions used to produce the first and second retardation films in the present invention to be aligned after the polymerizable compositions are applied and dried, the substrate has generally been subjected to alignment treatment, or an alignment film may be disposed on the substrate. Examples of the alignment treatment include stretching treatment, rubbing treatment, polarized UV-visible light irradiation treatment, ion beam treatment, and oblique deposition of SiO₂ on the substrate. The alignment film used may be a commonly used alignment film. Examples of such an alignment film include: compounds such as polyimides, polysiloxanes, polyamides, polyvinyl alcohols, polycarbonates, polystyrenes, polyphenylene ethers, polyarylates, polyethylene terephthalates, polyethersulfones, epoxy resins, epoxy acrylate resins, acrylic resins, azo compounds, coumarin compounds, chalcone compounds, cinnamate compounds, fulgide compounds, anthraquinone compounds, and arylethene compounds; and polymers and copolymers of these compounds. When rubbing is used for the alignment treatment of a compound, it is preferable that the crystallization of the compound is facilitated by the alignment treatment or a heating process performed after the alignment treatment. When the alignment treatment performed is other than rubbing, the compound used is preferably a photo-alignment material.

The alignment treatment method for aligning the first retardation layer in the present invention is preferably stretching treatment, rubbing treatment after application of an alignment film, or treatment using a photo-alignment film and is more preferably the treatment using a photo-alignment film. The treatment for aligning the second retardation layer is preferably vertical alignment film treatment and photo-alignment film treatment. For the case of the second retardation layer, the alignment treatment is not always necessary, depending on the type of polymerizable composition.

### (Application)

A commonly used coating method may be used to obtain the first and second retardation films in the present invention, and examples of the coating method include an applicator method, a bar coating method, a spin coating method, a roll coating method, a direct gravure coating method, a reverse gravure coating method, a flexographic coating method, an inkjet method, a die coating method, a cap coating method, a dip coating method, a slit coating method, and a spray coating method. After each polymerizable composition is applied, the composition is dried.

It is preferable that, after the application of the polymerizable composition, the liquid crystal molecules in the polymerizable composition are uniformly aligned while a smectic phase or a nematic phase is maintained. One example of the alignment method is a heat treatment method. Specifically, after the polymerizable composition is applied to the substrate, the polymerizable composition is heated to a temperature equal to or higher than the N (nematic phase)-I (isotropic liquid phase) transition temperature (hereinafter abbreviated as the N-I transition temperature) of the polymerizable composition to bring the polymerizable composition into the isotropic liquid state. Then, if necessary, the liquid crystal composition is gradually cooled, and the nematic phase thereby appears. In this case, it is preferable that the temperature is temporarily held at the temperature at which the liquid crystal phase appears. This allows liquid crystal phase domains to grow sufficiently, so that a monodomain is formed. Alternatively, after the polymerizable composition is applied to the substrate, heat treatment is performed such that the temperature is held constant for a certain time within the temperature range in which the nematic phase of the polymerizable composition appears.

If the heating temperature is excessively high, each polymerizable liquid crystal compound may undergo a non-preferable polymerization reaction and thereby deteriorate. If the polymerizable composition is cooled excessively, the polymerizable composition may undergo phase separation. In this case, crystals may precipitate, or a higher-order liquid crystal phase such as a smectic phase may appear, and it may be impossible to complete the alignment treatment.

With the above heat treatment, the retardation film produced is more uniform and has less alignment defects than retardation films produced by a simple application method.

After the uniform alignment treatment is performed as described above, the polymerizable composition may be cooled to the lowest possible temperature at which the liquid crystal phase does not undergo phase separation, i.e., until the polymerizable composition is supercooled. By polymerizing the polymerizable liquid crystalline compound at this temperature with the liquid crystal phase aligned, a retardation film with high alignment order and excellent transparency can be obtained.

### (Polymerization Process)

The dried polymerizable composition uniformly aligned is subjected to polymerization treatment generally by irradiation with visible-UV light or heating. Specifically, when light irradiation is used for the polymerization, irradiation with visible-UV light of 420 nm or less is preferable, and irradiation with UV light having a wavelength of 250 to 370 nm is most preferable. If the polymerizable composition is, for example, decomposed under the visible-UV light of 420 nm or less, it is sometimes preferable to perform the polymerization treatment with visible-UV light of 420 nm or more.

### (Polymerization Method)

Examples of the method for polymerizing the polymerizable compositions used to produce the retardation film of the present invention include an active energy ray irradiation method and a thermal polymerization method. The active energy ray irradiation method is preferred because the reaction proceeds at room temperature without heating. In particular, a method including irradiation with light such as UV light is preferable because of its simple procedure. The temperature during irradiation is set such that each polymerizable composition can maintain its liquid crystal phase. It is preferable, if at all possible, to hold the temperature at 30° C. or lower, in order to avoid induction of thermal polymerization of the polymerizable composition. Generally, in the course of heating, the polymerizable liquid crystal composition is in the liquid crystal phase within the range of from C (solid)-N(nematic) transition temperature (hereinafter abbreviated as the C-N transition temperature) to the N-I transition temperature. However, in the course of cooling, the polymerizable composition is in a thermodynamically non-equilibrium state, and thus the liquid crystal state may be maintained without solidification even at the C-N transition temperature or lower. This state is referred to as a supercooled state. In the present invention, the supercooled state of the liquid crystal composition is also regarded as the state in which the liquid crystal phase is maintained. Specifically, irradiation with UV light of 390 nm or less is preferable, and irradiation with light having a wavelength of 250 to 370 nm is most preferable. However, if the polymerizable composition is, for example, decomposed under UV light of 390 nm or less, it is sometimes preferable to perform the polymerization treatment with UV light of 390 nm or more. Preferably, the light used is diffused light and is unpolarized light. The irradiation intensity of the UV light is preferably within the range of 0.05 kW/m² to 10 kW/m². The irradiation intensity of the UV light is particularly preferably within the range of 0.2 kW/m² to 2 kW/m². If the intensity of the UV light is less than 0.05 kW/m², a considerable time is required to complete the polymerization. If the intensity exceeds 2 kW/m², the liquid crystal molecules in the polymerizable composition tend to undergo photo-decomposition, and a large amount of polymerization heat is generated. In this case, the temperature during polymerization increases, and the order parameter of the polymerizable liquid crystal varies, so that the retardation of the film after polymerization may deviate from the intended retardation.

A retardation film having a plurality of regions with different alignment directions may be obtained by polymerizing only specific portions under UV irradiation using a mask, changing the alignment state of the unpolymerized portions by application of an electric field, a magnetic field, heat, etc., and then polymerizing the unpolymerized portions.

When only the specific portions are polymerized under UV irradiation using the mask, an electric field, a magnetic field, heat, etc. may be applied in advance to the unpolymerized polymerizable liquid crystal composition to control alignment, and the polymerizable composition in this state may be irradiated with light through the mask to polymerize the polymerizable composition. A retardation film having a plurality of regions with different alignment directions may also be obtained in the manner described above.

The retardation film obtained by polymerization of the polymerizable liquid crystal compositions used in the present invention may be separated from the substrate, and the separated retardation film may be used alone. The retardation film may not be separated from the substrate, and the retardation film with the substrate may be used. In particular, since the retardation film is unlikely to contaminate other members, the retardation film is useful for a substrate for deposition and is also useful when another substrate is laminated onto the retardation film.

### (Optical Film)

The optical film of the present invention includes the first retardation layer and the second retardation layer. The first retardation layer plays a role in providing an intended retardation, and the second retardation layer plays a role in compensating for the angular dependence of the first retardation layer. These layers may be formed on the front and rear sides of one substrate. These layers may be formed on different substrates, and then these substrates may be laminated. Alternatively, after these layers are formed on different substrates, one of them may be separated and then laminated onto the other. Both of these layers may be separated from the substrates, and the separated layers may be laminated.

### (Elliptically Polarizing Plate)

By laminating the optical film of the present invention onto a linearly polarizing plate, the elliptically polarizing plate of the present invention can be produced. Generally, the linearly polarizing plate used has a protective film on one or both sides of a polarizer. No particular limitation is imposed on the polarizer, and any of various polarizers may be used. Examples of the polarizer include: a film obtained by uniaxially stretching a hydrophilic polymer film such as a polyvinyl alcohol-based film, a partially formalized polyvinyl alcohol-based film, or an ethylene-vinyl acetate copolymer-based partially saponified film with a dichroic material such as iodine or a dichroic dye adsorbed thereon; and polyene-based alignment films such as dehydrated products of polyvinyl alcohol and dehydrochlorinated products of polyvinyl chloride. Of these, a film obtained by stretching a polyvinyl alcohol-based film to align the adsorbed dichroic material (iodine or a dichroic dye) is preferably used. A wire grid-type polarizing plate, for example, may also be used.

As described above, the elliptically polarizing plate is formed by laminating the retardation film of the present invention onto the linearly polarizing plate. Alternatively, the polymerizable compositions used in the present invention may be applied directly to a polarizing plate to thereby directly form a retardation film layer on the polarizing plate.

### (Liquid Crystal Display Device)

The optical film of the present invention can be used for a liquid crystal display device. In the liquid crystal display device, at least a liquid crystal medium layer, a TFT driving circuit, a black matrix layer, a color filter layer, a spacer, and an electrode circuit suitable for the liquid crystal medium layer are held between at least two substrates. An optical compensation layer, a polarizing plate layer, and a touch panel layer are generally disposed outside the two substrates. However, the optical compensation layer, an overcoat layer, the polarizing plate layer, and an electrode layer for the touch panel may be held between the two substrates.

Examples of the alignment mode of the liquid crystal display device include a TN mode, a VA mode, an IPS mode, an FFS mode, and an OCB mode. When the optical film is used for an optical compensation film or an optical compensation layer, the optical film may be produced so as to provide a retardation suitable for the alignment mode. A patterned retardation film may also be used.

### (Organic Light-Emitting Display Device)

The optical film and the elliptically polarizing plate of the present invention can be used for the organic light-emitting display device of the present invention. They may be used as an antireflective film of the organic light-emitting display device.

### EXAMPLES

The present invention will next be described by way of Examples and Comparative Examples. However, the present invention is not limited thereto. “Parts” and “%” are based on mass, unless otherwise specified.

### <Production of First Retardation Layer (First Retardation Film)>

### (Polymerizable Composition (1))

30 Parts of the compound represented by formula (30-a-1), 62 parts of the compound represented by formula (20-a-1), 8 parts of the compound represented by formula (20-b-1), and 200 parts of toluene were added, and the mixture was heated to 80° C. and stirred to dissolve the compounds. After dissolution was complete, the mixture was returned to room temperature. Then 3 parts of IRGACURE 907 (Irg907: manufactured by BASF), 0.1 parts of p-methoxyphenol (MEHQ), and 0.2 parts of MEGAFACE F-554 (F-554: manufactured by DIC Corporation) were added, and the resulting mixture was further stirred to thereby obtain a solution. The solution was clear and uniform. The solution obtained was filtered through a 0.20 μm membrane filter to thereby obtain a polymerizable composition (1) for an Example.

### (Polymerizable Compositions (2) to (46))

Polymerizable compositions (2) to (21) and (31) to (32) for Examples and polymerizable compositions (41) to (46) for Comparative Examples were obtained under the same conditions as in the preparation of the polymerizable composition (1) except that ratios of compounds shown in tables below were changed as shown in the tables.

Specific compositions of the polymerizable compositions (1) to (21) and (31) to (32) for the present invention and the polymerizable compositions (41) to (46) for the Comparative Examples are shown in Tables 1 to 5 below.

TABLE 1

| Poly- | | | | | | | | | |
|---|---|---|---|---|---|---|---|---|---|
| meriz- | | | | | | | | | |
| able | | | | | | | | | |
| compo- | | | | | | | | | |
| sition | (1) | (2) | (3) | (4) | (5) | (6) | (7) | (8) | (9) |
| 30-a-1 | 30 | 90 | | | | | | | |
| 30-a-2 | | | 40 | 90 | | | | | |
| 30-a-3 | | | | | 30 | 90 | 50 | 70 | |
| 30-a-4 | | | | | | | | | 90 |
| 30-a-5 | | | | | 45 | | | | |
| 30-a-6 | | | | | | | | | |
| 30-a-7 | | | | | | | | | |
| 30-a-8 | | | | | | | | | |
| 20-a-1 | 62 | | | | | | | 25 | |
| 20-a-2 | | | 50 | | 20 | | | | |
| 20-a-3 | | | | | | | 40 | | |
| 20-a-4 | | | | | | | | | |
| 20-a-5 | | | | | | | | | |
| 20-a-6 | | | | | | | | | |
| 20-a-7 | | | | | | | | | |
| 20-a-8 | | | | | | | | | |
| 10-b-1 | | | | | | | | | |
| 10-b-2 | | | | | | | | | |
| 10-b-3 | | | | | | 10 | | | |
| 10-b-4 | | | | | | | | | |
| 20-b-1 | 8 | | 10 | | 5 | | 10 | | 10 |
| 20-b-2 | | 10 | | 10 | | | | 5 | |
| 20-b-3 | | | | | | | | | |
| 20-b-4 | | | | | | | | | |
| 20-b-5 | | | | | | | | | |
| Irg907 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 | 0.2 | 0.2 |
| F-556 | | | | | | | | | |
| Toluene | 200 | 200 | 200 | 200 | 200 | 200 | 200 | 200 | 200 |
| PGMEA | | | | | | | | | |

TABLE 2

| Poly- | | | | | | | | | |
|---|---|---|---|---|---|---|---|---|---|
| meriz- | | | | | | | | | |
| able | | | | | | | | | |
| compo- | | | | | | | | | |
| sition | (10) | (11) | (12) | (13) | (14) | (15) | (16) | (17) | (18) |
| 30 a-1 | | | | | | | | | |
| 30-a-2 | | | | | | | | | |
| 30-a-3 | | | | | | | | | |
| 30-a-4 | 50 | 50 | 95 | 60 | 30 | | | | |
| 30-a-5 | | | | | | 70 | 95 | | |
| 30-a-6 | | | | | | | | 50 | 95 |
| 30-a-7 | | | | | | | | | |
| 30-a-8 | | | | | | | | | |
| 20-a-1 | | | | | | | | | |
| 20-a-2 | 40 | | | | | | | | |
| 20-a-3 | | 35 | | | | | | | |
| 20-a-4 | | | | | | 20 | | | |
| 20-a-5 | | | | | | | | 45 | |
| 20-a-6 | | | | 30 | 55 | | | | |
| 20-a-7 | | | | | | | | | |
| 20-a-8 | | | | | | | | | |
| 10-b-1 | | | | 10 | | 10 | | | |
| 10-b-2 | | 15 | | | | | | | 5 |
| 10-b-3 | | | | | | | | 5 | |
| 10-b-4 | | | | | | | | | |
| 20-b-1 | | | | | | | 5 | | |
| 20-b-2 | 10 | | 5 | | 15 | | | | |
| 20-b-3 | | | | | | | | | |
| 20-b-4 | | | | | | | | | |
| 20-b-5 | | | | | | | | | |
| Irg907 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 | 0.2 | 0.2 |
| F-556 | | | | | | | | | |
| Toluene | 200 | 200 | 200 | 200 | 200 | 200 | 200 | 200 | 200 |
| PGMEA | 3 | 3 | 3 | 3 | 3 | 3 | 3 | 3 | 3 |

TABLE 3

| Poly- | | | | | | | | | |
|---|---|---|---|---|---|---|---|---|---|
| meriz- | | | | | | | | | |
| able | | | | | | | | | |
| compo- | | | | | | | | | |
| sition | (19) | (20) | (21) | (31) | (32) | (41) | (42) | (43) | (44) |
| 30-a-1 | | | | | | | | | |
| 30-a-2 | | | | | | | | | |
| 30-a-3 | | | | | | | | | |
| 30-a-4 | | | | | | | | | |
| 30-a-5 | | | | | | | | | |
| 30-a-6 | | | | | | | | | |
| 30-a-7 | 50 | | | | | | | | |
| 30-a-8 | | 50 | 30 | | | | | | |
| 20-a-1 | | | | | | 100 | 90 | | |
| 20-a-2 | | | | | | | | | 50 |
| 20-a-3 | | | | | | | | | |
| 20-a-4 | | | | | | | | | |
| 20-a-5 | | | | | | | | 95 | 40 |
| 20-a-6 | | | | | | | | | |
| 20-a-7 | 47 | 47 | | | | | | | |
| 20-a-8 | | | 65 | | | | | | |
| 10-b-1 | | | | 20 | 20 | | | 5 | |
| 10-b-2 | | | | | | | | | |
| 10-b-3 | | | | | | | | | |
| 10-b-4 | | | | | 10 | | | | |
| 20-b-1 | 3 | | 5 | | | | | | 10 |
| 20-b-2 | | 3 | | | | | 10 | | |
| 20-b-3 | | | | 40 | 30 | | | | |
| 20-b-4 | | | | 40 | 40 | | | | |
| 20-b-5 | | | | | | | | | |
| Irg907 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 |
| F-554 | 0.2 | 0.2 | 0.2 | | | 0.2 | 0.2 | 0.2 | 0.2 |
| F-556 | | | | 0.2 | 0.2 | | | | |
| Toluene | 200 | 200 | 200 | | | 200 | 200 | 200 | 200 |
| PGMEA | | | | 400 | 400 | | | | |

TABLE 4

| Polymerizable composition | (45) | (46) |
|---|---|---|
| 30-a-1 | | |
| 30-a-2 | | |
| 30-a-3 | | |
| 30-a-4 | | |
| 30-a-5 | | |
| 30-a-6 | | |
| 30-a-7 | | |
| 30-a-8 | | |
| 20-a-1 | | |
| 20-a-2 | | |
| 20-a-3 | | |
| 20-a-4 | | |
| 20-a-5 | | |
| 20-a-6 | | |
| 20-a-7 | 100 | |
| 20-a-8 | | 86 |
| 10-b-1 | | |
| 10-b-2 | | |
| 10-b-3 | | |
| 10-b-4 | | |
| 20-b-1 | | |
| 20-b-2 | | |
| 20-b-3 | | |
| 20-b-4 | | |
| 20-b-5 | | 14 |
| Irg907 | 3 | 3 |
| MEHQ | 0.1 | 0.1 |
| F-554 | 0.2 | 0.2 |
| F-556 | | |
| Toluene | 200 | 200 |
| PGMEA | 3 | 3 |

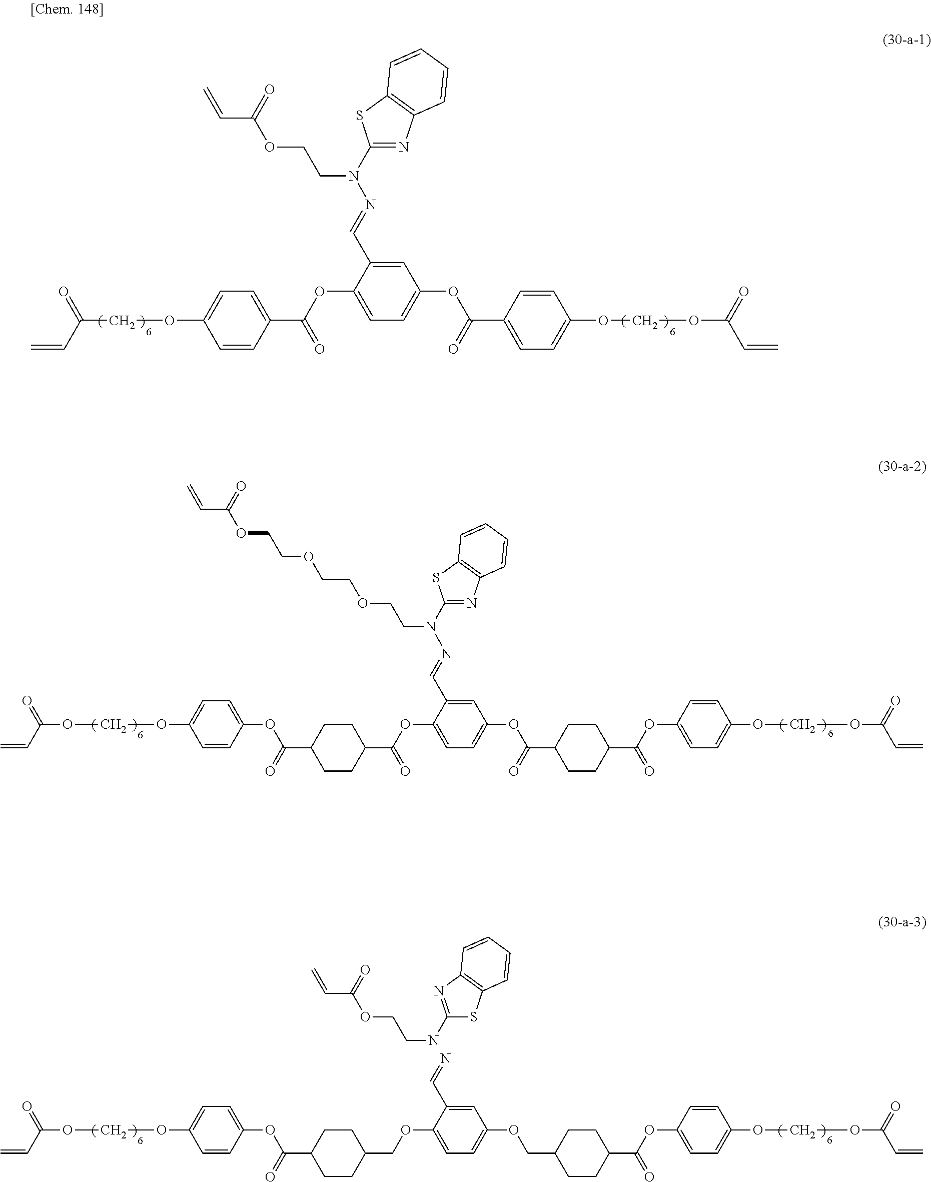

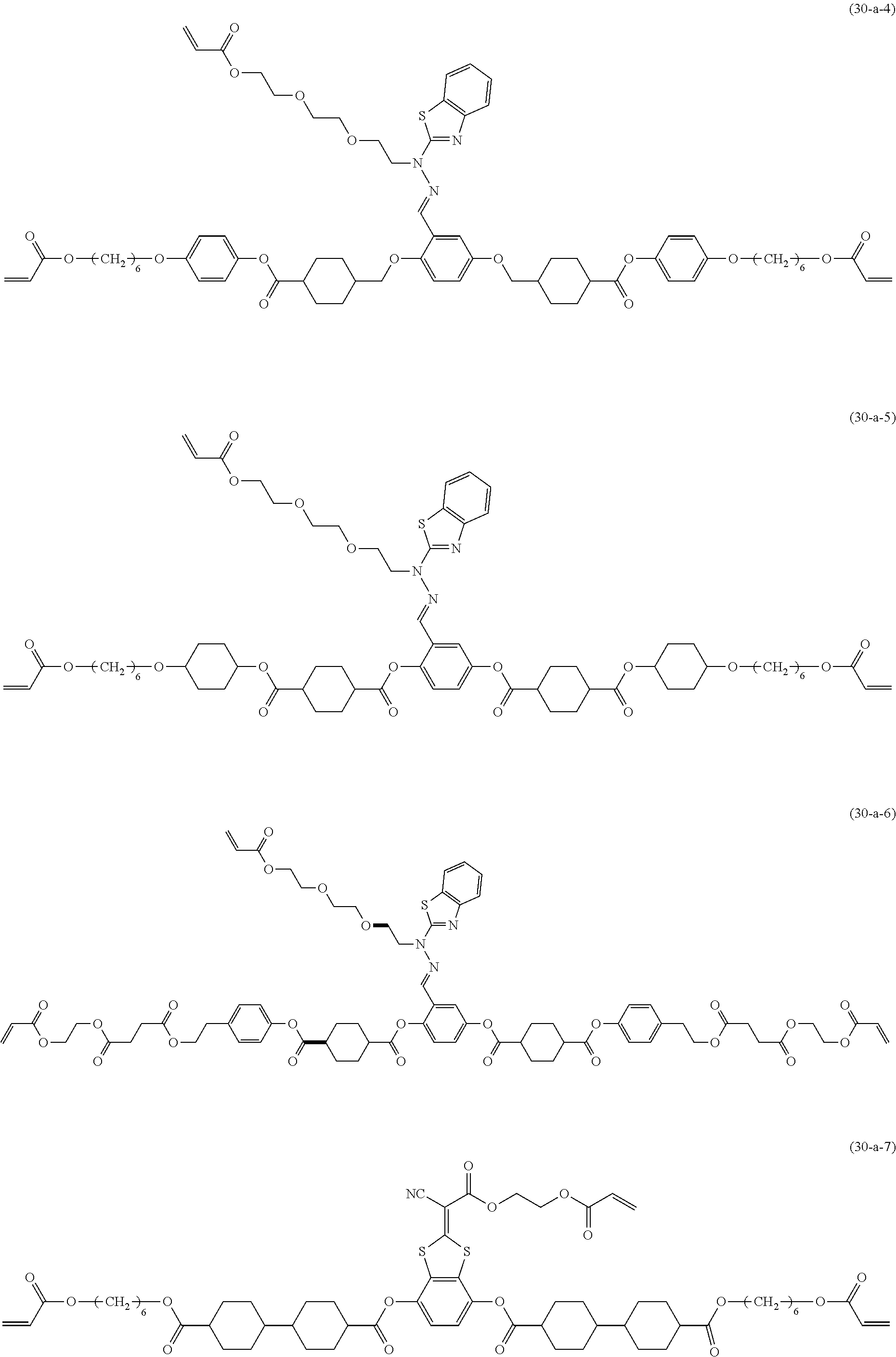

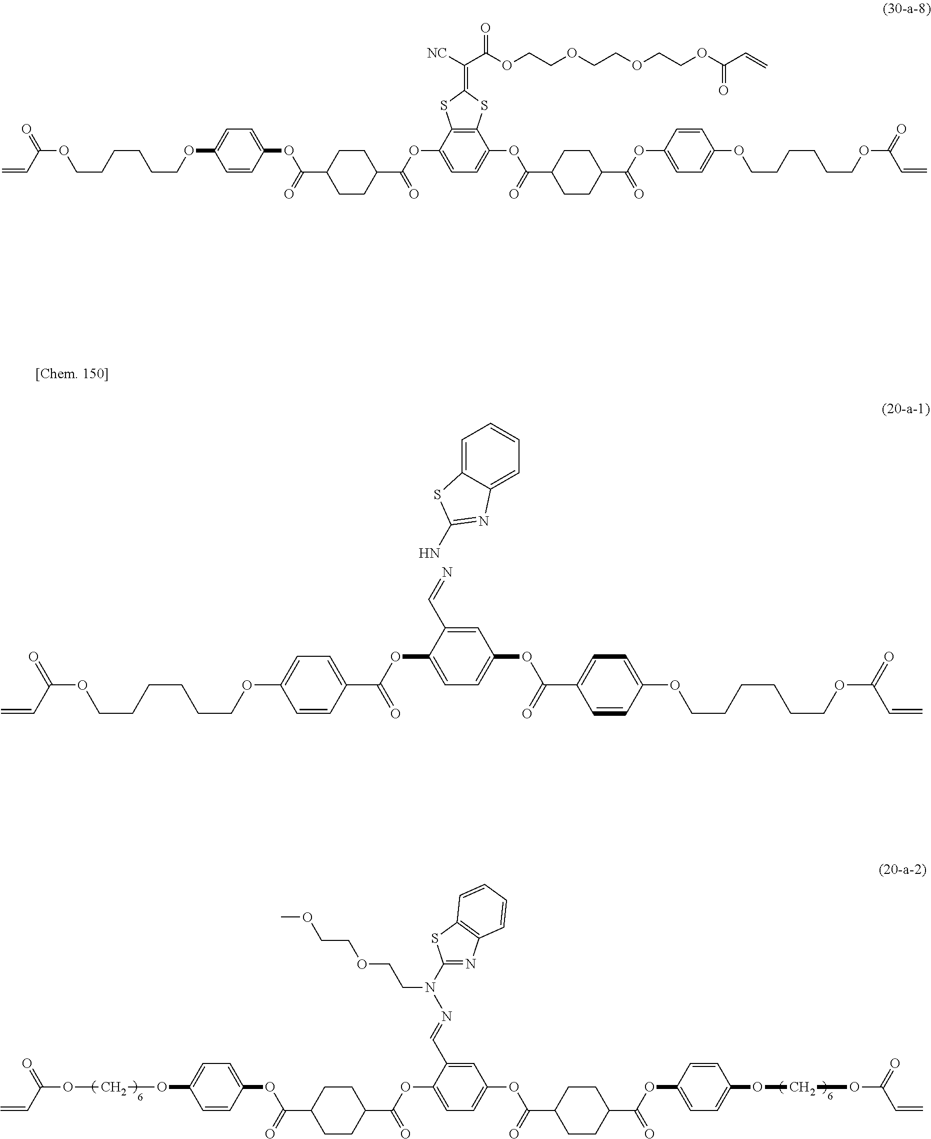

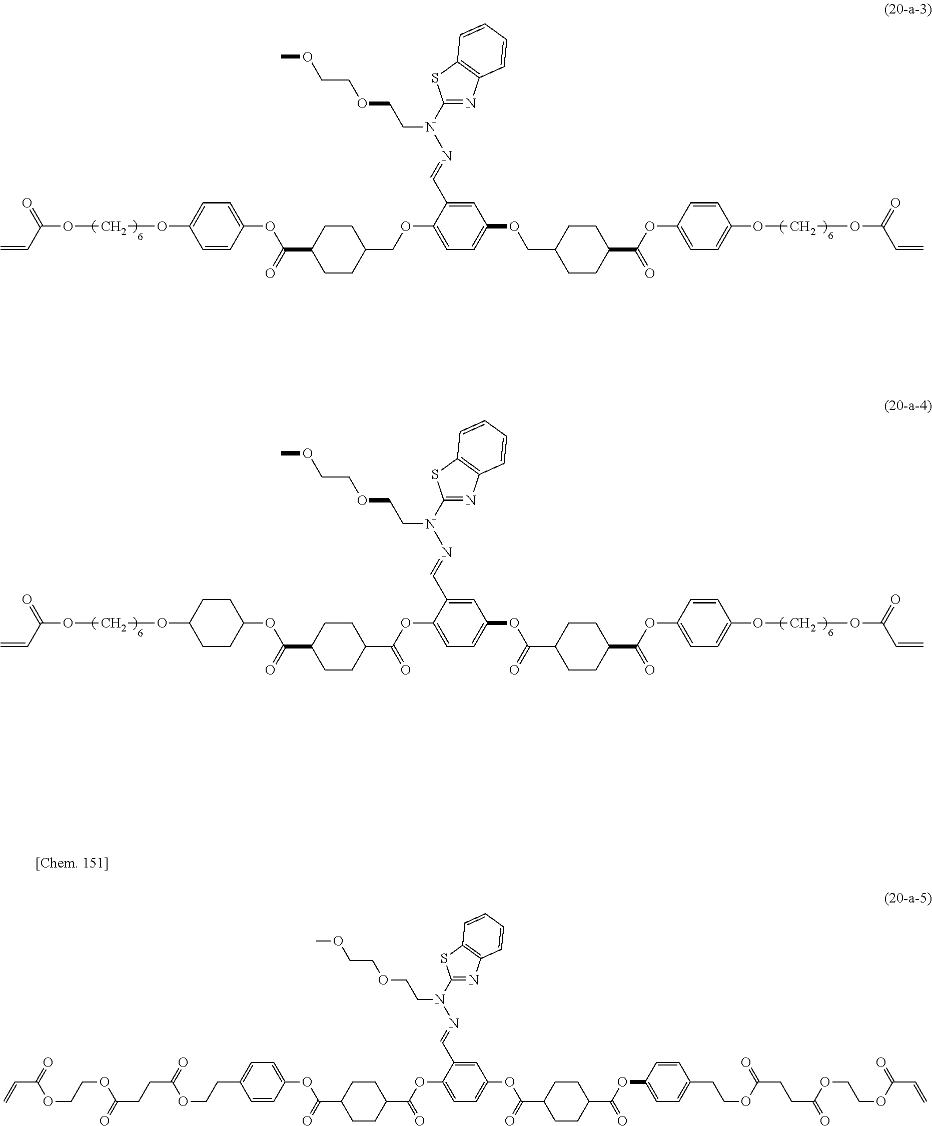

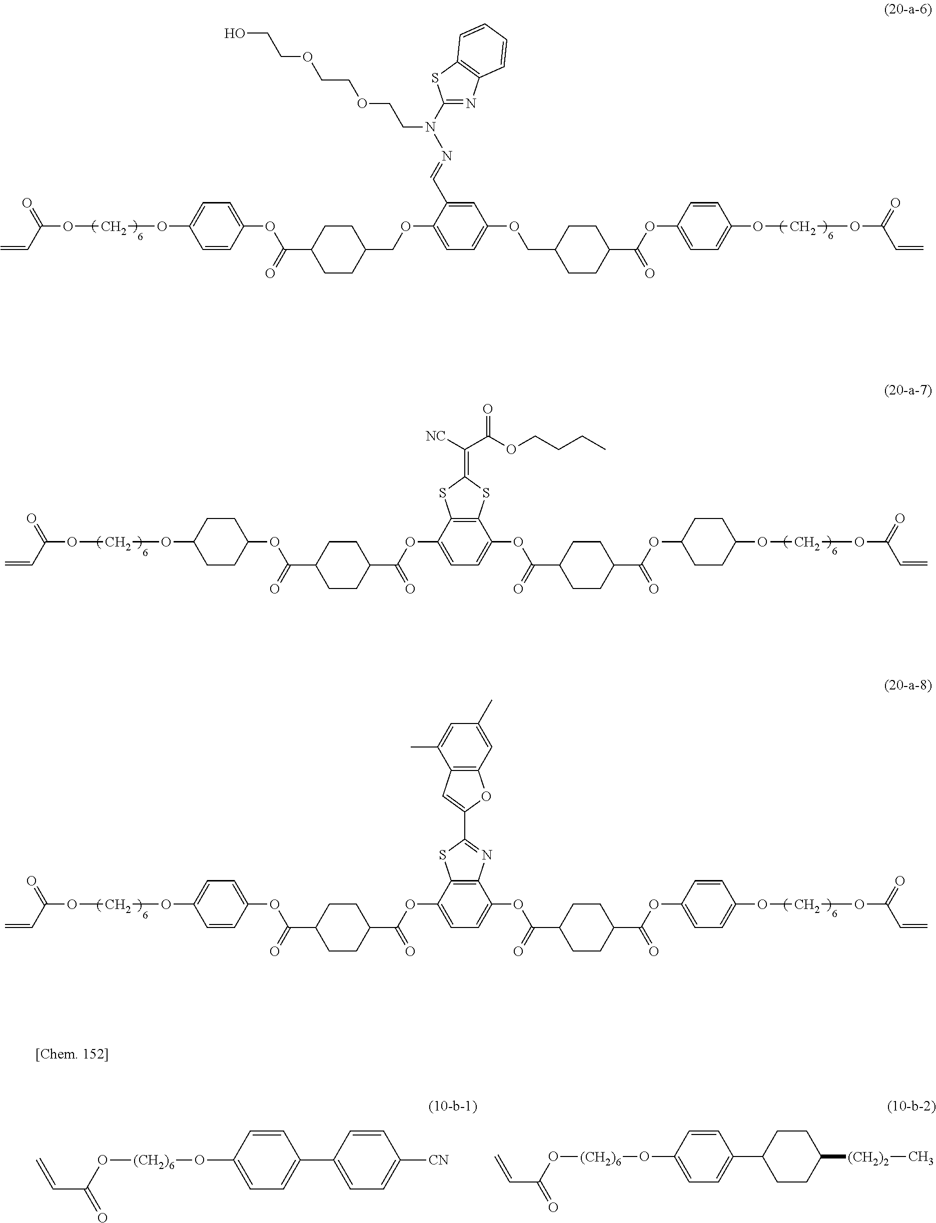

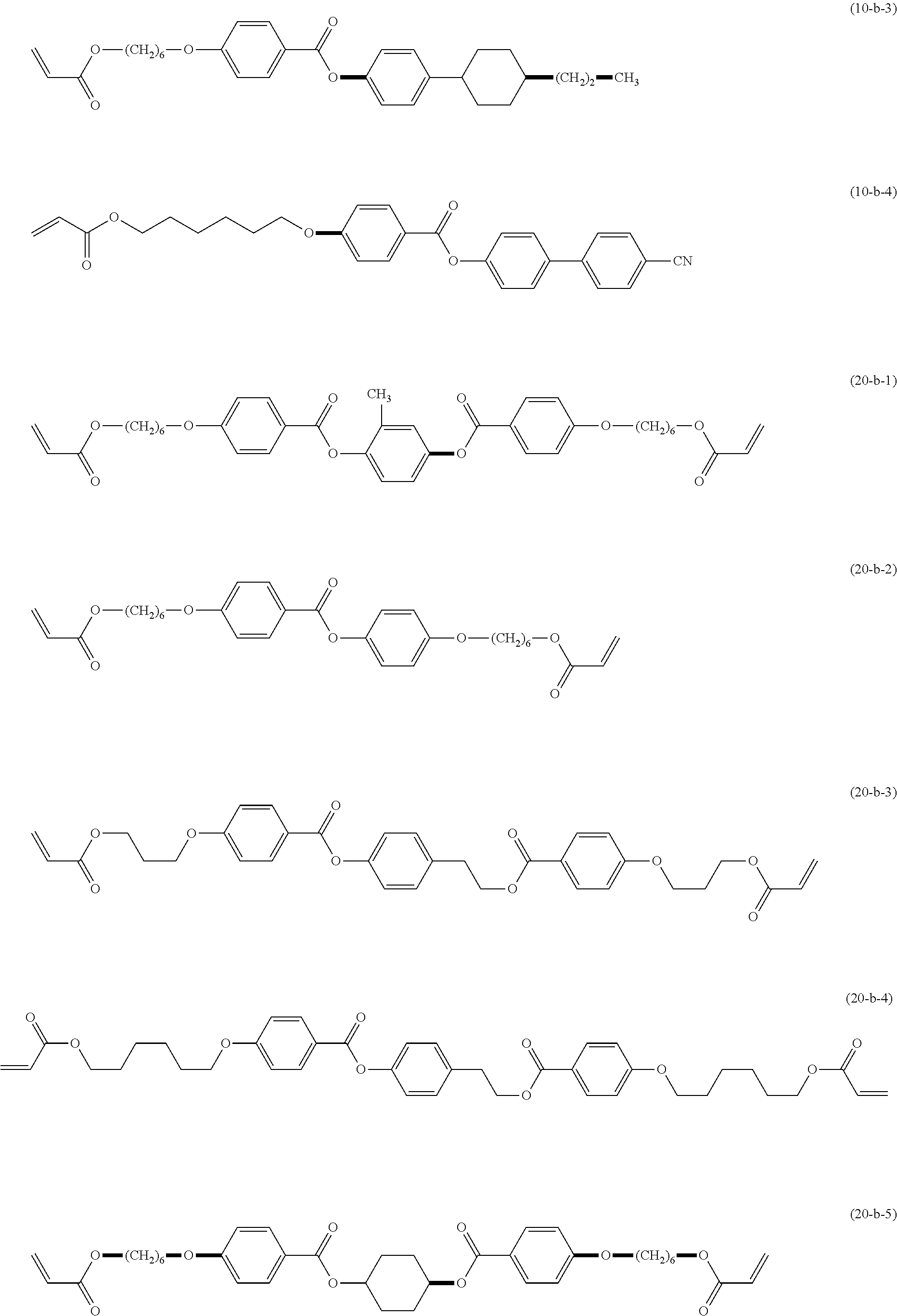

The Re(450 nm)/Re(550 nm) of each of the above compounds is as follows. Formula (30-a-1): 0.82, formula (30-a-2): 0.81, formula (30-a-3): 0.82, formula (30-a-4): 0.82, formula (30-a-5): 0.83, formula (30-a-6): 0.84, formula (30-a-7): 0.84, formula (30-a-8): 0.85, formula (20-a-1): 0.83, formula (20-a-2): 0.80, formula (20-a-3): 0.75, formula (20-a-4): 0.72, formula (20-a-5): 0.84, formula (20-a-6): 0.77, formula (20-a-7): 0.86, formula (20-a-8): 0.83, formula (10-b-1): 1.10, formula (10-b-2): 1.08, formula (10-b-3): 1.09, formula (10-b-4): 1.15, formula (20-b-1): 1.13, formula (20-b-2): 1.12, formula (20-b-3): 1.12, formula (20-b-4): 1.12.

### (Production of Positive a Retardation Films)

Retardation films (A1) to (A21) were produced using the polymerizable compositions (1) to (21) under the following conditions.

A Z-TAC substrate (manufactured by Fujifilm Corporation) was spin-coated with a 3% polyvinyl alcohol solution (a solution mixture of pure water and ethanol at a weight rate of 1:1 was used as the solvent), and the solution was dried at 120° C. for 5 minutes and subjected to rubbing treatment using a rayon cloth. One of the polymerizable compositions (1) to (21) was applied to the PVA film using a spin coater such that the retardation at 550 nm was adjusted to 138±5 nm and then dried at 80° C. for 3 minutes. The obtained coating of the polymerizable composition was irradiated with UV rays including UVB with an energy of 1 J/cm² to thereby obtain a thin retardation film.

The value of Re(450 nm)/Re(550 nm) of each of the retardation films is shown in Table 5 (where Re(450) represents an in-plane retardation at a wavelength of 450 nm, and Re(550) represents an in-plane retardation at a wavelength of 550 nm)). The value of Re(450 nm)/Re(550 nm) was measured using a retardation measurement device RETS-100 (manufactured by Otsuka Electronics Co., Ltd.).

TABLE 5

| Retardation film | Polymerizable composition | Re(450 nm)/Re(550 nm) |
|---|---|---|
| A1 | (1) | 0.851 |
| A2 | (2) | 0.850 |
| A3 | (3) | 0.837 |
| A4 | (4) | 0.841 |
| A5 | (5) | 0.836 |
| A6 | (6) | 0.847 |
| A7 | (7) | 0.823 |
| A8 | (8) | 0.838 |
| A9 | (9) | 0.851 |
| A10 | (10) | 0.842 |
| A11 | (11) | 0.835 |
| A12 | (12) | 0.835 |
| A13 | (13) | 0.833 |
| A14 | (14) | 0.838 |
| A15 | (15) | 0.835 |
| A16 | (16) | 0.845 |
| A17 | (17) | 0.853 |
| A18 | (18) | 0.852 |
| A19 | (19) | 0.858 |
| A20 | (20) | 0.863 |
| A21 | (21) | 0.851 |
| A41 | (41) | 0.830 |
| A42 | (42) | 0.859 |
| A43 | (43) | 0.853 |
| A44 | (44) | 0.849 |
| A45 | (45) | 0.860 |
| A46 | (46) | 0.861 |

### <Production of Second Retardation Layer (Second Retardation Film)>

### (Production of Positive C Retardation Films)

One of polymerizable compositions (31) and (32) was applied to a TAC substrate (manufactured by Fujifilm Corporation) using a spin coater such that the retardation Rth at 550 nm was adjusted to 90±10 nm, then dried at 60° C. for 3 minutes, and cooled at room temperature for 1 min. The obtained coating of the polymerizable composition was irradiated with UV rays including UVB with an energy of 1 J/cm² to thereby obtain one of retardation films (C1) and (C2). The characteristics of each of the obtained positive C retardation films are shown in Table 6.

TABLE 6

| Retardation film | Polymerizable composition | Re (550 nm) | Rth (50 nm) |
|---|---|---|---|
| C1 | (31) | 1 | 85 |
| C2 | (32) | 2 | 95 |

### (Production of Circularly Polarizing Plates)

One of the above positive A retardation plates and one of the positive C retardation plates were laminated in this order on a commercial polarizing plate to produce one of circularly polarizing plates in Examples (1) to (23) and Comparative Examples (1) to (6) shown in Table 7.

Each of the circularly polarizing plates produced by the method described above was used to evaluate its viewability according to evaluation criteria below.

### (Viewability Evaluation)

### (Color Tone)

Color tone was evaluated as follows. Instead of a circularly polarizing plate used in a SAMSUNG GALAXY SII equipped with an organic EL panel, one of the circularly polarizing plates was laminated, and the tones of black color when the circularly polarizing plate was viewed from the front and at an angle of 45° were evaluated according to the following criteria.

A: Almost no coloration of reflected light is visually observed (allowable).

B: Negligible coloration of the reflected light is visually observed but causes no practical problem (allowable).

C: Slight coloration of the reflected light is visually observed but causes no practical problem (allowable).

D: Coloration of the reflected light is visually observed but is allowable for some applications (allowable)

E: Strong coloration of the reflected light is visually observed and is not allowable.

Each of the circularly polarizing plates used was left to stand in a thermostatic bath at 80° C. for 500 hours, and then the color tones were evaluated according to the same criteria. The results are shown in Table 7.

TABLE 7

| | | | | | | After left to | After left to |
|---|---|---|---|---|---|---|---|
| | Circularly | Positive A | Positive C | | | stand at high | stand at high |
| | polarizing | retardation | retardation | Initial | Initial | temperature | temperature |
| | plate | plate | plate | Front | 45° | Front | 45° |
| Example 1 | (P1) | A1 | C1 | A | A | A | B |
| Example 2 | (P2) | A2 | C1 | A | A | A | A |
| Example 3 | (P3) | A3 | C1 | A | A | A | B |
| Example 4 | (P4) | A4 | C1 | A | A | A | A |
| Example 5 | (P5) | A5 | C1 | A | A | A | A |
| Example 6 | (P6) | A6 | C1 | A | A | A | A |
| Example 7 | (P7) | A6 | C2 | A | A | A | A |
| Example 8 | (P8) | A7 | C1 | A | A | A | A |
| Example 9 | (P9) | A8 | C1 | A | A | A | A |
| Example 10 | (P10) | A9 | C1 | A | A | A | A |
| Example 11 | (P11) | A10 | C1 | A | A | A | A |
| Example 12 | (P12) | A11 | C1 | A | A | A | A |
| Example 13 | (P13) | A12 | C1 | A | A | A | A |
| Example 14 | (P14) | A13 | C1 | A | A | A | A |
| Example 15 | (P15) | A14 | C1 | A | A | A | B |
| Example 16 | (P16) | A15 | C1 | A | A | A | A |
| Example 17 | (P17) | A16 | C1 | A | A | A | A |
| Example 18 | (P18) | A17 | C1 | A | A | A | A |
| Example 19 | (P19) | A18 | C1 | A | A | A | A |
| Example 20 | (P20) | A19 | C1 | A | B | A | C |
| Example 21 | (P21) | A20 | C1 | A | B | A | C |
| Example 22 | (P22) | A21 | C1 | A | B | A | C |
| Comparative | (P23) | A41 | C1 | A | A | E | E |
| Example 1 | | | | | | | |
| Comparative | (P24) | A42 | C1 | A | A | E | E |
| Example 2 | | | | | | | |
| Comparative | (P25) | A43 | C1 | A | A | E | E |
| Example 3 | | | | | | | |
| Comparative | (P26) | A44 | C1 | A | A | E | E |
| Example 4 | | | | | | | |
| Comparative | (P27) | A45 | C1 | A | A | E | E |
| Example 5 | | | | | | | |
| Comparative | (P28) | A46 | C1 | A | A | E | E |
| Example 6 | | | | | | | |

As can be seen from the above results, in each of the circularly polarizing plates obtained in Examples 1 to 22 according to the present invention, the change in color tone after the circularly polarizing plate was left to stand at high temperature was in an allowable range. However, in each of the circularly polarizing plates in Comparative Examples 1 to 6 in which the first retardation layer contained no compound A, the coloration after the circularly polarizing plate was left to stand at high temperature was at a non-allowable level.

1. An optical film comprising: a first retardation layer; and a second retardation layer,
wherein the first retardation layer is formed of a cured product of a polymerizable composition containing at least one compound A having at least three polymerizable groups and satisfying (formula 1) below and at least one compound B satisfying (formula 2) below,
wherein the second retardation layer is formed of a cured product of a polymerizable composition containing at least one compound satisfying (formula 1) below and/or at least one compound B satisfying (formula 2) below:
Re(450)/Re(550)<1, (formula 1)
Re(450)/Re(550)>1, (formula 2)
(wherein Re(450) represents an in-plane retardation at a wavelength of 450 nm when a compound used is formed into a film, and Re(550) represents an in-plane retardation at a wavelength of 550 run when the compound used is formed into the film), and
wherein the first retardation layer satisfies nx>ny≅nz, and the second retardation layer satisfies nx≅ny<nz (where nz represents a refractive index in a thickness direction; nx represents an in-plane refractive index in an in-plane direction in which the in-plane refractive index is maximum; and ny represents an in-plane refractive index in an in-plane direction orthogonal to the direction for nx).

2. The optical film according to claim 1,
wherein the compound A is a compound represented by general formula (9):
P⁹¹\S⁹¹—X⁹¹ₘ₉MG⁹¹\X⁹²—S⁹²ₙ₉P⁹² (9)
(wherein P⁹¹ and P⁹² each independently represent a polymerizable group;
S⁹¹ and S⁹² each independently represent a spacer group or a single bond; when a plurality of S⁹¹s and S⁹² are present, they may be the same or different;
X⁹¹ and X⁹² each independently represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that P⁹¹—(S⁹¹—X⁹¹)— and P⁹²—(S⁹²—X⁹²)— contain no —O—O— bond); when a plurality of X⁹¹s and X⁹²s are present, they may be the same or different;
m9 and n9 each independently represent an integer from 0 to 5;
MG⁹¹ represents general formula (a9): 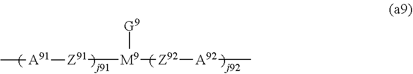
(in general formula (a9), A⁹¹ and A⁹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, each of which may be unsubstituted or substituted by at least one L¹; when a plurality of A⁹¹s and/or A⁹²s are present, they may be the same or different;
in general formula (a9), Z⁹¹ and Z⁹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond; when a plurality of Z⁹¹s and/or Z⁹²s are present, they may be the same or different;
in general formula (a9), M⁹ represents a group selected from formula (M-91) to formula (M-101) below: 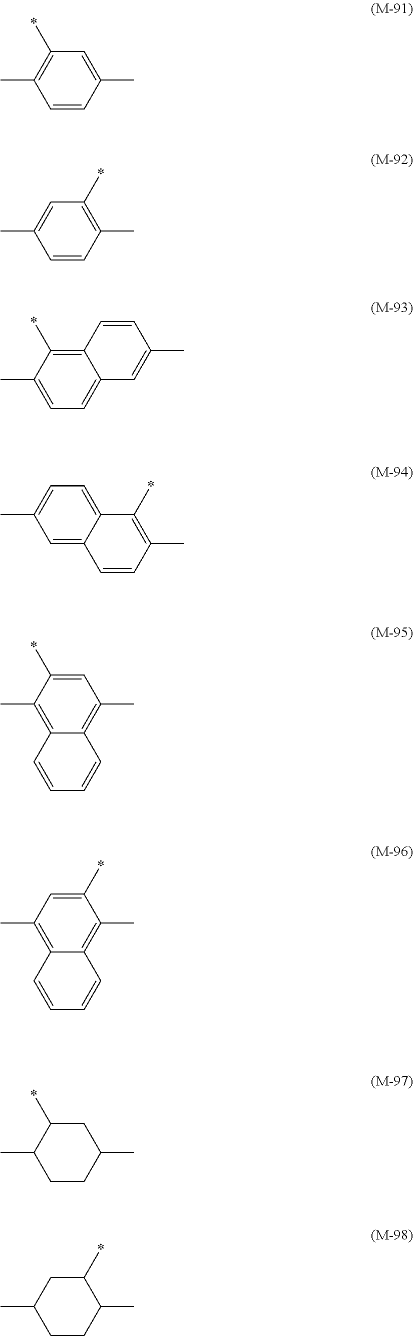 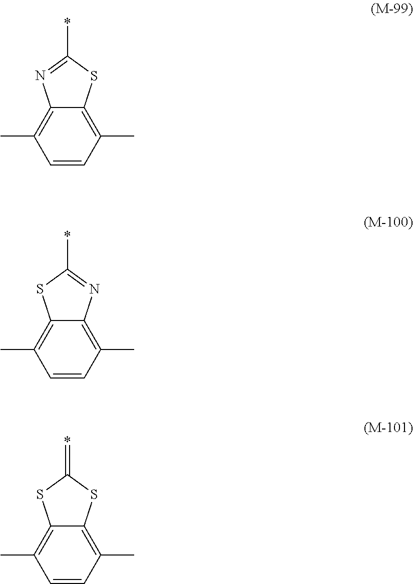
the groups represented by formula (M-91) to formula (M-101) may be unsubstituted or substituted by at least one L¹;
in general formula (a9), G⁹ represents a group selected from general formula (G-91) to general formula (G-95) below: 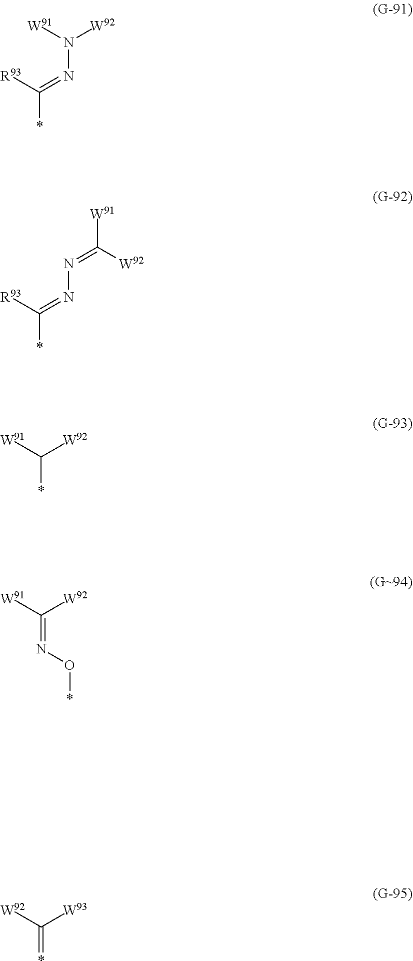
(wherein R⁹³ represents a hydrogen atom or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by —O—, —S—, —CO—, —COO—, —OCO—, —CO—S—, —S—CO—, —O—CO—O—, —CO—NH—, —NH—CO—, or —C≡C—;
W⁹¹ represents a group that has at least one aromatic group and has 5 to 30 carbon atoms and that may be unsubstituted or substituted by at least one L¹;
W⁹² represents a group represented by P⁹³—(S⁹³—X⁹³)ⱼ₉₃—; P⁴³ represents a polymerizable group; S⁹³ represents a spacer group or a single bond; when a plurality of S⁹³s are present, they may be the same or different; X⁹³ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that P⁴³—(S⁹³—X⁹³)ⱼ₉₃— contains no —O—O— bond); when a plurality of X⁹³s are present, they may be the same or different; j93 represents an integer from 1 to 10;
W⁹³ represents a halogen atom, a cyano group, a hydroxy group, a nitro group, a carboxyl group, a carbamoyloxy group, an amino group, a sulfamoyl group, a group having at least one aromatic group and having 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— group or two or more nonadjacent —CH₂— groups in each of the alkyl group, the cycloalkyl group, the alkenyl group, the cycloalkenyl group, the alkoxy group, the acyloxy group, and the alkylcarbonyloxy group being each independently optionally replaced by —O—, —S—, —CO—, —COO—, —OCO—, —CO—S—, —S—CO—, —O—CO—O—, —CO—NH—, —NH—CO—, or —C≡C—);
when M⁹ is selected from formula (M-91) to formula (M-100), G⁹ is selected from formula (G-91) to formula (G-94): when M⁹ represents formula (M-101), G⁹ represents formula (G-95); * in each of M⁹ and G⁹ represents a bonding portion; one of two bonds in M⁹ other than * is bonded to Z⁹¹ or A⁹¹ present; the other one of the two bonds is bonded to Z⁹² or A⁹² present;
L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C≡C—; when a plurality of L's are present in the compound, they may be the same or different;
j91, and j92 each independently represent an integer from 1 to 5; and j91+j92 represents an integer from 2 to 6)).

3. The optical film according to claim 1,
wherein the compound B satisfying (formula 2) and used for the second retardation layer includes a compound represented by general formula (1-b) and/or a compound represented by general formula (2-b): 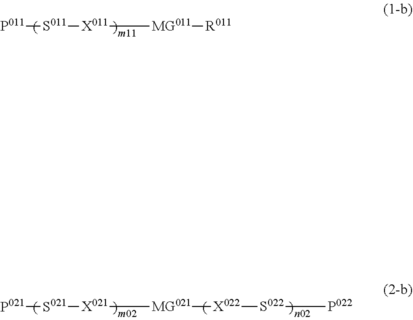
(wherein P⁰¹¹, P⁰²¹, and P⁰²² each independently represent a polymerizable group;
S⁰¹, S⁰²¹, and S⁰²² each independently represent a spacer group or a single bond; when a plurality of S⁰¹¹s, S⁰²¹s, and S⁰²²s are present, they may be the same or different;
X⁰¹¹, X⁰²¹, and X⁰²² each independently represent —O—, —S—, —OCH₂—, —CH_{z}O—, —CO—, —COO—, —OCO—, —CO—S—, —S—CO—, —O—CO—O—, —CO—NH—, —NH—CO—, —SCH₂, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂COO—, —CH₂—OCO—, —CH═CH—, —N═N—, —CH═N—N—CH—, —CF═CF—, —C≡C—, or a single bond (provided that each P—(S—X)— bond contains no —O—O—); when a plurality of X⁰¹¹s, X^{O21}s, and X⁰²²s are present, they may be the same or different;
m11 represents an integer of 0 to 8;
m02 and n02 each independently represent an integer from 0 to 5;
R⁰¹¹ represents a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by —O—, —S—, —CO—, —COO—, —OCO—, —CO—S—, —S—CO—, —O—CO—O—, —CO—NH—, —NH—CO—, or —C≡C—;
MG⁰¹¹ and MG⁰²¹ each independently represent formula (b): 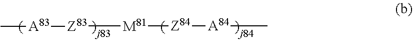
(in formula (b), A⁸³ and A⁸⁴ each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, each of which may be unsubstituted or substituted by at least one L²; when a plurality of A⁸³s and/or A⁸⁴s are present, they may be the same or different;
in formula (b), Z⁸³ and Z⁸⁴ each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond; when a plurality of Z⁸³s and/or Z⁸⁴s are present, they may be the same or different;
in formula (b), M⁸¹ represents a group selected from a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-tetrahydronaphthalene-2,6-diyl group, a naphthylene-1,4-diyl group, a naphthylene-1,5-diyl group, a naphthylene-1,6-diyl group, a naphthylene-2,6-diyl group, a phenanthrene-2,7-diyl group, a 9,10-dihydrophenanthrene-2,7-diyl group, a 1,2,3,4,4a,9,10a-octahydrophenanthrene-2,7-diyl group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, and a fluorene-2,7-diyl group, each of which may be unsubstituted or substituted by at least one L²;
in formula (b), L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, the alkyl group being linear or branched, any hydrogen atom in the alkyl group being optionally replaced by a fluorine atom, one —CH₂— group or two or more nonadjacent —CH₂— groups in the alkyl group being each independently optionally replaced by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C≡C—; when a plurality of L²s are present in the compound, they may be the same or different;
in formula (b), j83 and j84 each independently represent an integer from 0 to 5; and j83+j84 represents an integer from 1 to 5)).

4. An elliptically polarizing plate comprising: the optical film according to claim 1; and a polarizing plate laminated onto the optical film.

5. A display device comprising the optical film according to claim 1.

6. A display device comprising the elliptically polarizing plate according to claim 4.

7. An organic light-emitting display device comprising the elliptically polarizing plate according to claim 4.
